(19) United States
(12) Patent Application Publication
(10) Pub. No.: US 2014/0234759 A1
(43) Pub. Date: Aug. 21, 2014

(54) ACTINIC RAY- OR RADIATION-SENSITIVE RESIN COMPOSITION, ACTINIC RAY- OR RADIATION-SENSITIVE FILM AND METHOD OF FORMING PATTERN

(71) Applicant: FUJIFILM Corporation, Tokyo (JP)

(72) Inventors: Shohei KATAOKA, Shizuoka (JP); Akinori SHIBUYA, Shizuoka (JP); Junichi ITO, Shizuoka (JP); Tomoki MATSUDA, Shizuoka (JP); Toshiaki FUKUHARA, Shizuoka (JP); Naohiro TANGO, Shizuoka (JP); Kaoru IWATO, Shizuoka (JP); Masahiro YOSHIDOME, Shizuoka (JP); Shinichi SUGIYAMA, Shizuoka (JP); Yoko TOKUGAWA, Shizuoka (JP)

(73) Assignee: FUJIFILM Corporation, Tokyo (JP)

(21) Appl. No.: 14/229,240

(22) Filed: Mar. 28, 2014

Related U.S. Application Data
(63) Continuation of application No. PCT/JP2012/075738, filed on Sep. 27, 2012.
(60) Provisional application No. 61/543,527, filed on Oct. 5, 2011.

(30) Foreign Application Priority Data
Sep. 30, 2011 (JP) 2011-218278

(51) Int. Cl. G03F 7/038

(52) U.S. Cl. CPC G03F 7/038
USPC 430/9; 430/270.1; 430/325; 549/237; 549/233; 549/235; 549/240; 549/231; 549/232

(57) ABSTRACT

According to one embodiment, there is provided an actinic ray- or radiation-sensitive resin composition containing
(A) a resin containing a repeating unit represented by general formula (1) below and a repeating unit that is decomposed by an action of an acid to generate an alkali-soluble group, and
(B) a compound that generates the acid when exposed to actinic rays or radiation,

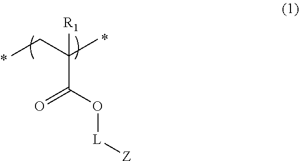

where
L represents a bivalent connecting group,
R₁ represents a hydrogen atom or an alkyl group, and
Z represents a cyclic acid anhydride structure.

### CROSS-REFERENCE TO RELATED APPLICATIONS

This application is a Continuation application of PCT Application No. PCT/JP2012/075738, filed Sep. 27, 2012 and based upon and claims the benefit of priority from prior Japanese Patent Application No. 2011-218278, filed Sep. 30, 2011; and U.S. Provisional Application No. 61/543,527, filed Oct. 5, 2011, the entire contents of all of which are incorporated herein by reference.

### BACKGROUND OF THE INVENTION

1. Field of the Invention

The present invention relates to an actinic ray- or radiation-sensitive resin composition, an actinic ray- or radiation-sensitive film and a method of forming a pattern using the same. The present invention relates to, for example, an actinic ray- or radiation-sensitive resin composition, an actinic ray- or radiation-sensitive film and a method of forming a pattern using the same that is suitable for use in an ultramicrolithography process applicable to a process for manufacturing a super-LSI or a high-capacity microchip, etc. and other photofabrication processes. More particularly, the present invention relates to an actinic ray- or radiation-sensitive resin composition, an actinic ray- or radiation-sensitive film and a method of forming a pattern using the same that is suitable for exposure by means of an ArF excimer laser as a light source.

2. Description of the Related Art

Since the emergence of the resist for a KrF excimer laser (248 nm), it has been of common practice to employ an image forming method in which chemical amplification is utilized in order to compensate for any sensitivity decrease caused by light absorption. For example in a positive chemical amplification method as an image forming method, first, a photoacid generator contained in exposed areas is decomposed by light irradiation using an excimer laser, electron beams, extreme ultraviolet rays, etc. to thereby generate an acid. Then, in the stage of, for example, the bake after the exposure (Post-Exposure Bake: PEB), the generated acid is utilized as a catalyst of reaction so that the alkali-insoluble group contained in the photosensitive composition is converted to an alkali-soluble group. Thereafter, the exposed areas are removed using an alkali solution.

In this method, when the solubility of exposed areas in the developer is poor, the pattern swells, thereby causing the problems of pattern collapse and line edge roughness. Compositions comprising a resin with an acid anhydride structure are preferable from the viewpoint of the solubility in the developer, since the acid anhydride is hydrolyzed by the alkali developer, thereby producing two carboxylic acids (see, for example, patent references 1 to 3). However, further improvements of the pattern collapse and line edge roughness are required for the compositions defined in the patent references 1 to 3.

### PRIOR ART REFERENCE

### Patent Reference

Patent reference 1: Jpn. Pat. Appln. KOKAI Publication No. (hereinafter referred to as JP-A-) 2007-31354,
Patent reference 2: Japanese Patent No. 4315756, and
Patent reference 3: Japanese Patent No. 4144957.

### BRIEF SUMMARY OF THE INVENTION

It is an object of the present invention to provide an actinic ray- or radiation-sensitive resin composition with which the pattern collapse can be inhibited and the line edge roughness can be improved. It is other objects of the present invention to provide an actinic ray- or radiation-sensitive film formed from the composition and a method of forming a pattern using the composition.

The present invention below is completed by the inventors as a result of their hard effort to resolve the problem above.

[1] An actinic ray- or radiation-sensitive resin composition comprising:

(A) a resin containing a repeating unit represented by general formula (1) below and a repeating unit that is decomposed by an action of an acid to generate an alkali-soluble group, and

(B) a compound that generates the acid when exposed to actinic rays or radiation,

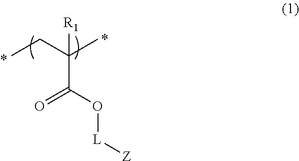

where

L represents a bivalent connecting group,

R₁ represents a hydrogen atom or an alkyl group, and

Z represents a cyclic acid anhydride structure.

[2] The actinic ray- or radiation-sensitive resin composition according to [1], wherein L in the general formula (1) contains at least one oxygen atom.

[3] The actinic ray- or radiation-sensitive resin composition according to [1] or [2], wherein Z in the general formula (1) contains a polycyclic structure.

[4] The actinic ray- or radiation-sensitive resin composition according to [3], wherein Z in the general formula (1) is represented by general formula (2) below,

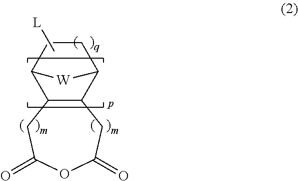

where

L is L of general formula (1) above,

W is absent or represents a methylene group, an ethylene group, an oxygen atom or a sulfur atom,

p represents an integer of 1 or greater,

q represents an integer of 0 to 2, and

each m independently represents an integer of 0 to 2.

[5] The actinic ray- or radiation-sensitive resin composition according to [4], wherein Z in the general formula (1) is represented by general formula (3) below,

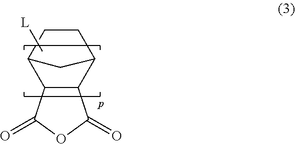

where

L is L of general formula (1) above, and

p is 1 or 2.

[6] The actinic ray- or radiation-sensitive resin composition according to any one of [1] to [5], wherein the resin (A) contains the repeating unit represented by the general formula (1) in an amount of 5 to 50 mol % and the repeating unit that is decomposed by an action of an acid to generate an alkali-soluble group in an amount of 30 to 70 mol %.

[7] An actinic ray- or radiation-sensitive film comprising the actinic ray- or radiation-sensitive resin composition according to any one of [1] to [6].

[8] A method of forming a pattern, comprising:

forming an actinic ray- or radiation-sensitive film containing the actinic ray- or radiation-sensitive resin composition according to any one of [1] to [6],

exposing the film to the actinic rays or radiation, and

developing the exposed film.

[9] A process for manufacturing an electronic device comprising the method according to [8].

[10] An electronic device manufactured by the process according to [9].

[11] A compound represented by general formula (4) below,

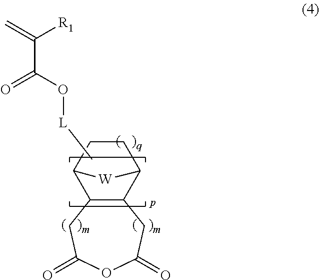

where

L represents a bivalent connecting group,

R₁ represents a hydrogen atom or an alkyl group,

W is absent or represents a methylene group, an ethylene group, an oxygen atom or a sulfur atom,

p represents an integer of 1 or greater,

q represents an integer of 0 to 2, and

each m independently represents an integer of 0 to 2.

The present invention has made it feasible to provide an actinic ray- or radiation-sensitive resin composition with which the pattern collapse can be inhibited and the line edge roughness can be improved. The present invention has also made it feasible to provide an actinic ray- or radiation-sensitive film formed from the composition and a method of forming a pattern using the composition.

### DETAILED DESCRIPTION OF THE INVENTION

Embodiments of the present invention will be described below in detail.

With respect to the expression of a group and atomic group used in this specification, the expression even when there is no mention of “substituted and unsubstituted” encompasses groups not only having no substituent but also having substituents. For example, the expression “alkyl groups” which is not shown to be substituted or unsubstituted encompasses not only alkyls having no substituent (unsubstituted alkyls) but also alkyls having substituents (substituted alkyls).

In the present invention, the terms “actinic rays” and “radiation” mean, for example, brightline spectra from a mercury lamp, far ultraviolet represented by excimer laser, extreme ultraviolet (EUV light), X-rays, electron beams (EB) and the like. In the present invention, the term “light” means actinic rays or radiation.

In the present invention, the term “exposure”, unless otherwise noted, means not only light irradiation using a mercury lamp, far ultraviolet represented by excimer laser, X-rays, EUV light, etc. but also lithography using particle beams, such as an electron beam and an ion beam.

The actinic ray- or radiation-sensitive resin composition according to the present invention includes (A) a resin containing a repeating unit represented by general formula (1) to be described below and a repeating unit that is decomposed by an action of an acid to generate an alkali-soluble group (hereinafter also referred to as a resin (A)), and (B) a compound that generates the acid when exposed to actinic rays or radiation (hereinafter also referred to as a compound (Z)).

The inventors have found that the pattern collapse can be inhibited and the line edge roughness can be improved by the use of the composition comprising any of repeating units of general formula (1) to be described below.

The above-mentioned various components will be described in sequence below.

[1] Resin (A)

(1) Repeating Unit Represented by General Formula (1)

The resin (A) in the actinic-ray- or radiation-sensitive resin composition of the present invention contains any of repeating units represented by general formula (1) below.

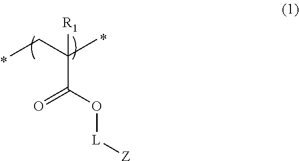

In general formula (1),

L represents a bivalent connecting group,

R₁ represents a hydrogen atom or an alkyl group, and

Z represents a cyclic acid anhydride structure.

A reason for the inhibition of pattern collapse and improvement of line edge roughness attained by the incorporation of any of repeating units of general formula (1) above in the actinic-ray- or radiation-sensitive resin composition of the present invention is presumably as follows.

Each of the repeating units of general formula (1) has a cyclic acid anhydride structure represented by Z. In this context, “a cyclic acid anhydride structure “means a structure in which a part of ring skeltons included in a mono- or poly-cyclic cycloalkyl group is substituted with —CO—O—CO—. The acid anhydride structure is hydrolyzed by a developer to generate two carboxylic acids, so that the solubility of the resin (A) in the developer can be increased. As a result, presumably, any pattern swell at the pattern formation can be inhibited, thereby attaining the inhibition of pattern collapse and improvement of line edge roughness.

Further, in the repeating units of general formula (1), the connecting group L lies between the principal chain and the protective group Z. The principal chain and the protective group Z being a moiety at which hydrolysis occurs can be set apart by the presence of the connecting group, so that these can be promptly hydrolyzed. As a result, presumably, a higher swell inhibiting effect can be exerted, thereby attaining the inhibition of pattern collapse and improvement of line edge roughness.

In general formula (1) above, it is preferable for the alkyl group represented by R₁ to be a linear, branched or cyclic alkyl group having 1 to 10 carbon atoms. A substituent may be introduced in the alkyl group represented by R₁. Preferable substituents are a hydroxyl group and a halogen atom. As the halogen atom, there can be mentioned a fluorine atom, a chlorine atom, a bromine atom or an iodine atom. Preferably, R₁ is a hydrogen atom, a methyl group, a hydroxymethyl group or a trifluoromethyl group. A hydrogen atom and a methyl group are most preferable.

L is not particularly limited as long as it is a bivalent connecting group. For example, an alkylene group, a cycloalkylene group, an arylene group, —O—, —S—, —C(═O)—, —SO₂—, —SO₃—, —N(Rd)- or a combination of these are exemplified. In the above formula, Rd represents a hydrogen atom or an alkylene group. Preferably, L represents an alkylene group, a cycloalkylene group, —O—, —C(═O)—, —NH— or a combination of these. More preferably, L represents a combination of an alkylene group and —O—, a combination of an alkylene group, —C(═O)— and —O—, or a combination of an alkylene group, —C(═O)— and —NH—. Still preferably, L represents a combination of an alkylene group and —O— or a combination of an alkylene group and —C(═O)—O—. When an alkylene group is included in L, the alkylene group in L is preferably connected with an oxygen atom in an ester group of the general formula (I) which is adjacent to L. A substituent may be introduced in the alkylene group, cycloalkylene group and arylene group. As the substituent, there can be mentioned, for example, an alkyl group, a cycloalkyl group, an alkoxy group, an alkoxycarbonyl group, —OH, —NH₂, —SO₂NH₂—, —N(Rd2)SO₂(Rd3). Rd2 and Rd3 are each independently a hydrogen atom or an alkyl group. An alkylene group may be a straight or branched, preferably it has 1 to 20 carbon atoms, more preferably it has 1 to 10 carbon atoms, and still preferably it has 1 to 5 carbon atoms. A cycloalkylene group has preferably 3 to 20 carbon atoms, more preferably 4 to 10 carbon atoms, and still preferably 5 to 7 carbon atoms as carbon atoms contained in a cyclic structure. Furthermore, L is most preferably a bivalent connecting group represented by —CH₂—COO—* (* represents a binding site to Z).

Z is preferably one having a polycyclic structure comprising a plurality of rings linked to each other. When Z has a polycyclic structure, the storage stability of the actinic-ray- or radiation-sensitive resin composition of the present invention at the storage of the composition in the state of being dissolved in a solvent is enhanced. The reason therefore is that in the polycyclic structure, the acid anhydride once hydrolyzed is returned to the original form by a ring closure reaction.

A substituent may be introduced in the carbon atoms constituting the cyclic acid anhydride structure represented by Z. The substituent is preferably a monovalent organic group. As the monovalent organic group, there can be mentioned an alkyl group, a cycloalkyl group, an alkoxy group, an alkoxycarbonyl group, —OH, —NH₂, —SO₂NH₂ and —N(Rd4)SO₂(Rd5). Rd4 and Rd5 are each independently a hydrogen atom or an alkyl group. The monovalent organic group is preferably an alkyl group, an alkoxy group or an alkoxycarbonyl group, more preferably an alkyl group. An alkyl group may be a straight or branched, preferably it has 1 to 20 carbon atoms, more preferably it has 1 to 10 carbon atoms, and still preferably it has 1 to 5 carbon atoms. The number of carbon atoms contained in the alkoxy group is preferably 1 to 10, more preferably 1 to 5 and still preferably 1 to 3. When a plurality of substituents are introduced in Z, the substituents may be linked to each other, thereby forming a ring. The number of substituents is preferably in the range of 0 to 4, more preferably 0 to 2.

Preferably, Z has a structure expressed by general formula (2) below.

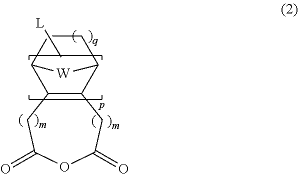

In general formula (2),

L is L of general formula (1) above,

W is absent or represents a methylene group, an ethylene group, an oxygen atom or a sulfur atom,

p represents an integer of 1 or greater,

q represents an integer of 0 to 2, and

each of m independently represents an integer of 0 to 2.

W is preferably a methylene group, an ethylene group or an oxygen atom, more preferably a methylene group or an oxygen atom. A methylene group is most preferable.

In the formula, p is preferably an integer of 1 or 2, more preferably 1.

It is preferable for each m to be 0.

In the formula, q is preferably 0 or 1.

Among the structures of general formula (2) above, the structures of general formula (3) below are preferable.

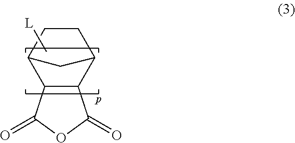

In general formula (3),

L is L of general formula (1) above, and

p is 1 or 2.

In general formula (2) and (3), L binds to any of carbon atoms forming the cyclic acid anhydride structure.

Nonlimiting particular examples of the repeating units with the structures of general formula (1) are shown below.

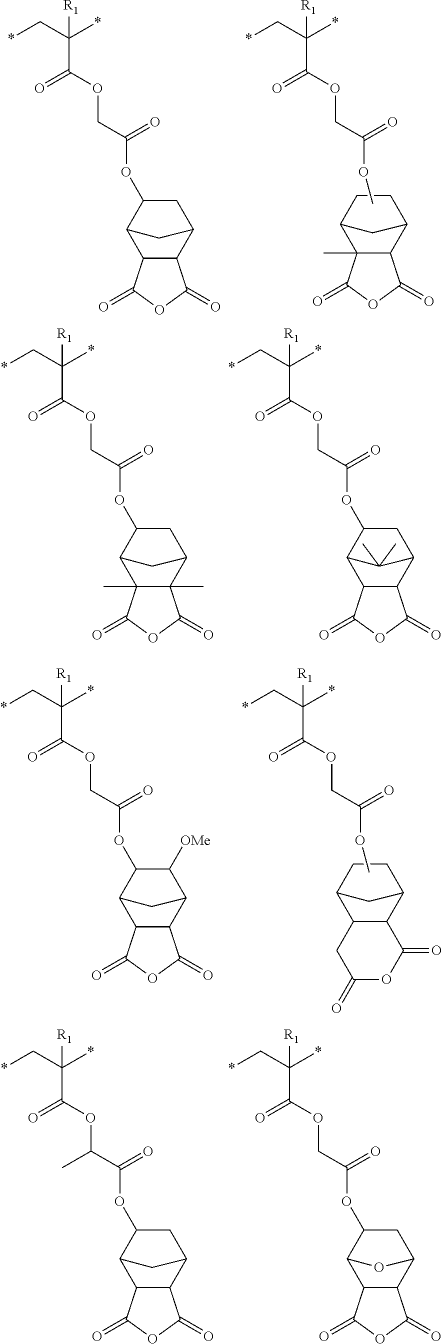

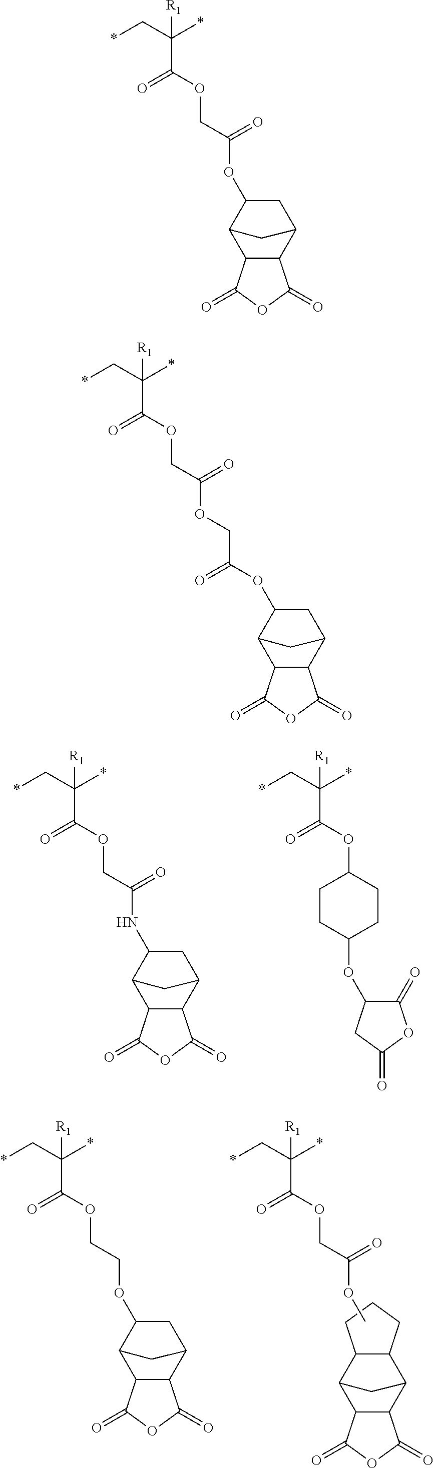

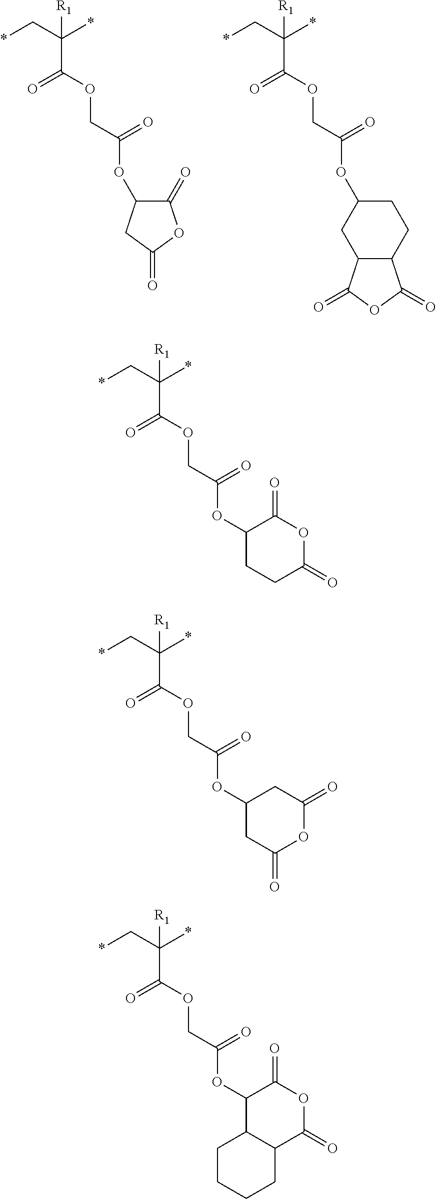

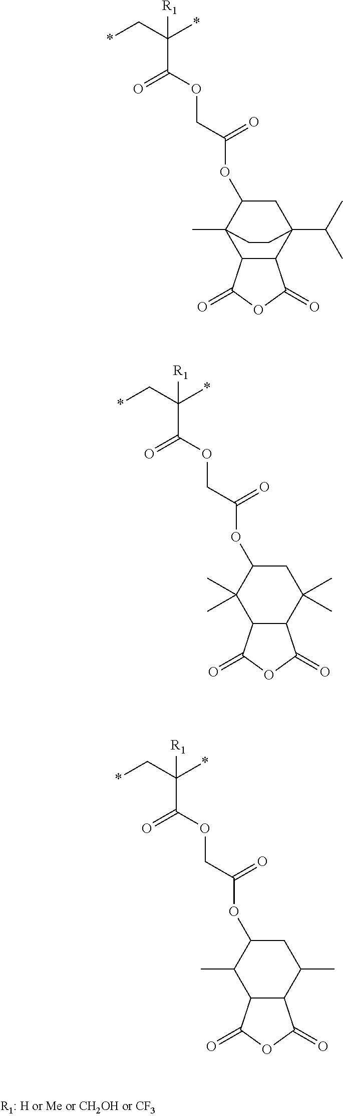

The content of repeating unit with any of the structures represented by general formula (1) based on all the repeating units of the resin (A) is preferably in the range of 15 to 50 mol %, more preferably 10 to 40 mol % and further more preferably 15 to 35 mol %.

(2) Repeating Unit that is Decomposed by an Action of an Acid to Generate an Alkali-Soluble Group

The resin (A) further comprises a repeating unit (s) that is decomposed by an action of an acid to generate an alkali-soluble group. The repeating unit (s) that is decomposed by an action of an acid to generate an alkali-soluble group (hereinafter also referred to as a repeating unit containing an acid-decomposable group) has a structure protected by a group that is decomposed by the action of an acid to thereby eliminate an alkali-soluble group.

As the alkali soluble group, there can be mentioned a phenolic hydroxyl group, a carboxyl group, a fluoroalcohol group, a sulfonate group, a sulfonamido group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group or the like.

As preferred alkali soluble groups, there can be mentioned a carboxyl group, a fluoroalcohol group (preferably hexafluoroisopropanol group) and a sulfonate group.

The acid-decomposable group is preferably a group as obtained by substituting the hydrogen atom of any of these alkali soluble groups with an acid eliminable group.

As the acid eliminable group, there can be mentioned, for example, —C(R₃₆)(R₃₇)(R₃₈), —C(R₃₆)(R₃₇)(OR₃₉), —C(R₀₁)(R₀₂)(OR₃₉) or the like.

In the formulae, each of R₃₆ to R₃₉ independently represents an alkyl group, a cycloalkyl group, an aryl group, an aralkyl group or an alkenyl group. R₃₆ and R₃₇ may be bonded with each other to thereby form a ring structure.

Each of R₀₁ and R₀₂ independently represents a hydrogen atom, an alkyl group, a cycloalkyl group, an aryl group, an aralkyl group or an alkenyl group.

Preferably, the acid-decomposable group is a cumyl ester group, an enol ester group, an acetal ester group, a tertiary alkyl ester group or the like. A tertiary alkyl ester group is more preferred.

The repeating unit with an acid-decomposable group is preferably any of those represented by general formula (AI) below.

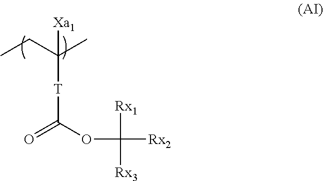

In general formula (AI),

Xa₁ represents a hydrogen atom, an optionally substituted methyl group or any of the groups of formula —CH₂—R₉. R₉ represents a hydroxyl group or a monovalent organic group. The monovalent organic group is, for example, an alkyl group having 5 or less carbon atoms or an acyl group having 5 or less carbon atoms. Preferably, the monovalent organic group is an alkyl group having 3 or less carbon atoms, more preferably a methyl group. Xa₁ preferably represents a hydrogen atom, a methyl group, a trifluoromethyl group or a hydroxymethyl group.

T represents a single bond or a bivalent connecting group.

Each of Rx₁ to Rx₃ independently represents an alkyl group (linear or branched) or a cycloalkyl group (monocyclic or polycyclic). At least two of Rx₁ to Rx₃ may be bonded with each other to thereby form a cycloalkyl group (monocyclic or polycyclic).

As the bivalent connecting group represented by T, there can be mentioned an alkylene group, a group of the formula —COO-Rt-, a group of the formula —O-Rt- or the like. In the formulae, Rt represents an alkylene group or a cycloalkylene group.

T is preferably a single bond or a group of the formula —COO-Rt-. Rt is preferably an alkylene group having 1 to 5 carbon atoms, more preferably a —CH₂— group, —(CH₂)₂— group or —(CH₂)₃— group.

The alkyl group represented by each of Rx₁ to Rx₃ is preferably one having 1 to 4 carbon atoms, such as a methyl group, an ethyl group, an n-propyl group, an isopropyl group, an n-butyl group, an isobutyl group or a t-butyl group.

The cycloalkyl group represented by each of Rx₁ to Rx₃ is preferably a cycloalkyl group of one ring, such as a cyclopentyl group or a cyclohexyl group, or a cycloalkyl group of multiple rings, such as a norbornyl group, a tetracyclodecanyl group, a tetracyclododecanyl group or an adamantyl group.

The cycloalkyl group formed by bonding of at least two of Rx₁ to Rx₃ is preferably a cycloalkyl group of one ring, such as a cyclopentyl group or a cyclohexyl group, or a cycloalkyl group of multiple rings, such as a norbornyl group, a tetracyclodecanyl group, a tetracyclododecanyl group or an adamantyl group. It is particularly preferable to be a cycloalkyl group of one ring having 5 or 6 carbon atoms.

In a preferred mode, Rx₁ is a methyl group or an ethyl group, and Rx₂ and Rx₃ are bonded with each other to thereby form any of the above-mentioned cycloalkyl groups.

Each of these groups may have a substituent. As the substituent, there can be mentioned, for example, an alkyl group (1 to 4 carbon atoms), a halogen atom, a hydroxyl group, an alkoxy group (1 to 4 carbon atoms), a carboxyl group, an alkoxycarbonyl group (2 to 6 carbon atoms) or the like. The number of carbon atoms of the substituent is preferably 8 or less.

The total content of the repeating units with acid-decomposable groups is preferably in the range of 30 to 70 mol %, more preferably 40 to 60 mol %, based on all the repeating units of the resin (A). It is even more preferable to be 45 to 55 mol %.

Specific examples of the preferred repeating units with acid-decomposable groups will be shown below, which however in no way limit the scope of the present invention.

In the following formulae, each of Rx and Xa₁ represents a hydrogen atom, CH₃, CF₃ or CH₂OH. Each of Rxa and Rxb represents an alkyl group having 1 to 4 carbon atoms. Z represents a substituent containing a polar group. When a plurality of Zs exist, they may be identical to or different from each other. p represents 0 or a positive integer. Particular examples and preferred example of Z are same as particular examples and preferred example of R₁₀ in general formula (II-1) to be described below.

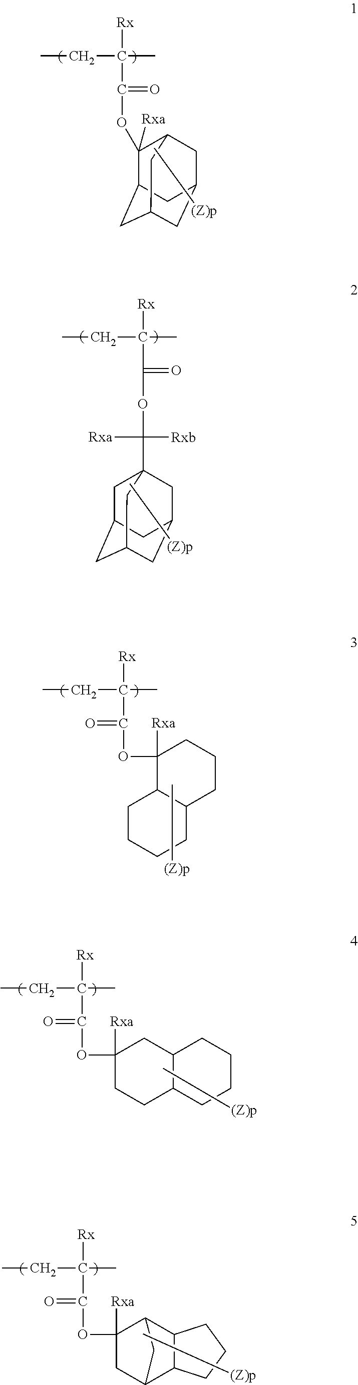

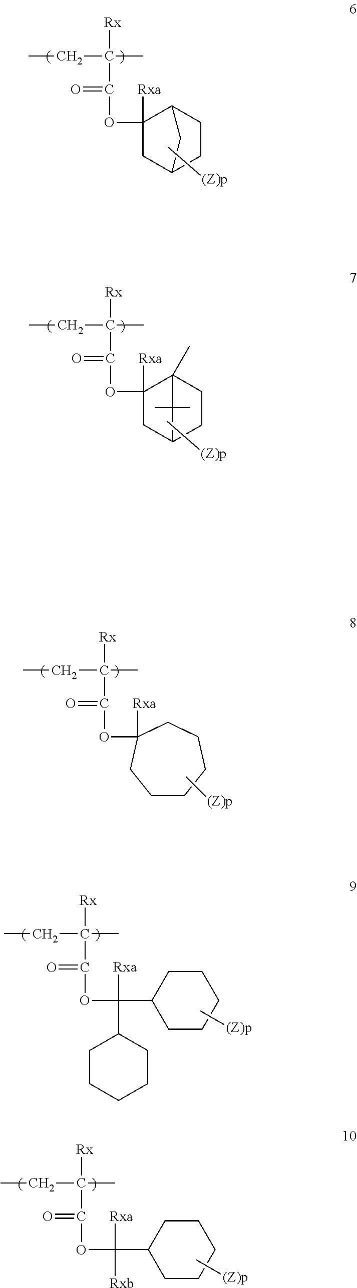

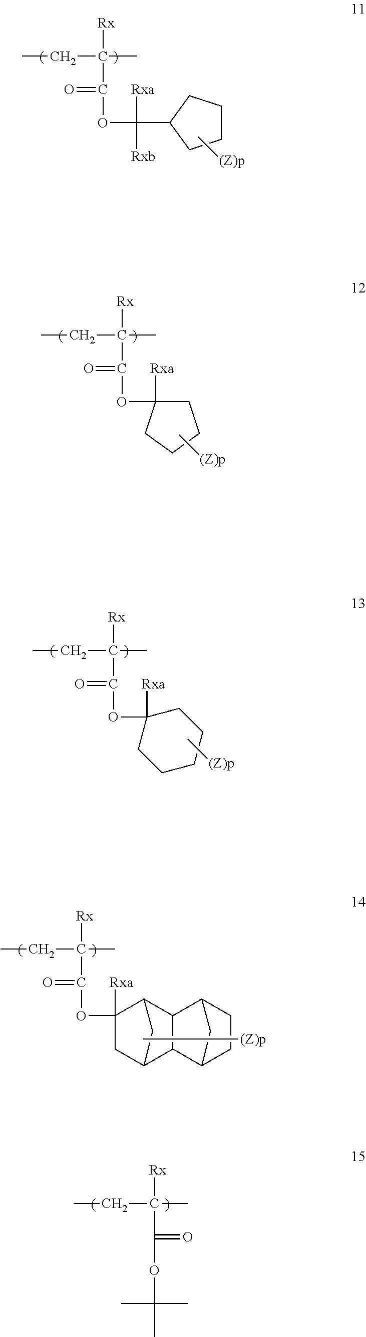

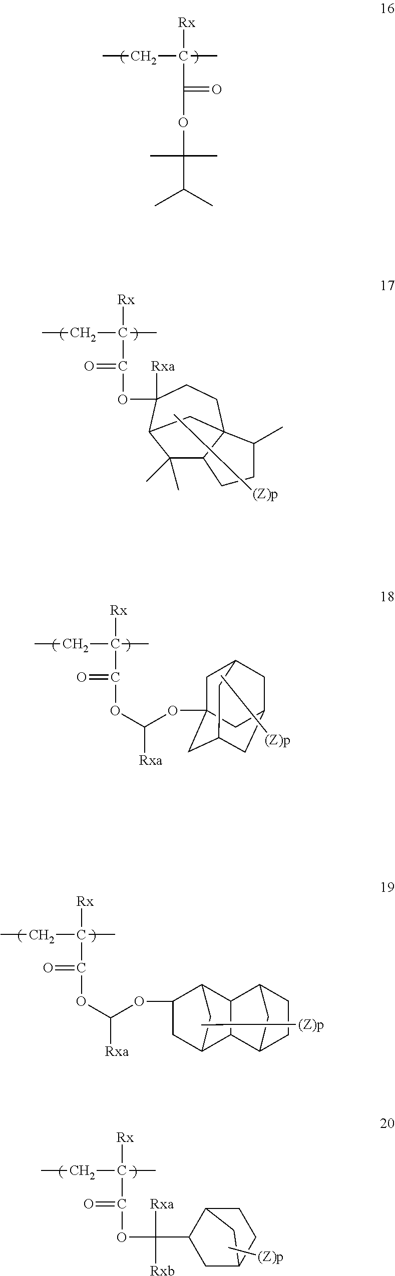

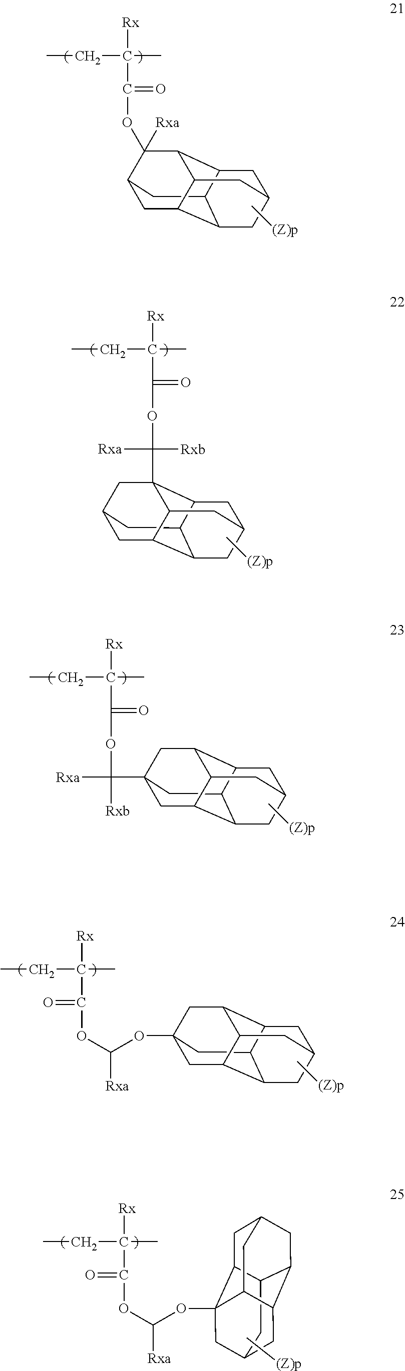

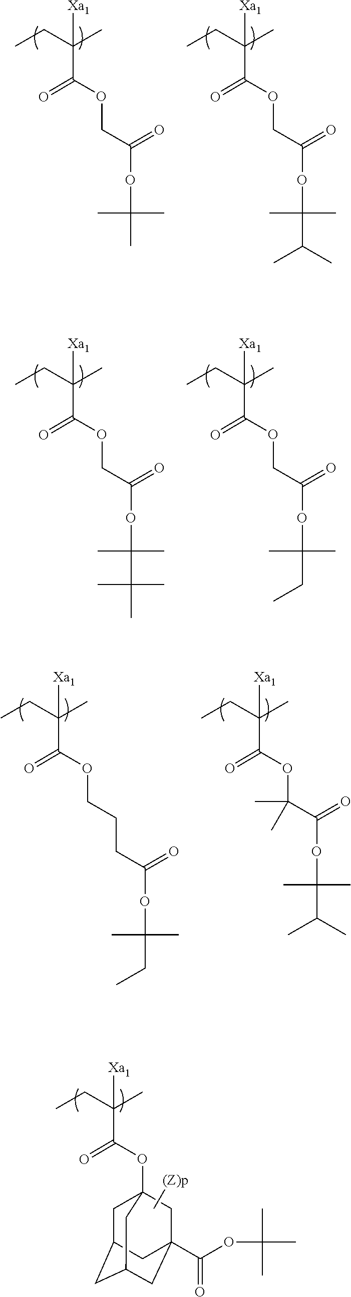

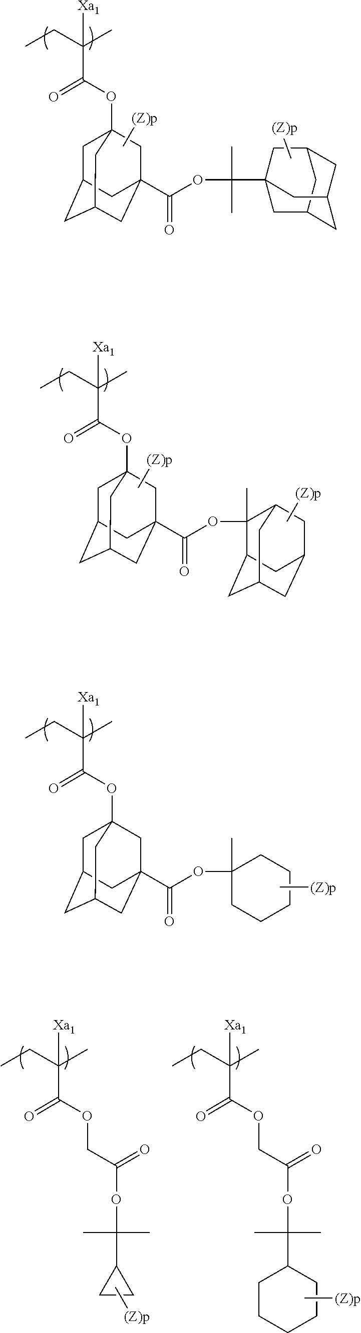

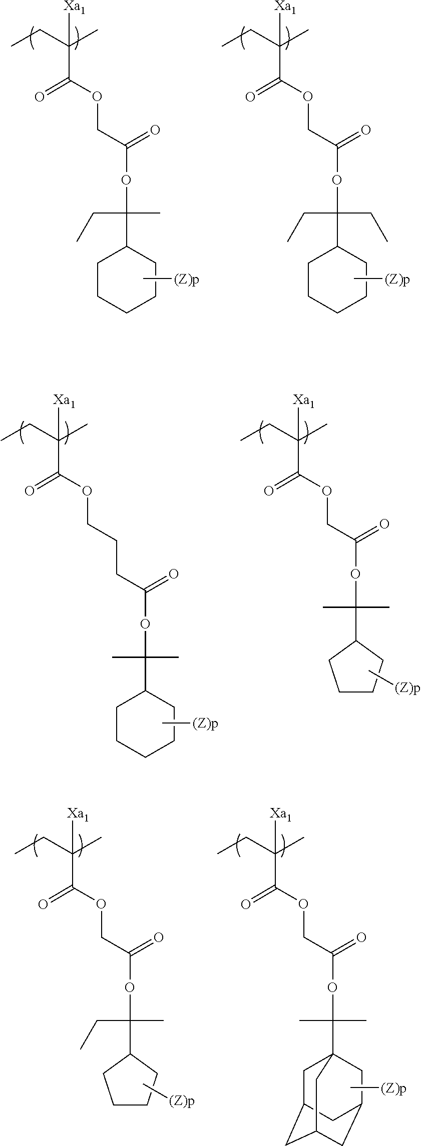

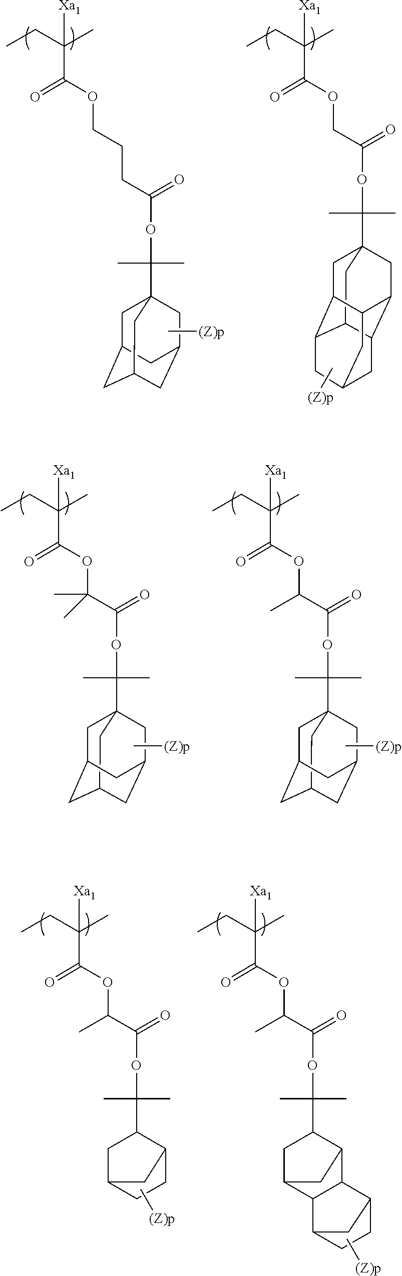

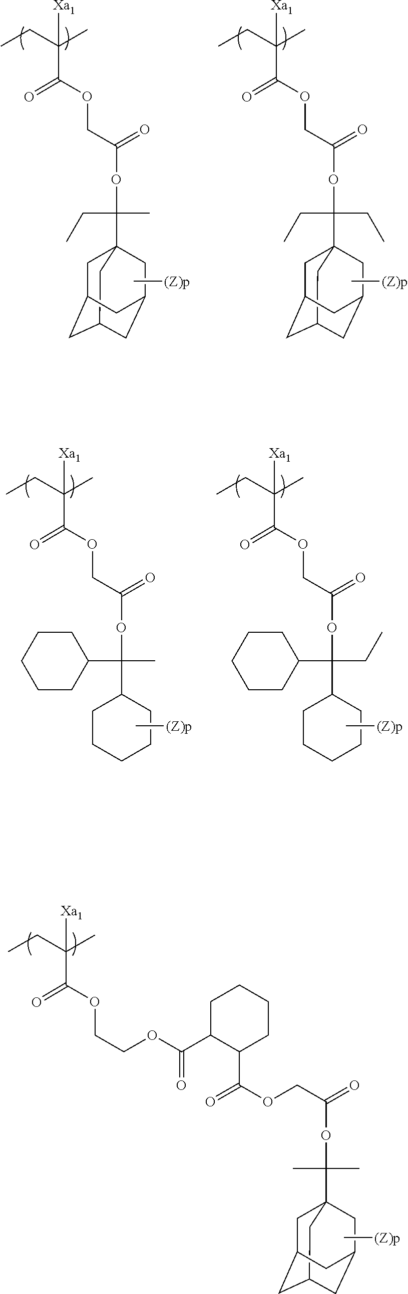

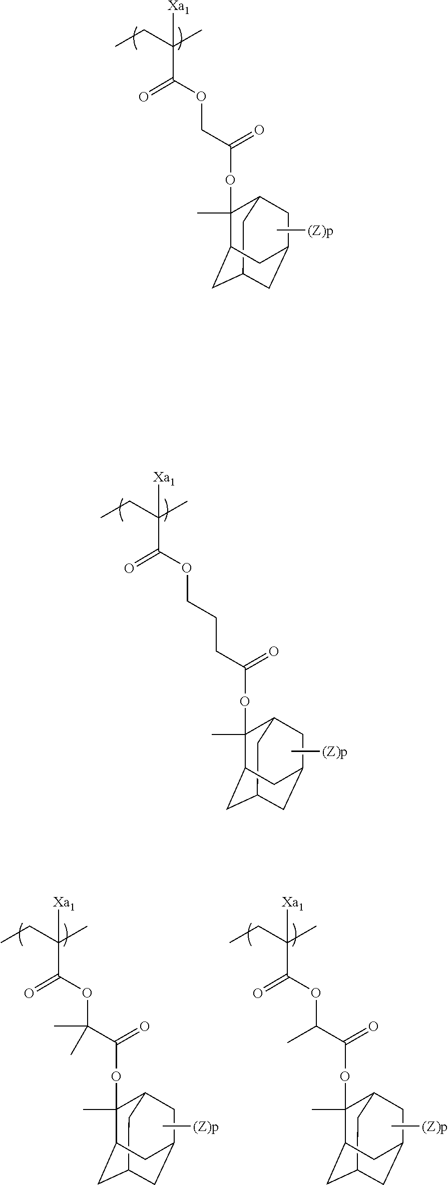

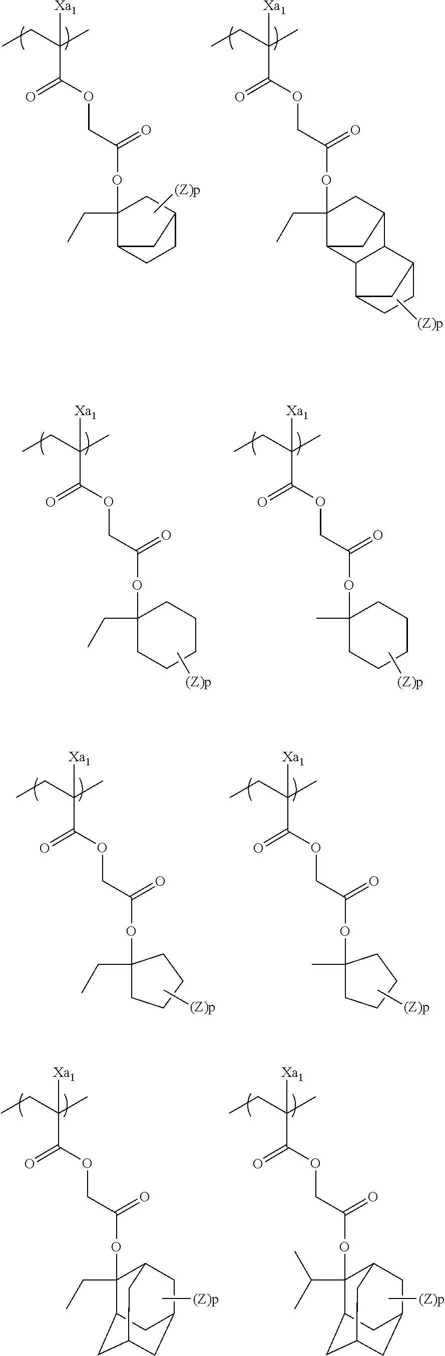

It is more preferred that the resin (A) contains at least either any of repeating units represented by general formula (I) below or any of repeating units represented by general formula (II) below as the repeating unit represented by general formula (AI).

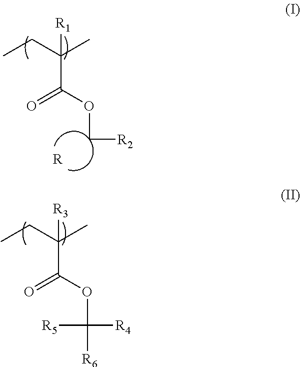

In general formulae (I) and (II),

each of R₁ and R₃ independently represents a hydrogen atom, an optionally substituted methyl group or any of the groups of formula —CH₂—R₉. R₉ represents a hydroxyl group or a monovalent organic group.

Each of R₂, R₄, R₅ and R₆ independently represents an alkyl group or a cycloalkyl group.

R represents an atomic group required for forming an alicyclic structure in cooperation with a carbon atom.

As a substituent can be present on methyl group represented by R₁ or R₃, a fluorine atom is examplefied.

R₁ and R₃ preferably represents a hydrogen atom, a methyl group, a trifluoromethyl group or a hydroxymethyl group. Particular examples and preferred examples of the monovalent organic group represented by R₉ are the same as those of R₉ in the general formula (AI).

The alkyl group represented by R₂ may be linear or branched, and may have a substituent.

The cycloalkyl group represented by R₂ may be monocyclic or polycyclic, and may have a substituent.

R₂ preferably represents an alkyl group, more preferably an alkyl group having 1 to 10 carbon atoms, especially 1 to 5 carbon atoms. As examples thereof, there can be mentioned a methyl group and an ethyl group.

R represents an atomic group required for forming an alicyclic structure together with a carbon atom. The alicyclic structure formed by R together with the carbon atom is preferably an alicyclic structure of a single ring, and preferably has 3 to 7 carbon atoms, more preferably 5 or 6 carbon atoms.

R₃ preferably represents a hydrogen atom or a methyl group, more preferably a methyl group.

Each of the alkyl groups represented by R₄, R₅ and R₆ may be linear or branched, and may have a substituent. The alkyl groups preferably are those each having 1 to 4 carbon atoms, such as a methyl group, an ethyl group, an n-propyl group, an isopropyl group, an n-butyl group, an isobutyl group and a t-butyl group.

Each of the cycloalkyl groups represented by R₄, R₅ and R₆ may be monocyclic or polycyclic, and may have a substituent. The cycloalkyl groups are preferably a cycloalkyl group of a single ring, such as a cyclopentyl group or a cyclohexyl group, and a cycloalkyl group of multiple rings, such as a norbornyl group, a tetracyclodecanyl group, a tetracyclododecanyl group or an adamantyl group.

Each of the alkyl groups or cycloalkyl groups represented by R₂, R₄, R₅ and R₆ may have a substituent. As such a substituent, there can be mentioned the group same as a substituent containing a polar group in R₁₀ of general formula (II-1) to be described below.

As the repeating units of general formula (I), there can be mentioned those of general formula (I-a) below, for example.

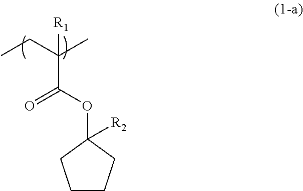

In general formula (I-a), R₁ and R₂ have the same meaning as in general formula (I).

The repeating units represented by general formula (II) are preferably those of general formula (IIa) below.

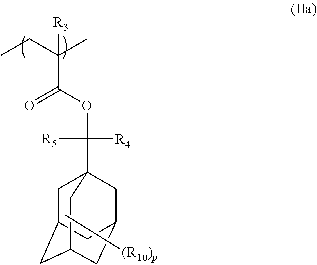

In general formula (IIa),

Each of R₃ to R₅ has the same meaning as in general formula (II).

R₁₀ represents a substituent containing a polar group. When a plurality of R₁₀s exist, they may be identical to or different from each other. As the substituent containing a polar group, there can be mentioned, for example, a hydroxyl group, a cyano group, an amino group, an alkylamido group or a sulfonamido group; or a linear or branched alkyl group, or cycloalkyl group having at least one of these groups. An alkyl group having a hydroxyl group is preferred. A branched alkyl group having a hydroxyl group is more preferred. An isopropyl group is especially preferred as the branched alkyl group.

In the formula, p is an integer of 0 to 15, preferably in the range of 0 to 2, and more preferably 0 or 1.

The resin (A) is preferably a resin containing at least one of any of repeating units represented by general formula (I) above and any of repeating units represented by general formula (II) above as the repeating unit containing the acid-decomposable group. Also, in the another embodiment, the resin (A) is more preferably a resin containing at least two of repeating units represented by general formula (I) above as the repeating unit containing the acid-decomposable group.

The repeating unit containing acid-decomposable group contained in the resins (A) may be used either individually or in combination. When a plurality of the repeating unit containing the acid-decomposable group are simultaneously used in resin (A), preferred combinations thereof are shown below. In the following formulae, each of R independently represents a hydrogen atom or methyl group.

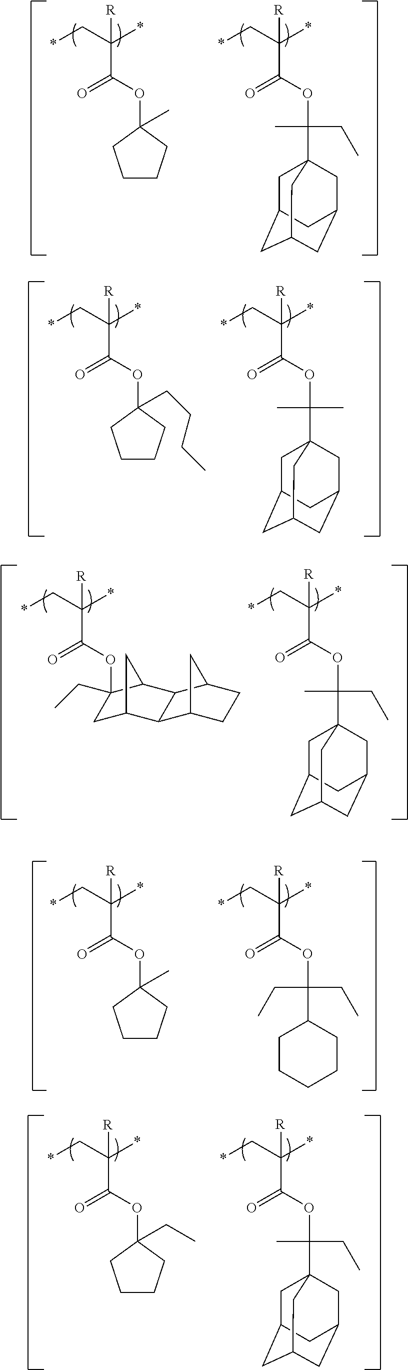

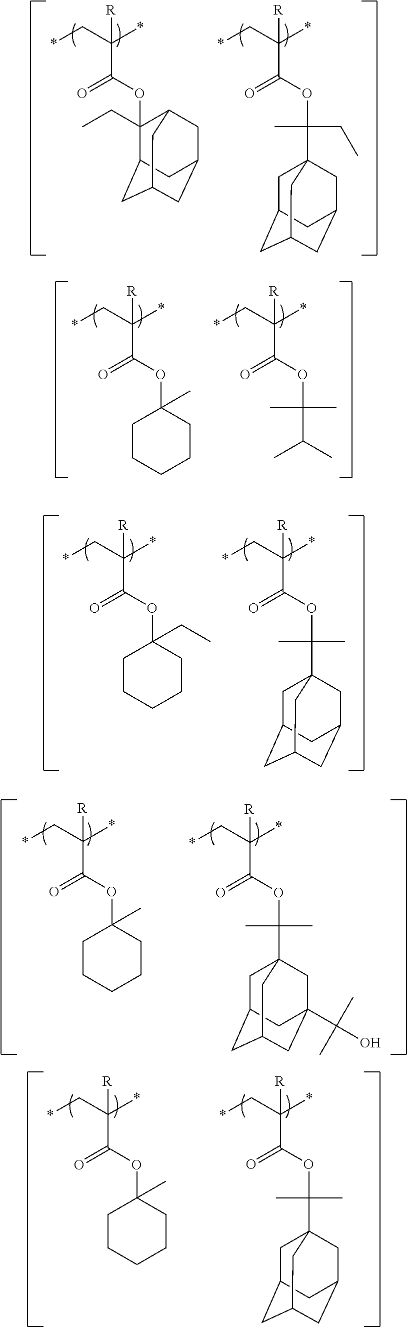

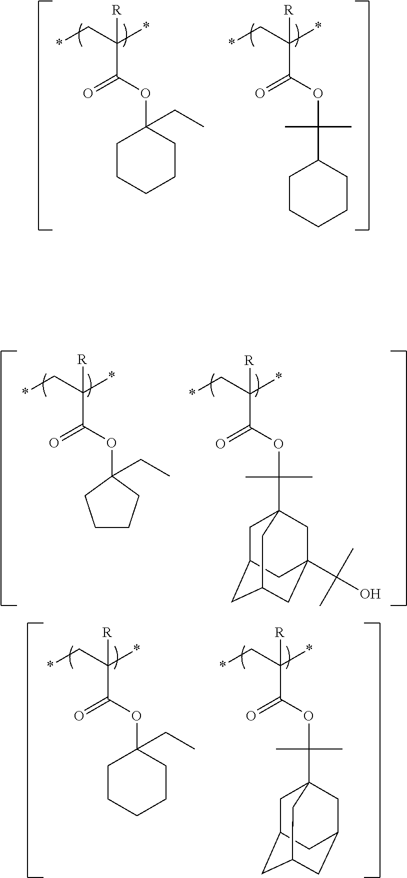

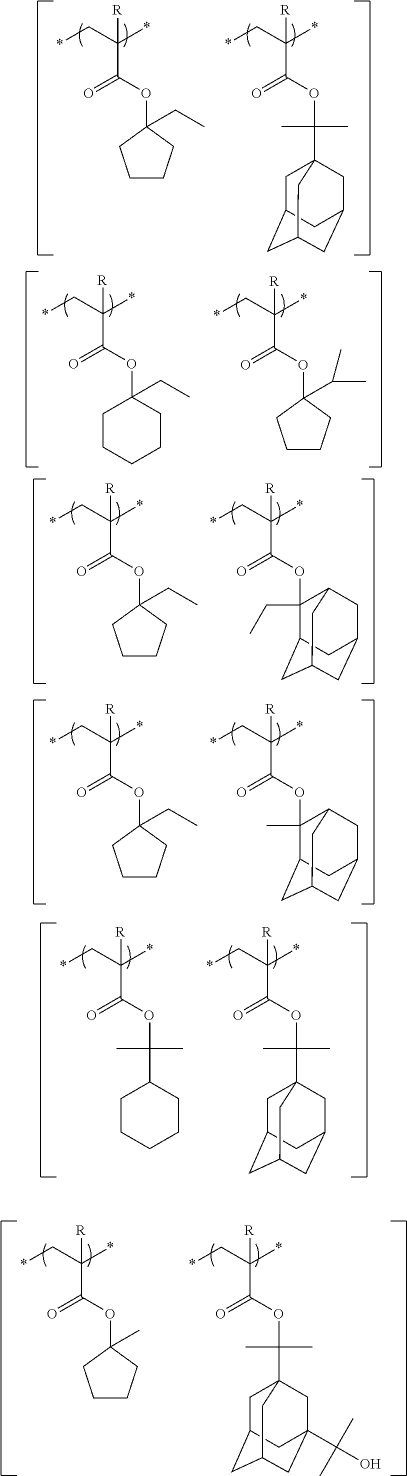

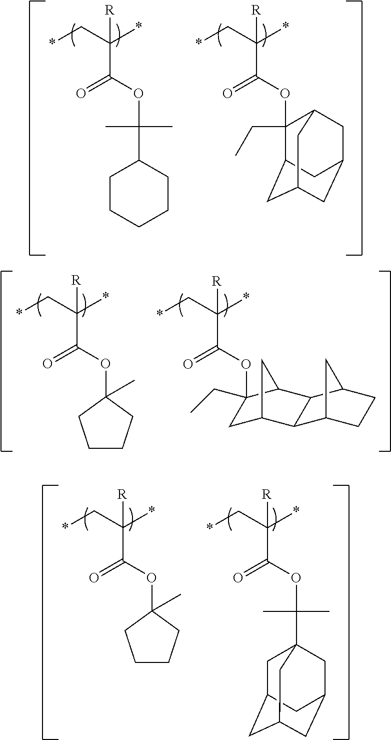

(3) Repeating Unit Containing a Lactone Structure, Sultone Structure, and/or Cyano Group

The resin (A) may contains any of the repeating units containing at least one structure selected from the group consisting of a lactone structure, sultone structure, and/or cyano group.

At first, a repeating unit containing a lacton structure and a repeating unit containing a sultone structure will be described below.

Lactone structures or sultone structures of a 5 to 7-membered ring are preferred, and in particular, those resulting from condensation of lactone structures or sultone structures of a 5 to 7-membered ring with other cyclic structures effected in a fashion to form a bicyclo structure or spiro structure are preferred. The possession of repeating units having a lactone structure or sultone structure represented by any of the following general formulae (LC1-1) to (LC1-17), (SL1-1) and (SL1-2) is more preferred. The lactone structures or sultone structures may be directly bonded to the principal chain of the resin. Preferred lactone structures or sultone structures are those of formulae (LC1-1), (LC1-4), (LC1-5) or (LC1-8). (LC1-4) is more preferable. The use of these specified lactone structures or sultone structures would ensure inhibition of pattern collapse and improvement in LER.

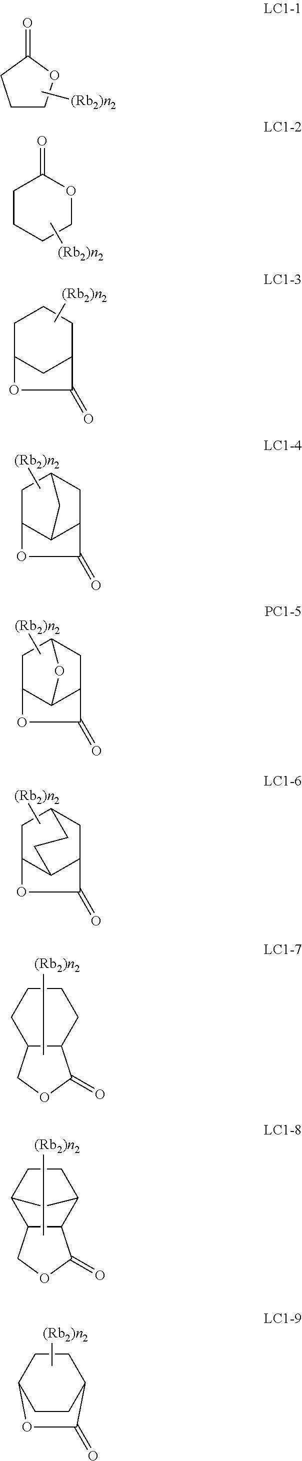

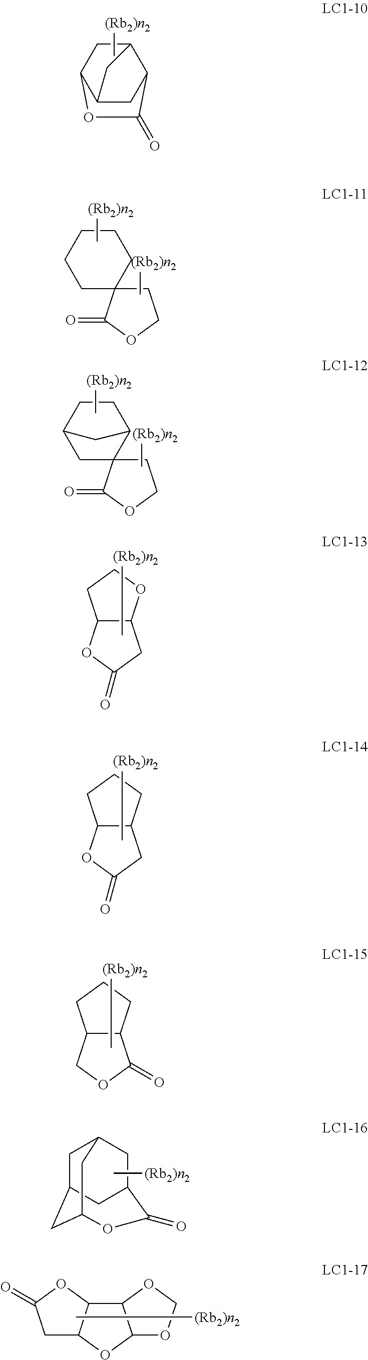

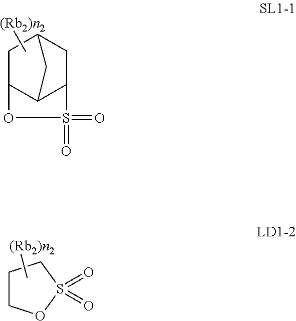

The presence of a substituent (Rb₂) on the portion of the lactone structure or the sultone structure is optional. As a preferred substituent (Rb₂), there can be mentioned an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group or the like. Of these, an alkyl group having 1 to 4 carbon atoms, a cyano group and an acid-decomposable group are more preferred. In the formulae, n₂ is an integer of 0 to 4. When n₂ is 2 or greater, the plurality of present substituents (Rb₂) may be identical to or different from each other. Further, the plurality of present substituents (Rb₂) may be bonded to each other to thereby form a ring.

In an embodiment, it is preferable that the resin (A) contains a repeating unit represented by the following general formula (AII′) as the repeating unit containing a lactone structure or sultone structure.

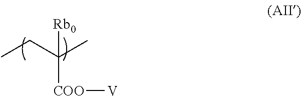

In general formula (AII′),

Rb₀ represents a hydrogen atom, a halogen atom or an optionally substituted alkyl group having 1 to 4 carbon atoms. As a preferred substituent optionally contained in the alkyl group represented by Rb₀, there can be mentioned a hydroxyl group or a halogen atom. As the halogen atom represented by Rb₀, there can be mentioned a fluorine atom, a chlorine atom, a bromine atom or an iodine atom. The Ab₀ is preferably a hydrogen atom, a methyl group, a hydroxymethyl group or a trifluoromethyl group. A hydrogen atom and a methyl group are especially preferred.

V represents a monovalent organic group containing a lactone structure or sultone structure. Preferably, V represents a group having a structure represented by any of general formulae (LC1-1) to (LC1-17), (SL1-1) and (SL1-2) above.

Specific examples of the repeating units having a sultone structure represented by general formula (AII′) above will now be shown, which however in no way limit the scope of the present invention. In formulae below, Rx represents H, CH₃, CH₂OH or CF₃.

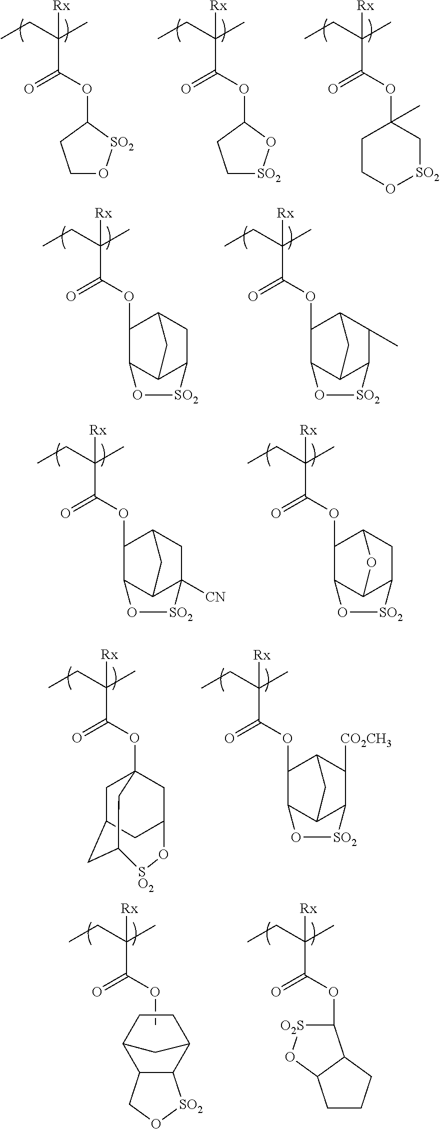

Specific examples of the repeating units having a lactone structure represented by general formula (AII′) above will now be shown, which however in no way limit the scope of the present invention. In formulae below, Me represents a methyl group and Rx represents H, CH₃, CH₂OH or CF₃.

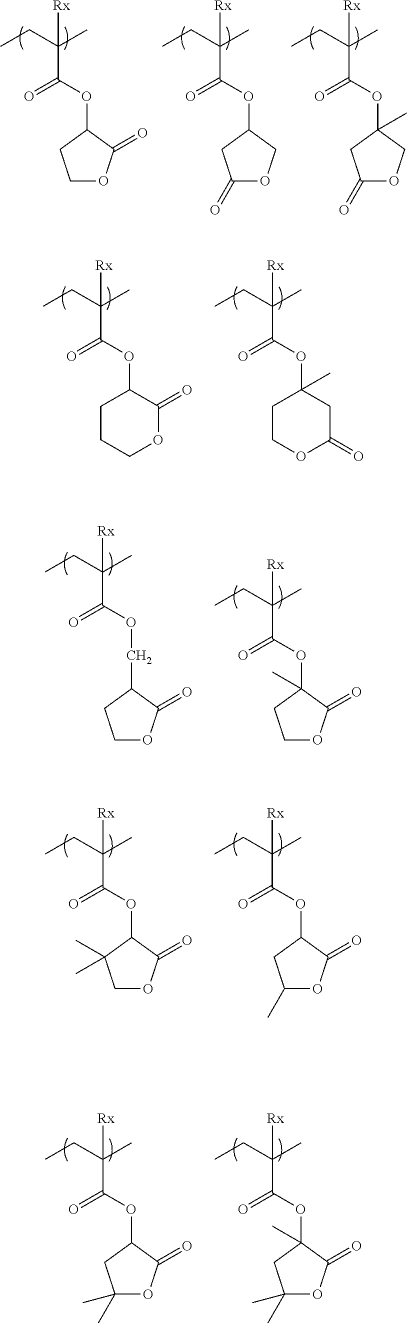

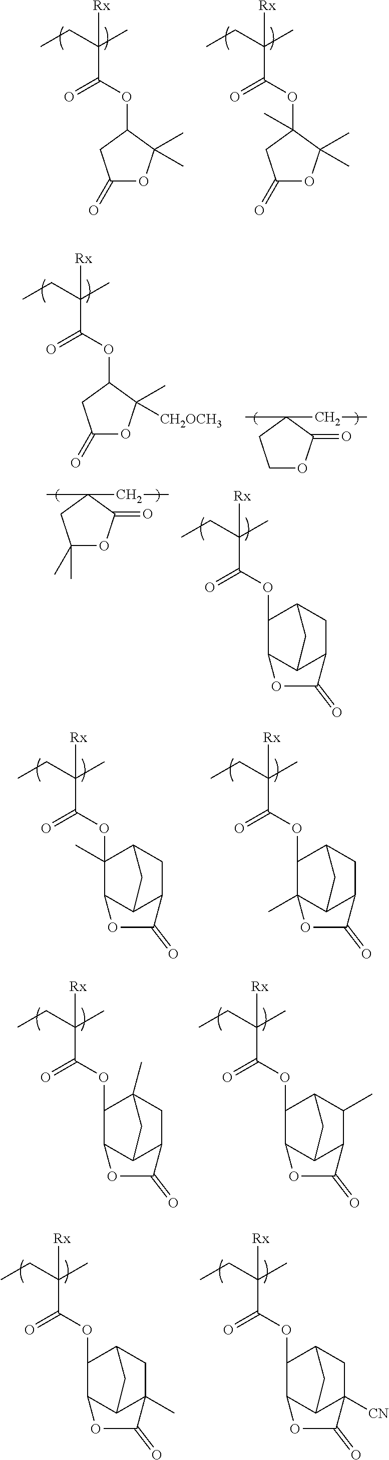

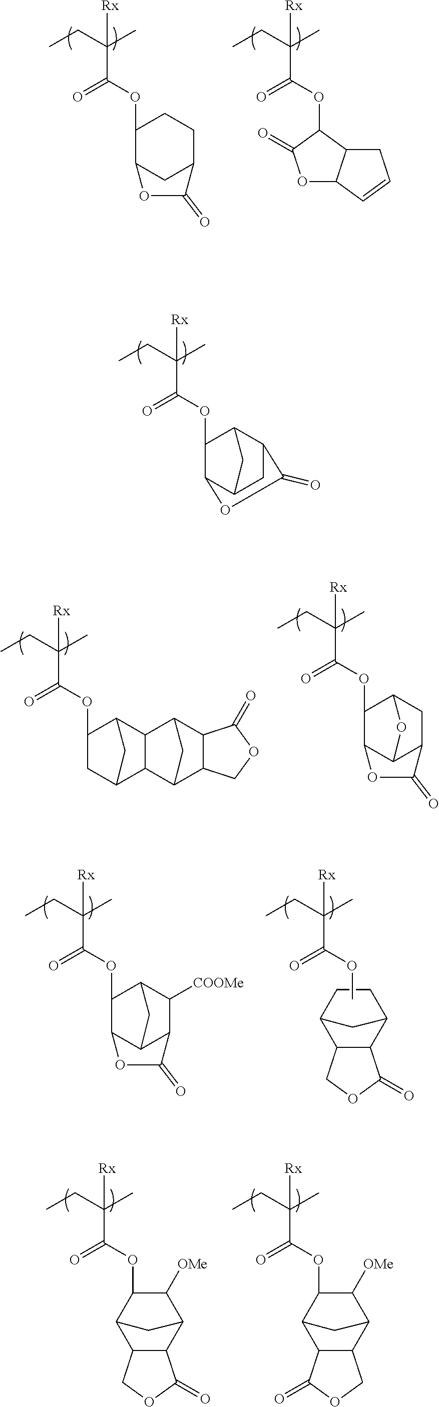

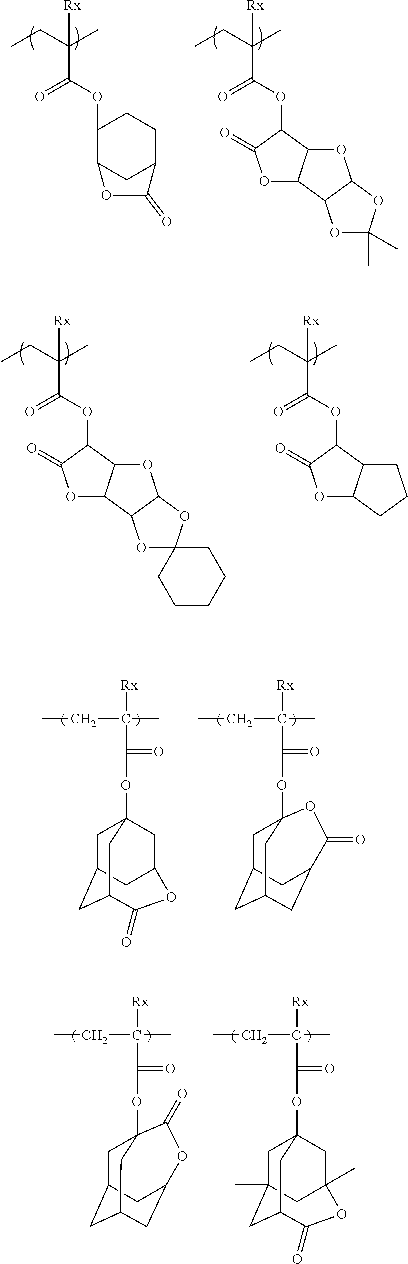

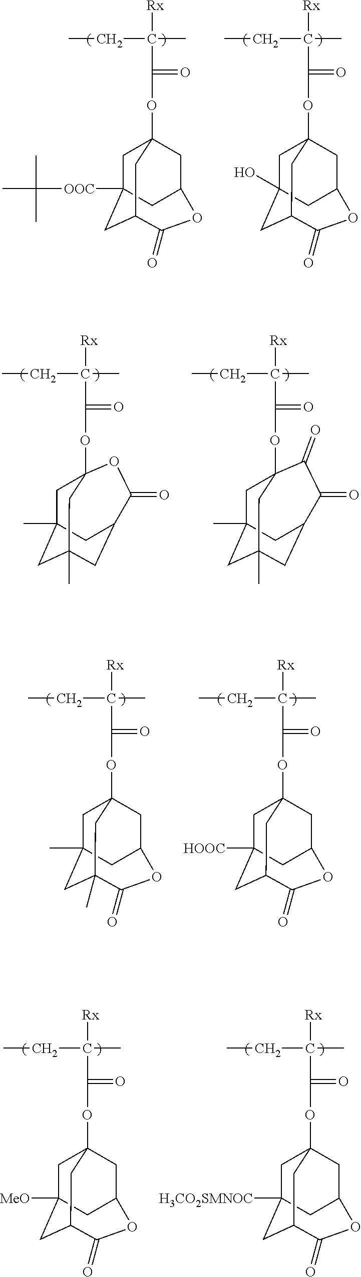

Especially preferred repeating units containing lactone group represented by general formula (AII′), the followings can be exemplified. Selecting the best lactone group can improve a pattern profile (for example, inhibition of the pattern collapse), LER and iso-dense dependense. In the formulae below, Rx represents H, CH₃, CH₂OH, or CF₃.

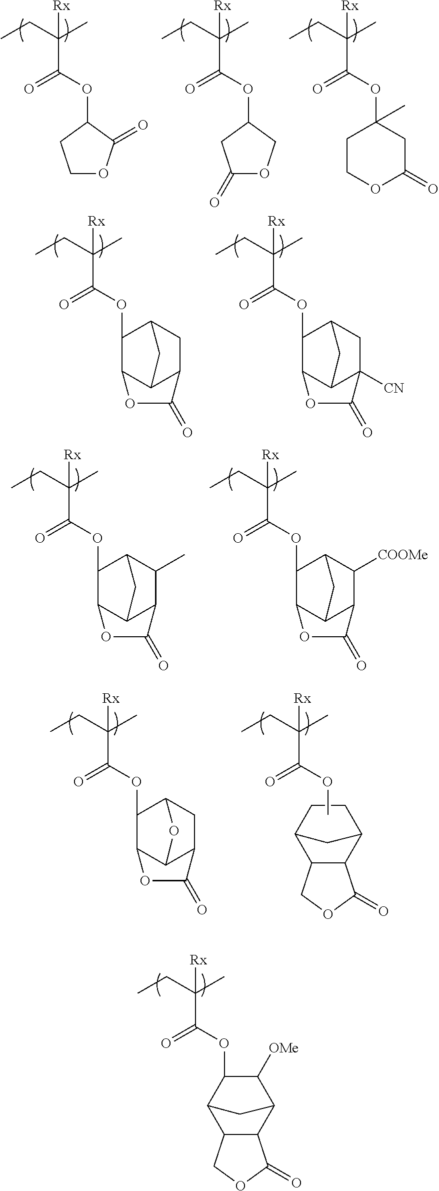

In another embodiment, the resin (A) preferably contains a repeating unit represented by general formula (III) below as the repeating unit having a lactone structure or a sultone structure.

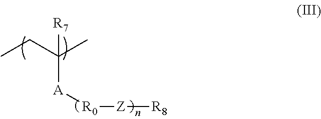

In the formula (III),

A represents an ester bond (—COO—) or an amido bond (—CONH—).

Ro, each independently in the presence of two or more groups, represents an alkylene group, a cycloalkylene group or a combination thereof.

Z, each independently in the presence of two or more groups, represents an ether bond, an ester bond, an amido bond, a urethane bond represented by

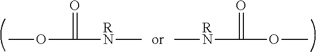

or a urea bond

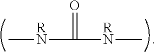

In the formulae, R represents a hydrogen atom, an alkyl group, a cycloalkyl group or an aryl group.

R₈ represents a monovalent organic group with a lactone structure or a sultone structure.

n represents the number of repetitions of the structure of the formula —R₀—Z— and is an integer of 1 to 5. 1 is preferable.

R₇ represents a hydrogen atom, a halogen atom or an alkyl group.

Each of the alkylene group and cycloalkylene group represented by R₀ may have a substituent.

Z preferably represents an ether bond or an ester bond, most preferably an ester bond.

The alkyl group represented by R₇ is preferably an alkyl group having 1 to 4 carbon atoms, more preferably a methyl group or an ethyl group and most preferably a methyl group. Each of the alkylene group and cycloalkylene group represented by R₀ and the alkyl group represented by R₇ may be substituted. As substituents, there can be mentioned, for example, a halogen atom such as a fluorine atom, a chlorine atom or a bromine atom, a mercapto group, a hydroxyl group, an alkoxy group such as a methoxy group, an ethoxy group, an isopropoxy group, a t-butoxy group or a benzyloxy group, an acyl group such as an acetyl group or a propionyl group, an acetoxy group and the like. R₇ preferably represents a hydrogen atom, a methyl group, a trifluoromethyl group or a hydroxymethyl group.

The chain alkylene group represented by R₀ is preferably a chain alkylene having 1 to 10 carbon atoms, more preferably 1 to 5 carbon atoms, for example, a methylene group, an ethylene group, a propylene group or the like. The cycloalkylene group is preferably a cycloalkylene having 3 to 20 carbon atoms. As such, there can be mentioned, for example, cyclohexylene, cyclopentylene, norbornylene, adamantylene or the like. The chain alkylene groups are preferred from the viewpoint of the exertion of the effect of the present invention. A methylene group is especially preferred.

The substituent with a lactone structure or sultone structure represented by R₈ is not limited as long as the lactone structure is contained. As particular examples thereof, there can be mentioned the lactone structures or the sultone structures of general formulae (LC1-1) to (LC1-17), (SL1-1) and (SL1-2) to be shown hereinafter. Of these, the structures of general formula (LC1-4) are most preferred. In general formulae (LC1-1) to (LC1-17), (SL1-1) and (SL1-2), n₂ is more preferably 2 or less.

R₈ preferably represents a monovalent organic group with an unsubstituted lactone structure or sultone structure or a monovalent organic group with a lactone structure or sultone structure substituted with a methyl group, a cyano group or an alkoxycarbonyl group. More preferably, R₈ represents a monovalent organic group with a lactone structure or sultone structure substituted with a cyano group (cyanolactone or cyanosultone).

Specific examples of the repeating units having the groups with a lactone structure or sultone structure of general formula (III) will be shown below, which however in no way limit the scope of the present invention. In the following specific examples, R represents a hydrogen atom, an optionally substituted alkyl group or a halogen atom. Preferably, R represents a hydrogen atom, a methyl group, a hydroxymethyl group or an acetoxymethyl group.

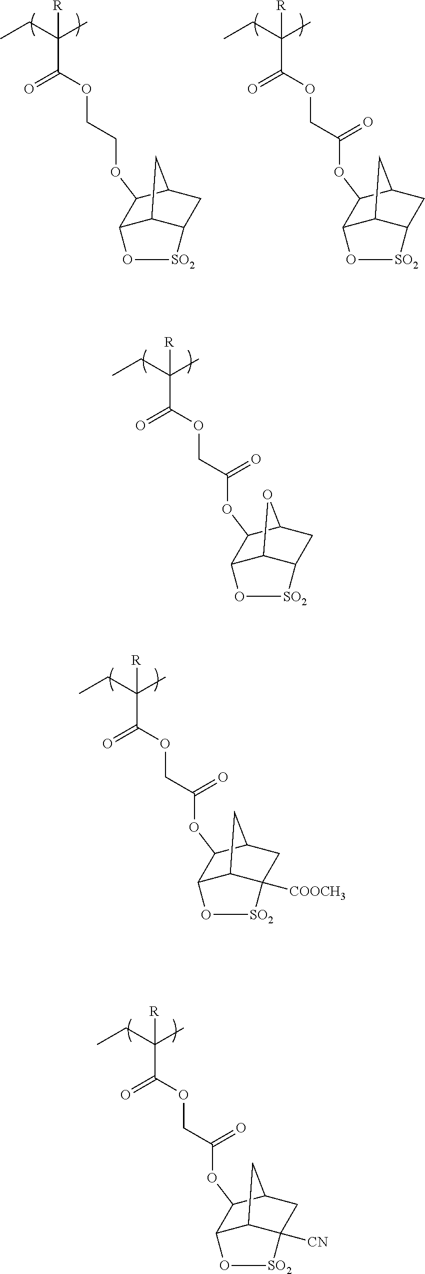

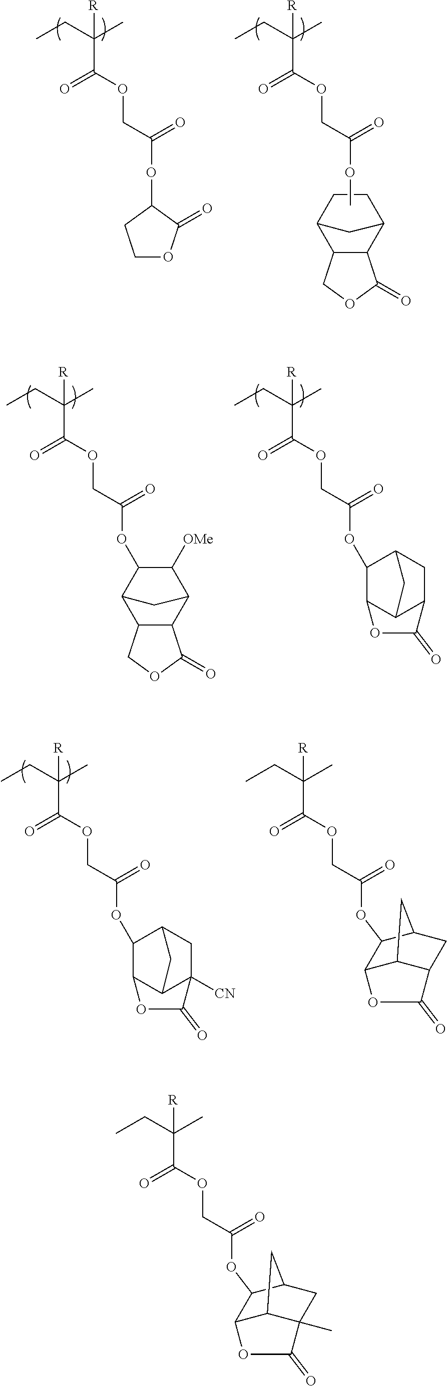

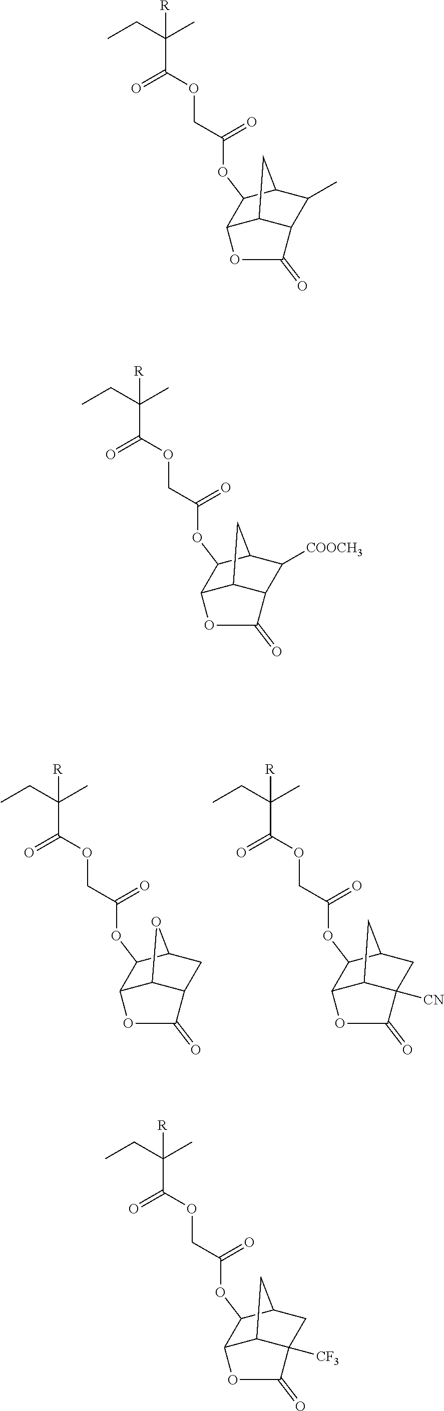

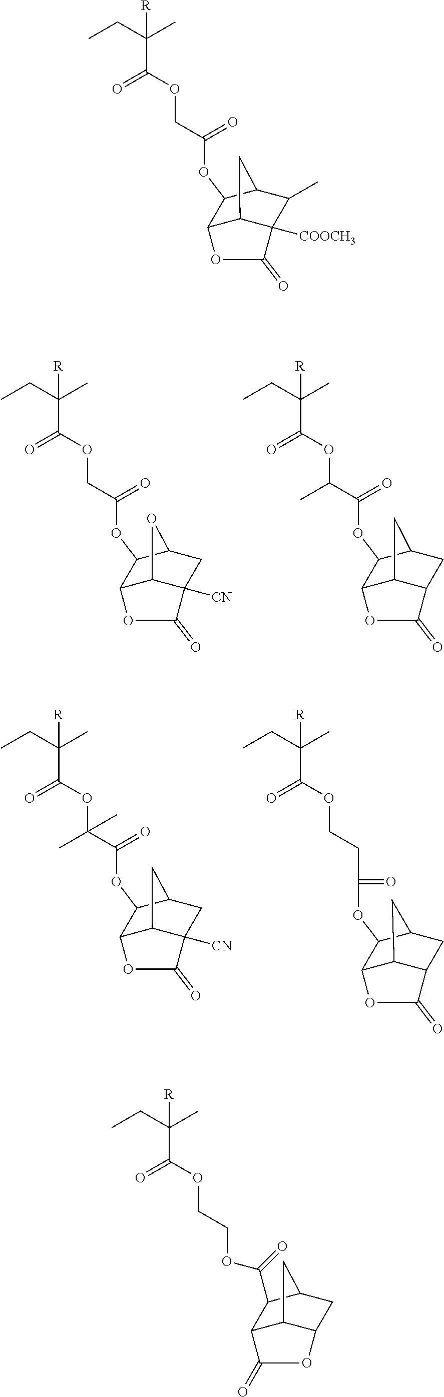

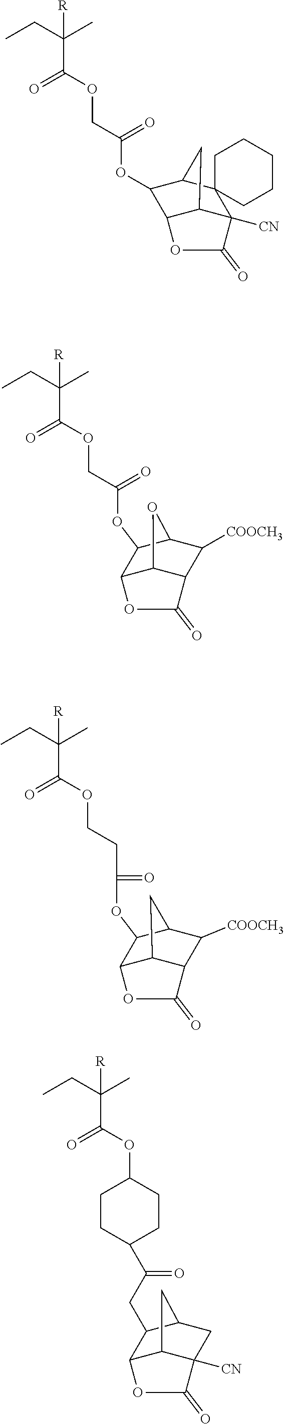

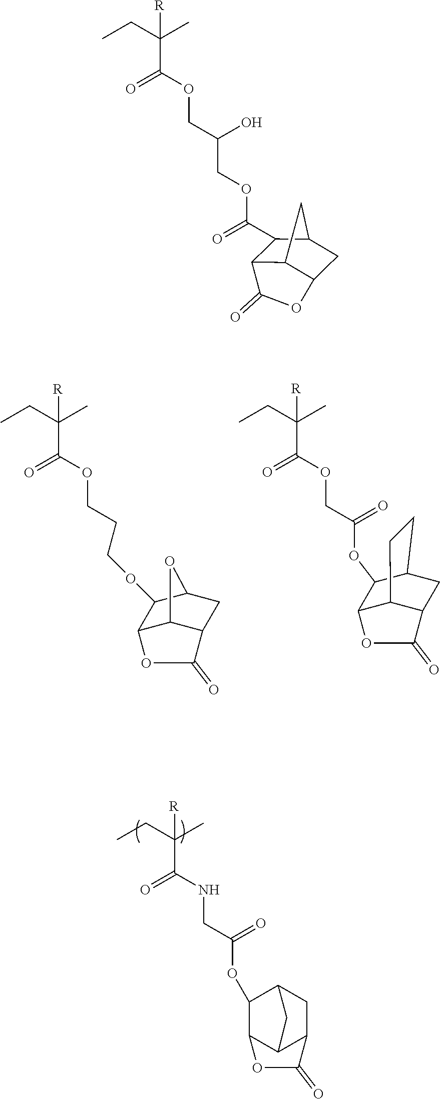

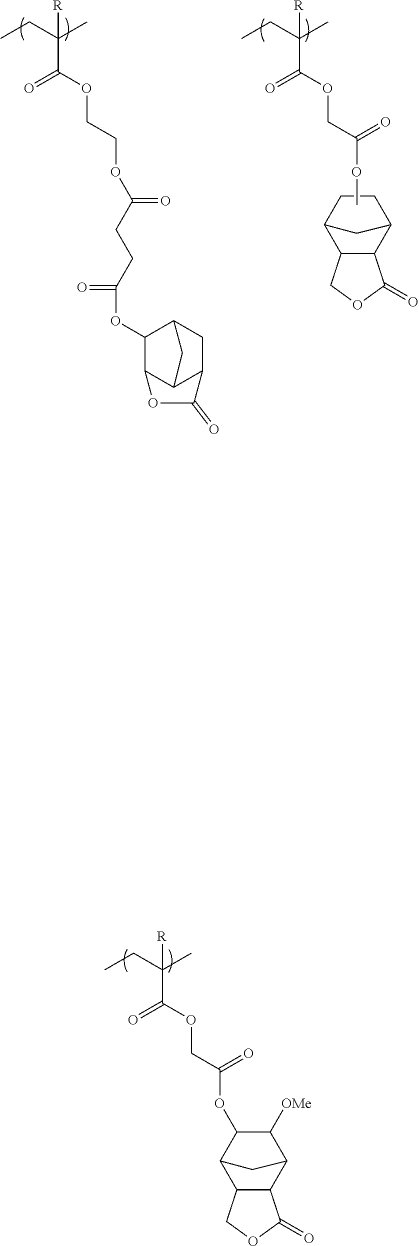

Each of the repeating units having a lactone group or sultone group is generally present in the form of optical isomers. Any of the optical isomers may be used. It is appropriate to use both a single type of optical isomer alone and a plurality of optical isomers in the form of a mixture. When a single type of optical isomer is mainly used, the optical purity (ee) thereof is preferably 90% or higher, more preferably 95% or higher.

In order to enhance the effect of the present invention, it is practicable to simultaneously employ two or more repeating units having a lactone group or sultone group. In this case, it is preferred to select the two or more repeating units having a lactone group or sultone group from among those of general formula (III) and simultaneously use them. Especially, it is preferred to select two or more repeating units having a lactone group or sultone group from among those of general formula (III) in which n is 1 and simultaneously use them.

Now, a repeating unit containing a cyano group will be described.

Similarly to the repeating unit with a lactone structure or a sultone structure, the repeating unit containing a cyano group contributes to the inhibition of pattern collapse and improvement of line edge roughness.

It is preferable for the repeating unit containing a cyano group to be a repeating unit with an alicyclic hydrocarbon structure substituted with a cyano group. The alicyclic hydrocarbon structure is preferably an adamantyl group, a diamantyl group or a norbornane group. In the following formulae, Ra represents a hydrogen atom or an alkyl group (preferably an alkyl group having 1 to 4 carbon atoms). A substituent may be introduced in the alkyl group. As such a substituent, there can be mentioned, for example, a hydroxyl group or a halogen atom. As the halogen atom introduced in Ra, there can be mentioned a fluorine atom, a chlorine atom, a bromine atom or an iodine atom. Preferably, Ra is a hydrogen atom, a methyl group, a hydroxymethyl group or a trifluoromethyl group. A hydrogen atom and a methyl group are especially preferable.

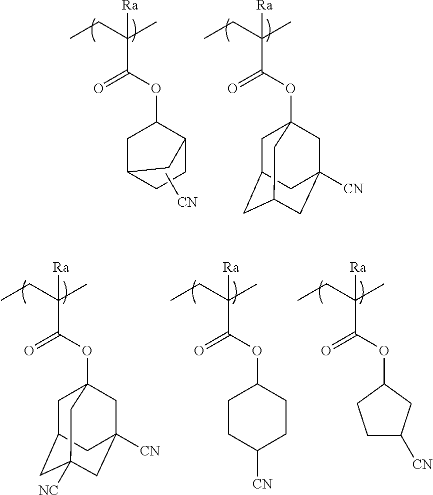

In the present invention, it is preferable for the repeating unit containing at least any of the above-mentioned lactone structure, sultone structure and cyano group to be expressed by any of general formulae (II-1) to (II-4) below.

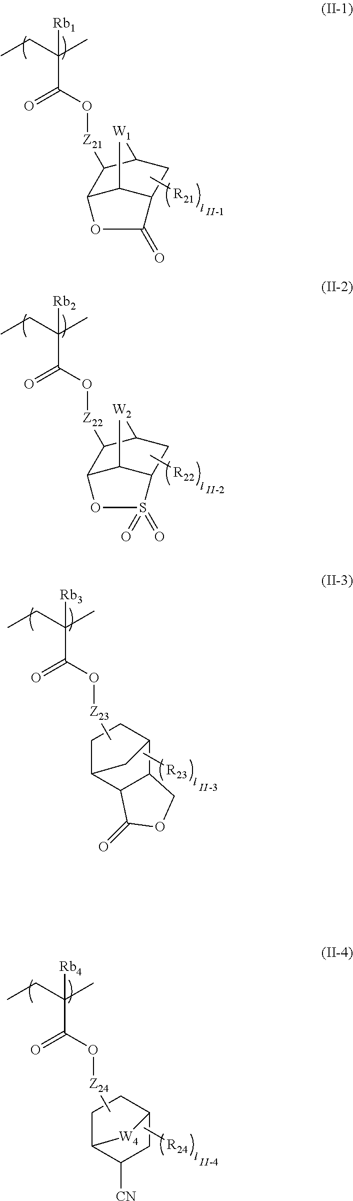

In general formulae (II-1) to (II-4) above,

each of R₂₁, R₂₂, R₂₃ and R₂₄ independently represents a monovalent organic group.

Each of Rb₁, Rb₂, Rb₃ and Rb₄ independently represents a hydrogen atom or an alkyl group.

Each of W₁, W₂ and W₄ independently represents an alkylene group or an oxygen atom.

Each of Z₂₁, Z₂₂, Z₂₃ and Z₂₄ independently represents a single bond or a bivalent connecting group.

In the formulae, l_{II-1} is an integer of 0 to 8,

l_{II-2} is an integer of 0 to 8,

l_{II-3} is an integer of 0 to 9, and

l_{II-4} is an integer of 0 to 6.

As the monovalent organic group represented by R₂₁, R₂₂, R₂₃ or R₂₄, there can be mentioned an alkyl group, a cycloalkyl group, an alkoxycarbonyl group, a cyano group, a hydroxyl group or an alkoxy group. When there are two or more R₂₁s, R₂₂s, R₂₃s or R₂₄s, the two or more may be bonded to each other, thereby forming a ring.

The alkyl group represented by R₂₁, R₂₂, R₂₃ or R₂₄ is preferably an alkyl group having 1 to 4 carbon atoms, more preferably a methyl group or an ethyl group. A methyl group is most preferable. As the cycloalkyl group, there can be mentioned a cyclopropyl group, a cyclobutyl group, a cyclopentyl group or a cyclohexyl group. As the alkoxycarbonyl group, there can be mentioned, for example, a methoxycarbonyl group, an ethoxycarbonyl group, an n-butoxycarbonyl group and a t-butoxycarbonyl group. As the alkoxy group, there can be mentioned, for example, a methoxy group, an ethoxy group, a propoxy group, an isopropoxy group and a butoxy group. Substituents may be introduced in these groups. As such substituents, there can be mentioned a hydroxyl group; an alkoxy group such as a methoxy group or an ethoxy group; a cyano group; and a halogen atom such as a fluorine atom.

More preferably, each of R₂₁, R₂₂, R₂₃ and R₂₄ is a methyl group, a cyano group or an alkoxycarbonyl group, further more preferably a cyano group.

Each of Rb₁, Rb₂, Rb₃ and Rb₄ is preferably a hydrogen atom, a methyl group or a trifluoromethyl group, more preferably a hydrogen atom or a methyl group.

Each of W₁, W₂ and W₄ is preferably an alkylene group having 1 to 3 carbon atoms (for example, a methylene group or an ethylene group) or an oxygen atom, more preferably a methylene group or an oxygen atom.

The bivalent connecting group represented by each of Z₂₁, Z₂₂, Z₂₃ and Z₂₄ is preferably an alkylene group, a bivalent connecting group with a mono- or polycycloalkyl structure, an ether bond, an ester bond, a carbonyl group or a bivalent connecting group comprised of a combination of these.

More preferably, each of Z₂₁, Z₂₂, Z₂₃ and Z₂₄ is a single bond or any of bivalent connecting groups of the formula —Zx-CO₂—.

In the formula, Zx represents a linear or branched alkylene group or a mono- or polycycloalkylene group, preferably a methylene group, an ethylene group, a cyclohexylene group, an adamantylene group or a norbornylene group.

Each of l_{II-1}, l_{II-2} and l_{II-3} is preferably an integer of 0 to 4, more preferably 0 or 1; and

l_{II-4} is preferably an integer of 0 to 2, more preferably 0.

The content of repeating unit containing any of a lactone structure, a sultone structure and a cyano group (when two or more types are contained, the sum thereof) based on all the repeating units of the resin is preferably in the range of 15 to 70 mol %, more preferably 20 to 65 mol % and further more preferably 25 to 60 mol %.

(4) Repeating Unit Having a Hydroxyl Group

Resin (A) may further contain a repeating unit having a hydroxyl group. The containment of this repeating unit would realize enhancements of adhesion to substrate and developer affinity. The repeating unit having a hydroxyl group is preferably a repeating unit with a structure of alicyclic hydrocarbon substituted with a hydroxyl group, and preferably has no acid-decomposable group. In the alicyclic hydrocarbon structure substituted with a hydroxyl group, the alicyclic hydrocarbon structure preferably consists of an adamantyl group, a diamantyl group or a norbornane group. As preferred alicyclic hydrocarbon structures substituted with a hydroxyl group, there can be mentioned the partial structures of the following general formulae (VIIa) to (VIIc).

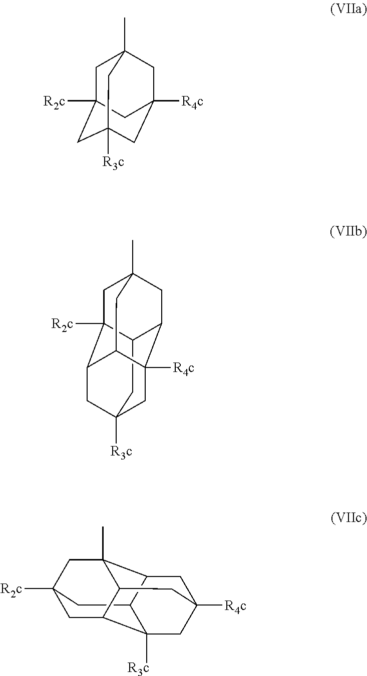

In general formulae (VIIa) to (VIIc),

each of R₂c to R₄c independently represents a hydrogen atom or a hydroxyl group, providing that at least one of the R₂c to R₄c represents a hydroxyl group. Preferably, one or two of the R₂c to R₄c are hydroxyl groups and the remainder is a hydrogen atom. In general formula (VIIa), more preferably, two of the R₂c to R₄c are hydroxyl groups and the remainder is a hydrogen atom.

As the repeating units having any of the partial structures of formulae (VIIa) to (VIIc), there can be mentioned those of the following general formulae (AIIa) to (AIIc).

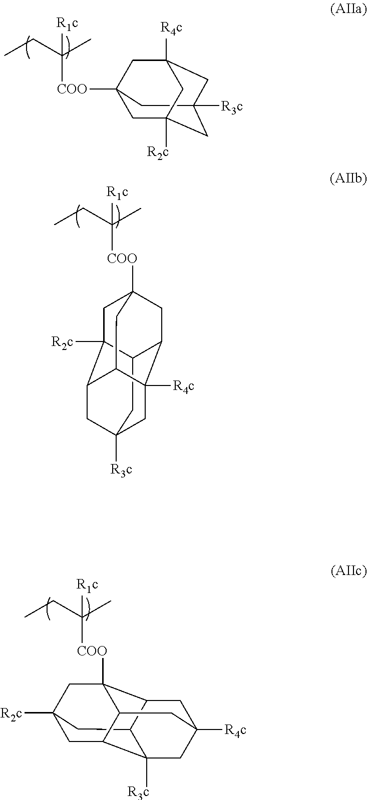

In general formulae (AIIa) to (AIIc),

R₁c represents a hydrogen atom, a methyl group, a trifluoromethyl group or a hydroxymethyl group.

R₂c to R₄c have the same meaning as those of general formulae (VIIa) to (VIIc).

The repeating unit having a hydroxyl group may or may not be contained in the resin (A). When the repeating unit having a hydroxyl group is contained in the resin (A), the content ratio of the repeating unit having a hydroxyl group, based on all the repeating units of resin (A), is preferably in the range of 5 to 30 mol %, more preferably 5 to 20 mol % and still more preferably 10 to 15 mol %.

Specific examples of the repeating units having a hydroxyl group will be shown below, which however in no way limit the scope of the present invention.

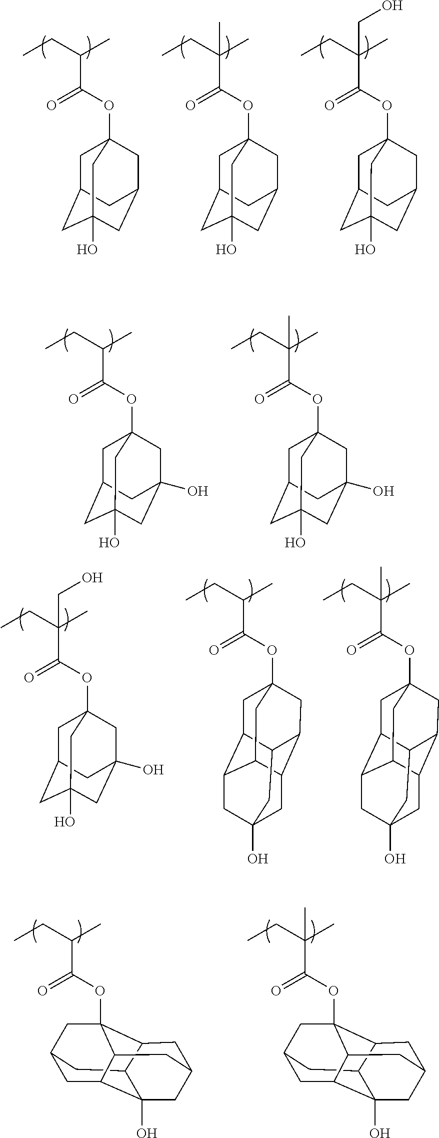

(5) Repeating Unit Having an Alkali-Soluble Group

Resin (A) can contain a repeating unit having an alkali-soluble group. As the alkali-soluble group, there can be mentioned a carboxyl group, a sulfonamido group, a sulfonylimide group, a bisulfonylimide group or an aliphatic alcohol substituted at its α-position with an electron-withdrawing group (for example, a hexafluoroisopropanol group). The possession of a repeating unit having a carboxyl group is more preferred. The incorporation of the repeating unit having an alkali-soluble group would increase the resolving power in contact hole usage. The repeating unit having an alkali-soluble group is preferably any of a repeating unit wherein the alkali-soluble group is directly bonded to the principal chain of a resin such as a repeating unit of acrylic acid or methacrylic acid, a repeating unit wherein the alkali-soluble group is bonded via a connecting group to the principal chain of a resin and a repeating unit wherein the alkali-soluble group is introduced in a terminal of a polymer chain by the use of a chain transfer agent or polymerization initiator having the alkali-soluble group in the stage of polymerization. The connecting group may have a monocyclic or polycyclic hydrocarbon structure. The repeating unit of acrylic acid or methacrylic acid is especially preferred.

The repeating unit having an alkali-soluble group may or may not be contained in the resin (A). When the repeating unit having an alkali-soluble group is contained in the resin (A), the content ratio of the repeating unit having an alkali-soluble group based on all the repeating units of resin (A) is preferably in the range of 1 to 15 mol %, more preferably 3 to 10 mol % and still more preferably 4 to 8 mol %.

Specific examples of the repeating units having an alkali-soluble group will be shown below, which however in no way limit the scope of the present invention.

In the formulae, Rx represents H, CH₃, CH₂OH, or CF₃.

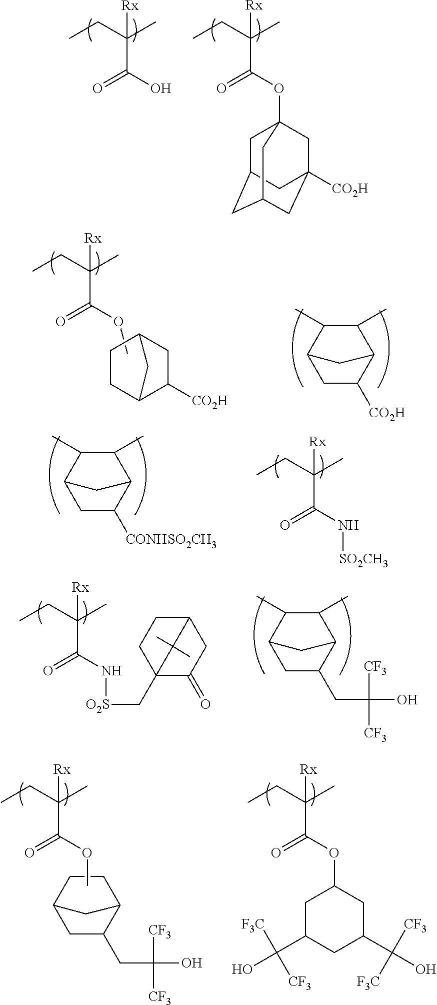

(6) Repeating Unit that has a Structure of Alicyclic Hydrocarbon Having No Polar Group

Resin (A) can further contain a repeating unit that has a structure of alicyclic hydrocarbon having no polar group (such as an above-mentioned alkali-soluble group, a hydroxyl group, a cyano group, etc.) and that exhibits no acid decomposability. As such a repeating unit, there can be mentioned any of the repeating units of general formula (IV) below.

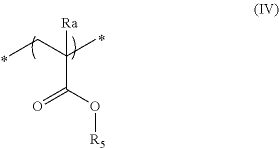

In general formula (IV), R₅ represents a hydrocarbon group having at least one cyclic structure and having no polar group.

Ra represents a hydrogen atom, an alkyl group or a group of the formula —CH₂—O—Ra₂ in which Ra₂ represents a hydrogen atom, an alkyl group or an acyl group. Ra preferably represents a hydrogen atom, a methyl group, a trifluoromethyl group, a hydroxymethyl group or the like, more preferably a hydrogen atom and a methyl group.

The cyclic structures contained in R₅ include a monocyclic hydrocarbon group and a polycyclic hydrocarbon group. As the monocyclic hydrocarbon group, there can be mentioned, for example, a cycloalkyl group having 3 to 12 carbon atoms, such as a cyclopentyl group, a cyclohexyl group, a cycloheptyl group or a cyclooctyl group, or a cycloalkenyl group having 3 to 12 carbon atoms, such as a cyclohexenyl group. Preferably, the monocyclic hydrocarbon group is a monocyclic hydrocarbon group having 3 to 7 carbon atoms. A cyclopentyl group and a cyclohexyl group are more preferred.

The polycyclic hydrocarbon groups include ring-assembly hydrocarbon groups and crosslinked-ring hydrocarbon groups. Examples of the ring-assembly hydrocarbon groups include a bicyclohexyl group, a perhydronaphthalene group and the like. As the crosslinked-ring hydrocarbon rings, there can be mentioned, for example, bicyclic hydrocarbon rings, such as pinane, bornane, norpinane, norbornane and bicyclooctane rings (e.g., bicyclo[2.2.2]octane ring or bicyclo[3.2.1]octane ring); tricyclic hydrocarbon rings, such as adamantane, tricyclo[5.2.1.0^{2,6}]decane and tricyclo[4.3.1.1^{2,5}]undecane rings; and tetracyclic hydrocarbon rings, such as tetracyclo[4.4.0.1^{2,5}.1^{7,10}]dodecane and perhydro-1,4-methano-5,8-methanonaphthalene rings. Further, the crosslinked-ring hydrocarbon rings include condensed-ring hydrocarbon rings, for example, condensed rings resulting from condensation of multiple 5- to 8-membered cycloalkane rings, such as perhydronaphthalene (decalin), perhydroanthracene, perhydrophenanthrene, perhydroacenaphthene, perhydrofluorene, perhydroindene and perhydrophenarene rings.

As preferred crosslinked-ring hydrocarbon rings, there can be mentioned, for example, a norbornyl group, an adamantyl group, a bicyclooctanyl group and a tricyclo[5,2,1,0^{2,6}]decanyl group. As more preferred crosslinked-ring hydrocarbon rings, there can be mentioned a norbornyl group and an adamantyl group.

These alicyclic hydrocarbon groups may have substituents. As preferred substituents, there can be mentioned, for example, a halogen atom, an alkyl group, a hydroxyl group in which a hydrogen atom is substituted and an amino group in which a hydrogen atom is substituted. The halogen atom is preferably a bromine, chlorine or fluorine atom, and the alkyl group is preferably a methyl, ethyl, butyl or t-butyl group. The alkyl group may further have a substituent. As the optional further substituent, there can be mentioned a halogen atom, an alkyl group, a hydroxyl group in which a hydrogen atom is substituted or an amino group in which a hydrogen atom is substituted.

As the group in which a hydrogen atom is substituted, there can be mentioned, for example, an alkyl group, a cycloalkyl group, an aralkyl group, a substituted methyl group, a substituted ethyl group, an alkoxycarbonyl group or an aralkyloxycarbonyl group. The alkyl group is preferably an alkyl group having 1 to 4 carbon atoms. The substituted methyl group is preferably a methoxymethyl, methoxythiomethyl, benzyloxymethyl, t-butoxymethyl or 2-methoxyethoxymethyl group. The substituted ethyl group is preferably a 1-ethoxyethyl or 1-methyl-1-methoxyethyl group. The acyl group is preferably an aliphatic acyl group having 1 to 6 carbon atoms, such as a formyl, acetyl, propionyl, butyryl, isobutyryl, valeryl or pivaloyl group. The alkoxycarbonyl group is, for example, an alkoxycarbonyl group having 1 to 4 carbon atoms.

The repeating unit that has a structure of alicyclic hydrocarbon having no polar group, exhibiting no acid decomposability may or may not be contained in the resin (A). When the repeating unit that has a structure of alicyclic hydrocarbon having no polar group, exhibiting no acid decomposability is contained in the resin (A), the content ratio of the repeating unit, based on all repeating units of resin (A), is preferably in the range of 1 to 20 mol %, more preferably 2 to 15 mol %.

Specific examples of the repeating units that have a structure of alicyclic hydrocarbon having no polar group, exhibiting no acid decomposability will be shown below, which however in no way limit the scope of the present invention. In the formulae, Ra represents H, CH₃, CH₂OH or CF₃.

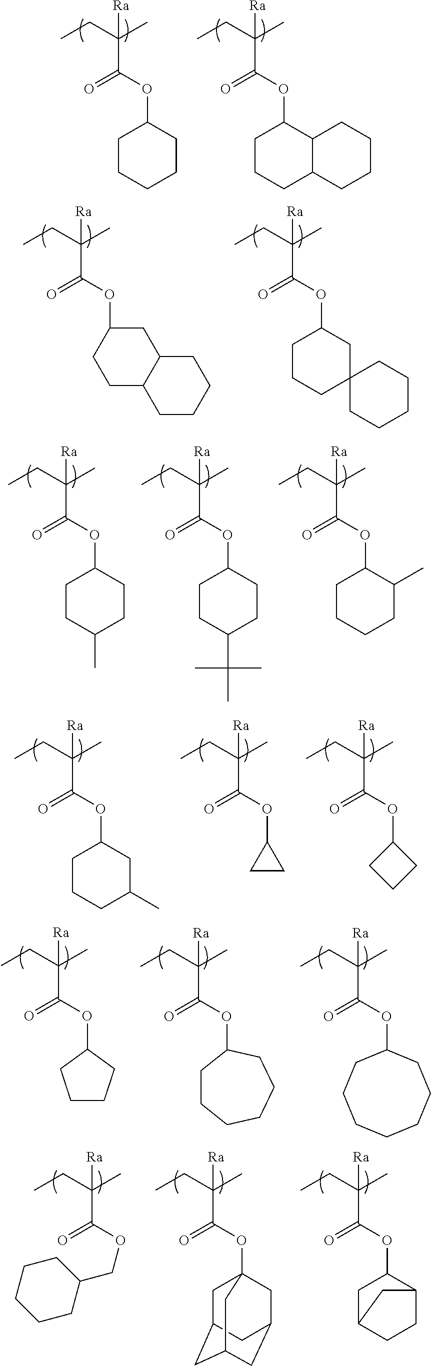

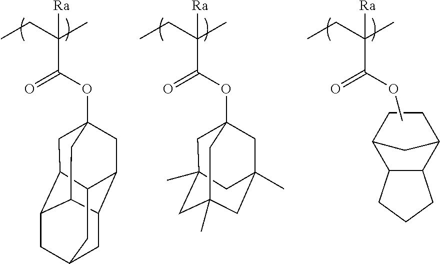

Resin (A) may have, in addition to the foregoing repeating structural units, various repeating structural units for the purpose of regulating the dry etching resistance, standard developer adaptability, substrate adhesion, resist profile and generally required properties of the resist such as resolving power, heat resistance and sensitivity.

As such repeating structural units, there can be mentioned those corresponding to the following monomers, which however are nonlimiting.

The use of such repeating structural units would enable fine regulation of the required properties of resin (A), especially: (1) solubility in applied solvents, (2) film forming easiness (glass transition point), (3) alkali developability, (4) film thinning (selections of hydrophilicity/hydrophobicity and alkali-soluble group), (5) adhesion of unexposed area to substrate, and (6) dry etching resistance, etc.

As appropriate monomers, there can be mentioned, for example, a compound having an unsaturated bond capable of addition polymerization, selected from among acrylic esters, methacrylic esters, acrylamides, methacrylamides, allyl compounds, vinyl ethers, vinyl esters and the like.

In addition, any unsaturated compound capable of addition polymerization that is copolymerizable with monomers corresponding to the above various repeating structural units may be copolymerized therewith.

The molar ratios of individual repeating structural units contained in resin (A) are appropriately determined from the viewpoint of regulation of not only the dry etching resistance of the resist but also the standard developer adaptability, substrate adhesion, resist profile and generally required properties of the resist such as the resolving power, heat resistance and sensitivity.

When the composition of the present invention is one for ArF exposure, it is preferred for resin (A) to have no aromatic group substantially from the viewpoint of transparency to ArF beams. More specifically, the content ratio of the repeating unit having an aromatic group based on all the repeating units of resin (A) is preferably no more than 5 mol %, more preferably no more than 3 mol % and ideally 0 mol % (i.e. the repeating unit having aromatic group is not contained in resin (A)).

It is preferred for resin (A) to contain an alicycic hydrocarbon structure with single ring or multiple rings.

From the viewpoint of the compatibility with hydrophobic resin (HR) described below, it is preferred for resin (A) to contain neither a fluorine atom nor a silicon atom.

In resin (A), preferably, all the repeating units consist of (meth)acrylate repeating units. In that instance, use can be made of any of a resin wherein all the repeating units consist of methacrylate repeating units, a resin wherein all the repeating units consist of acrylate repeating units and a resin wherein all the repeating units consist of methacrylate repeating units and acrylate repeating units. However, it is preferred for the acrylate repeating units to account for 50 mol % or less of all the repeating units.

Resin (A) can be synthesized by conventional techniques (for example, radical polymerization). As general synthetic methods, there can be mentioned, for example, a batch polymerization method in which a monomer species and an initiator are dissolved in a solvent and heated so as to accomplish polymerization and a dropping polymerization method in which a solution of monomer species and initiator is added by dropping to a heated solvent over a period of 1 to 10 hours. The dropping polymerization method is preferred. As a reaction solvent, there can be mentioned, for example, an ether, such as tetrahydrofuran, 1,4-dioxane or diisopropyl ether; a ketone, such as methyl ethyl ketone or methyl isobutyl ketone; an ester solvent, such as ethyl acetate; an amide solvent, such as dimethylformamide or dimethylacetamide; or the solvent capable of dissolving the composition of the present invention, such as propylene glycol monomethyl ether acetate, propylene glycol monomethyl ether or cyclohexanone, to be described hereinafter. It is preferred to perform the polymerization with the use of the same solvent as employed in the actinic-ray- or radiation-sensitive resin composition of the present invention. This would inhibit any particle generation during storage.

The polymerization reaction is preferably carried out in an atmosphere of inert gas, such as nitrogen or argon. The polymerization is initiated by the use of a commercially available radical initiator (azo initiator, peroxide, etc.) as a polymerization initiator. Among the radical initiators, an azo initiator is preferred. An azo initiator having an ester group, a cyano group or a carboxyl group is especially preferred. As preferred initiators, there can be mentioned azobisisobutyronitrile, azobisdimethylvaleronitrile, dimethyl 2,2′-azobis(2-methylpropionate) and the like. According to necessity, a supplementation of initiator or divided addition thereof may be effected. After the completion of the reaction, the reaction mixture is poured into a solvent. The desired polymer is recovered by a method for powder or solid recovery, etc. The concentration during the reaction is in the range of 5 to 50 mass %, preferably 10 to 30 mass %. The reaction temperature is generally in the range of 10° to 150° C., preferably 30° to 120° C. and more preferably 60° to 100° C.

The weight average molecular weight of resin (A) in terms of polystyrene molecular weight as measured by GPC is preferably in the range of 1000 to 200,000, more preferably 2000 to 20,000, still more preferably 3000 to 18,000 and further preferably 5000 to 16,000. The regulation of the weight average molecular weight to 1000 to 200,000 would prevent deteriorations of heat resistance and dry etching resistance and also prevent deterioration of developability and increase of viscosity leading to poor film forming property.

Use is made of the resin whose dispersity (molecular weight distribution) is generally in the range of 1.0 to 3.0, preferably 1.0 to 2.6, more preferably 1.0 to 2.0 and most preferably 1.4 to 2.0. The lower the molecular weight distribution, the more excellent the resolving power and resist profile and the smoother the side wall of the resist pattern to thereby attain an excellence in roughness.

In the actinic ray- or radiation-sensitive resin composition of the present invention, the content ratio of resin (A), based on the total solid content of the whole composition, is preferably in the range of 30 to 99 mass %, more preferably 60 to 95 mass %. Resin (A) may be used either individually or in combination. As long as the effect of the invention is not compromised, the actinic ray- or radiation-sensitive resin composition of the present invention may contain any other resins in addition to resin (A). As any other resins in addition to resin (A), a resin that is decomposed by the action of an acid and may contains the repeating unit included in resin (A) or a resin that is decomposed by the action of an acid and is already-known.

[2] Compound that Generates an Acid when Exposed to Actinic Rays or Radiation (Z)

The composition according to the present invention contains a compound that generates an acid when exposed to actinic rays or radiation (Z) (hereinafter also referred to as “acid generator”).

As the acid generator, use can be made of a member appropriately selected from among a photoinitiator for photocationic polymerization, a photoinitiator for photoradical polymerization, a photo-achromatic agent and photo-discoloring agent for dyes, any of publicly known compounds that generate an acid when exposed to actinic rays or radiation employed in microresists, etc., and mixtures thereof.

As the acid generator, a diazonium salt, a phosphonium salt, a sulfonium salt, an iodonium salt, an imide sulfonate, an oxime sulfonate, diazosulfone, disulfone and o-nitrobenzyl sulfonate can be exemplified.

As preferred compounds among the acid generators, those represented by the following general formulae (ZI), (ZII) and (ZIII) can be exemplified.

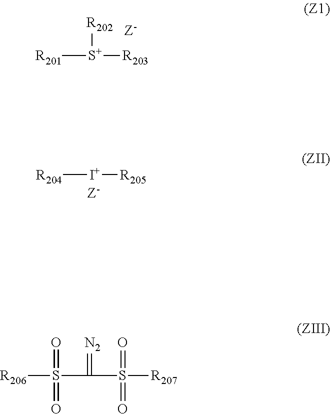

In the above general formula (ZI),

each of R₂₀₁, R₂₀₂ and R₂₀₃ independently represents an organic group.

The number of carbon atoms in the organic group represented by R₂₀₁, R₂₀₂ and R₂₀₃ is generally in the range of 1 to 30, preferably 1 to 20.

Two of R₂₀₁ to R₂₀₃ may be bonded to each other to thereby form a ring structure. The ring structure may contain therein an oxygen atom, a sulfur atom, an ester group, an amido group or a carbonyl group. As the group formed by the mutual bonding of two of R₂₀₁ to R₂₀₃, there can be mentioned, for example, an alkylene group, such as a butylene group or a pentylene group.

Z⁻ represents a nonnucleophilic anion.

As the nonnucleophilic anion represented by Z⁻, a sulfonate anion, a carboxylate anion, a sulfonylimide anion, a bis(alkylsulfonyl)imide anion, and a tris(alkylsulfonyl)methide anion can be exemplified.

The nonnucleophilic anion means an anion whose capability of inducing a nucleophilic reaction is extremely low. Any decomposition over time attributed to an intramolecular nucleophilic reaction can be suppressed by the use of this anion. Therefore, when this anion is used, the stability over time of the relevant composition and the film formed therefrom can be enhanced.

As the sulfonate anion, an aliphatic sulfonate anion, an aromatic sulfonate anion, and a camphor sulfonate anion can be exemplified.

As the carboxylate anion, an aliphatic carboxylate anion, an aromatic carboxylate anion, and an aralkyl carboxylate anion can be exemplified.

The aliphatic moiety of the aliphatic sulfonate anion and the aliphatic carboxylate anion may be an alkyl group or a cycloalkyl group, being preferably an alkyl group having 1 to 30 carbon atoms or a cycloalkyl group having 3 to 30 carbon atoms. As such, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group and a bornyl group can be exemplified.

As a preferred aromatic group of the aromatic sulfonate anion and aromatic carboxylate anion, an aryl group having 6 to 14 carbon atoms, such as a phenyl group, a tolyl group and a naphthyl group can be exemplified.

The alkyl group, cycloalkyl group and aryl group of the aliphatic sulfonate anion and aromatic sulfonate anion may have one or more substituents. As the substituent of the alkyl group, cycloalkyl group and aryl group of the aliphatic sulfonate anion and aromatic sulfonate anion, a nitro group, a halogen atom (fluorine atom, chlorine atom, bromine atom or iodine atom), a carboxy group, a hydroxy group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms) can be exemplified. The aryl group or ring structure of these groups may further have an alkyl group (preferably having 1 to 15 carbon atoms) or a cycloalkyl group (preferably having 3 to 15 carbon atoms) as its substituent.

As a preferred aralkyl group of the aralkyl carboxylate anion, an aralkyl group having 7 to 12 carbon atoms, such as a benzyl group, a phenethyl group, a naphthylmethyl group, a naphthylethyl group, and a naphthylbutyl group can be exemplified.

The alkyl group, cycloalkyl group, aryl group and aralkyl group of the aliphatic carboxylate anion, aromatic carboxylate anion and aralkyl carboxylate anion may have a substituent. As the substituent, aromatic carboxylate anion and aralkyl carboxylate anion, the same halogen atom, alkyl group, cycloalkyl group, alkoxy group, and alkylthio group, etc. as mentioned with respect to the aromatic sulfonate anion can be exemplified.

As the sulfonylimide anion, a saccharin anion can be exemplified.

The alkyl group of the bis(alkylsulfonyl)imide anion and tris(alkylsulfonyl)methide anion is preferably an alkyl group having 1 to 5 carbon atoms. As such, a methyl group, an ethyl group, a propyl group, an isopropyl group, an n-butyl group, an isobutyl group, a sec-butyl group, a pentyl group, and a neopentyl group can be exemplified. As a substituent of these alkyl groups, a halogen atom, an alkyl group substituted with a halogen atom, an alkoxy group, an alkylthio group, an alkyloxysulfonyl group, an aryloxysulfonyl group, and a cycloalkylaryloxysulfonyl group can be exemplified. An alkyl group substituted with a fluorine atom is preferred.

As the other nonnucleophilic anions, phosphorus fluoride, boron fluoride and antimony fluoride can be exemplified.

The nonnucleophilic anion represented by Z⁻ is preferably selected from among an aliphatic sulfonate anion substituted at least at its α-position of sulfonic acid with a fluorine atom, an aromatic sulfonate anion substituted with a fluorine atom or a group having a fluorine atom, a bis(alkylsulfonyl)imide anion whose alkyl group is substituted with a fluorine atom and a tris(alkylsulfonyl)methide anion whose alkyl group is substituted with a fluorine atom. More preferably, the nonnucleophilic anion is a perfluorinated aliphatic sulfonate anion having 4 to 8 carbon atoms or a benzene sulfonate anion having a fluorine atom. Still more preferably, the nonnucleophilic anion is a nonafluorobutane sulfonate anion, a perfluorooctane sulfonate anion, a pentafluorobenzene sulfonate anion or a 3,5-bis(trifluoromethyl)benzene sulfonate anion.

It is preferable for the acid generator to be a compound capable of generating any of sulfonic acids of general formula (Iz) below. As the sulfonic acids of general formula (Iz) contain cyclic organic groups, for the same reason as mentioned above, the resolution and roughness performance can be enhanced thereby.

Therefore, when the acid generator is, for example, any of the compounds of general formulae (ZI) and (ZII), it is preferable for the above-mentioned aromatic sulfonate anion to be an anion capable of producing any of acids of formula (Iz) below.

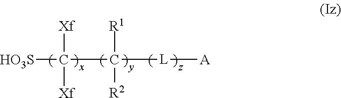

In formula (Iz), each Xf independently represents a fluorine atom or an alkyl group substituted with at least one fluorine atom.

Each of R¹ and R² independently represents a hydrogen atom, a fluorine atom or an alkyl group. When two or more R¹s or R²s are contained, the two or more may be identical to or different from each other.

L represents a bivalent connecting group. When two or more instances of L are contained, they may be identical to or different from each other.

A represents a cyclic organic group.

In the formula, x is an integer of 1 to 20, y an integer of 0 to 10 and z an integer of 0 to 10.

General formula (Iz) will be described in detail below.

The alkyl group of the alkyl group substituted with a fluorine atom, represented by Xf preferably has 1 to 10 carbon atoms, more preferably 1 to 4 carbon atoms. The alkyl group substituted with a fluorine atom, represented by Xf is preferably a perfluoroalkyl group.

Xf is preferably a fluorine atom or a perfluoroalkyl group having 1 to 4 carbon atoms. In particular, there can be mentioned a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Of these, a fluorine atom and CF₃ are preferable. It is especially preferable for each Xf to be a fluorine atom.

A substituent (preferably a fluorine atom) may be introduced in the alkyl group represented by each of R¹ and R². The alkyl group preferably has 1 to 4 carbon atoms. More preferably, the alkyl group is a perfluoroalkyl group having 1 to 4 carbon atoms. The substituted alkyl group represented by each of R¹ and R² is, for example, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Of these, CF₃ is preferable.

Each of R¹ and R² is preferably a fluorine atom or CF₃.

In the formula, y is preferably 0 to 4, more preferably 0; x is preferably 1 to 8, more preferably 1 to 4 and most preferably 1; and z is preferably 0 to 8, more preferably 0 to 4.

The bivalent connecting group represented by L is not particularly limited. As the bivalent connecting group, there can be mentioned —COO—, —OCO—, —CONR— or —NRCO— (in which R represents a hydrogen atom, an alkyl group [preferably having 1 to 6 carbon atoms] or a cycloalkyl group [preferably having 3 to 10 carbon atoms]), —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), a connecting group comprised of two or more of these, or the like. The bivalent connecting group is preferably one whose sum of carbon atoms is 12 or less. Of these, —COO—, —OCO—, —CONR—, —NRCO—, —CO—, —O—, —SO₂—, —COO-alkylene-, —OCO-alkylene-, —CONR-alkylene- and —NRCO-alkylene- are more preferable. —COO—, —OCO— and —SO₂— are further preferable.

The cyclic organic group represented by A is not particularly limited as long as a cyclic structure is contained. As the cyclic organic group, there can be mentioned an alicyclic group, an aryl group, a heterocyclic group (including not only any of those exhibiting aromaticity but also those exhibiting no aromaticity, for example, including tetrahydropyran ring and lactone ring structures) or the like.

The alicyclic group may be monocyclic or polycyclic. Preferably, the alicyclic group is a monocycloalkyl group, such as a cyclopentyl group, a cyclohexyl group or a cyclooctyl group, or a polycycloalkyl group, such as a norbornyl group, a tricyclodecanyl group, a tetracyclodecanyl group, a tetracyclododecanyl group or an adamantyl group. Of the mentioned groups, alicyclic groups with a bulky structure having 7 or more carbon atoms, namely, a norbornyl group, a tricyclodecanyl group, a tetracyclodecanyl group, a tetracyclododecanyl group and an adamantyl group are preferable from the viewpoint of inhibiting any in-film diffusion in the operation of post-exposure bake (PEB), thereby enhancing the mask error enhancement factor (MEEF).

The aryl group may be monocyclic or polycyclic. As the aryl group, there can be mentioned a benzene ring, a naphthalene ring, a phenanthrene ring or an anthracene ring. In particular, the naphthalene of low absorbance is preferable from the viewpoint of the absorbance at 193 nm.

The heterocyclic group may be monocyclic or polycyclic. As the heterocyclic group, there can be mentioned one derived from a furan ring, a thiophene ring, a benzofuran ring, a benzothiophene ring, a dibenzofuran ring, a dibenzothiophene ring, a pyridine ring or a decahydroisoquinoline ring. In particular, heterocyclic groups derived from a furan ring, a thiophene ring, a pyridine ring and a decahydroisoquinoline ring are preferable.

Further, as the cyclic organic group, there can be mentioned a lactone structure.

A substituent may be introduced in the above cyclic organic group. As the substituent, there can be mentioned an alkyl group (may be linear or branched, preferably having 1 to 12 carbon atoms), a cycloalkyl group (may be any of a monocycle, a polycycle and a spiro ring, preferably having 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, a sulfonic ester group or the like. The carbon as a constituent of the cyclic organic group (carbon contributing to ring formation) may be a carbonyl carbon.

As the organic groups represented by R₂₀₁, R₂₀₂ and R₂₀₃ in the structural unit (ZI), there can be mentioned, for example, the corresponding groups of compounds (ZI-1), (ZI-2), (ZI-3) or (ZI-4) to be described hereinafter.

Compounds having two or more of the structures of the general formula (ZI) may be used as the acid generator. For example, use may be made of a compound having a structure in which at least one of the R₂₀₁ to R₂₀₃ of one of the compounds of the general formula (ZI) is bonded to at least one of the R₂₀₁ to R₂₀₃ of another of the compounds of the general formula (ZI) via a single bond or connecting group.

As more preferred (ZI) components, the following compounds (ZI-1) to (ZI-4) can be exemplified.

The compounds (ZI-1) are arylsulfonium compounds of the general formula (ZI) wherein at least one of R₂₀₁ to R₂₀₃ is an aryl group, namely, compounds containing an arylsulfonium as a cation.

In the arylsulfonium compounds, all of the R₂₀₁ to R₂₀₃ may be aryl groups. It is also appropriate that the R₂₀₁ to R₂₀₃ are partially an aryl group and the remainder is an alkyl group or a cycloalkyl group.

As the arylsulfonyl compound, there can be mentioned, for example, a triarylsulfonium compound, a diarylalkylsulfonium compound, an aryldialkylsulfonium compound, a diarylcycloalkylsulfonium compound and an aryldicycloalkylsulfonium compound.

The aryl group of the arylsulfonium compounds is preferably a phenyl group or a naphthyl group, more preferably a phenyl group. The aryl group may be one having a heterocyclic structure containing an oxygen atom, nitrogen atom, sulfur atom or the like. As the aryl group having a heterocyclic structure, a pyrrole residue, a furan residue, a thiophene residue, an indole residue, a benzofuran residue, and a benzothiophene residue can be exemplified. When the arylsulfonium compound has two or more aryl groups, the two or more aryl groups may be identical to or different from each other.

The alkyl group or cycloalkyl group contained in the arylsulfonium compound according to necessity is preferably a linear or branched alkyl group having 1 to 15 carbon atoms or a cycloalkyl group having 3 to 15 carbon atoms. As such, a methyl group, an ethyl group, a propyl group, an n-butyl group, a sec-butyl group, a t-butyl group, a cyclopropyl group, a cyclobutyl group, and a cyclohexyl group can be exemplified.

The aryl group, alkyl group or cycloalkyl group represented by R₂₀₁ to R₂₀₃ may have one or more substituents. As the substituent, an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxy group, and a phenylthio group can be exemplified. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. More preferred substituents are an alkyl group having 1 to 6 carbon atoms and an alkoxy group having 1 to 6 carbon atoms. The substituents may be contained in any one of the three R₂₀₁ to R₂₀₃, or alternatively may be contained in all three of R₂₀₁ to R₂₀₃. When R₂₀₁ to R₂₀₃ represent an aryl group, the substituent preferably lies at the p-position of the aryl group.

Now, the compounds (ZI-2) will be described.

The compounds (ZI-2) are compounds represented by the formula (ZI) wherein each of R₂₀₁ to R₂₀₃ independently represents an organic group having no aromatic ring. The aromatic rings include an aromatic ring having a heteroatom.

The organic group having no aromatic ring represented by R₂₀₁ to R₂₀₃ generally has 1 to 30 carbon atoms, preferably 1 to 20 carbon atoms.

Preferably, each of R₂₀₁ to R₂₀₃ independently represents an alkyl group, a 2-oxoalkyl group, an alkoxycarbonylmethyl group, an allyl group, and a vinyl group. More preferred groups include a linear or branched 2-oxoalkyl group and an alkoxycarbonylmethyl group. Especially preferred is a linear or branched 2-oxoalkyl group.

As preferred alkyl groups and cycloalkyl groups represented by R₂₀₁ to R₂₀₃, a linear or branched alkyl group having 1 to 10 carbon atoms (for example, a methyl group, an ethyl group, a propyl group, a butyl group or a pentyl group) and a cycloalkyl group having 3 to 10 carbon atoms (for example, a cyclopentyl group, a cyclohexyl group or a norbornyl group) can be exemplified. As more preferred alkyl groups, a 2-oxoalkyl group and an alkoxycarbonylmethyl group can be exemplified. As more preferred cycloalkyl group, a 2-oxocycloalkyl group can be exemplified.

The 2-oxoalkyl group may be linear or branched. A group having >C═O at the 2-position of the above-described alkyl group can be preferably exemplified. The 2-oxocycloalkyl group is preferably a group having >C═O at the 2-position of the above-described cycloalkyl group.

As preferred alkoxy groups of the alkoxycarbonylmethyl group, alkoxy groups having 1 to 5 carbon atoms can be exemplified. As such, there can be mentioned, for example, a methoxy group, an ethoxy group, a propoxy group, a butoxy group and a pentoxy group.

R₂₀₁ to R₂₀₃ may further have one or more substituents. As the substituents, a halogen atom, an alkoxy group (having, for example, 1 to 5 carbon atoms), a hydroxy group, a cyano group and a nitro group can be exemplified.

Now, the compounds (ZI-3) will be described.

The compounds (ZI-3) are those represented by the following general formula (ZI-3) which have a phenacylsulfonium salt structure.

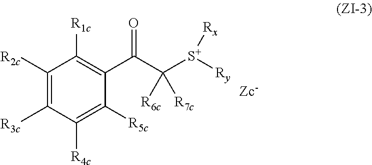

In the formula (ZI-3),

each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Each of R_{6c} and R_{7c} independently represents a hydrogen atom, an alkyl group, a cycloalkyl group, halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more of R_{1c} to R_{5c}, R_{5c} and R_{6c}, R_{6c} and R_{7c}, R_{5c} and Rₓ, and Rₓ and R_{y} may be bonded with each other to thereby form a ring structure. This ring structure may contain an oxygen atom, a sulfur atom, a ketone group, an ester bond or an amido bond.

As the above ring structure, an aromatic or non-aromatic hydrocarbon ring, an aromatic or non-aromatic heterocycle, or a polycyclic condensed rings resulting from condensation of two or more these rings are exemplified. As the ring structure, 3- to 10-memberd ring can be exemplified, 4- to 8-membered ring is preferred, and 5- or 6-membered ring is more preferred.

As the group formed by bonding of any two or more of R_{1c} to R_{5c}, and R_{6c} and R_{7c}, and Rₓ and R_{y}, there can be mentioned a butylene group, a pentylene group or the like.

As the group formed by bonding of R_{5c} and R_{6c}, and R_{5c} and Rₓ, a single bond or an alkylene group is preferred. As the alkykene group, there can be mentioned a methylene group, an ethylene group or the like.

Zc⁻ represents a nonnucleophilic anion. There can be mentioned the same nonnucleophilic anions as mentioned with respect to the Z⁻ of the general formula (ZI).

The alkyl group represented by R_{1c} to R_{7c} may be linear or branched. As such, there can be mentioned, for example, an alkyl group having 1 to 20 carbon atoms, preferably a linear or branched alkyl group having 1 to 12 carbon atoms (for example, a methyl group, an ethyl group, a linear or branched propyl group, a linear or branched butyl group or a linear or branched pentyl group). As the cycloalkyl group, there can be mentioned, for example, a cycloalkyl group having 3 to 10 carbon atoms (for example, a cyclopentyl group or a cyclohexyl group).

Each of the aryl groups represented by R_{1c} to R_{5c} preferably has 5 to 15 carbon atoms. As such, there can be mentioned, for example, a phenyl group or a naphthyl group.

The alkoxy group represented by R_{1c} to R_{5c} may be linear, or branched, or cyclic. As such, there can be mentioned, for example, an alkoxy group having 1 to 10 carbon atoms, preferably a linear or branched alkoxy group having 1 to 5 carbon atoms (for example, a methoxy group, an ethoxy group, a linear or branched propoxy group, a linear or branched butoxy group or a linear or branched pentoxy group) and a cycloalkoxy group having 3 to 10 carbon atoms (for example, a cyclopentyloxy group or a cyclohexyloxy group).

Particular examples of the alkoxy groups of the alkoxycarbonyl groups represented by R_{1c} to R_{5c} are the same as those of the alkoxy groups represented by R_{1c} to R_{5c}. Particular examples of the alkyl groups of the alkylcarbonyloxy groups and alkylthio groups represented by R_{1c} to R_{5c} are the same as those of the alkyl groups represented by R_{1c} to R_{5c}.

Particular examples of the cycloalkyl groups of the cycloalkylcarbonyloxy groups represented by R_{1c} to R_{5c} are the same as those of the cycloalkyl groups represented by R_{1c} to R_{5c}.

Particular examples of the aryl groups of the aryloxy groups and arylthio groups represented by R_{1c} to R_{5c} are the same as those of the aryl groups represented by R_{1c} to R_{5c}. Preferably, any one of R_{1c} to R_{5c} is a linear or branched alkyl group, a cycloalkyl group or a linear, branched or cyclic alkoxy group. More preferably, the sum of carbon atoms constituting R_{1c} to R_{5c} is in the range of 2 to 15. In such instances, the solubility in solvents can be increased, and any particle generation during storage can be inhibited.

The ring structure that may be formed by the mutual bonding of any two or more of R_{1c} to R_{5c} is preferably a 5- or 6-membered ring, most preferably a 6-membered ring (for example, a phenyl ring).

As the ring structure that may be formed by the mutual bonding of R_{5c} and R_{6c}, there can be mentioned a 4- or more membered ring (most preferably a 5- or 6-membered ring) formed in cooperation with the carbonyl carbon atom and carbon atom in general formula (ZI-3) by virtue of the formation of a single bond or an alkylene group (a methylene group, an ethylene group or the like) through the mutual bonding of R_{5c} and R_{6c}.

Each of the aryl groups represented by R_{6c} and R_{7c} preferably has 5 to 15 carbon atoms. For example, there can be mentioned a phenyl group or a naphthyl group. With respect to the forms of R_{6c} and R_{7c}, it is preferable for both thereof to be alkyl groups. In particular, it is preferable for each of R_{6c} and R_{7c} to be a linear or branched alkyl group having 1 to 4 carbon atoms. It is especially preferable for both thereof to be methyl groups.

When R_{6c} and R_{7c} are bonded to each other to thereby form a ring, the group formed by the bonding of R_{6c} and R_{7c} is preferably an alkylene group having 2 to 10 carbon atoms. As such, there can be mentioned, for example, an ethylene group, a propylene group, a butylene group, a pentylene group, a hexylene group or the like. Further, the ring formed by the bonding of R_{6c} and R_{7c} may have a heteroatom, such as an oxygen atom, in the ring.

As the alkyl groups and cycloalkyl groups represented by Rₓ and R_{y}, there can be mentioned the same alkyl groups and cycloalkyl groups as set forth above with respect to R_{1c} to R_{7c}.

As the 2-oxoalkyl group and 2-oxocycloalkyl group, there can be mentioned the alkyl group and cycloalkyl group represented by R_{1c} to R_{7c} having >C═O at the 2-position thereof.

With respect to the alkoxy group of the alkoxycarbonylalkyl group, there can be mentioned the same alkoxy groups as mentioned above with respect to R_{1c} to R_{5c}. As the alkyl group thereof, there can be mentioned, for example, an alkyl group having 1 to 12 carbon atoms, preferably a linear alkyl group having 1 to 5 carbon atoms (e.g., a methyl group or an ethyl group).

The allyl groups are not particularly limited. However, preferred use is made of an unsubstituted allyl group or an allyl group substituted with a cycloalkyl group of a single ring or multiple rings (preferably, a cycloalkyl group having 3 to 10 carbon atoms).

The vinyl groups are not particularly limited. However, preferred use is made of an unsubstituted vinyl group or a vinyl group substituted with a cycloalkyl group of a single ring or multiple rings (preferably, a cycloalkyl group having 3 to 10 carbon atoms).

As the ring structure that may be formed by the mutual bonding of R_{5c} and Rₓ, there can be mentioned 5 or more-memberd ring (especially preferably, a 5-membered ring) formed in cooperation with the sulfur atom and carbonyl carbon atom of general formula (ZI-3) by bonding R_{5c} and Rₓ each other to thereby form a single bond or alkylene group (a methylene group, an ethylene group, or the like).

As the ring structure that may be formed by the mutual bonding of Rₓ and R_{y}, there can be mentioned a 5-membered or 6-membered ring, especially preferably a 5-membered ring (namely, a tetrahydrothiophene ring), formed by bivalent Rₓ and R_{y} (for example, a methylene group, an ethylene group, a propylene group or the like) in cooperation with the sulfur atom of general formula (ZI-3).

Each of Rₓ and R_{y} is preferably an alkyl group or cycloalkyl group having preferably 4 or more carbon atoms. The alkyl group or cycloalkyl group has more preferably 6 or more carbon atoms and still more preferably 8 or more carbon atoms.

A substituent may further be introduced in each of the groups represented by R_{1c} to R_{7c}, Rₓ and R_{y}. As such a substituent, there can be mentioned a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, an aryloxycarbonyloxy group or the like.

In general formula (ZI-3) above, preferably, each of R_{1c}, R_{2c}, R_{4c} and R_{5c} independently is a hydrogen atom, and R_{3c} is a non-hydrogen-atom group, namely, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Specific examples of the cation part in the compounds represented by general formula (ZI-2) or (ZI-3) will be described below.

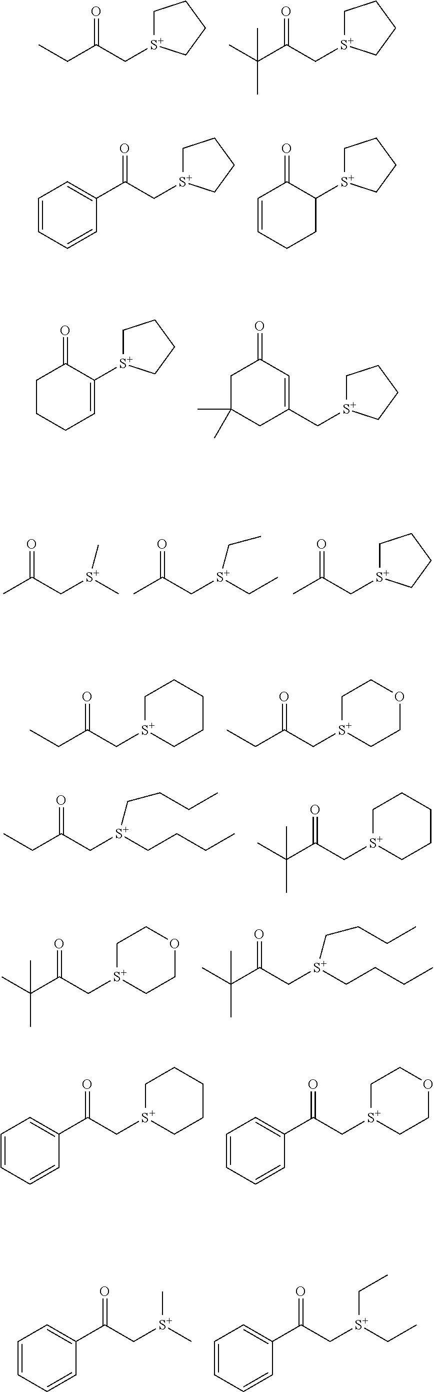

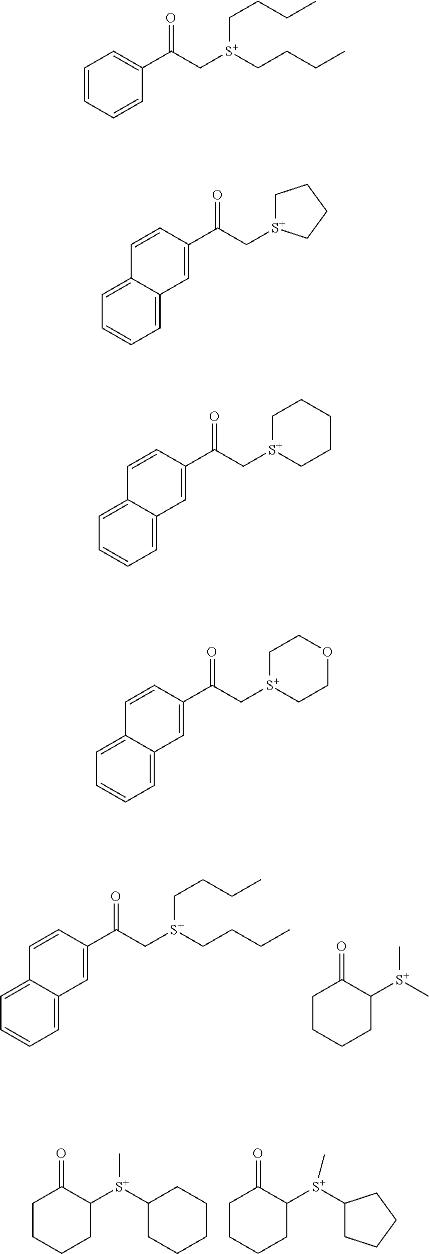

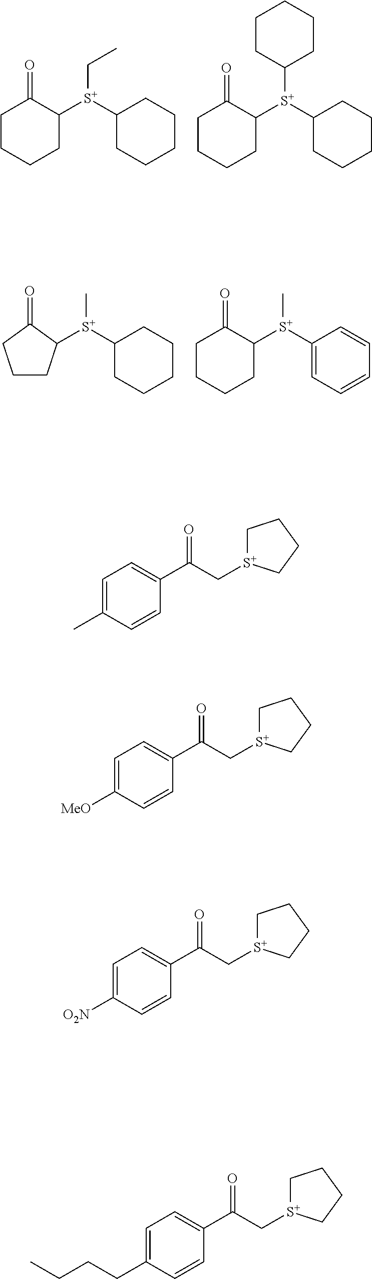

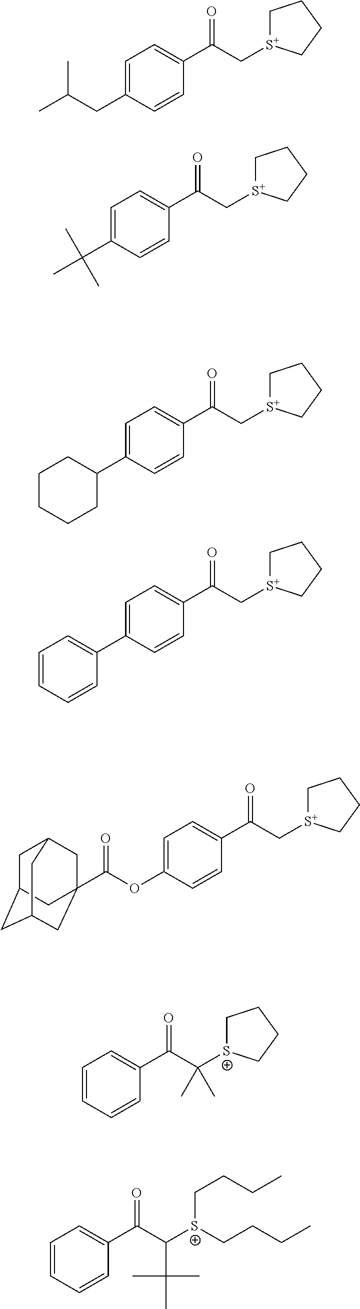

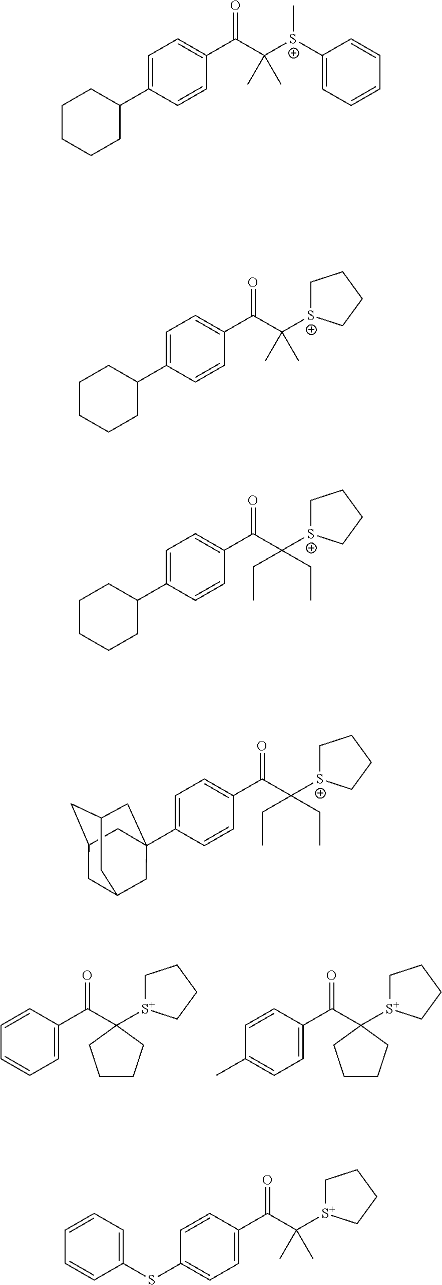

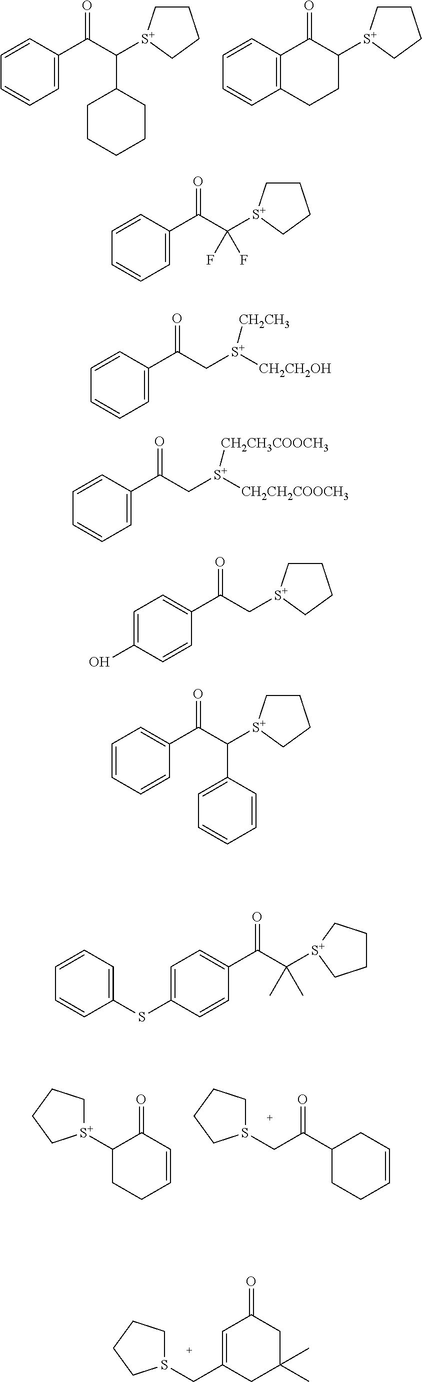

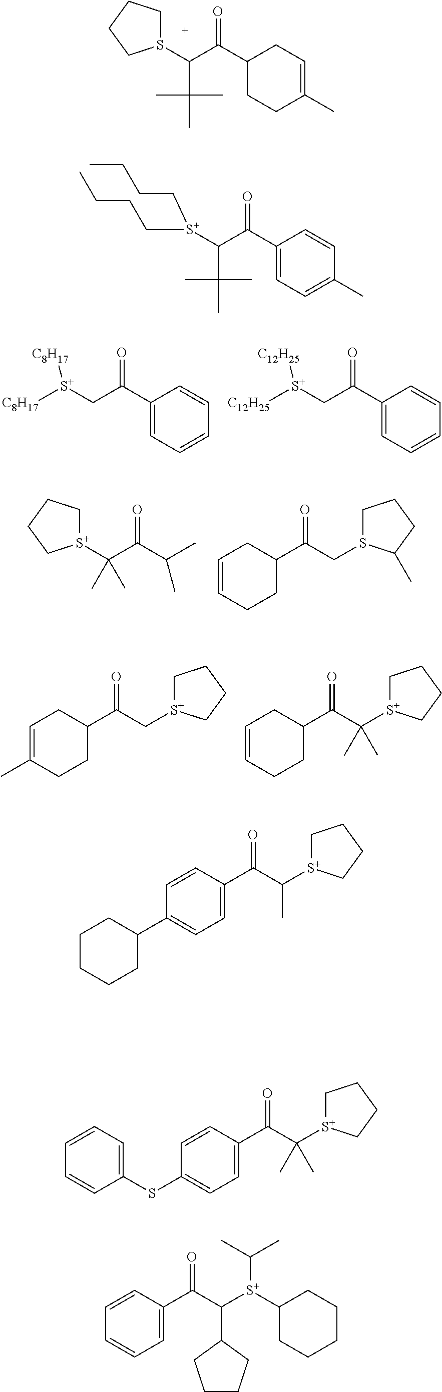

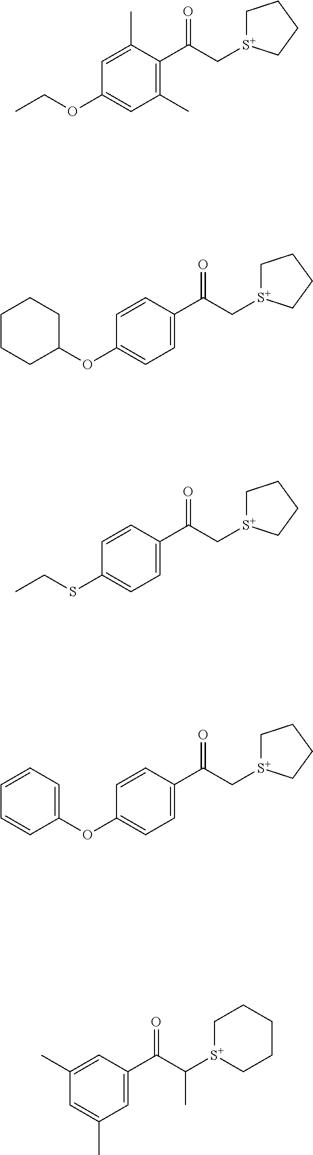

Now, the compounds (ZI-4) will be described.

The structural units (ZI-4) are those of general formula (ZI-4) below.

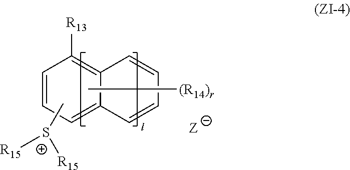

In general formula (ZI-4),

R₁₃ represents a group with a hydrogen atom, a fluorine atom, a hydroxyl group, an alkyl group, a cycloalkyl group, an alkoxy group, an alkoxycarbonyl group or a cycloalkyl group. These groups may have one or more substituents.

R₁₄, each independently in the instance of R₁₄s, represents a group with a hydroxyl group, an alkyl group, a cycloalkyl group, an alkoxy group, an alkoxycarbonyl group, an alkylcarbonyl group, an alkylsulfonyl group, a cycloalkylsulfonyl group or a cycloalkyl group. These groups may have one or more substituents.

Each of R₁₅s independently represents an alkyl group, a cycloalkyl group or a naphthyl group, provided that the two R₁₅s may be bonded to each other to thereby form a ring. These groups may have one or more substituents.

l is an integer of 0 to 2, and r is an integer of 0 to 8.

Z⁻ represents a nonnucleophilic anion. As such, there can be mentioned any of the same nonnucleophilic anions as mentioned with respect to the Z⁻ of the general formula (ZI).

In general formula (ZI-4), the alkyl groups represented by R₁₃, R₁₄ and R₁₅ may be linear or branched and preferably each have 1 to 10 carbon atoms. As such, there can be mentioned preferably a methyl group, an ethyl group, an n-butyl group, a t-butyl group and the like.

As the cycloalkyl groups represented by R₁₃, R₁₄ and R₁₅, there can be mentioned monocyclic or polycyclic cycloalkyl groups (preferably, a cycloalkyl group having 3 to 20 carbon atoms). Of these cycloalkyl groups, cyclopropyl, cyclopentyl, cyclohexyl, cycloheptyl and cyclooctyl are especially preferred.

The alkoxy groups represented by R₁₃ and R₁₄ may be linear or branched and preferably each have 1 to 10 carbon atoms. A methoxy group, an ethoxy group, an n-propoxy group, an n-butoxy group and the like are preferred.

The alkoxycarbonyl group represented by R₁₃ and R₁₄ may be linear or branched and preferably has 2 to 11 carbon atoms. A methoxycarbonyl group, an ethoxycarbonyl group, an n-butoxycarbonyl group and the like are preferred.

As the groups with a cycloalkyl group represented by R₁₃ and R₁₄, there can be mentioned a monocyclic or polycyclic cycloalkyl group (preferably, a cycloalkyl group having 3 to 20 carbon atoms), for example, a monocyclic or polycyclic cycloalkyloxy group and an alkoxy group with a monocyclic or polycyclic cycloalkyl group. These groups may further have one or more substituents.

With respect to each of the monocyclic or polycyclic cycloalkyloxy groups represented by R₁₃ and R₁₄, the sum of carbon atoms thereof is preferably 7 or greater, more preferably in the range of 7 to 15. Further, having a monocyclic cycloalkyl group is preferred. The monocyclic cycloalkyloxy group of which the sum of carbon atoms is 7 or greater is one composed of a cycloalkyloxy group, such as a cyclopropyloxy group, a cyclobutyloxy group, a cyclopentyloxy group, a cyclohexyloxy group, a cycloheptyloxy group, a cyclooctyloxy group or a cyclododecanyloxy group, optionally having a substituent selected from among an alkyl group such as methyl, ethyl, propyl, butyl, pentyl, hexyl, heptyl, octyl, dodecyl, 2-ethylhexyl, isopropyl, sec-butyl, t-butyl or isoamyl, a hydroxyl group, a halogen atom (fluorine, chlorine, bromine or iodine), a nitro group, a cyano group, an amido group, a sulfonamido group, an alkoxy group such as methoxy, ethoxy, hydroxyethoxy, propoxy, hydroxypropoxy or butoxy, an alkoxycarbonyl group such as methoxycarbonyl or ethoxycarbonyl, an acyl group such as formyl, acetyl or benzoyl, an acyloxy group such as acetoxy or butyryloxy, a carboxyl group and the like, provided that the sum of carbon atoms thereof, including those of any optional substituent introduced in the cycloalkyl group, is 7 or greater.

As the polycyclic cycloalkyloxy group of which the sum of carbon atoms is 7 or greater, there can be mentioned a norbornyloxy group, a tricyclodecanyloxy group, a tetracyclodecanyloxy group, an adamantyloxy group or the like.

With respect to each of the alkyloxy groups having a monocyclic or polycyclic cycloalkyl group represented by R₁₃ and R₁₄, the sum of carbon atoms thereof is preferably 7 or greater, more preferably in the range of 7 to 15. Further, the alkoxy group having a monocyclic cycloalkyl group is preferred. The alkoxy group having a monocyclic cycloalkyl group of which the sum of carbon atoms is 7 or greater is one composed of an alkoxy group, such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy or isoamyloxy, substituted with the above optionally substituted cycloalkyl group of a single ring, provided that the sum of carbon atoms thereof, including those of the substituents, is 7 or greater. For example, there can be mentioned a cyclohexylmethoxy group, a cyclopentylethoxy group, a cyclohexylethoxy group or the like. A cyclohexylmethoxy group is preferred.

As the alkoxy group having a polycyclic cycloalkyl group of which the sum of carbon atoms is 7 or greater, there can be mentioned a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group and the like. Of these, a norbornylmethoxy group, a norbornylethoxy group and the like are preferred.

With respect to the alkyl group of the alkylcarbonyl group represented by R₁₄, there can be mentioned the same specific examples as mentioned above with respect to the alkyl groups represented by R₁₃ to R₁₅.

The alkylsulfonyl and cycloalkylsulfonyl groups represented by R₁₄ may be linear, branched or cyclic and preferably each have 1 to 10 carbon atoms. For example, a methanesulfonyl group, an ethanesulfonyl group, an n-propanesulfonyl group, an n-butanesulfonyl group, a cyclopentanesulfonyl group, a cyclohexanesulfonyl group and the like are preferred.

Each of the groups may have one or more substituents. As such substituents, there can be mentioned, for example, a halogen atom (e.g., a fluorine atom), a hydroxyl group, a carboxyl group, a cyano group, a nitro group, an alkoxy group, an alkoxyalkyl group, an alkoxycarbonyl group, an alkoxycarbonyloxy group or the like.

As the alkoxy group, there can be mentioned, for example, a linear, branched or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group or a cyclohexyloxy group.

As the alkoxyalkyl group, there can be mentioned, for example, a linear, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group or a 2-ethoxyethyl group.

As the alkoxycarbonyl group, there can be mentioned, for example, a linear, branched or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group or a cyclohexyloxycarbonyl group.

As the alkoxycarbonyloxy group, there can be mentioned, for example, a linear, branched or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group or a cyclohexyloxycarbonyloxy group.

The cyclic structure that may be formed by the bonding of the two R₁₅s to each other is preferably a 5- or 6-membered ring, especially a 5-membered ring (namely, a tetrahydrothiophene ring) formed by two R₁₅s in cooperation with the sulfur atom of general formula (ZI-4). The cyclic structure may condense with an aryl group or a cycloalkyl group. The cyclic structure may have substituents. As such a substituent, there can be mentioned, for example, a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group and the like as mentioned above. The cyclic structure may have a plurality of substituents and these substituents may be bonded to each other so as to form a ring (such as an aromatic or non-aromatic hydrocarbon ring, an aromatic or non-aromatic heterocycle, a polycyclic condensed rings resulting from condensation of two or more these rings are exemplified or the like).

It is preferred for the R₁₅ of general formula (ZI-4) to be a methyl group, an ethyl group, the above-mentioned bivalent group allowing two R₁₅s to be bonded to each other so as to form a tetrahydrothiophene ring structure in cooperation with the sulfur atom of the general formula (ZI-4), or the like.

Each of R₁₃ and R₁₄ may have one or more substituents. As such substituents, there can be mentioned, for example, a hydroxyl group, an alkoxy group, an alkoxycarbonyl group, a halogen atom (especially, a fluorine atom) or the like.

In the formula, 1 is preferably 0 or 1, and more preferably 1.

In the formula, r is preferably 0 to 2.

Specific examples of the cation part in the structural unit (ZI-4) will be shown below.

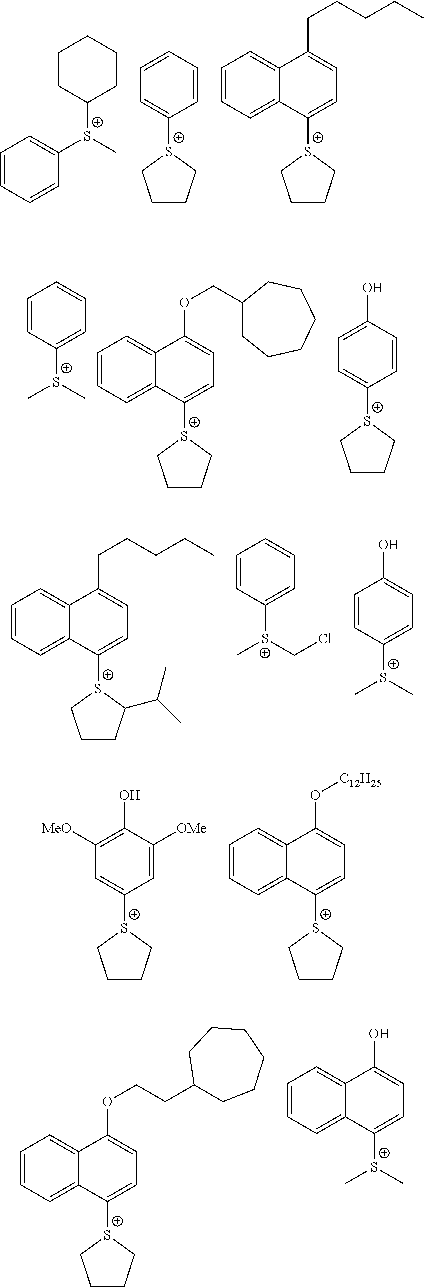

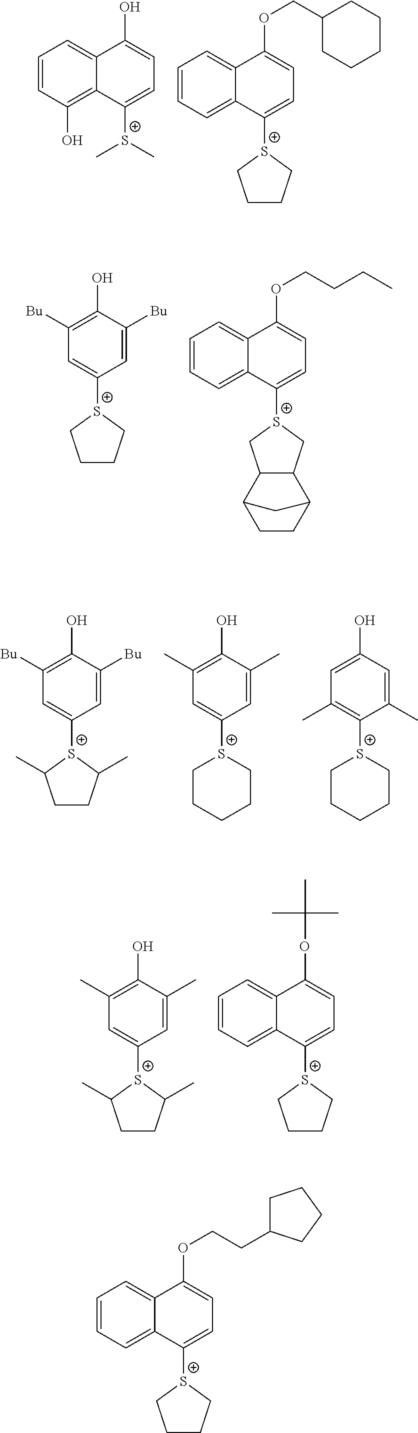

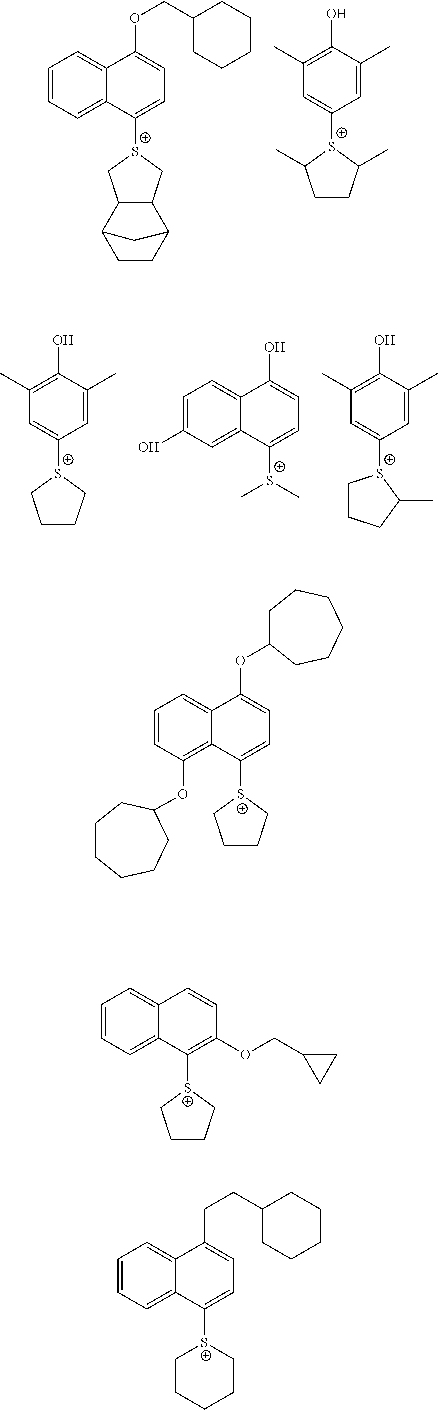

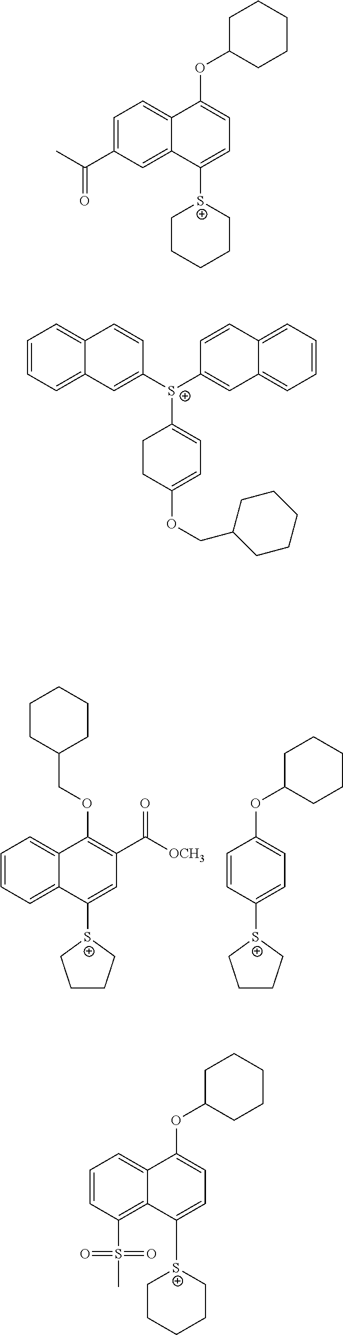

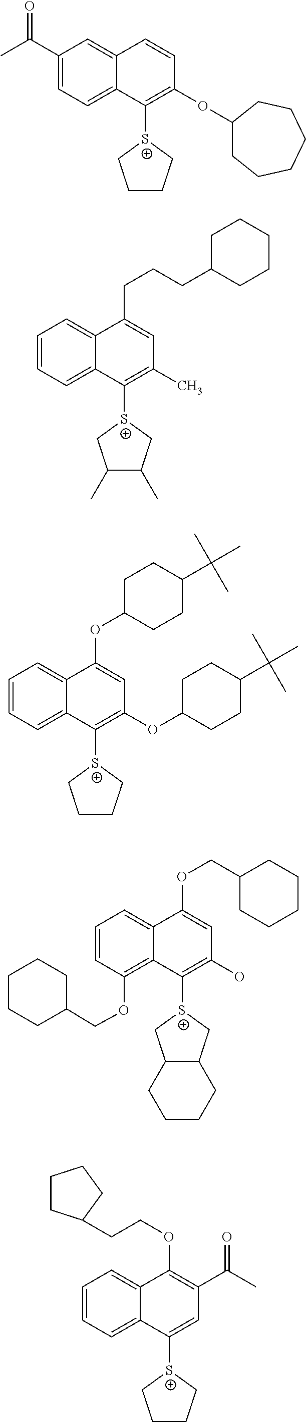

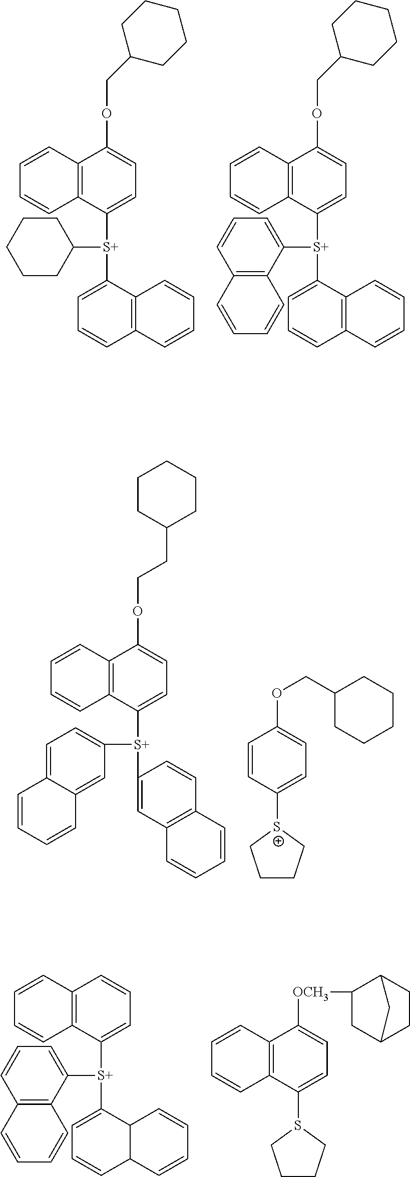

Now the general formulae (ZII) and (ZIII) will be described.

In general formulae (ZII) and (ZIII),

each of R₂₀₄ to R₂₀₇ independently represents an aryl group, an alkyl group or a cycloalkyl group.

The aryl group represented by each of R₂₀₄ to R₂₀₇ is preferably a phenyl group or a naphthyl group, more preferably a phenyl group. The aryl group may be one having a heterocyclic structure containing an oxygen atom, nitrogen atom, sulfur atom, etc. As the skelton of the aryl group having a heterocyclic structure, a pyrrole residue, a furan residue, a thiophene residue, an indole residue, a benzofuran residue, and a benzothiophene residue can be exemplified.

As preferred alkyl groups and cycloalkyl groups represented by R₂₀₄ to R₂₀₇, a linear or branched alkyl group having 1 to 10 carbon atoms and a cycloalkyl group having 3 to 10 carbon atoms can be exemplified. As the alkyl group, for example, a methyl group, an ethyl group, a propyl group, a butyl group and a pentyl group can be exemplified. As the cycloalkyl group, for example, a cyclopentyl group, a cyclohexyl group and a norbornyl group can be exemplified.

The aryl group, alkyl group and cycloalkyl group represented by R₂₀₄ to R₂₀₇ may have one or more substituents. As a possible substituent on the aryl group, alkyl group and cycloalkyl group represented by R₂₀₄ to R₂₀₇, an alkyl group (having, for example, 1 to 15 carbon atoms), a cycloalkyl group (having, for example, 3 to 15 carbon atoms), an aryl group (having, for example, 6 to 15 carbon atoms), an alkoxy group (having, for example, 1 to 15 carbon atoms), a halogen atom, a hydroxy group, and a phenylthio group can be exemplified.

Z⁻ represents a nonnucleophilic anion. As such, the same nonnucleophilic anions as mentioned with respect to the Z⁻ in the general formula (ZI) can be exemplified.

As the acid generators, the compounds represented by the following general formulae (ZIV), (ZV) and (ZVI) can further be exemplified.

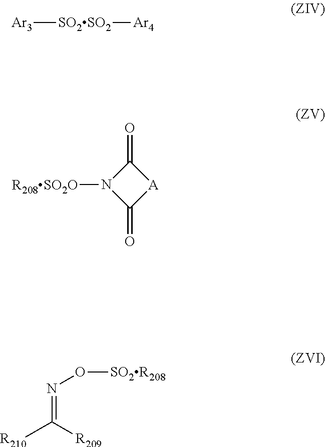

In the general formulae (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

As specific examples of the aryl group represented by Ar₃, Ar₄, R₂₀₈, R₂₀₉ and R₂₁₀, for example, the same aryl group as explained with respect to R₂₀₁, R₂₀₂ and R₂₀₃ can be exemplified.

As specific examples of the alkyl group and the cycloalkyl group, for example, the same alkyl group and the cycloalkyl group as explained with respect to R₂₀₁, R₂₀₂ and R₂₀₃ can be exemplified.

As the alkylene group represented by A, for example, the one having 1 to 12 carbon atoms such as a methylene group, an ethylene group, a propylene group, an isopropylene group, a butylene group, an isobutylene group, or the like can be exemplified.

As the alkenylene group represented by A, for example, the one having 2 to 12 carbon atoms such as an ethenylene group, a propenylene group, a butenylene group, or the like can be exemplified.

As the arylene group represented by A, for example, the one having 6 to 10 carbon atoms such as a phenylene group, a tolylene group, a naphthylene group, or the like can be exemplified.

Among the acid generators, the compounds represented by the general formulae (ZI) to (ZIII) are more preferred.

The acid generator is preferably a compound capable of generating an acid containing one sulfonic acid group or imido group. More preferably, the acid generator is a compound capable of generating a monovalent perfluoroalkanesulfonic acid, or a compound capable of generating a monovalent aromatic sulfonic acid substituted with a fluorine atom or a group containing a fluorine atom, or a compound capable of generating a monovalent imidic acid substituted with a fluorine atom or a group containing a fluorine atom. Further more preferably, the acid generator is a sulfonium salt of fluorinated alkanesulfonic acid, fluorinated benzenesulfonic acid, fluorinated imidic acid or fluorinated methide acid. With respect to acid generators, it is especially preferred for the generated acid to be a fluorinated alkanesulfonic acid, fluorinated benzenesulfonic acid or fluorinated imidic acid of −1 or below pKa. When these acid generators are used, the sensitivity can be enhanced.

According to one preferable embodiment of the present invention, the acid generator is expressed by general formula (I′) below. The use of compounds of general formula (I′) below enhances the transmission of exposure light through the film, thereby contributing to the improvement of line edge roughness and depth of focus (DOF).

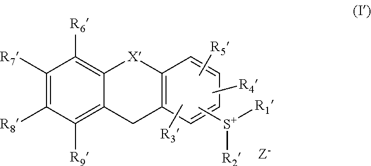

In general formula (I′) above,

X′ represents an oxygen atom, a sulfur atom or —N(Rₓ′)—.

R₁′ and R₂′ may be linked to each other thereby forming a ring. Any two or more of R₆′ to R₉′, R₃′ and R₉′, R₄′ and R₅′, R₅′ and Rₓ′, and R₆′ and Rₓ′ may be linked to each other, thereby forming a ring.

Each of R₁′ and R₂′ independently represents an alkyl group, a cycloalkyl group or an aryl group.

Each of R₃′ to R₉′ independently represents a hydrogen atom, an alkyl group, a cycloalkyl group, an alkoxy group, an alkoxycarbonyl group, an acyl group, an alkylcarbonyloxy group, an aryl group, an aryloxy group, an aryloxycarbonyl group or an arylcarbonyloxy group.

Rₓ′ represents a hydrogen atom, an alkyl group, a cycloalkyl group, an acyl group, an alkenyl group, an alkoxycarbonyl group, an aryl group, an arylcarbonyl group or an aryloxycarbonyl group.

Z⁻ represents a nonnucleophilic anion. As the nonnucleophilic anion, there can be mentioned any of those represented by Z⁻ of general formula (ZI).

Especially preferred examples of the acid generators will be shown below.

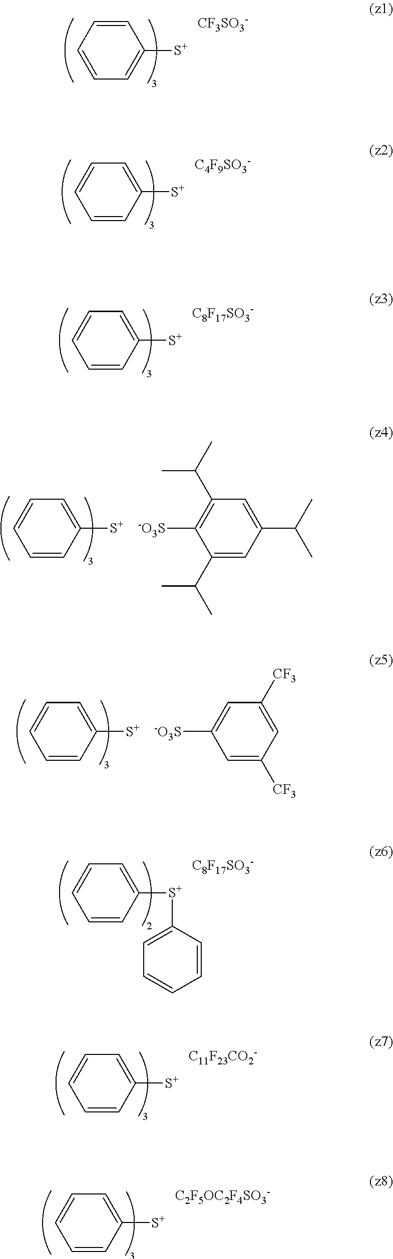

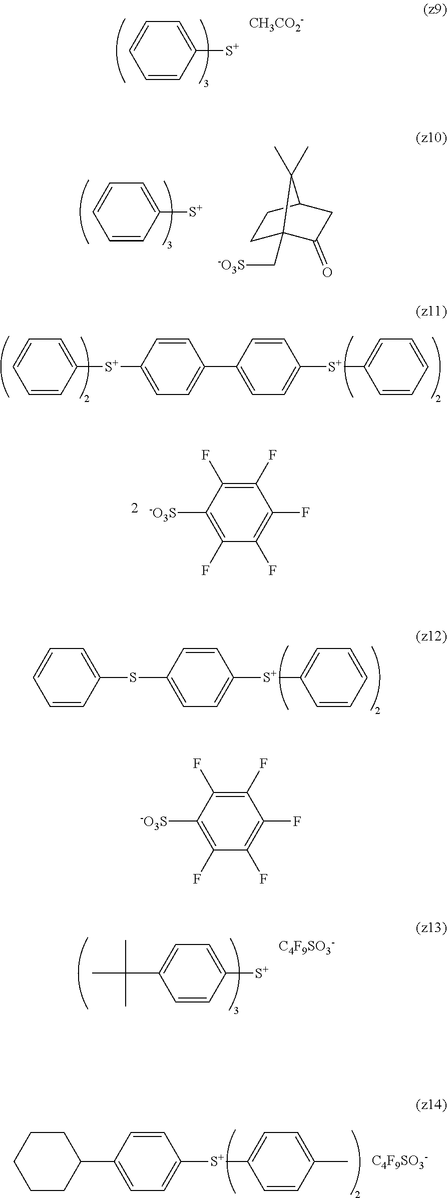

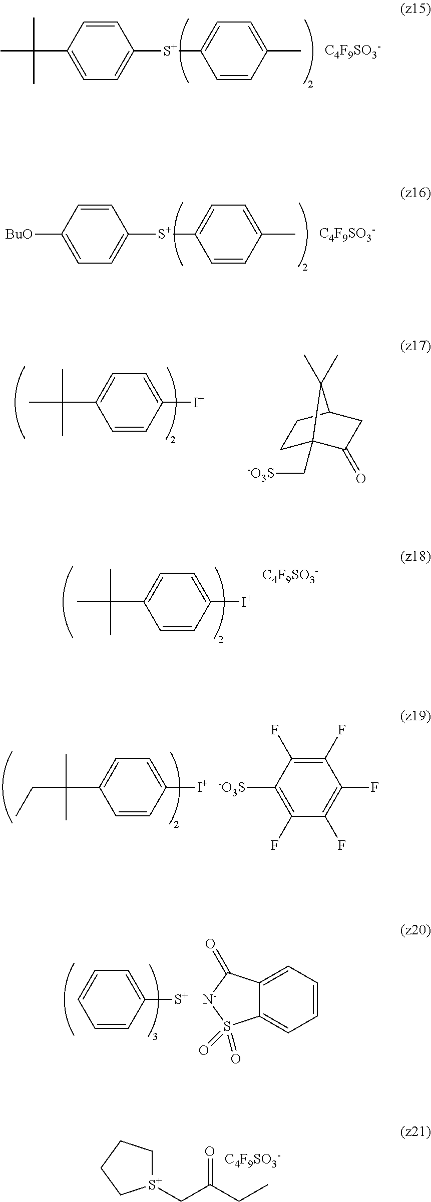

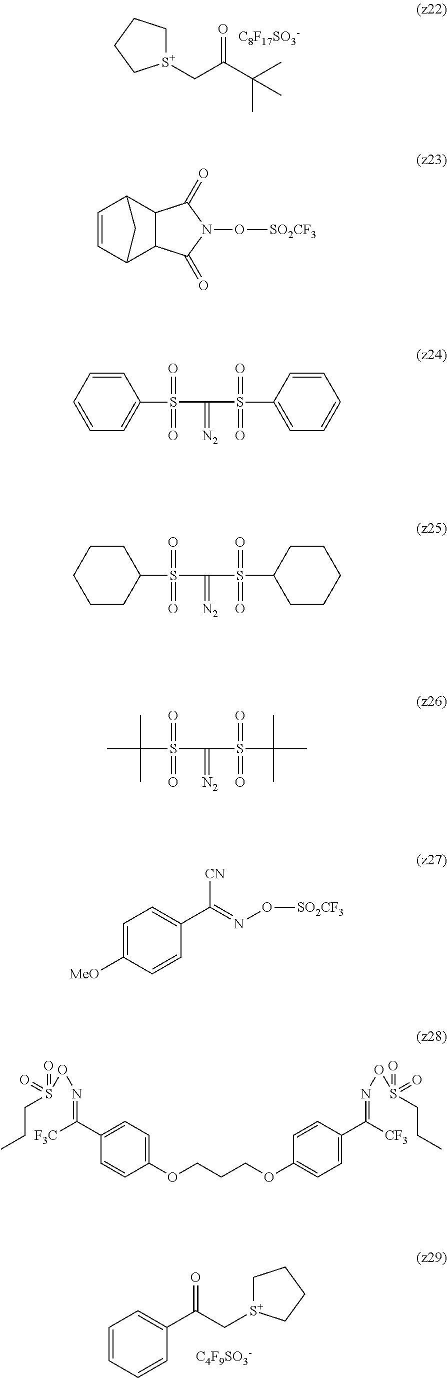

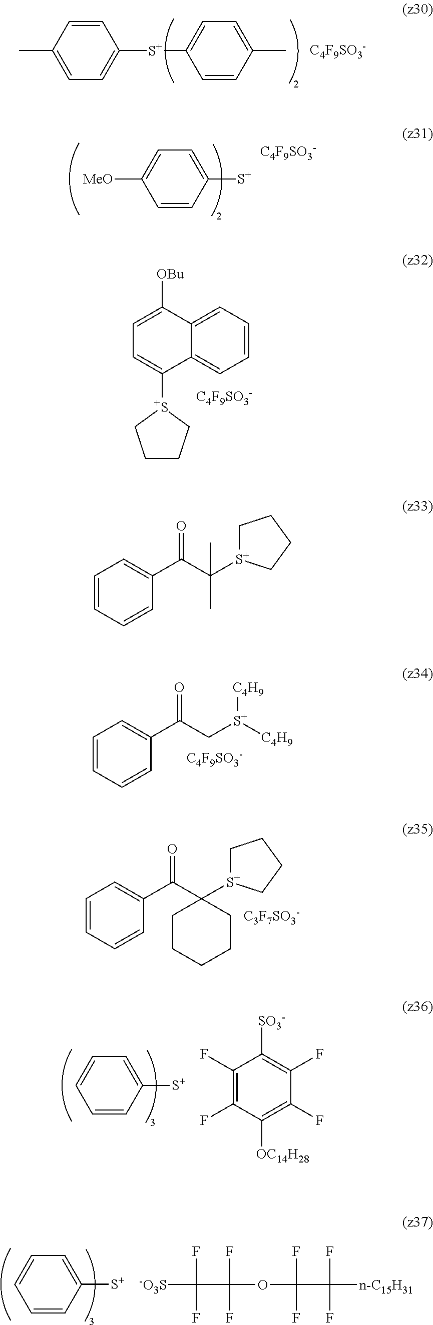

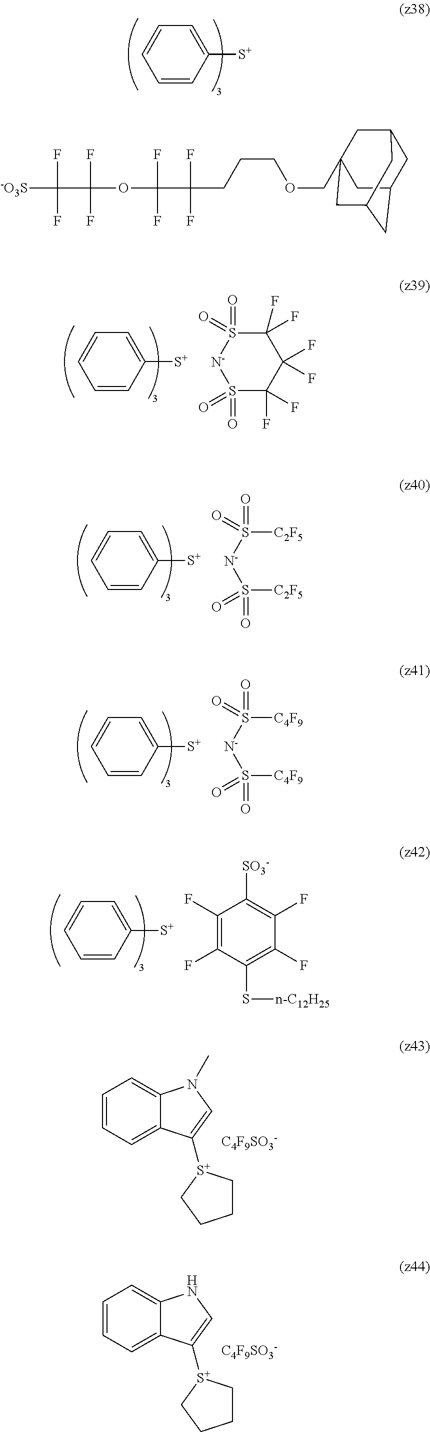

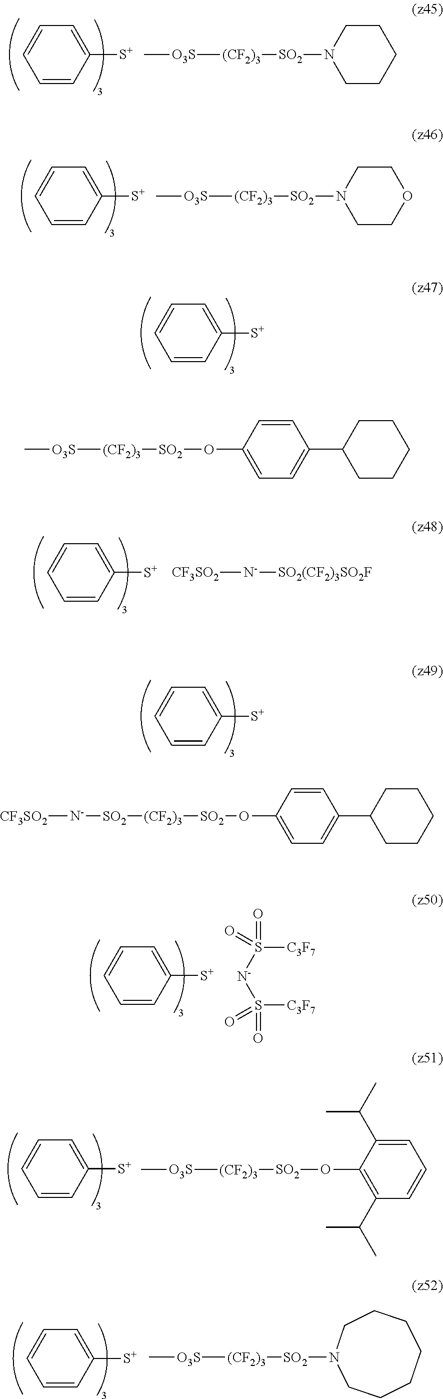

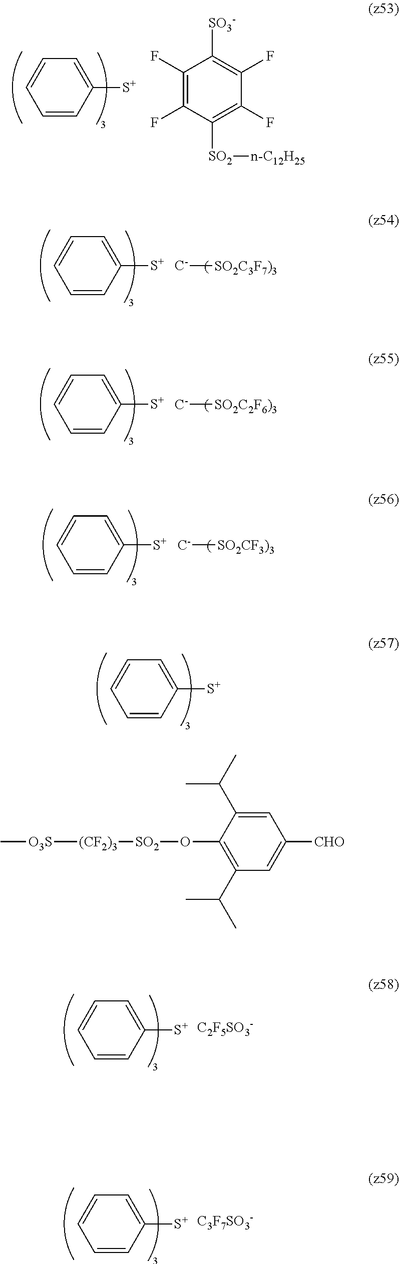

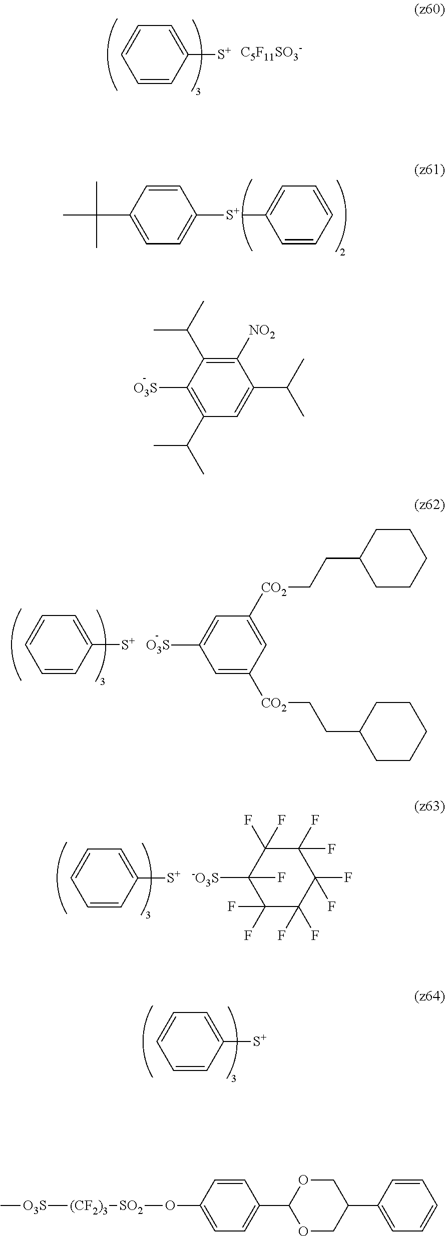

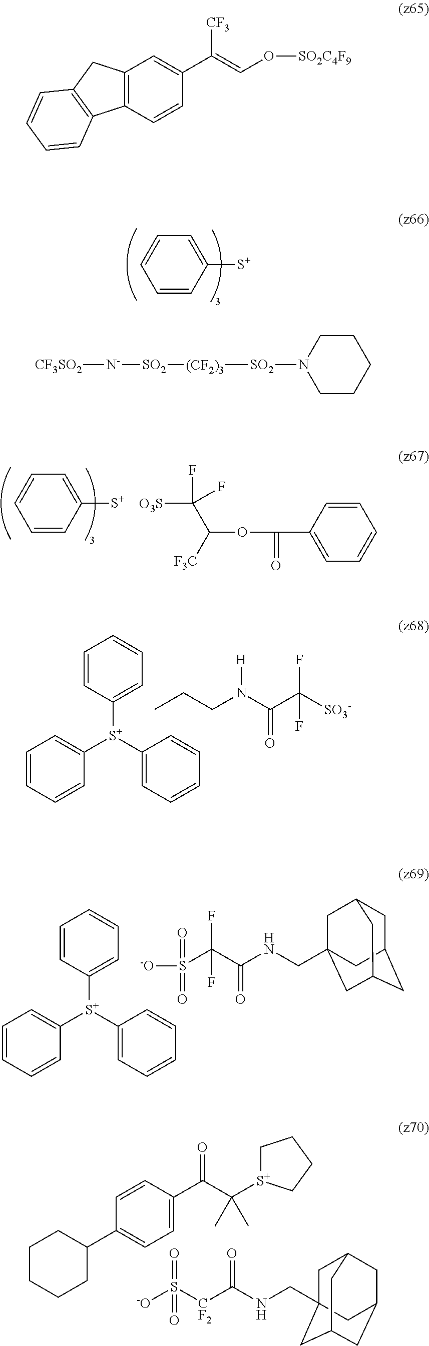

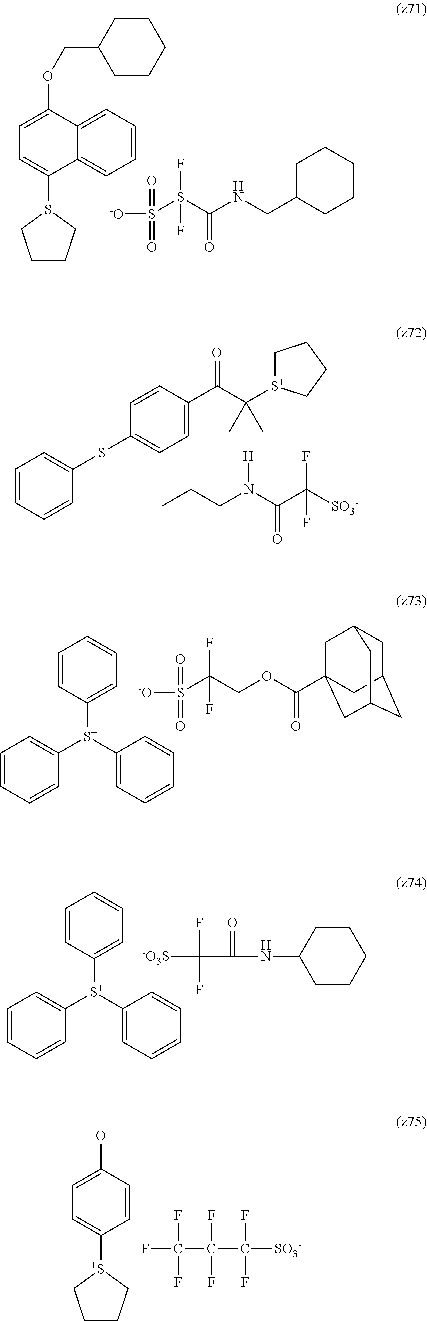

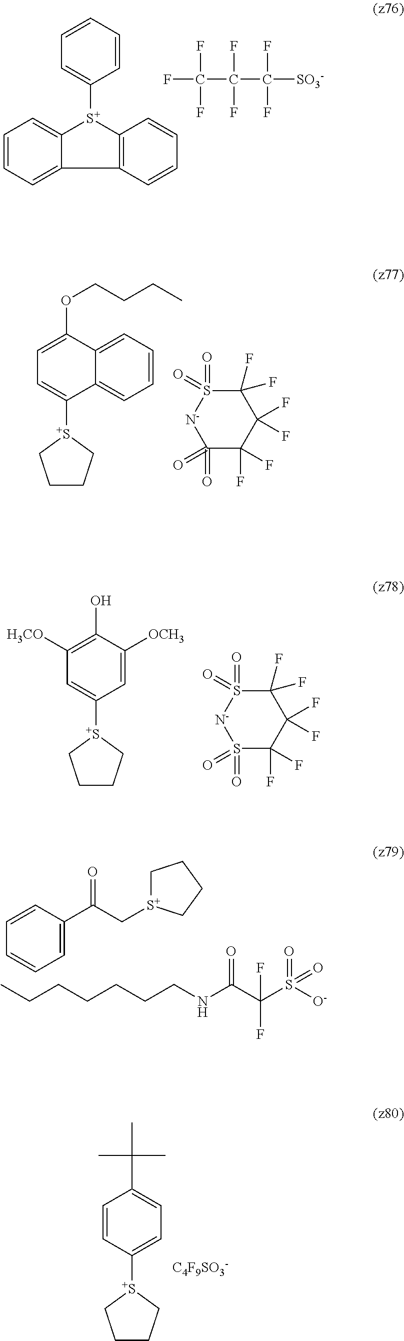

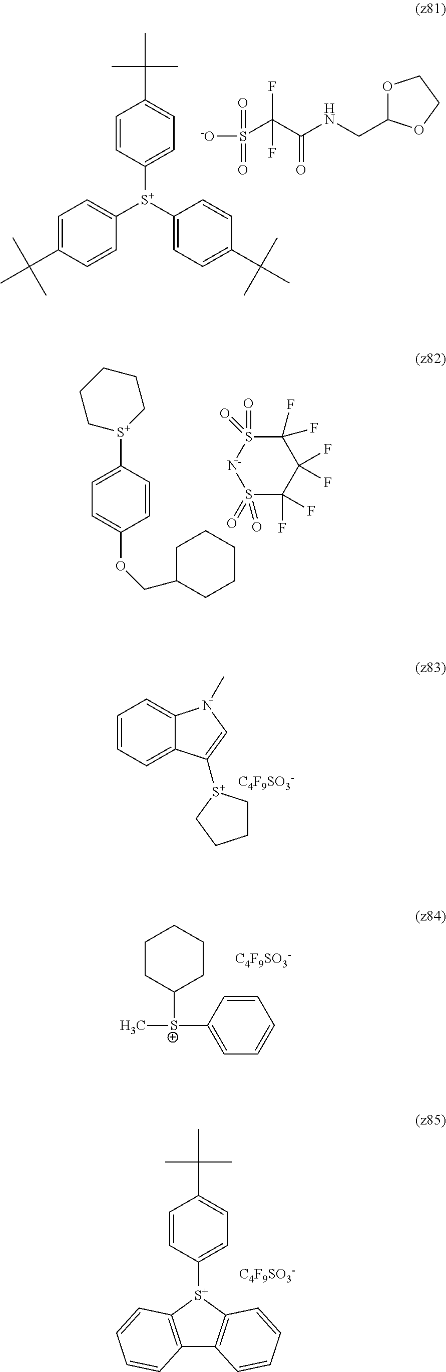

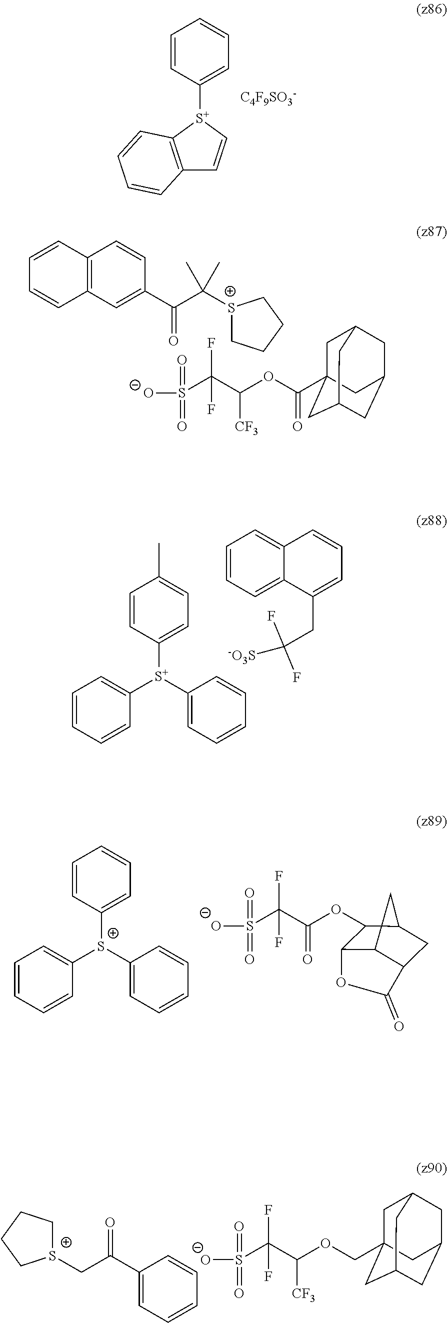

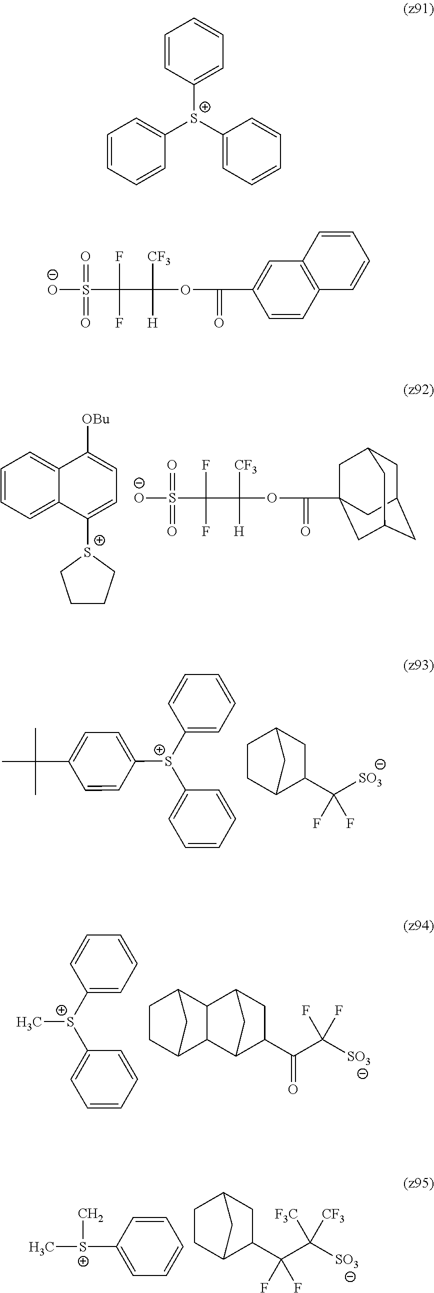

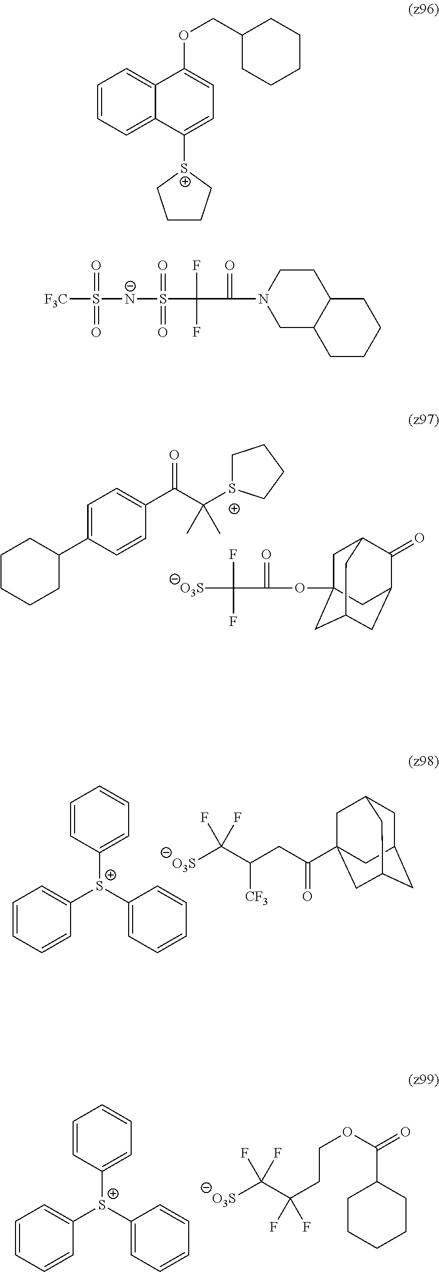

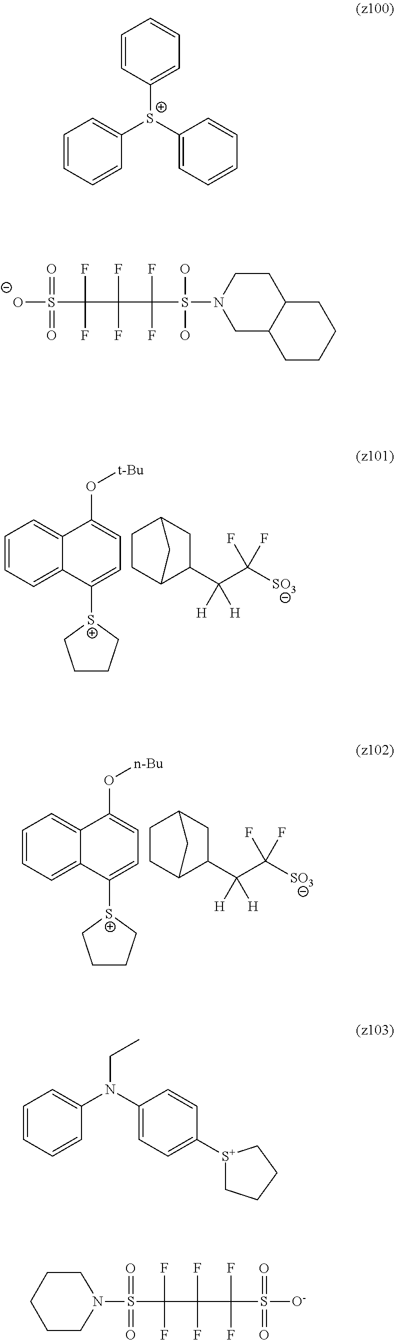

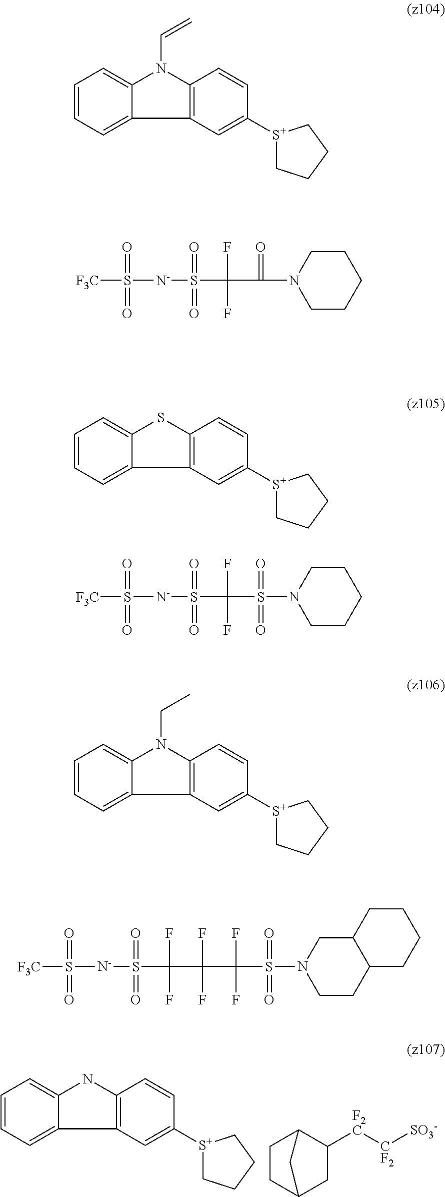

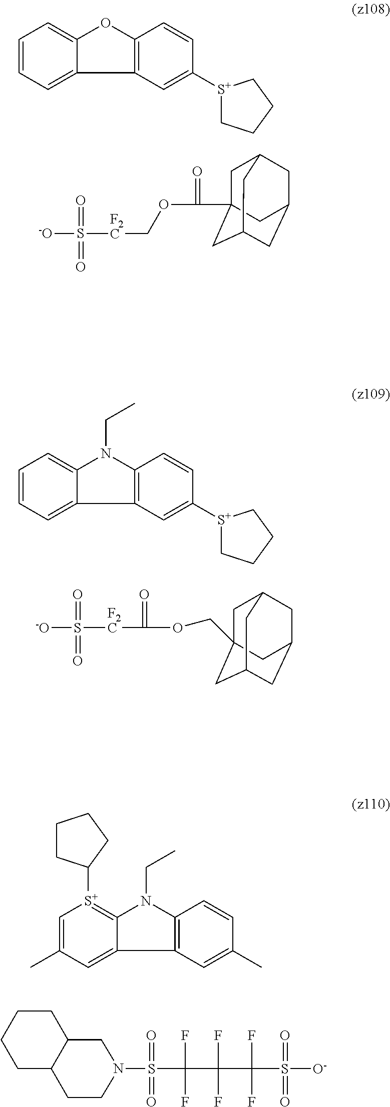

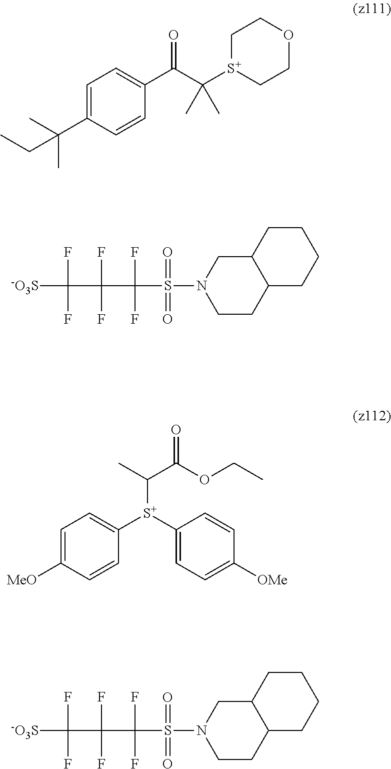

The acid generators can be synthesized by known method. For example, the acid generators can be synthesized according to the method described in JP-A-2007-161707. The acid generators can be used either individually or in combination of two or more kinds. The content of the acid generator, based on the total solids of the composition, is preferably in the range of 0.1 to 35 mass %, more preferably 5 to 30 mass % and further more preferably 15 to 25 mass %.

[3] Hydrophobic Resin (HR)

The actinic ray- or radiation-sensitive resin composition according to the present invention may further contain a resin (B) (hereinafter, referred to as “hydrophobic resin”) including a repeating unit containing at least either fluorine atom or silicon atom and being different from the resin (A).

At least either the fluorine atom or the silicon atom in the resin (B) may present either in the principal chain or in the side chain.

When the resin (B) contains one or more fluorine atoms, a partial structure containing one or more fluorine atoms is preferably an alkyl group containing one or more fluorine atoms, a cycloalkyl group containing one or more fluorine atoms, or an aryl group containing one or more fluorine atoms.

The alkyl group containing one or more fluorine atoms is a linear or branched alkyl group having at least one hydrogen atom thereof substituted with one or more fluorine atoms. The group preferably has 1 to 10 carbon atoms, more preferably 1 to 4 carbon atoms. Further, other substituents may also be contained.

The cycloalkyl group containing one or more fluorine atoms is a monocyclic or polycyclic alkyl group having at least one hydrogen atom thereof substituted with one or more fluorine atoms. Further, other substituents may also be contained.

The aryl group containing one or more fluorine atoms is an aryl group having at least one hydrogen atom of an aryl group substituted with one or more fluorine atoms. As the aryl group, a phenyl or a naphthyl group can be exemplified. Further, other substituents may also be contained.

As preferred alkyl groups containing one or more fluorine atoms, cycloalkyl groups containing one or more fluorine atoms and aryl groups containing one or more fluorine atoms, groups of the following general formulae (F2) to (F4) can be exemplified, which however in no way limit the scope of the present invention.

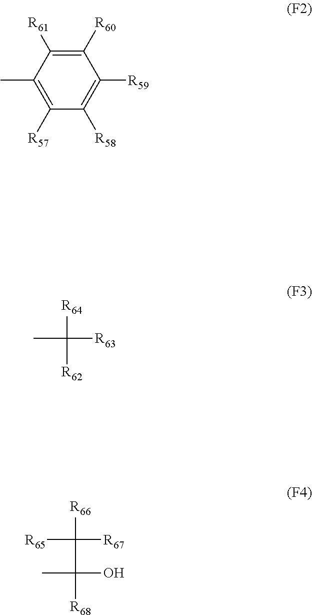

In the general formulae (F2) to (F4),

each of R₅₇ to R₆₈ independently represents a hydrogen atom, a fluorine atom or an alkyl group in condition that: at least one of R₅₇-R₆₁ represents a fluorine atom or an alkyl group having at least one hydrogen atom thereof substituted with one or more fluorine atoms; at least one of R₆₂-R₆₄ represents a fluorine atom or an alkyl group having at least one hydrogen atom thereof substituted with one or more fluorine atoms; and at least one of R₆₅-R₆₈ represents a fluorine atom or an alkyl group having at least one hydrogen atom thereof substituted with one or more fluorine atoms. These alkyl groups preferably are those having 1 to 4 carbon atoms.

It is preferred that all of R₅₇-R₆₁ and R₆₅-R₆₇ represent fluorine atoms. Each of R₆₂, R₆₃ and R₆₈ preferably represents a fluoroalkyl group (preferably, having 1 to 4 carbon atoms), and more preferably represents a perfluoroalkyl group having 1 to 4 carbon atoms. When each of R₆₂ and R₆₃ represents a perfluoroalkyl group, R₆₄ preferably represents a hydrogen atom. R₆₂ and R₆₃ may be bonded to each other to form a ring.

Specific examples of the groups represented by the general formula (F2) include a p-fluorophenyl group, a pentafluorophenyl group, and a 3,5-di(trifluoromethyl)phenyl group.

Specific examples of the groups represented by the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

Specific examples of the groups represented by the general formula (F4) include —C(CF₃)₂OH, —C(C₂F₅)₂OH, —C(CF₃) (CH₃)OH, —CH(CF₃)OH and the like. Of these, —C(CF₃)₂OH is particularly preferred.

The partial structure containing a fluorine atom may directly be bonded to the principal chain. Alternatively, the partial structure may be bonded to the principal chain via an alkylene group, a phenylene group, an ether bond, a thioether bond, a carbonyl group, an ester bond, an amido bond, a urethane bond, a ureylene bond, or a combination of at least two of these.

Preferred repeating units containing one or more fluorine atoms are as follows.

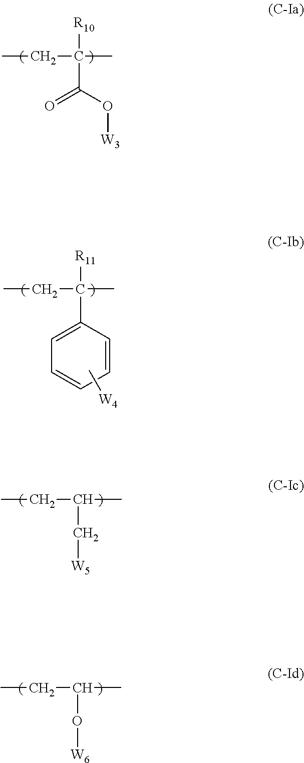

In the formulae (C-Ia) to (C-Id), R₁₀ and R₁₁ each independently represents a hydrogen atom, a fluorine atom, and an alkyl group. As the alkyl group, a linear or branched alkyl group having 1 to 4 carbon atoms is preferred and the alkyl group may have one or more substituents. As an alkyl group with one or more substituents, a fluorinated alkyl group can especially be exemplified.

Each of W₃ to W₆ independently represents an organic group containing one or more fluorine atoms. Specifically, groups represented by the general formulae (F2) to (F4) can be exemplified.

The resin (B) may further contain the following units as the repeating unit containing one or more fluorine atoms other than the repeating unit described above.

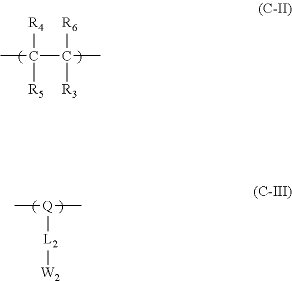

In the formulae (C-II) and (C-III), each of R₄ to R₇ independently represents a hydrogen atom, a fluorine atom, and an alkyl group. As the alkyl group, a linear or branched alkyl group having 1 to 4 carbon atoms is preferred. As an alkyl group with one or more substituents, a fluorinated alkyl group can especially be exemplified.

With the proviso that at least one of R₄ to R₇ represents a fluorine atom and R₄ and R₅ or R₆ and R₇ may form a ring.

W₂ represents an organic group containing one or more fluorine atoms. Specifically, groups represented by the general formulae (F2) to (F4) can be exemplified.

L2 represents a single bond or divalent connecting group. As the divalent connecting group, a substituted or nonsubstituted arylene group, a substituted or nonsubstituted alkylene group, —O—, —SO₂—, —CO—, —N(R)— (R represents a hydrogen atom or an alkyl group), —NHSO₂—, or a combination of two or more of these groups.

Q represents an alicyclic structure. The alicyclic structure may contain one or more substituents, and may either be monocyclic or polycyclic. When the alicyclic structure contains a polycyclic structure, it may be a bridged type. As the monocyclic one, a cycloalkyl group having 3 to 8 carbon atoms such as a cyclopenryl group, a cyclohexyl group, a cyclobutyl group, or a cyclobutyl group is preferred. As the polycyclic one, a group containing bicyclo-, tricyclo-, or tetracyclo-structure having 5 or more carbon atoms can be exemplified. The polycyclic one preferably is a cycloalkyl group having 6 to 20 carbon atoms such as an adamantyl group, a norbornyl group, a dicyclopentyl group, a tricyclodecanyl group, or a tetracyclododecyl group. At least a part of carbon atoms in the cycloalkyl group may be substituted with one or more heteroatoms such as oxygen atoms. Especially preferred Q include a norbornyl group, a tricyclodecanyl group, a tetracyclodecanyl group, or the like.

The resin (B) may contain one or more silicon atoms. As partial structure containing one or more silicon atoms, an alkylsilyl structure or a cyclosiloxane structure can be exemplified. Preferred alkylsilyl structure is the one containing one or more trialkylsilyl groups.

As the alkylsilyl structure and cyclosiloxane structure, any of the groups represented by the following general formulae (CS-1) to (CS-3) can be exemplified.

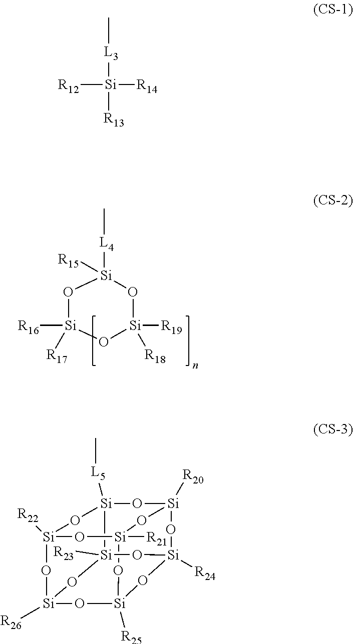

In the general formulae (CS-1) to (CS-3),

each of R₁₂ to R₂₆ independently represents a linear or branched alkyl group or a cycloalkyl group. The alkyl group preferably has 1 to 20 carbon atoms. The cycloalkyl group preferably has 3 to 20 carbon atoms.

Each of L₃ to L₅ represents a single bond or a bivalent connecting group. As the bivalent connecting group, any one or a combination of two or more groups selected from the group consisting of an alkylene group, a phenylene group, an ether group, a thioether group, a carbonyl group, an ester group, an amido group, a urethane group and a urea group can be exemplified.

In the formulae, n is an integer of 1 to 5, and preferably an integer of 2 to 4.

Repeating units having at least either fluorine atom or silicon atom is preferably a (metha)acrylate-type repeating unit.

Specific examples of the repeating units having at least either fluorine atom or silicon atom will be shown below, which however in no way limit the scope of the present invention. In the specific examples, X₁ represents a hydrogen atom, —CH₃, —F or —CF₃, and X₂ represents —F or —CF₃.

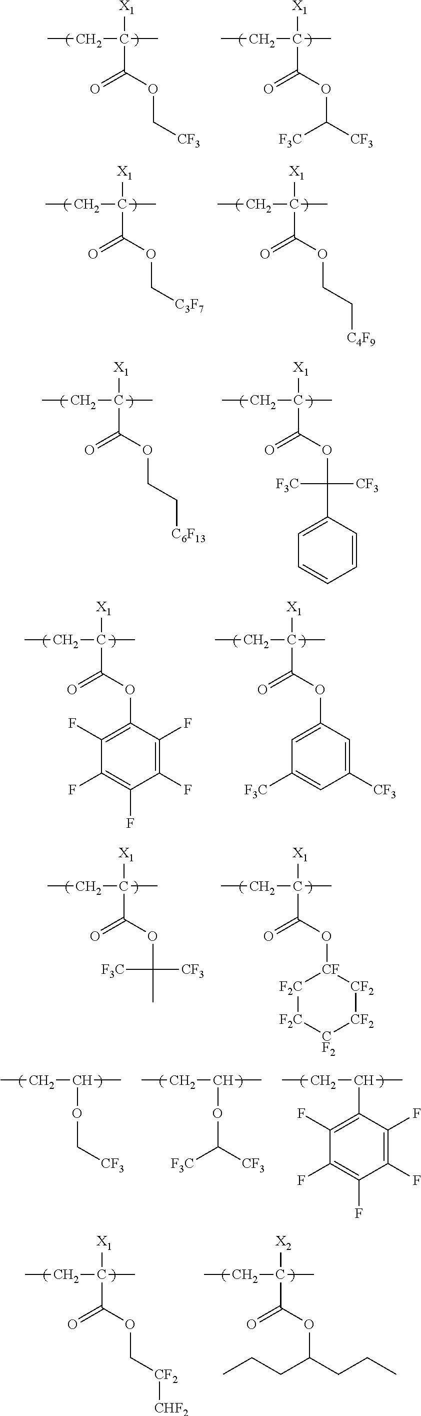

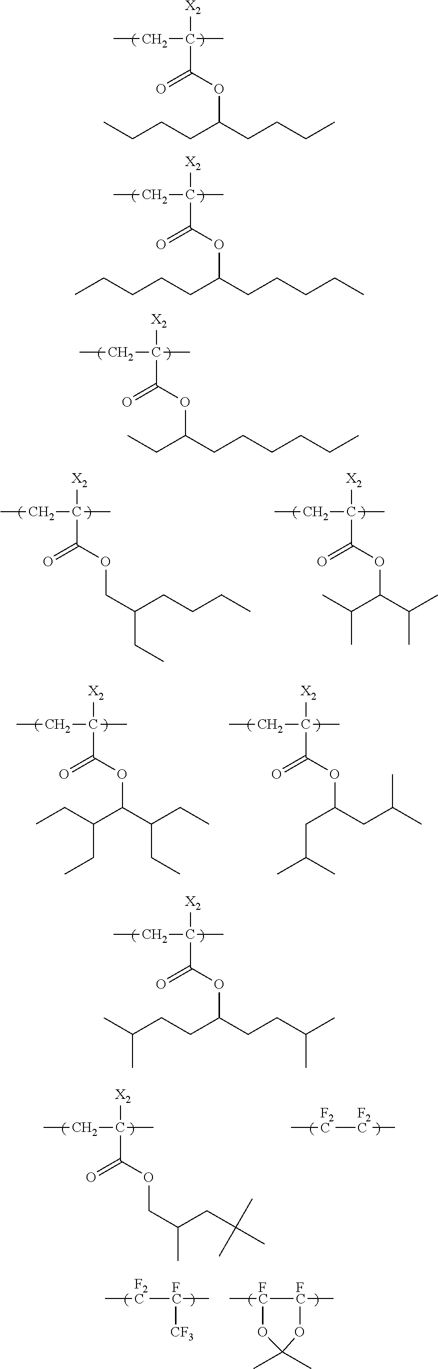

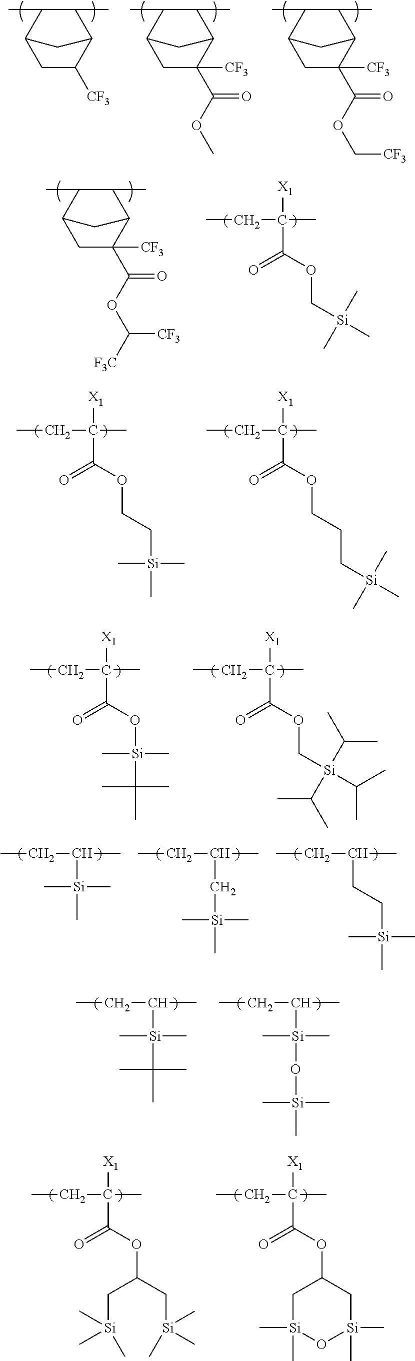

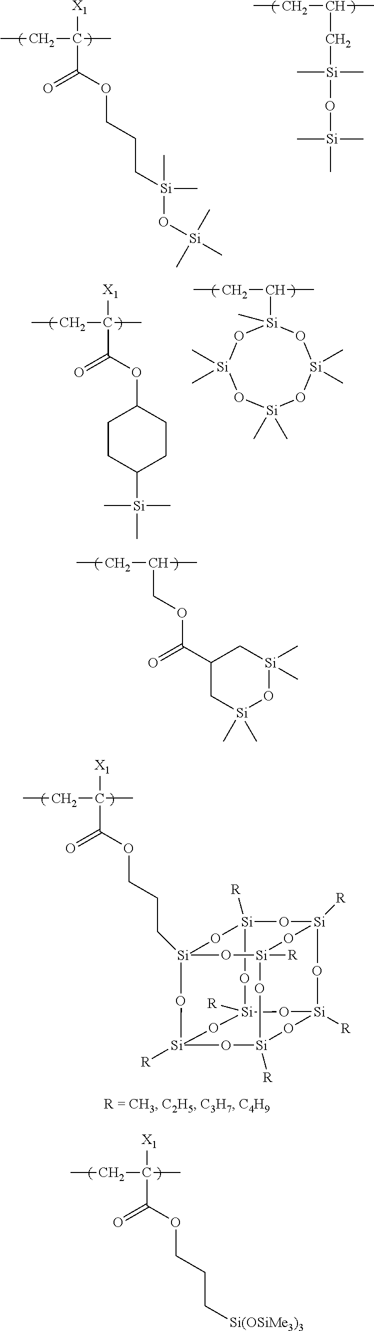

The resin (B) preferably contains a repeating unit (b) having at least one group selected from among the following groups (x) to (z):

(x) an alkali-soluble group;

(y) a group that is decomposed by the action of an alkali developer, resulting in an increase of solubility in the alkali developer; and

(z) a group that is decomposed by the action of an acid, resulting in an increase of solubility in the alkali developer.

As the repeating unit (b), the following types are exemplified.

a repeating unit (b′) containing at least either a fluorine atom or a silicon atom and at least one group selected from the group consisting of the above groups (x) to (z) simultaneously introduced in one side chain thereof;

a repeating unit (b*) containing at least one group selected from the group consisting of the above groups (x) to (z) but containing neither a fluorine atom nor a silicon atom; or

a repeating unit (b″) in which at least one group selected from the group consisting of the above groups (x) to (z) is introduced in its one side chain while at least either a fluorine atom or a silicon atom is introduced in a side chain other than the above side chain within the same repeating unit.

It is preferable for the resin (B) to contain the repeating unit (b′) as the repeating unit (b). Namely, it is preferable for the repeating unit (b) containing at least one group selected from the group consisting of the above groups (x) to (z) to further contain at least either a fluorine atom or a silicon atom.

When the resin (B) contains the repeating unit (b*), it is preferable for the resin (B) to be a copolymer with a repeating unit (repeating unit other than the above-mentioned repeating units [b′] and [b″]) containing at least either a fluorine atom or a silicon atom. In the repeating unit (b″), it is preferable for the side chain containing at least one group selected from the group consisting of the above groups (x) to (z) and the side chain containing at least either a fluorine atom or a silicon atom to be bonded to the same carbon atom of the principal chain, namely to be in a positional relationship shown in formula (K1) below.

In the formula, B1 represents a partial structure containing at least one group selected from the group consisting of the above groups (x) to (z), and B2 represents a partial structure containing at least either a fluorine atom or a silicon atom.

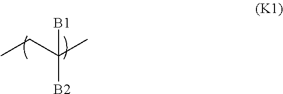

The group selected from the group consisting of the above groups (x) to (z) is preferably (x) an alkali-soluble group or (y) a polarity conversion group, more preferably (y) a polarity conversion group.

As the alkali-soluble group (x), a phenolic hydroxy group, a carboxylate group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group can be exemplified.

As preferred alkali soluble groups, a fluoroalcohol group (preferably hexafluoroisopropanol group), a sulfonimido group, and a bis(carbonyl)methylene group can be exemplified.

As the repeating unit having an alkali soluble group (x), preferred use is made of any of a repeating unit resulting from direct bonding of an alkali soluble group to the principal chain of a resin like a repeating unit of acrylic acid or methacrylic acid; a repeating unit resulting from bonding, via a connecting group, of an alkali soluble group to the principal chain of a resin; and a repeating unit resulting from polymerization with the use of a chain transfer agent or polymerization initiator having an alkali soluble group to introduce the same in a polymer chain terminal.

When the repeating unit (bx) is a repeating unit containing at least either a fluorine atom or a silicon atom (namely, when corresponding to the above-mentioned repeating unit [b′] or repeating unit [b″]), the partial structure containing a fluorine atom contained in the repeating unit (bx) can be the same as set forth above in connection with the repeating unit containing at least either a fluorine atom or a silicon atom. As such, preferably, there can be mentioned any of the groups of general formulae (F2) to (F4) above. Also in that instance, the partial structure containing a silicon atom contained in the repeating unit (bx) can be the same as set forth above in connection with the repeating unit containing at least either a fluorine atom or a silicon atom. As such, preferably, there can be mentioned any of the groups of general formulae (CS-1) to (CS-3) above.

The content of repeating units (bx) having an alkali soluble group (x) based on all the repeating units in the resin (B) is preferably in the range of 1 to 50 mol %, more preferably 3 to 35 mol %, and still more preferably 5 to 20 mol %.

Specific examples of the repeating units (bx) having an alkali soluble group (x) will be shown below, which however in no way limit the scope of the present invention. In the specific examples, each of X₁ represents H, —CH₃, —F or —CF₃. In the formulae, each of Rx represents H, CH₃, CF₃ or CH₂OH.

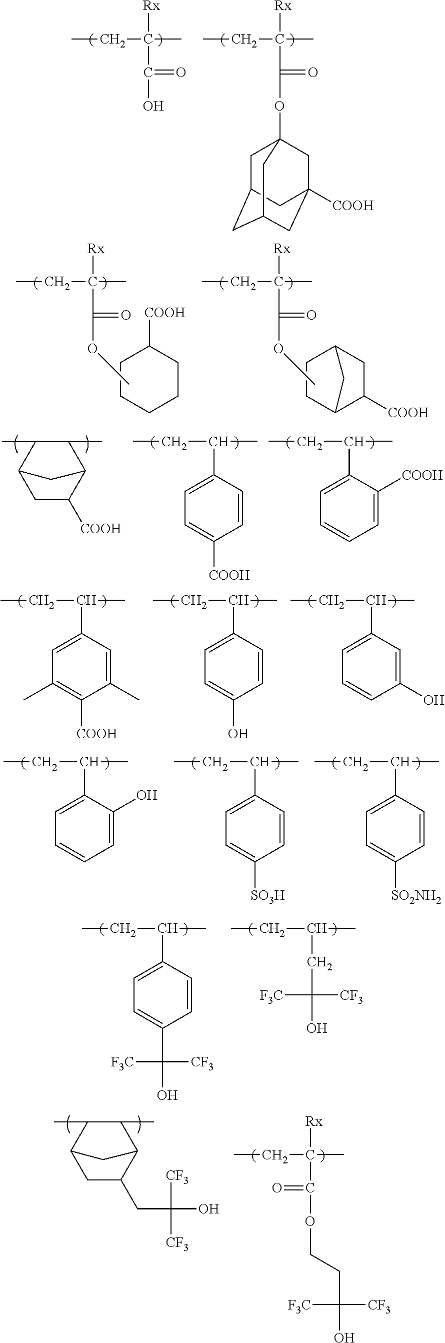

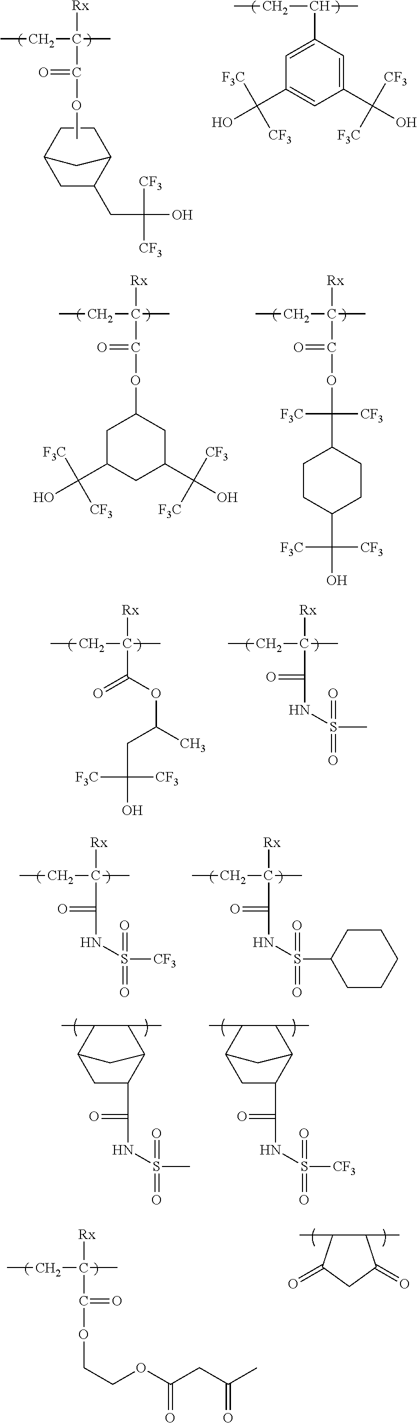

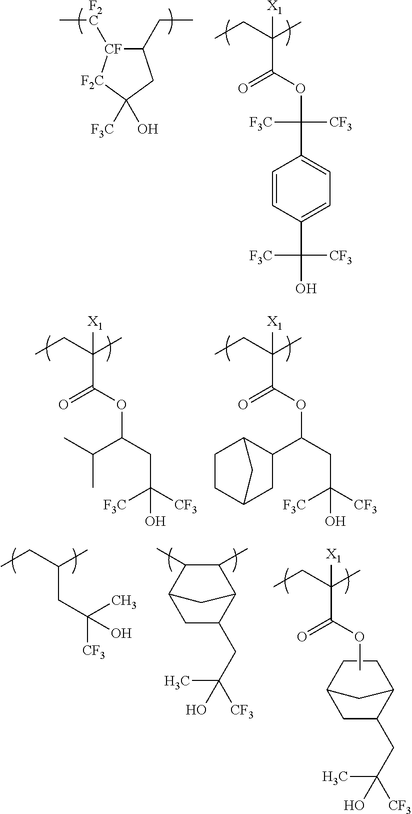

As the polarity conversion group (y), there can be mentioned, for example, a lactone group, a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—), a sulfonic ester group (—SO₂O—) or the like. A lactone group is preferred.

The polarity conversion group (y) is contained in, for example, two modes which are both preferred. In one mode, the polarity conversion group is contained in a repeating unit of an acrylic ester or methacrylic ester and introduced in a side chain of a resin. In the other mode, the polarity conversion group is introduced in a terminal of a polymer chain by using a polymerization initiator or chain transfer agent containing the polarity conversion group (y) in the stage of polymerization.

As particular examples of the repeating units (by) each containing a polarity conversion group (y), there can be mentioned the repeating units with lactone structures of formulae (KA-1-1) to (KA-1-17) to be shown hereinafter.

Further, it is preferable for the repeating unit (by) containing a polarity conversion group (y) to be a repeating unit containing at least either a fluorine atom or a silicon atom (namely, corresponding to the above-mentioned repeating unit [b′] or repeating unit [b″]). The resin comprising this repeating unit (by) is hydrophobic, and is especially preferable from the viewpoint of the reduction of development defects.

As the repeating unit (by), there can be mentioned, for example, any of the repeating units of formula (K0) below.

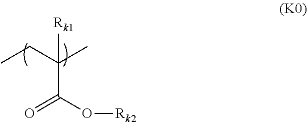

In the formula, Rₖ₁ represents a hydrogen atom, a halogen atom, a hydroxyl group, an alkyl group, a cycloalkyl group, an aryl group or a group containing a polarity conversion group; and Rₖ₂ represents an alkyl group, a cycloalkyl group, an aryl group or a group containing a polarity conversion group; provided that one of Rₖ₁ and Rₖ₂ is a group containing a polarity conversion group.

The polarity conversion group, as mentioned above, refers to a group that is decomposed by the action of an alkali developer to thereby increase its solubility in the alkali developer. It is preferred for the polarity conversion group to be a group represented by X in the partial structures of general formulae (KA-1) and (KB-1) below.

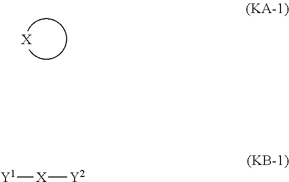

In general formulae (KA-1) and (KB-1), X represents a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—) or a sulfonic ester group (—SO₂O—).

Y¹ and Y² may be identical to or different from each other, and each thereof represents an electron withdrawing group.

The repeating unit (by) contains a preferred group whose solubility in an alkali developer is increased by containing a group with the partial structure of general formula (KA-1) or (KB-1). When the partial structure has no bonding hand as in the case of the partial structure of general formula (KA-1) or the partial structure of general formula (KB-1) in which Y¹ and Y² are monovalent, the above group with the partial structure refers to a group containing a monovalent or higher-valent group resulting from the deletion of at least one arbitrary hydrogen atom from the partial structure.

The partial structure of general formula (KA-1) or (KB-1) is linked at its arbitrary position to the principal chain of the resin (B) via a substituent.

The partial structure of general formula (KA-1) is a structure in which a ring structure is formed in cooperation with a group represented by X.

In general formula (KA-1), X is preferably a carboxylic ester group (namely, in the case of the formation of a lactone ring structure as KA-1), an acid anhydride group or a carbonic ester group. More preferably, X is a carboxylic ester group.

A substituent may be introduced in the ring structure of general formula (KA-1). For example, when Zₖₐ₁ is a substituent, nka substituents may be introduced.

Zₖₐ₁, or each of a plurality of Zₖₐ₁s independently, represents a halogen atom, an alkyl group, a cycloalkyl group, an ether group, a hydroxyl group, an amido group, an aryl group, a lactone ring group or an electron withdrawing group.

Zₖₐ₁s may be linked to each other to thereby form a ring. As the ring formed by the mutual linkage of Zₖₐ₁s, there can be mentioned, for example, a cycloalkyl ring or a heterocycle (for example, a cycloether ring or a lactone ring).

The above nka is an integer of 0 to 10, preferably 0 to 8, more preferably 0 to 5, further more preferably 1 to 4 and most preferably 1 to 3.

The electron withdrawing groups represented by Zₖₐ₁ are the same as those represented by Y¹ and Y² to be described hereinafter. These electron withdrawing groups may be substituted with other electron withdrawing groups.

Zₖₐ₁ is preferably an alkyl group, a cycloalkyl group, an ether group, a hydroxyl group or an electron withdrawing group. Zₖₐ₁ is more preferably an alkyl group, a cycloalkyl group or an electron withdrawing group. It is preferred for the ether group to be one substituted with, for example, an alkyl group or a cycloalkyl group, namely, to be an alkyl ether group or the like. The electron withdrawing group is as mentioned above.

As the halogen atom represented by Zₖₐ₁, there can be mentioned a fluorine atom, a chlorine atom, a bromine atom, an iodine atom or the like. Among these, a fluorine atom is preferred.

The alkyl group represented by Zₖₐ₁ may contain a substituent, and may be linear or branched. The linear alkyl group preferably has 1 to 30 carbon atoms, more preferably 1 to 20 carbon atoms. As the linear alkyl group, there can be mentioned, for example, a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, an n-decanyl group or the like. The branched alkyl group preferably has 3 to 30 carbon atoms, more preferably 3 to 20 carbon atoms. As the branched alkyl group, there can be mentioned, for example, an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, a t-decanyl (t-decanoyl) group or the like. It is preferred for the alkyl group represented by Zₖₐ₁ to be one having 1 to 4 carbon atoms, such as a methyl group, an ethyl group, an n-propyl group, an i-propyl group, an n-butyl group, an i-butyl group or a t-butyl group.

The cycloalkyl group represented by Zₖₐ₁ may contain a substituent and may be monocyclic or polycyclic. When polycyclic, the cycloalkyl group may be a bridged one. Namely, in that case, the cycloalkyl group may have a bridged structure. The monocycloalkyl group is preferably a cycloalkyl group having 3 to 8 carbon atoms. As such a cycloalkyl group, there can be mentioned, for example, a cyclopropyl group, a cyclopentyl group, a cyclohexyl group, a cyclobutyl group, a cyclooctyl group or the like. As the polycycloalkyl group, there can be mentioned a group with, for example, a bicyclo, tricyclo or tetracyclo structure having 5 or more carbon atoms. This polycycloalkyl group is preferably a cycloalkyl group having 6 to 20 carbon atoms. As such, there can be mentioned, for example, an adamantyl group, a norbornyl group, an isobornyl group, a camphonyl group, a bicyclopentyl group, an α-pinel group, a tricyclodecanyl group, a tetracyclododecyl group, and an androstanyl group. As the cyclooctyl group, any of the following structures are also preffered. The carbon atoms of each of the cycloalkyl groups may be partially replaced with a heteroatom, such as an oxygen atom.

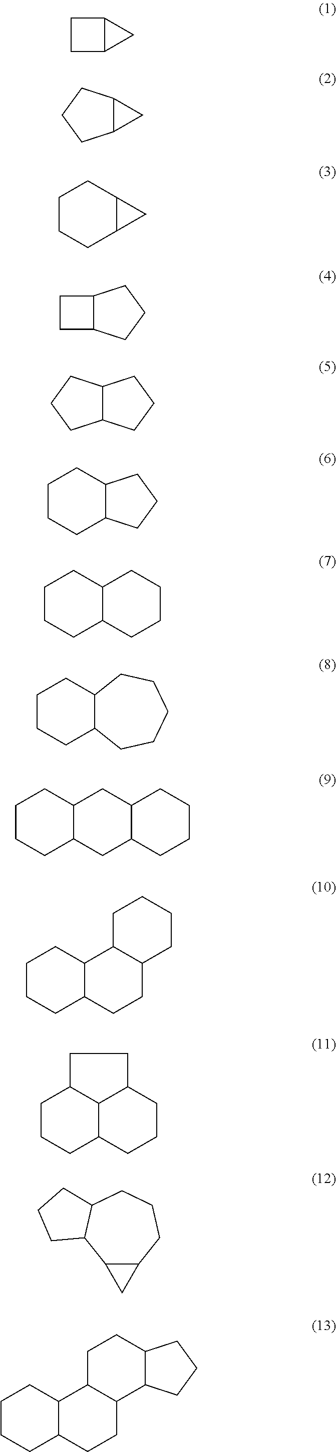

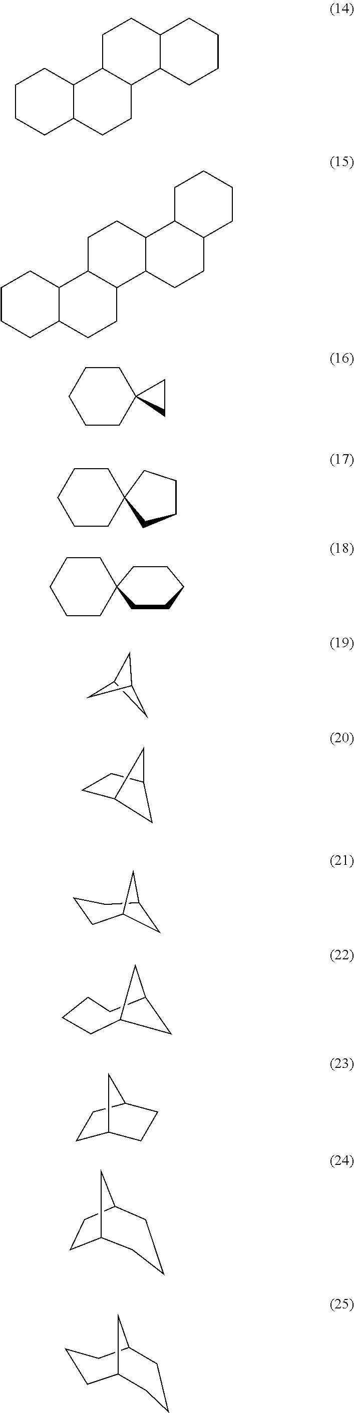

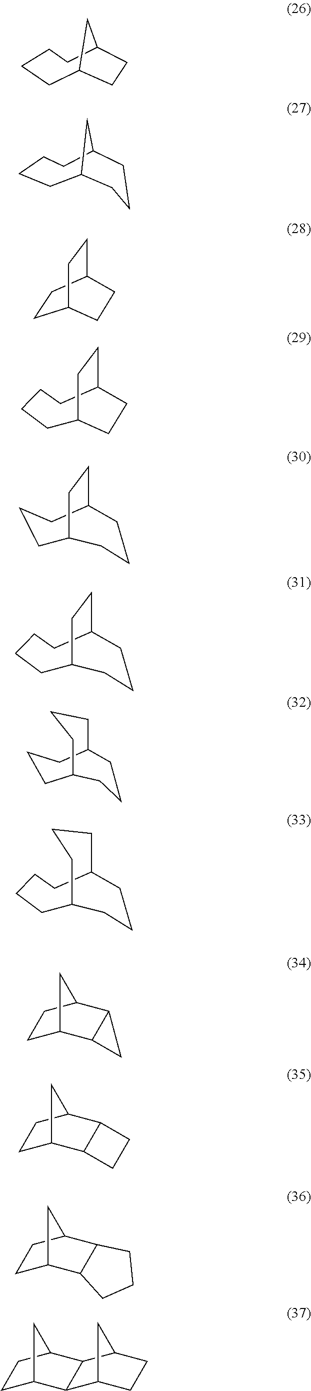

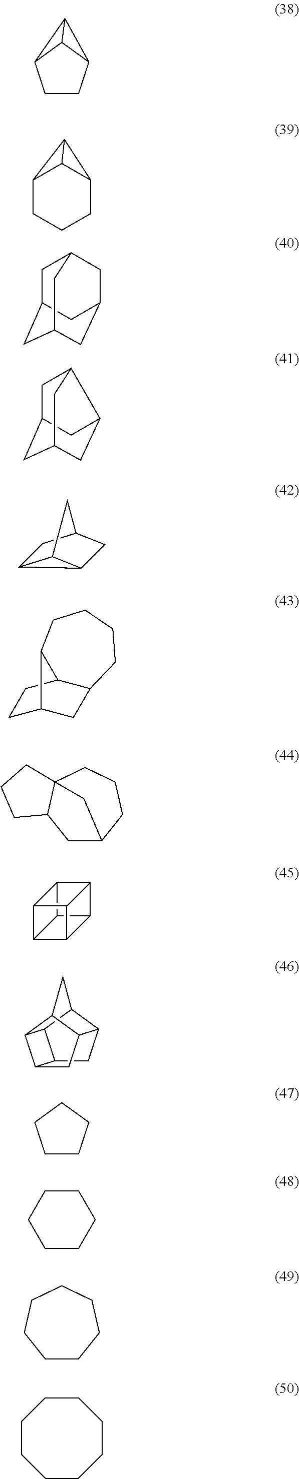

As preferred alicyclic moieties among the above, there can be mentioned an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group and a cyclododecanyl group. As more preferred alicyclic moieties, there can be mentioned an adamantyl group, a decalin group, a norbornyl group, a cedrol group, a cyclohexyl group, a cycloheptyl group, a cyclooctyl group, a cyclodecanyl group, a cyclododecanyl group and a tricyclodecanyl group.

As a substituent that can be introduced in these alicyclic structures, there can be mentioned an alkyl group, a halogen atom, a hydroxyl group, an alkoxy group, a carboxyl group or an alkoxycarbonyl group. The alkyl group is preferably a lower alkyl group, such as a methyl group, an ethyl group, a propyl group, an isopropyl group or a butyl group. More preferably, the alkyl group is a methyl group, an ethyl group, a propyl group or an isopropyl group. As preferred alkoxy groups, there can be mentioned those each having 1 to 4 carbon atoms, such as a methoxy group, an ethoxy group, a propoxy group and a butoxy group. As a substituent that may be introduced in these alkyl and alkoxy groups, there can be mentioned a hydroxyl group, a halogen atom, an alkoxy group (preferably having 1 to 4 carbon atoms) or the like.

Further substituents may be introduced in these groups. As further substituents, there can be mentioned a hydroxyl group; a halogen atom (fluorine, chlorine, bromine or iodine); a nitro group; a cyano group; the above alkyl groups; an alkoxy group, such as a methoxy group, an ethoxy group, a hydroxyethoxy group, a propoxy group, a hydroxypropoxy group, an n-butoxy group, an isobutoxy group, a sec-butoxy group or a t-butoxy group; an alkoxycarbonyl group, such as a methoxycarbonyl group or an ethoxycarbonyl group; an aralkyl group, such as a benzyl group, a phenethyl group or a cumyl group; an aralkyloxy group; an acyl group, such as a formyl group, an acetyl group, a butyryl group, a benzoyl group, a cyanamyl group or a valeryl group; an acyloxy group, such as a butyryloxy group; the above alkenyl groups; an alkenyloxy group, such as a vinyloxy group, a propenyloxy group, an allyloxy group or a butenyloxy group; the above aryl groups; an aryloxy group, such as a phenoxy group; an aryloxycarbonyl group, such as a benzoyloxy group; and the like.

Preferably, X of general formula (KA-1) represents a carboxylic ester group and the partial structure of general formula (KA-1) is a lactone ring. A 5- to 7-membered lactone ring is preferred.

Further, as shown in formulae (KA-1-1) to (KA-1-17) below, the 5- to 7-membered lactone ring as the partial structure of general formula (KA-1) is preferably condensed with another ring structure in such a fashion that a bicyclo structure or a spiro structure is formed.

The peripheral ring structures to which the ring structure of general formula (KA-1) may be bonded can be, for example, those shown in formulae (KA-1-1) to (KA-1-17) below, or those similar to the same.

It is preferred for the structure containing the lactone ring structure of general formula (KA-1) to be the structure of any of formulae (KA-1-1) to (KA-1-17) below. The lactone structure may be directly bonded to the principal chain. As preferred structures, there can be mentioned those of formulae (KA-1-1), (KA-1-4), (KA-1-5), (KA-1-6), (KA-1-13), (KA-1-14) and (KA-1-17).

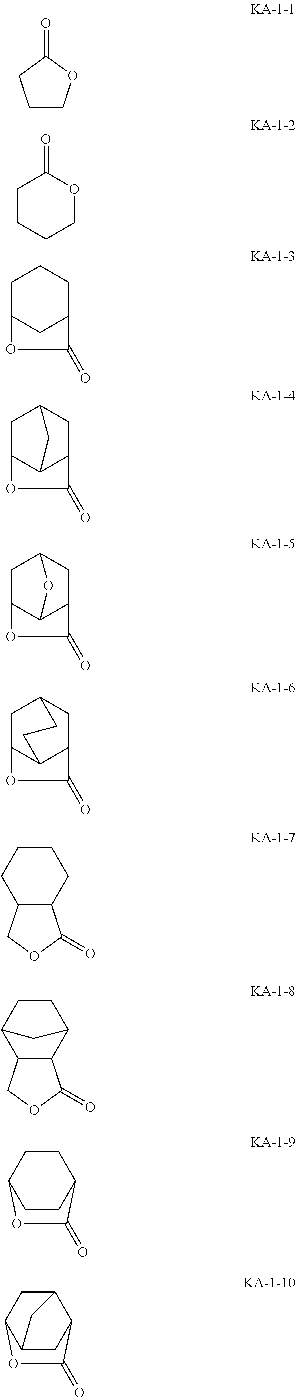

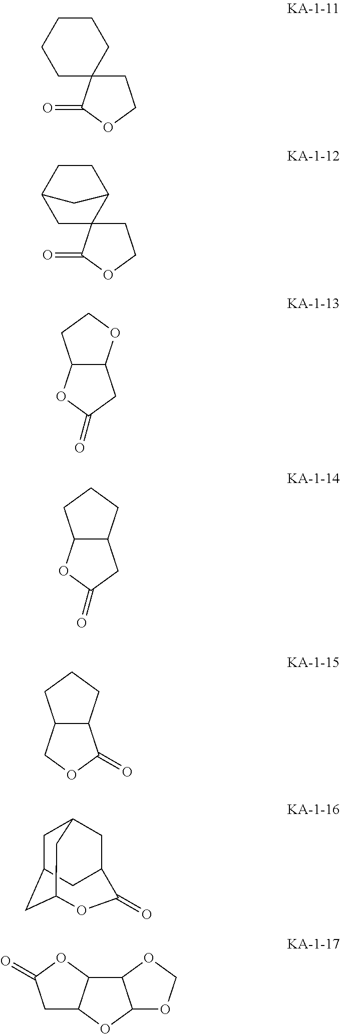

A substituent may optionally be introduced in the above structures containing the lactone ring structure. As preferred substituents, there can be mentioned the same as the substituents Zₖₐ₁ that may be introduced in the ring structure of general formula (KA-1) above.

In general formula (KB-1), X is preferably a carboxylic ester group (—COO—).

In general formula (KB-1), each of Y¹ and Y² independently represents an electron withdrawing group.

The electron withdrawing group has the partial structure of formula (EW) below. In formula (EW), * represents either a bonding hand directly bonded to the structure of general formula (KA-1) or a bonding hand directly bonded to X of general formula (KB-1).

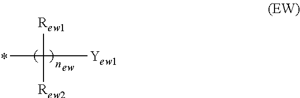

In formula (EW),

n_{ew} is the number of repetitions of each of the connecting groups of the formula —C(R_{ew1})(R_{ew2})—, being an integer of 0 or 1. When n_{ew} is 0, a single bond is represented, indicating the direct bonding of Y_{ew1}.

Y_{ew1} can be any of a halogen atom, a cyano group, a nitrile group, a nitro group, any of the halo(cyclo)alkyl groups or haloaryl groups of the formula —C(R_{f1}) (R_{f2})—R_{f3} to be described hereinafter, an oxy group, a carbonyl group, a sulfonyl group, a sulfinyl group and a combination thereof. The electron withdrawing groups may have, for example, the following structures. Herein, the “halo(cyclo)alkyl group” refers to an at least partially halogenated alkyl group or cycloalkyl group. The “haloaryl group” refers to an at least partially halogenated aryl group. In the following structural formulae, each of R_{ew3} and R_{ew4} independently represents an arbitrary structure. Regardless of the types of the structures of R_{ew3} and R_{ew4}, the partial structures of formula (EW) exhibit electron withdrawing properties, and may be linked to, for example, the principal chain of the resin. Preferably, each of R_{ew3} and R_{ew4} is an alkyl group, a cycloalkyl group or a fluoroalkyl group.

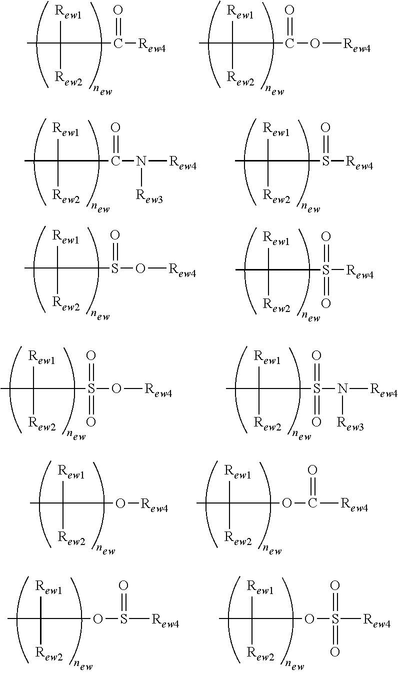

When Y_{ew1} is a bivalent or higher-valent group, the remaining bonding hand or hands form a bond with an arbitrary atom or substituent. At least any of the groups represented by Y_{ew1}, R_{ew1} and R_{ew2} may be linked via a further substituent to the principal chain of the resin (B).

Y_{ew1} is preferably a halogen atom or any of the halo(cyclo)alkyl groups or haloaryl groups of the formula —C(R_{f1}) (R_{f2})—R_{f3}.

Each of R_{ew1} and R_{ew2} independently represents an arbitrary substituent, for example, a hydrogen atom, an alkyl group, a cycloalkyl group or an aryl group.

At least two of R_{ew1}, R_{ew2} and Y_{ew1} may be linked to each other to thereby form a ring.

In the above formula, R_{f1} represents a halogen atom, a perhaloalkyl group, a perhalocycloalkyl group or a perhaloaryl group. R_{f1} is preferably a fluorine atom, a perfluoroalkyl group or a perfluorocycloalkyl group, more preferably a fluorine atom or a trifluoromethyl group.

Each of R_{f2} and R_{f3} independently represents a hydrogen atom, a halogen atom or an organic group. R_{f2} and R_{f3} may be linked to each other to thereby form a ring. As the organic group, there can be mentioned, for example, an alkyl group, a cycloalkyl group, an alkoxy group or the like. It is preferred for R_{f2} to represent the same groups as R_{f1} or to be linked to R_{f3} to thereby form a ring.

R_{f1} to R_{f3} may be linked to each other to thereby form a ring. As the formed ring, there can be mentioned a (halo)cycloalkyl ring, a (halo)aryl ring or the like.

As the (halo)alkyl groups represented by R_{f1} to R_{f3}, there can be mentioned, for example, the alkyl groups mentioned above as being represented by Zₖₐ₁ and structures resulting from halogenation thereof.

As the (per)halocycloalkyl groups and (per)haloaryl groups represented by R_{f1} to R_{f3} or contained in the ring formed by the mutual linkage of R_{f2} and R_{f3}, there can be mentioned, for example, structures resulting from halogenation of the cycloalkyl groups mentioned above as being represented by Zₖₐ₁, preferably fluorocycloalkyl groups of the formula —C₍ₙ₎F₍₂ₙ₋₂₎H and perfluoroaryl groups of the formula —C₍ₙ₎F₍ₙ₋₁₎. The number of carbon atoms, n, is not particularly limited. Preferably, however, it is in the range of 5 to 13, more preferably 6.

As preferred rings that may be formed by the mutual linkage of at least two of R_{ew1}, R_{ew2} and Y_{ew1}, there can be mentioned cycloalkyl groups and heterocyclic groups. Preferred heterocyclic groups are lactone ring groups. As the lactone rings, there can be mentioned, for example, the structures of formulae (KA-1-1) to (KA-1-17) above.

The repeating unit (by) may contain two or more of the partial structures of general formula (KA-1), or two or more of the partial structures of general formula (KB-1), or both any one of the partial structures of general formula (KA-1) and any one of the partial structures of general formula (KB-1).

A part or the whole of any of the partial structures of general formula (KA-1) may double as the electron withdrawing group represented by Y¹ or Y² of general formula (KB-1). For example, when X of general formula (KA-1) is a carboxylic ester group, the carboxylic ester group can function as the electron withdrawing group represented by Y¹ or Y² of general formula (KB-1).

When the repeating unit (by) corresponds to the above-mentioned repeating unit (b*) or repeating unit (b″) and contains any of the partial structures of general formula (KA-1), it is preferable for the partial structures of general formula (KA-1) to be a partial structure in which the polarity conversion group is expressed by —COO— appearing in the structures of general formula (KA-1).

The repeating unit (by) can be a repeating unit with the partial structure of general formula (KY-0) below.

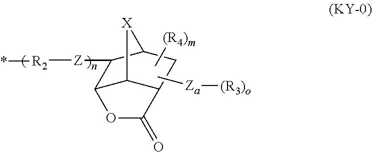

In general formula (KY-0),

R₂ represents a chain or cyclic alkylene group,

provided that when there are a plurality of R₂s, they may be identical to or different from each other.

R₃ represents a linear, branched or cyclic hydrocarbon group whose hydrogen atoms on constituent carbons are partially or entirely substituted with fluorine atoms.

R₄ represents a halogen atom, a cyano group, a hydroxyl group, an amido group, an alkyl group, a cycloalkyl group, an alkoxy group, a phenyl group, an acyl group, an alkoxycarbonyl group or any of the groups of the formula R—C(═O)— or R—C(═O)O— in which R is an alkyl group or a cycloalkyl group. When there are a plurality of R₄s, they may be identical to or different from each other. Two or more R₄s may be bonded to each other to thereby form a ring.

X represents an alkylene group, a cycloalkylene group, an oxygen atom or a sulfur atom.

Each of Z and Za represents a single bond, an ether bond, an ester bond, an amido bond, a urethane bond or a urea bond. When there are a plurality thereof, they may be identical to or different from each other.

In the formula, * represents a bonding hand to the principal chain or a side chain of the resin; o is the number of substituents, being an integer of 1 to 7; m is the number of substituents, being an integer of 0 to 7; and n is the number of repetitions, being an integer of 0 to 5.

The structure —R₂—Z— is preferably the structure of formula —(CH₂)p-COO— in which p is an integer of 1 to 5.

With respect to the chain or cyclic alkylene group represented by R₂, the preferred number of carbon atoms and particular examples are as mentioned above in connection with the chain or cyclic alkylene group represented by Z₂ of general formula (bb).

The number of carbon atoms of the linear, branched or cyclic hydrocarbon group represented by R₃ is preferably in the range of 1 to 30, more preferably 1 to 20 when the hydrocarbon group is linear; is preferably in the range of 3 to 30, more preferably 3 to 20 when the hydrocarbon group is branched; and is in the range of 6 to 20 when the hydrocarbon group is cyclic. As particular examples of the R₃ groups, there can be mentioned the above particular examples of the alkyl and cycloalkyl groups represented by Zₖₐ₁.

With respect to the alkyl groups and cycloalkyl groups represented by R₄ and R, the preferred number of carbon atoms and particular examples are as mentioned above in connection with the alkyl groups and cycloalkyl groups represented by Zₖₐ₁.

The acyl group represented by R₄ preferably has 1 to 6 carbon atoms. As such, there can be mentioned, for example, a formyl group, an acetyl group, a propionyl group, a butyryl group, an isobutyryl group, a valeryl group, a pivaloyl group or the like.

As the alkyl moiety of the alkoxy group and alkoxycarbonyl group represented by R₄, there can be mentioned a linear, branched or cyclic alkyl moiety. With respect to the alkyl moiety, the preferred number of carbon atoms and particular examples are as mentioned above in connection with the alkyl groups and cycloalkyl groups represented by Zₖₐ₁.

With respect to the alkylene group represented by X, a chain or cyclic alkylene group can be exemplified. The preferred number of carbon atoms and particular examples are as mentioned above in connection with the chain or cyclic alkylene group represented by R₂.

Moreover, as particular structures of the repeating units (by), there can be mentioned the repeating units with the following partial structures.

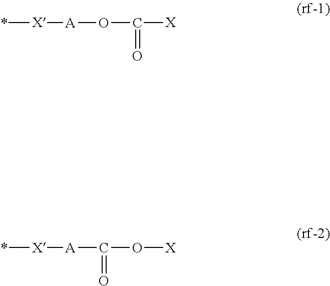

In general formulae (rf-1) and (rf-2),

X′ represents an electron withdrawing substituent, preferably a carbonyloxy group, an oxycarbonyl group, an alkylene group substituted with a fluorine atom or a cycloalkylene group substituted with a fluorine atom.

A represents a single bond or a bivalent connecting group of the formula —C(Rx)(Ry)-. In the formula, each of Rx and Ry independently represents a hydrogen atom, a fluorine atom, an alkyl group (preferably having 1 to 6 carbon atoms, optionally substituted with a fluorine atom) or a cycloalkyl group (preferably having 5 to 12 carbon atoms, optionally substituted with a fluorine atom). Each of Rx and Ry is preferably a hydrogen atom, an alkyl group or an alkyl group substituted with a fluorine atom.

X represents an electron withdrawing group. As particular examples thereof, there can be mentioned the electron withdrawing groups set forth above as being represented by Y¹ and Y². X is preferably a fluoroalkyl group, a fluorocycloalkyl group, an aryl group substituted with fluorine or a fluoroalkyl group, an aralkyl group substituted with fluorine or a fluoroalkyl group, a cyano group or a nitro group.

* represents a bonding hand to the principal chain or a side chain of the resin, namely, a bonding hand bonded to the principal chain of the resin through a single bond or a connecting group.

When X′ is a carbonyloxy group or an oxycarbonyl group, A is not a single bond.

The receding contact angle with water of the resin composition film after alkali development can be decreased by the polarity conversion effected by the decomposition of the polarity conversion group by the action of an alkali developer. The decrease of the receding contact angle between water and the film after alkali development is preferred from the viewpoint of the inhibition of development defects.

The receding contact angle with water of the resin composition film after alkali development is preferably 50° or less, more preferably 40° or less, further more preferably 35° or less and most preferably 30° or less at 23±3° C. in a humidity of 45±5%.

The receding contact angle refers to a contact angle determined when the contact line at a droplet-substrate interface draws back. It is generally known that the receding contact angle is useful in the simulation of droplet mobility in a dynamic condition. In brief, the receding contact angle can be defined as the contact angle exhibited at the recession of the droplet interface at the time of, after application of a droplet discharged from a needle tip onto a substrate, re-indrawing the droplet into the needle. Generally, the receding contact angle can be measured according to a method of contact angle measurement known as the dilation/contraction method.

The rate of hydrolysis of the resin (B) in an alkali developer is preferably 0.001 nm/sec or greater, more preferably 0.01 nm/sec or greater, further more preferably 0.1 nm/sec or greater and most preferably 1 nm/sec or greater.

Herein, the rate of hydrolysis of the resin (B) in an alkali developer refers to the rate of decrease of the thickness of a resin film formed from only the resin (B) in 23° C. TMAH (aqueous solution of tetramethylammonium hydroxide) (2.38 mass %)

It is preferred for the repeating unit (by) to be a repeating unit containing at least two polarity conversion groups.

When the repeating unit (by) contains at least two polarity conversion groups, it is preferred for the repeating unit to contain a group with any of the partial structures having two polarity conversion groups of general formula (KY-1) below. When the structure of general formula (KY-1) has no bonding hand, a group with a mono- or higher-valent group resulting from the removal of at least any arbitrary one of the hydrogen atoms contained in the structure is referred to.

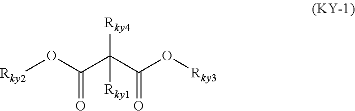

In general formula (KY-1),

each of R_{ky1} and R_{ky4} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group. Alternatively, both R_{ky1} and R_{ky4} may be bonded to the same atom to thereby form a double bond. For example, both R_{ky1} and R_{ky4} may be bonded to the same oxygen atom to thereby form a part (═O) of a carbonyl group.

Each of R_{ky2} and R_{ky3} independently represents an electron withdrawing group. Alternatively, R_{ky1} and R_{ky2} are linked to each other to thereby form a lactone structure, while R_{ky3} is an electron withdrawing group. The formed lactone structure is preferably any of the above-mentioned structures (KA-1-1) to (KA-1-17). As the electron withdrawing group, there can be mentioned any of the same groups as mentioned above with respect to Y¹ and Y² of general formula (KB-1). This electron withdrawing group is preferably a halogen atom, or any of the halo(cyclo)alkyl groups or haloaryl groups of the formula —C(R_{f1})(R_{f2})—R_{f3} above. Preferably, R_{ky3} is a halogen atom, or any of the halo(cyclo)alkyl groups or haloaryl groups of the formula —C(R_{f1})(R_{f2})—R_{f}3 above, while R_{ky2} is either linked to R_{kyl} to thereby form a lactone ring, or an electron withdrawing group containing no halogen atom.

R_{ky1}, R_{ky2} and R_{ky4} may be linked to each other to thereby form a monocyclic or polycyclic structure.

As R_{ky1} and R_{ky4}, there can be mentioned, for example, the same groups as set forth above with respect to Zₖₐ₁ of general formula (KA-1).

The lactone rings formed by the mutual linkage of R_{ky1} and R_{ky2} preferably have the structures of formulae (KA-1-1) to (KA-1-17) above. As the electron withdrawing groups, there can be mentioned those mentioned above as being represented by Y¹ and Y² of general formula (KB-1) above.

It is more preferred for the structure of general formula (KY-1) to be the structure of general formula (KY-2) below. The structure of general formula (KY-2) refers to a group with a mono- or higher-valent group resulting from the removal of at least any arbitrary one of the hydrogen atoms contained in the structure.

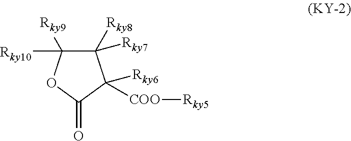

In formula (KY-2),

each of R_{ky6} to R_{ky10} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group.

At least two of R_{ky6} to R_{ky10} may be linked to each other to thereby form a monocyclic or polycyclic structure.

R_{ky5} represents an electron withdrawing group. As the electron withdrawing group, there can be mentioned any of the same groups as set forth above with respect to Y¹ and Y². This electron withdrawing group is preferably a halogen atom, or any of the halo(cyclo)alkyl groups or haloaryl groups of the formula —C(R_{f1}) (R_{f2})—R_{f3} above.

As R_{ky5} to R_{ky10}, there can be mentioned, for example, the same groups as set forth above with respect to Zₖₐ₁ of formula (KA-1).

It is more preferred for the structure of formula (KY-2) to be the partial structure of general formula (KY-3) below.

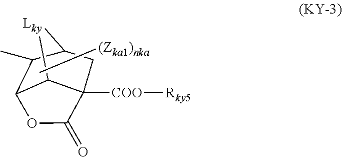

In formula (KY-3), Zₖₐ₁ and nka are as defined above in connection with general formula (KA-1). R_{ky5} is as defined above in connection with formula (KY-2).

L_{ky} represents an alkylene group, an oxygen atom or a sulfur atom. As the alkylene group represented by L_{ky}, there can be mentioned a methylene group, an ethylene group or the like. L_{ky} is preferably an oxygen atom or a methylene group, more preferably a methylene group.

The repeating units (b) are not limited as long as they are derived by polymerization, such as addition polymerization, condensation polymerization or addition condensation. Preferred repeating units are those obtained by the addition polymerization of a carbon to carbon double bond. As such repeating units, there can be mentioned, for example, acrylate repeating units (including the family having a substituent at the α- and/or β-position), styrene repeating units (including the family having a substituent at the α- and/or β-position), vinyl ether repeating units, norbornene repeating units, repeating units of maleic acid derivatives (maleic anhydride, its derivatives, maleimide, etc.) and the like. Of these, acrylate repeating units, styrene repeating units, vinyl ether repeating units and norbornene repeating units are preferred. Acrylate repeating units, vinyl ether repeating units and norbornene repeating units are more preferred. Acrylate repeating units are most preferred.

When the repeating unit (by) is a repeating unit containing at least either a fluorine atom or a silicon atom (namely, corresponding to the above repeating unit (b′) or (b″)), as the partial structure containing a fluorine atom within the repeating unit (by), there can be mentioned any of those set forth in connection with the repeating unit containing at least either a fluorine atom or a silicon atom above, preferably the groups of general formulae (F2) to (F4) above. As the partial structure containing a silicon atom within the repeating unit (by), there can be mentioned any of those set forth in connection with the repeating unit containing at least either a fluorine atom or a silicon atom above, preferably the groups of general formulae (CS-1) to (CS-3) above.

The content of repeating unit (by) in the resin (B), based on all the repeating units of the resin (B), is preferably in the range of 10 to 100 mol %, more preferably 20 to 99 mol %, further more preferably 30 to 97 mol % and most preferably 40 to 95 mol %.

Particular examples of the repeating units (by) containing a group whose solubility in an alkali developer is increased are shown below, which however in no way limit the scope of the repeating units.

In particular examples below, Ra represents a hydrogen atom, a fluorine atom, a methyl group or a trifluoromethyl group.

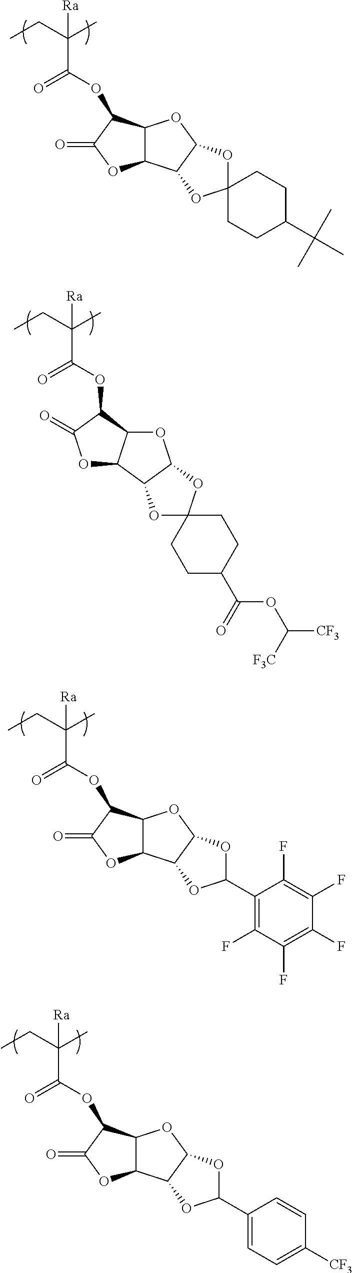

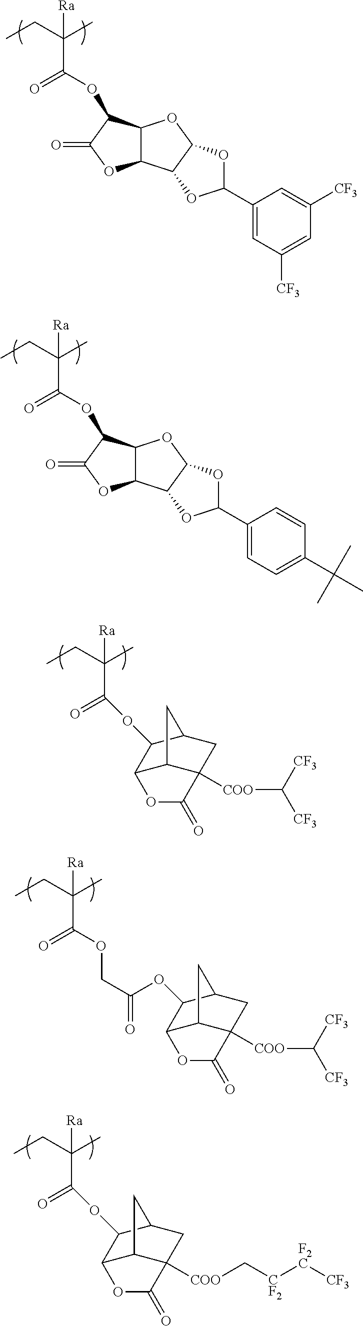

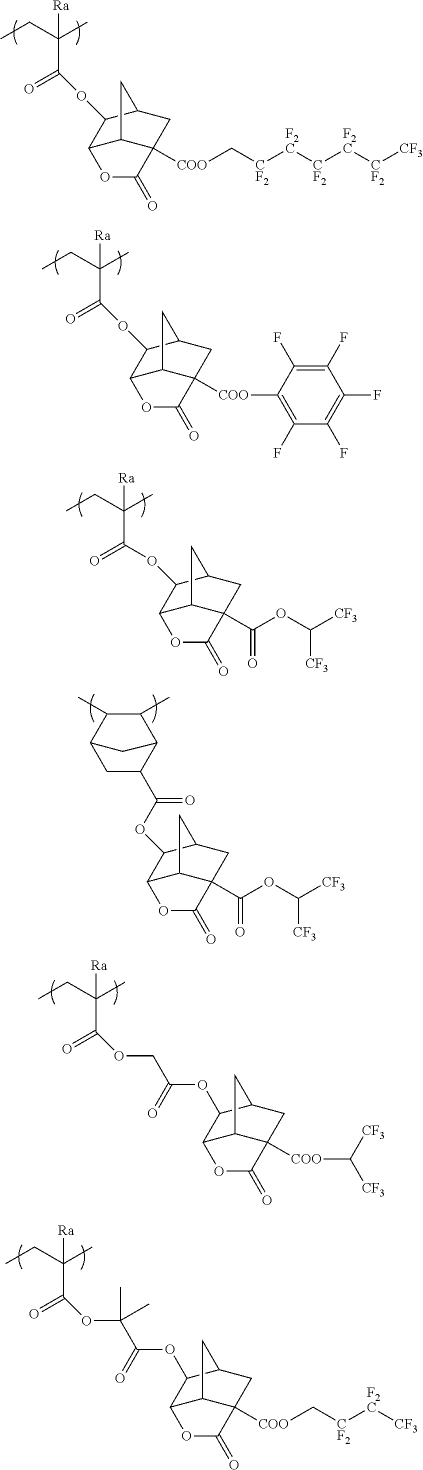

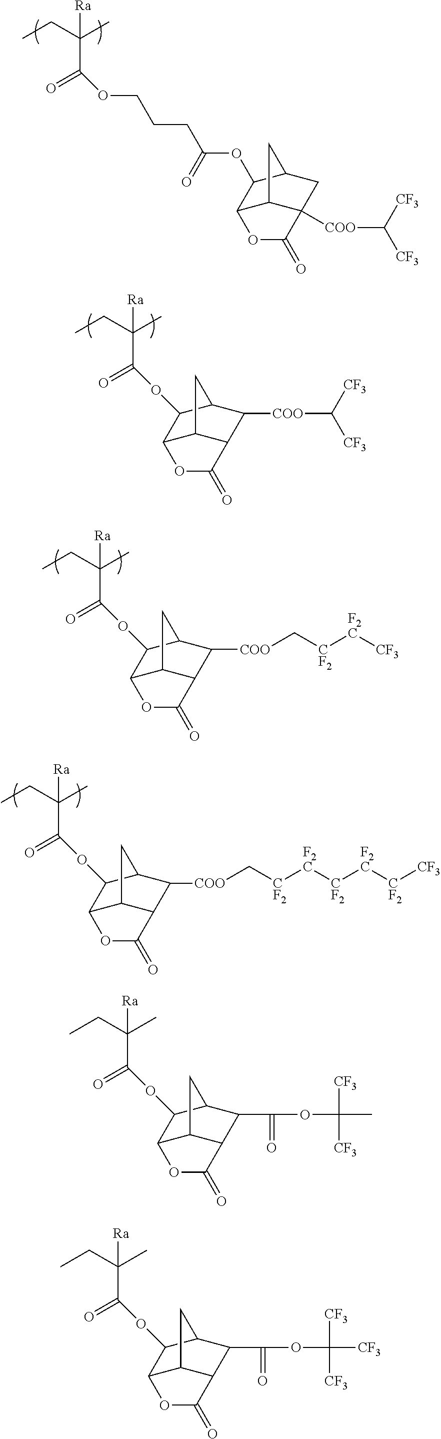

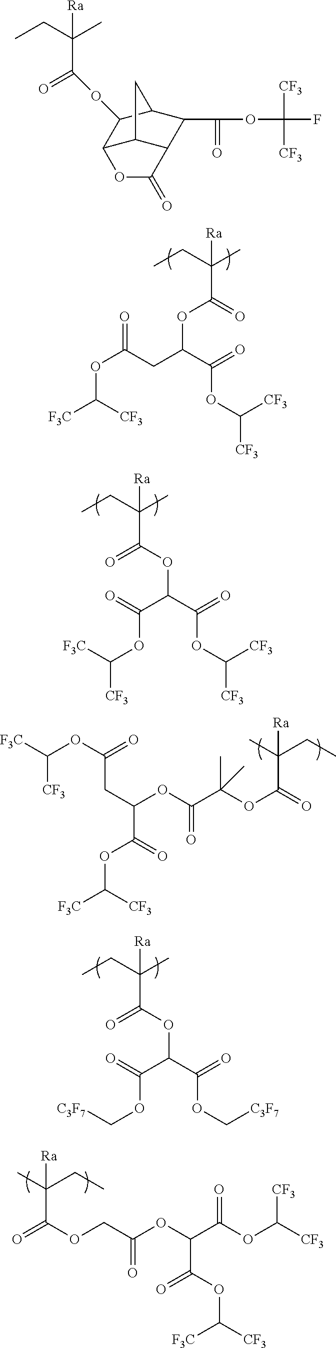

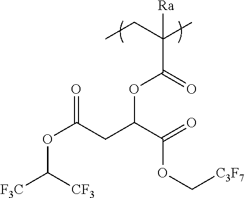

The repeating unit (bz) containing a group that is decomposed by the action of an acid (z), contained in the resin (B) can be the same as any of the repeating units each containing an acid-decomposable group set forth above in connection with the resin (A).

When the repeating unit (bz) is a repeating unit containing at least either a fluorine atom or a silicon atom (namely, when corresponding to the above-mentioned repeating unit [b′] or repeating unit [b″]), the partial structure containing a fluorine atom contained in the repeating unit (bz) can be the same as set forth above in connection with the repeating unit containing at least either a fluorine atom or a silicon atom. As such, preferably, there can be mentioned any of the groups of general formulae (F2) to (F4) above. Also in that instance, the partial structure containing a silicon atom contained in the repeating unit (bz) can be the same as set forth above in connection with the repeating unit containing at least either a fluorine atom or a silicon atom. As such, preferably, there can be mentioned any of the groups of general formulae (CS-1) to (CS-3) above.

The content of repeating unit (bz) containing a group that is decomposed by the action of an acid (z) in the resin (B), based on all the repeating units of the resin (B), is preferably in the range of 1 to 80 mol %, more preferably 10 to 80 mol % and further more preferably 20 to 60 mol %.

The repeating unit (b) containing at least one group selected from the group consisting of the above groups (x) to (z) has been described. The content of repeating unit (b) in the resin (B) is preferably in the range of 1 to 98 mol %, more preferably 3 to 98 mol %, further more preferably 5 to 97 mol % and most preferably 10 to 95 mol %, based on all the repeating units of the resin (B).

The content of repeating unit (b′) in the resin (B) is preferably in the range of 1 to 100 mol %, more preferably 3 to 99 mol %, further more preferably 5 to 97 mol % and most preferably 10 to 95 mol %, based on all the repeating units of the resin (B).

The content of repeating unit (b*) in the resin (B) is preferably in the range of 1 to 90 mol %, more preferably 3 to 80 mol %, further more preferably 5 to 70 mol % and most preferably 10 to 60 mol %, based on all the repeating units of the resin (B). The content of repeating unit containing at least either a fluorine atom or a silicon atom used in combination with the repeating unit (b*) is preferably in the range of 10 to 99 mol %, more preferably 20 to 97 mol %, further more preferably 30 to 95 mol % and most preferably 40 to 90 mol %, based on all the repeating units of the resin (B).

The content of repeating unit (b″) in the resin (B) is preferably in the range of 1 to 100 mol %, more preferably 3 to 99 mol %, further more preferably 5 to 97 mol % and most preferably 10 to 95 mol %, based on all the repeating units of the resin (B).

The resin (B) may further contain any of the repeating units represented by the following general formula (V).

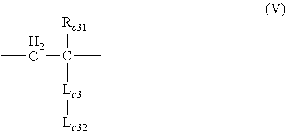

In the formula (V),

R_{c31} represents a hydrogen atom, an alkyl group, an alkyl group optionally substituted with one or more fluorine atoms, a cyano group or a group of the formula —CH₂—O—R_{ac2} in which R_{ac2} represents a hydrogen atom, an alkyl group or an acyl group. R_{c31} is preferably a hydrogen atom, a methyl group, a hydroxymethyl group, or a trifluoromethyl group, more preferably a hydrogen atom or a methyl group.

R_{c32} represents a group containing an alkyl group, a cycloalkyl group, an alkenyl group, a cycloalkenyl group, or an aryl group. These groups may be substituted with fluorine atom and/or silicon atom.

L_{c3} represents a single bond or a bivalent connecting group.

In the formula (V), the alkyl group represented by R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms such as a phenyl group or a naphthyl group.

These groups may have one or more substituents.

Preferably, R_{c32} represents an unsubstituted alkyl group or an alkyl group substituted with one or more fluorine atoms.

L_{c3} represents a single bond or a bivalent connecting group. As the bivalent connecting group represented by L_{c3}, an alkylene group (preferably having 1 to 5 carbon atoms), an oxy group, a phenylene group, or an ester bond (a group represented by —COO—) can be exemplified.

The resin (B) may further contain any of the repeating units represented by general formula (BII-AB) below.

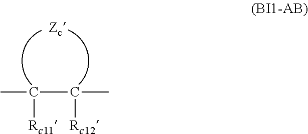

In the formula (BII-AB),

each of R_{c11}′ and R_{c12}′ independently represents a hydrogen atom, a cyano group, a halogen atom or an alkyl group.

Zc′ represents an atomic group containing bonded two carbon atoms (C—C) and required for forming an alicyclic structure.

When any of the groups contained in the repeating unit represented by general formulae (V) or (BII-AB) is substituted with a fluorine atom or a silicone atom, the repeating unit is also corresponding to the aforementioned repeating unit containing at least either a fluorine atom or a silicon atom.

Specific examples of the repeating unit represented by general formulae (V) or (BII-AB) will be shown below, which however in no way limit the scope of the present invention. In the formulae, Ra represents H, CH₃, CH₂OH, CF₃ or CN. Note that the repeating unit in which Ra represents CF₃ also corresponds to the repeating unit containing at least either a fluorine atom or a silicon atom.

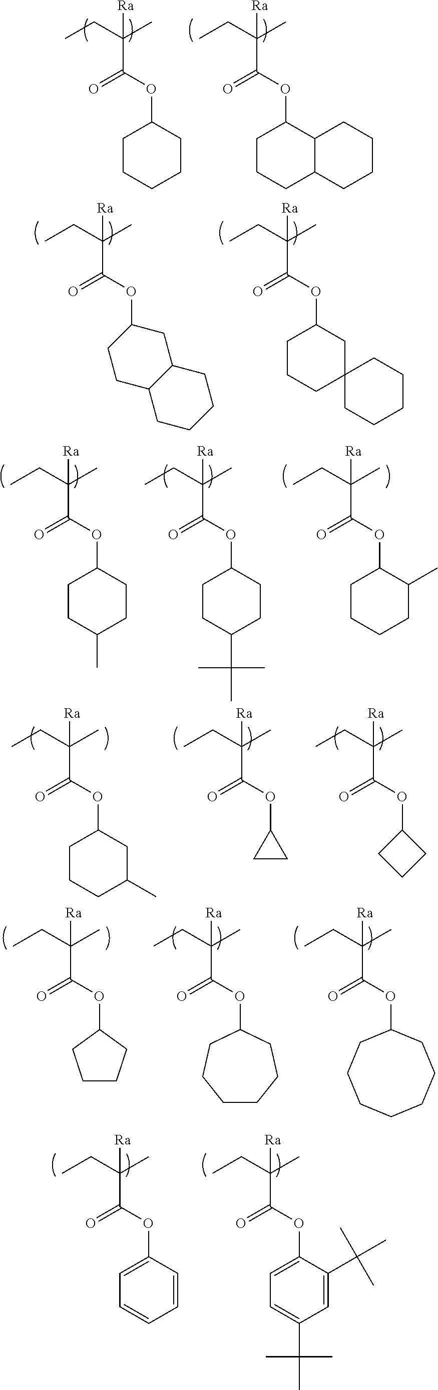

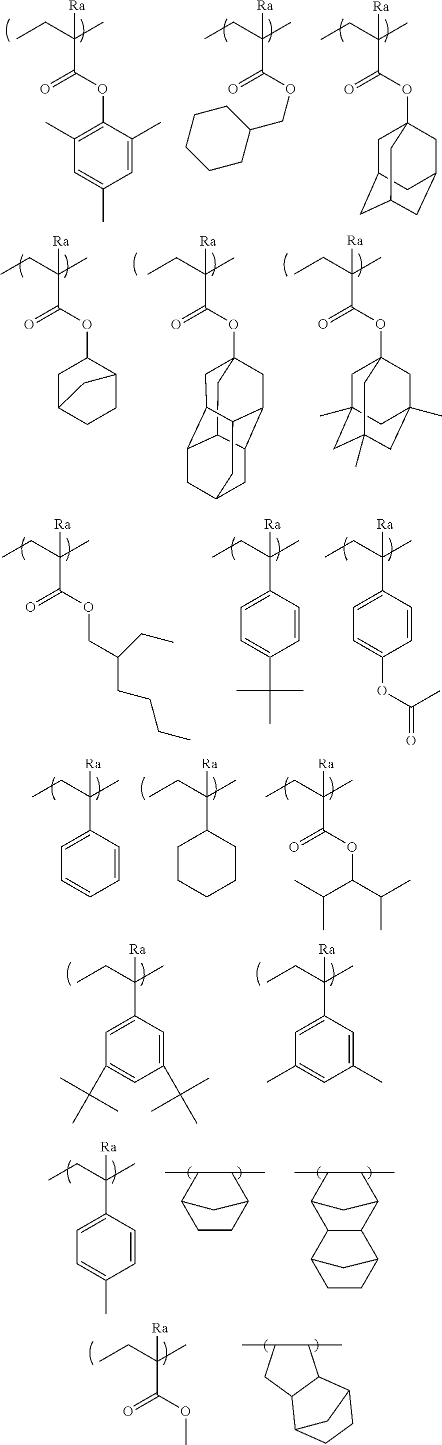

Impurities such as metals in the resin (B) should naturally be of low quantity as in the resin (A). The content of residual monomers and oligomer components is preferably in the range of 0 to 10 mass %, more preferably 0 to 5 mass %, and still more preferably 0 to 1 mass %. Accordingly, there can be obtained a composition being free from in-liquid foreign matters and a change in sensitivity, etc. over time. From the viewpoint of resolving power, resist profile, side wall of resist pattern, roughness, etc., the molecular weight distribution (Mw/Mn, also referred to as the degree of dispersal) thereof is preferably in the range of 1 to 3, more preferably 1 to 2, still more preferably 1 to 1.8 and most preferably 1 to 1.5.

A variety of commercially available products can be used as the resin (B), and also the resin can be synthesized in accordance with conventional methods (for example, by radical polymerization). As general synthesizing methods, a batch polymerization method in which a monomer species and an initiator are dissolved in a solvent and heated to carry out polymerization and a dropping polymerization method in which a solution of monomer species and initiator is dropped into a hot solvent over a period of 1 to 10 hours can be exemplified. Of these, the dropping polymerization method is preferred.

A reaction solvent, a polymerization initiator, a condition of a reaction (temperature, concentration or the like) and a purification method after a reaction are the same as the case of the resin (A).

Specific examples of the resin (B) will be shown below. The following Table 1 shows the component ratio of individual repeating units (the positional relationship of numerics indicating component ratios of Table 1 corresponds to that of the individual repeating units of each resin shown in the specific examples below), weight average molecular weight, and degree of dispersal with respect to each of the resins.

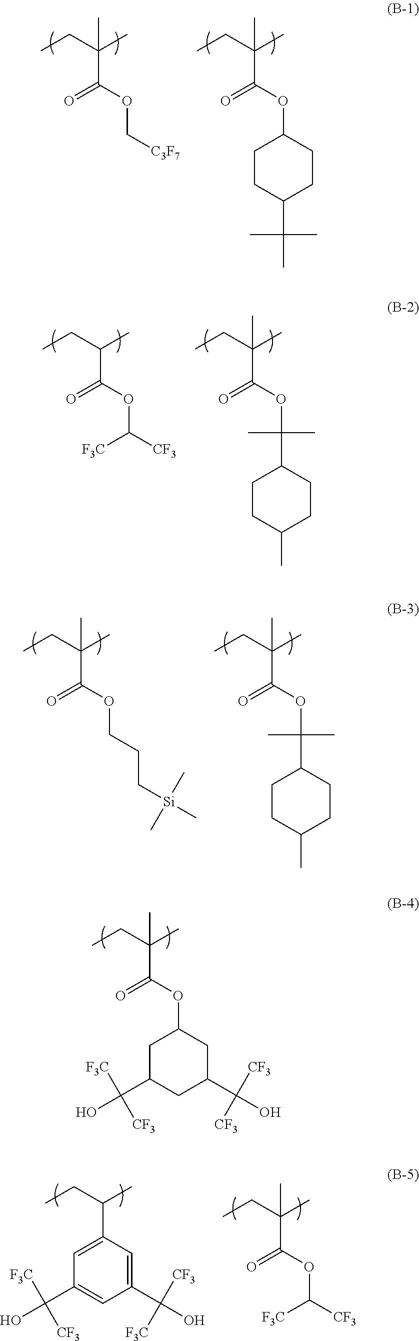

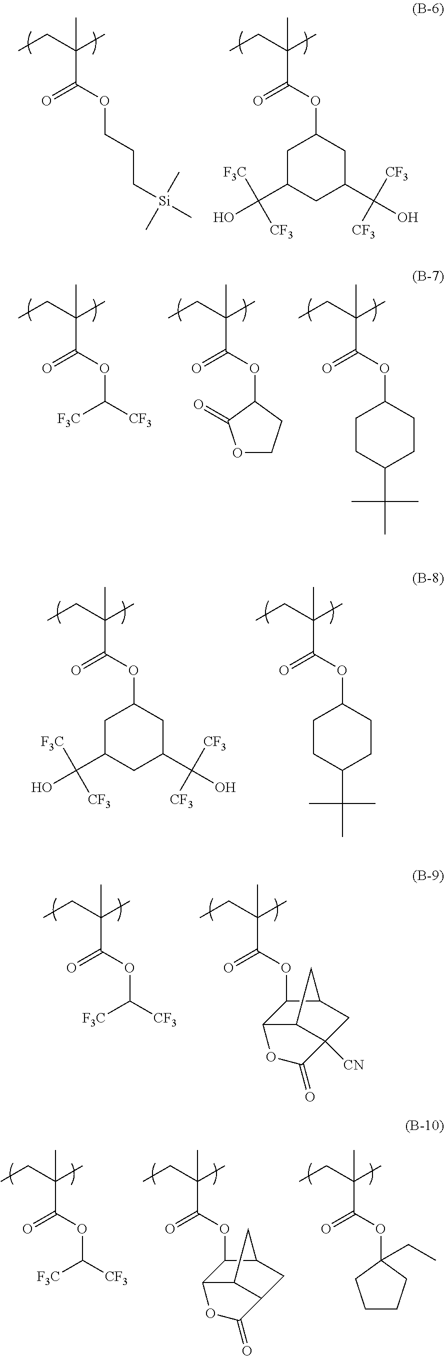

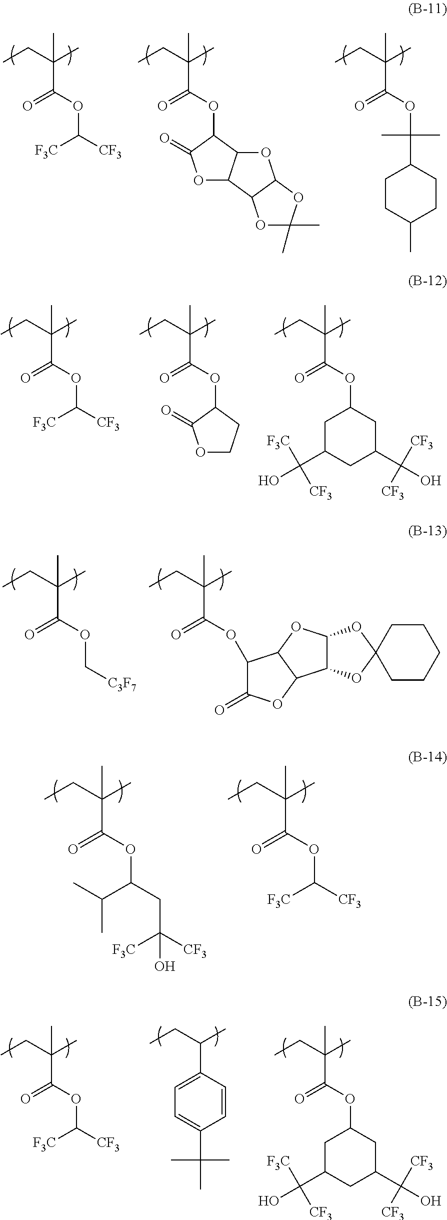

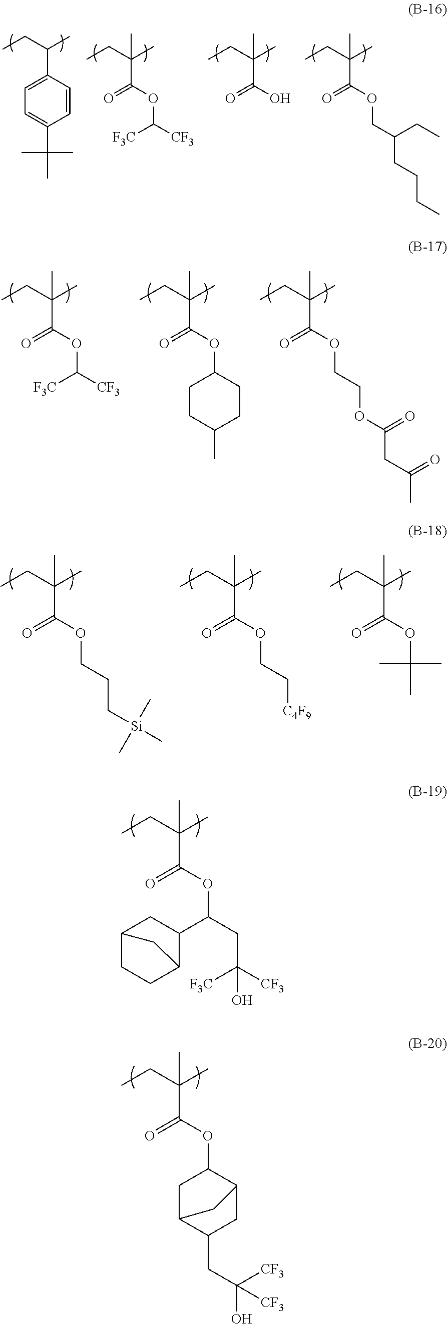

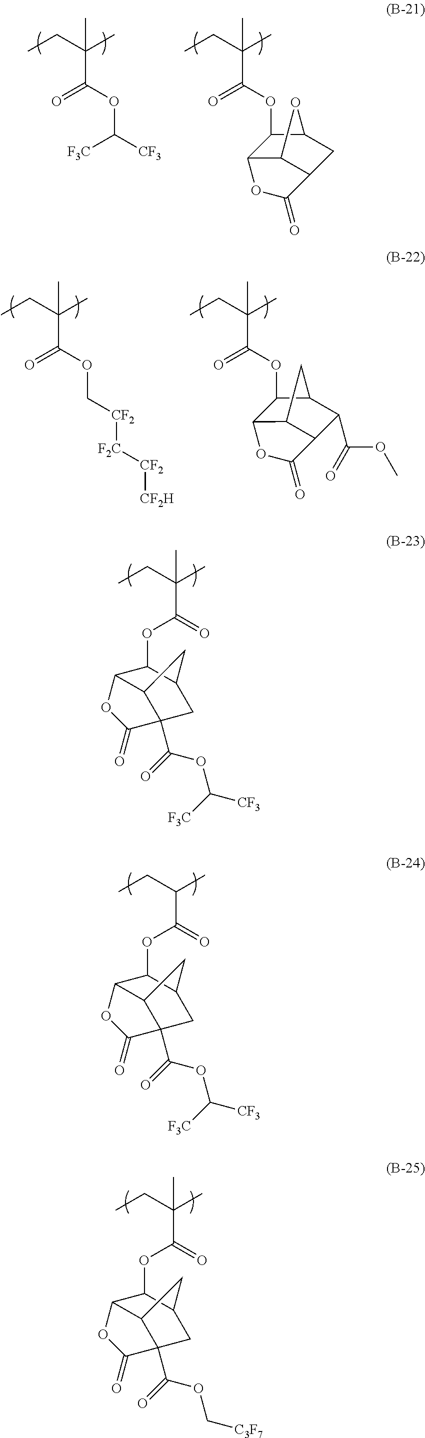

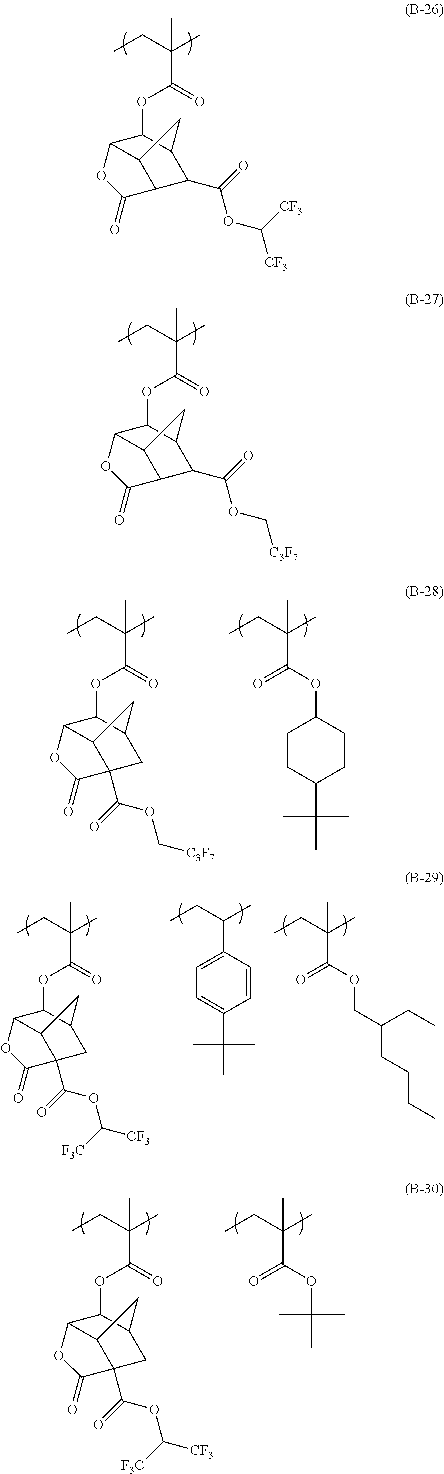

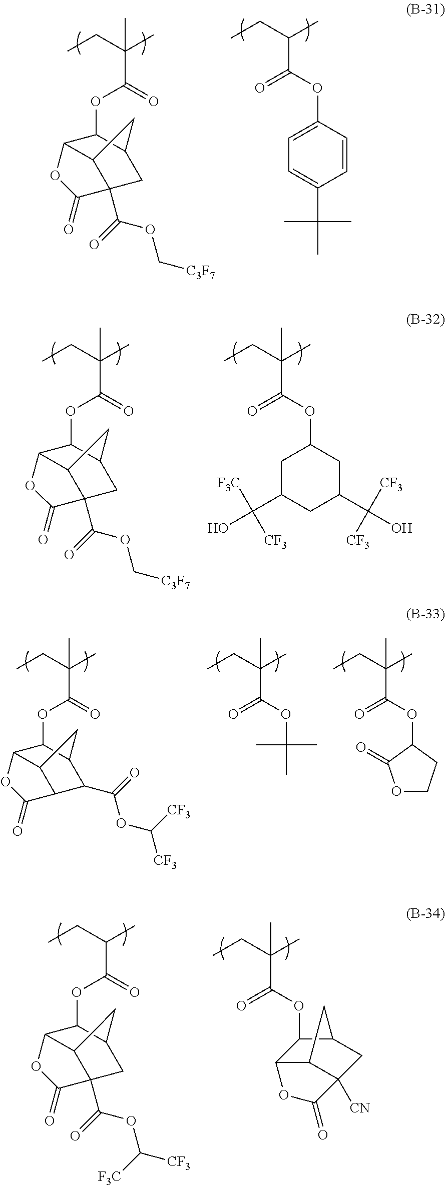

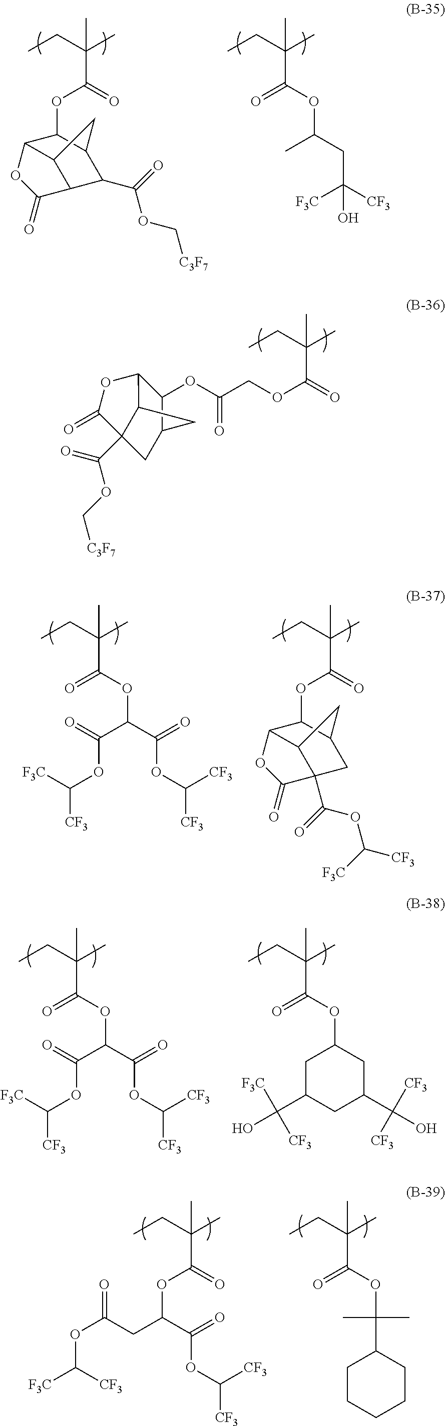

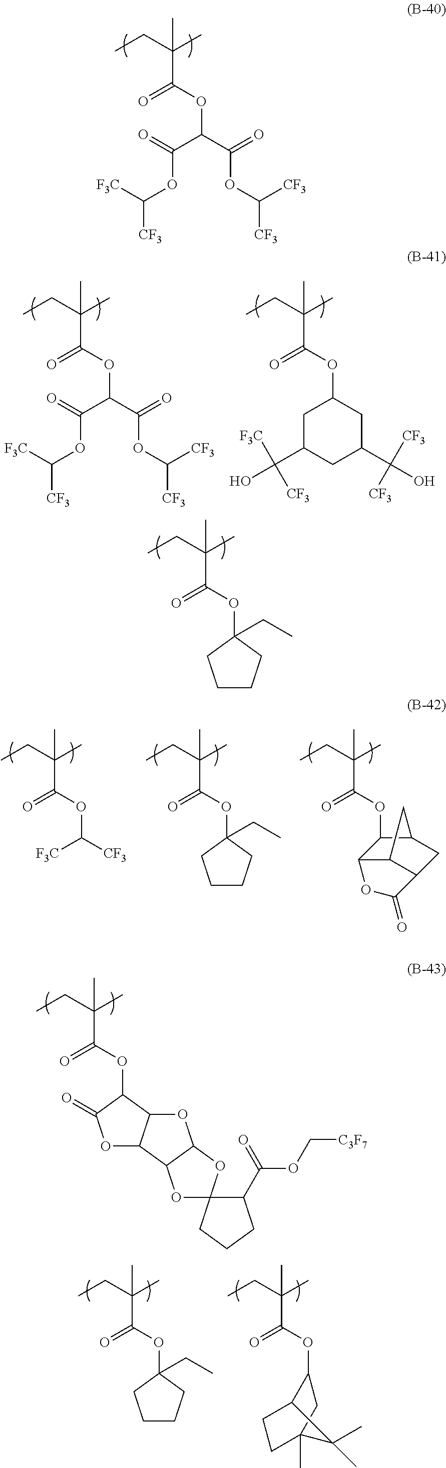

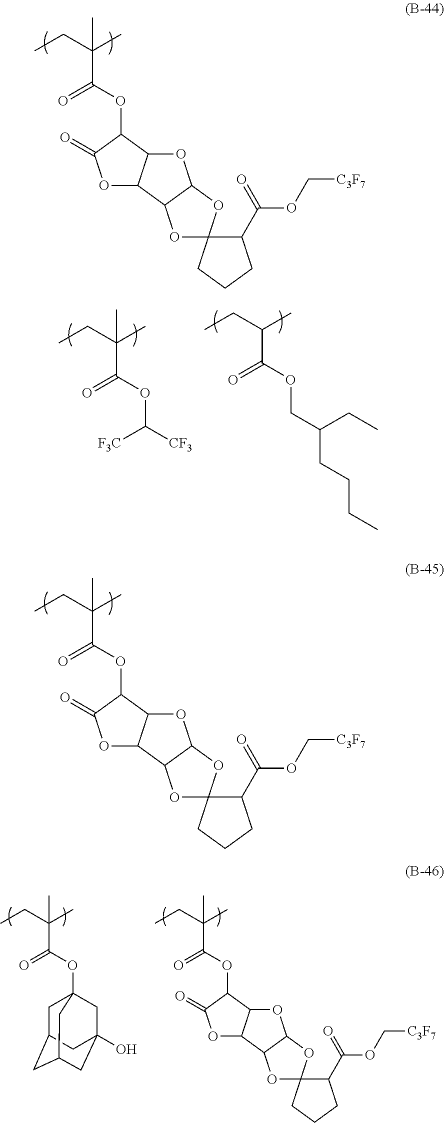

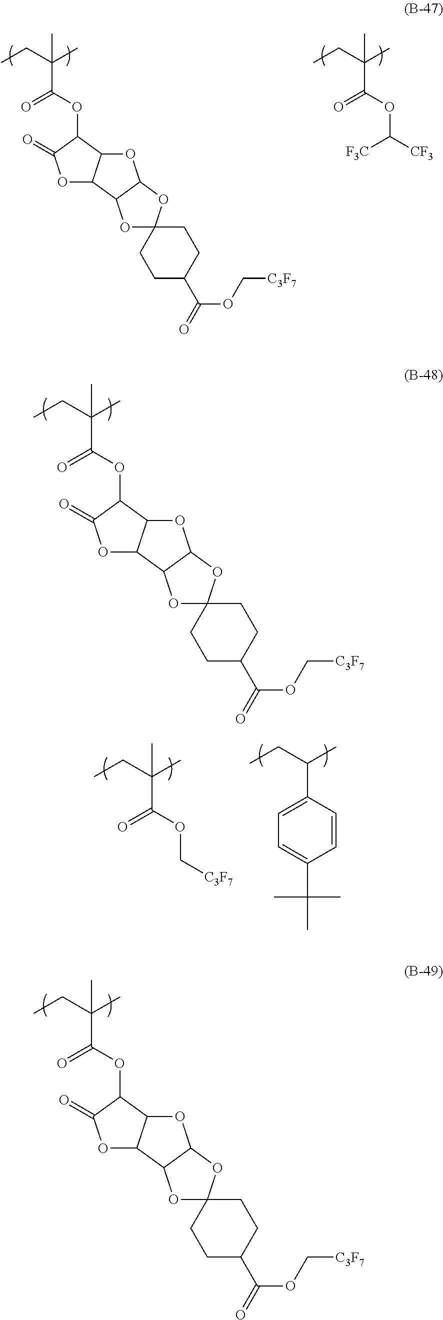

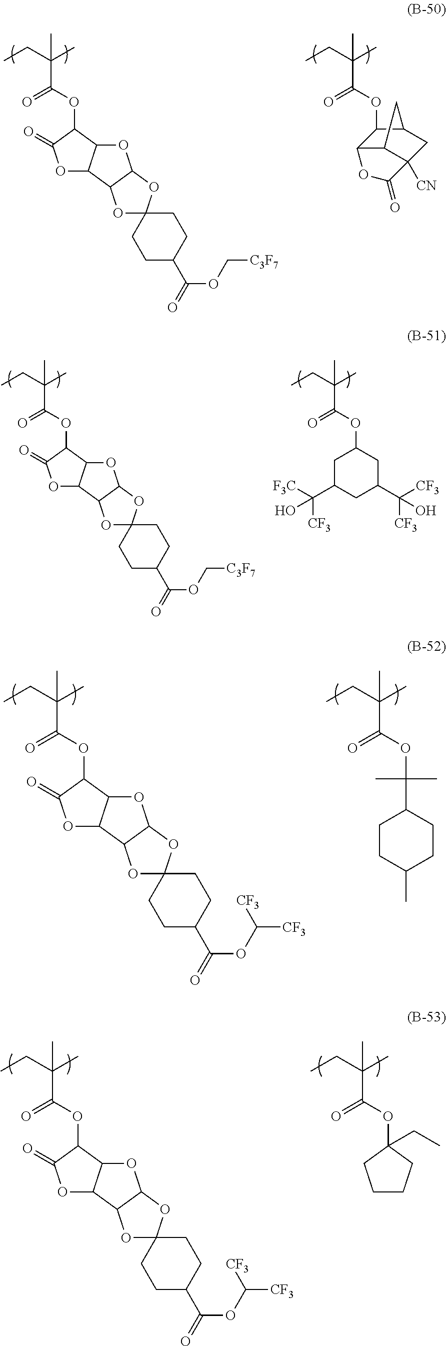

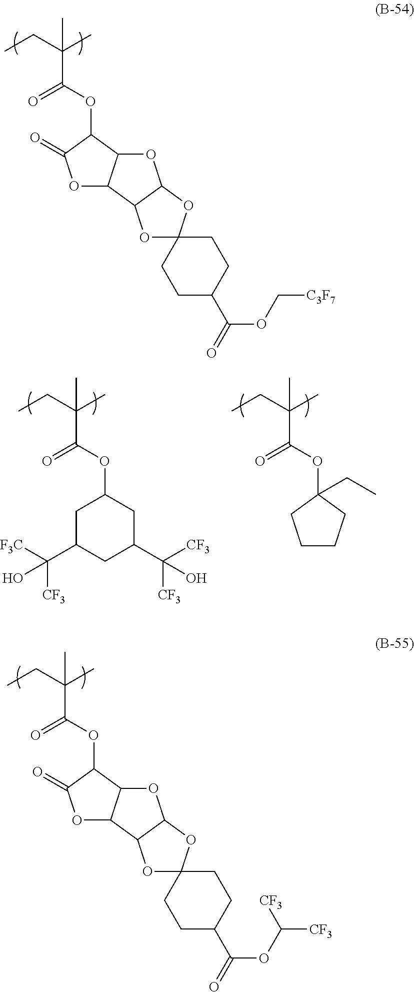

TABLE 1

| Polymer | Component ratio (mol %) | Mw | Mw/Mn |
|---|---|---|---|
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 20/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 80/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |

When the hydrophobic resin (B) containing at least either a fluorine atom or a silicon atom is contained in the actinic-ray- or radiation-sensitive resin composition according to the present invention, the resin (B) is unevenly distributed in the surface layer of the film formed from the composition. When the immersion medium is water, the receding contact angle of the surface of the film with respect to water is increased, so that the immersion-water tracking properties can be enhanced.

The receding contact angle of a film after baking and before exposing the film cinsisting of the actinic-ray- or radiation-sensitive resin composition according to the present invention is preferably in the range of 60° to 90°, more preferably 65° or higher, further more preferably 70° or higher, and particularly preferably 75° or higher as measured under the conditions of temperature 23±3° C. and humidity 45±5%.

Although the resin (B) is unevenly localized on any interface, as different from the surfactant, the hydrophobic resin does not necessarily have to have a hydrophilic group in its molecule and does not need to contribute toward uniform mixing of polar/nonpolar substances.

In the operation of liquid immersion exposure, it is needed for the liquid for liquid immersion to move on a wafer while tracking the movement of an exposure head involving high-speed scanning on the wafer and thus forming an exposure pattern. Therefore, the contact angle of the liquid for liquid immersion with respect to the film in dynamic condition is important, and it is required for the actinic ray-sensitive or radiation-sensitive resin composition to be capable of tracking the high-speed scanning of the exposure head without leaving droplets.

Because of its hydrophobicity, the resin (B) is likely to cause impairment of development residue (scum) and blob defects after alkali development. Containing three or more polymer chains via at least one branch portion increases the rate of dissolution in alkali as compared with that of a linear-chain resin, so that the development residue (scum) and blob defect performances can be improved thereby.

When the resin (B) contains fluorine atoms, the content of the fluorine atoms based on the molecular weight of the resin (B) is preferably in the range of 5 to 80 mass %, and more preferably 10 to 80 mass %. The repeating unit containing fluorine atoms preferably exists in the resin (B) in an amount of 10 to 100 mass %, more preferably 30 to 100 mass %.

When the resin (B) contains silicon atoms, the content of the silicon atoms based on the molecular weight of the resin (B) is preferably in the range of 2 to 50 mass %, more preferably 2 to 30 mass %. The repeating unit containing silicon atoms preferably exists in the resin (B) in an amount of 10 to 90 mass %, more preferably 20 to 80 mass %.

The weight average molecular weight of the resin (B) is preferably in the range of 1,000 to 100,000, more preferably 2,000 to 50,000, and still more preferably 3,000 to 30,000. Here, the weight average molecular weight of the resin is in terms of standard polystyrene molecular weight and is measured by GPC (carrier: tetrahydrofurane(THF)).

The content of resin (B) in the actinic-ray- or radiation-sensitive resin composition can be controlled so that the receding contact angle of a film of the actinic-ray- or radiation-sensitive resin composition is in the range above. The content of resin (B) in the actinic-ray- or radiation-sensitive resin composition, based on the total solids of the actinic-ray- or radiation-sensitive resin composition, is preferably in the range of 0.01 to 20 mass %, more preferably 0.1 to 15 mass %, further more preferably 0.1 to 10 mass % and especially preferably 0.5 to 8 mass %.

The resin (B) either may be used individually or in combination.

[4] Basic Compound

The actinic-ray- or radiation-sensitive resin composition of the present invention preferably contains a basic compound.

The basic compound is preferably a nitrogenous organic basic compound. Such useful basic compounds are not particularly limited. However, for example, the compounds of categories (1) to (4) below are preferably used.

(1) Compounds of General Formula (BS-1) Below

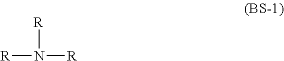

In the general formula (BS-1),

each of Rs independently represents any of a hydrogen atom, an alkyl group (linear or branched), a cycloalkyl group (monocyclic or polycyclic), an aryl group and an aralkyl group, provided that in no event all three Rs are hydrogen atoms.

The number of carbon atoms of the alkyl group represented by R is not particularly limited. However, it is generally in the range of 1 to 20, preferably 1 to 12.

The number of carbon atoms of the cycloalkyl group represented by R is not particularly limited. However, it is generally in the range of 3 to 20, preferably 5 to 15.

The number of carbon atoms of the aryl group represented by R is not particularly limited. However, it is generally in the range of 6 to 20, preferably 6 to 10. In particular, a phenyl group, a naphthyl group and the like can be mentioned.

The number of carbon atoms of the aralkyl group represented by R is not particularly limited. However, it is generally in the range of 7 to 20, preferably 7 to 11. In particular, a benzyl group and the like can be mentioned.

In the alkyl group, cycloalkyl group, aryl group and aralkyl group represented by R, a hydrogen atom thereof may be replaced by a substituent. As the substituent, there can be mentioned, for example, an alkyl group, a cycloalkyl group, an aryl group, an aralkyl group, a hydroxyl group, a carboxyl group, an alkoxy group, an aryloxy group, an alkylcarbonyloxy group, an alkyloxycarbonyl group or the like.

In the compounds of the general formula (BS-1), preferably, only one of the three Rs is a hydrogen atom, and also preferably, none of the Rs is a hydrogen atom.

Specific examples of the compounds of the general formula (BS-1) include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline and the like.

In the general formula (BS-1), any of the compounds in which at least one of the Rs is a hydroxylated alkyl group can be mentioned as a preferred form of the compounds. Specific examples of the compounds include triethanolamine, N,N-dihydroxyethylaniline and the like.

With respect to the alkyl group represented by R, an oxygen atom may be present in the alkyl chain to thereby form an oxyalkylene chain. The oxyalkylene chain preferably consists of —CH₂CH₂O—. As particular examples thereof, there can be mentioned tris(methoxyethoxyethyl)amine, compounds shown by way of example in column 3 line 60 et seq. of U.S. Pat. No. 6,040,112 and the like.

(2) Compound with Nitrogenous Heterocyclic Structure

The heterocyclic structure may optionally have aromaticity. It may have a plurality of nitrogen atoms, and also may have a heteroatom other than nitrogen. For example, there can be mentioned compounds with an imidazole structure (2-phenylbenzoimidazole, 2,4,5-triphenylimidazole and the like), compounds with a piperidine structure (N-hydroxyethylpiperidine, bis(1,2,2,6,6-pentamethyl-4-piperidyl) sebacate and the like), compounds with a pyridine structure (4-dimethylaminopyridine and the like) and compounds with an antipyrine structure (antipyrine, hydroxyantipyrine and the like).

Further, compounds with two or more ring structures can be appropriately used. For example, there can be mentioned 1,5-diazabicyclo[4.3.0]non-5-ene, 1,8-diazabicyclo[5.4.0]-undec-7-ene and the like.

(3) Amine Compound with Phenoxy Group

The amine compounds with a phenoxy group are those having a phenoxy group at the end of the alkyl group of each of the amine compound opposite to the nitrogen atom. The phenoxy group may have a substituent, such as an alkyl group, an alkoxy group, a halogen atom, a cyano group, a nitro group, a carboxyl group, a carboxylic ester group, a sulfonic ester group, an aryl group, an aralkyl group, an acyloxy group, an aryloxy group or the like.

Compounds having at least one oxyalkylene chain between the phenoxy group and the nitrogen atom are preferred. The number of oxyalkylene chains in each molecule is preferably in the range of 3 to 9, more preferably 4 to 6. Among the oxyalkylene chains, —CH₂CH₂O— is preferred.

Particular examples thereof include 2-[2-{2-(2,2-dimethoxy-phenoxyethoxy)ethyl}-bis-(2-methoxyethyl)]-amine, compounds (C1-1) to (C3-3) shown by way of example in section [0066] of US 2007/0224539 A1 and the like.

(4) Ammonium Salt

Ammonium salts can also be appropriately used. Hydroxides and carboxylates are preferred. Preferred particular examples thereof are tetraalkylammonium hydroxides, a typical example of which is tetrabutylammonium hydroxide.

As other compounds usable in the composition of the present invention, there can be mentioned compounds synthesized in Examples of JP-A-2002-363146, compounds described in section [0108] of JP-A-2007-298569 and the like.

The basic compound either may be used individually or in combination.

The content of basic compound, based on the total solids of the actinic-ray- or radiation-sensitive resin composition according to present invention, is usually in the range of 0.001 to 10 mass %, preferably 0.01 to 5 mass %.

The molar ratio of acid generator to basic compound is preferably in the range of 2.5 to 300. A molar ratio of 2.5 or higher is preferred from the viewpoint of sensitivity and resolving power. A molar ratio of 300 or below is preferred from the viewpoint of suppressing any resolving power drop due to pattern thickening over time until the baking treatment after exposure. The molar ratio is more preferably in the range of 5.0 to 200, further more preferably 7.0 to 150.

[5] Low-Molecular Compound Having a Nitrogen Atom and a Group that is Eliminated by the Action of an Acid

The composition according to the present invention may further contain a low-molecular compound having a nitrogen atom and a group that is eliminated by the action of an acid [hereinafter also referred to as “low-molecular compound (D)” or “compound (D)”].

The group that is cleaved when acted on by an acid is not particularly limited. However, an acetal group, a carbonate group, a carbamate group, a tertiary ester group, a tertiary hydroxyl group and a hemiaminal ether group are preferably used. A carbamate group and a hemiaminal ether group are especially preferred.

The molecular weight of the low-molecular compound (D) having a group that is cleaved when acted on by an acid is preferably in the range of 100 to 1000, more preferably 100 to 700 and most preferably 100 to 500.

As the compound (D), an amine derivative having a group that is cleaved when acted on by an acid being connected to a nitrogen atom is preferred.

The compound (D) may contain a carbamate group with a protective group, the carbamate group being connected to a nitrogen atom. The protective group contained in the carbamate group can be represented, for example, by the following formula (d-1).

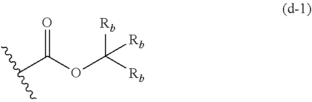

In the formula (d-1),

Each of Rbs independently represents a hydrogen atom, an alkyl group, a cycloalkyl group, an aryl group, an aralkyl group, or an alkoxyalkyl group. At least two of Rbs may be connected to each other to form a ring.

The alkyl group, the cycloalkyl group, the aryl group and the aralkyl group represented by Rb may be substituted with a functional group (a hydroxyl group, a cyano group, an amino group, a pyrrolidino group, a piperidino group, a morpholino group, an oxo group or the like), an alkoxy group or a halogen atom. The same applies to the alkoxyalkyl group represented by Rb.

As the alkyl group, the cycloalkyl group, the aryl group, and the aralkyl group (these groups may be substituted with the above functional group, an alkoxy group, or a halogen atom) represented by Rb, the following groups can be exemplified:

a group derived from a linear or branched alkane such as methane, ethane, propane, butane, pentane, hexane, heptane, octane, nonane, decane, undecane, or dodecane; and the group derived from the alkane and substituted with one or more cycloalkyl groups such as a cyclobutyl group, a cyclopentyl group, or a cyclohexyl group;

a group derived from cycloalkane such as cyclobutane, cyclopentane, cyclohexane, cycloheptane, cyclooctane, norbornane, adamantane, or noradamantane; and the group derived from the cycloalkane and substituted with one or more linear or branched alkyl group such as a methyl group, an ethyl group, a n-propyl group, an i-propyl group, a n-butyl group, a 2-methylpropyl group, a 1-methylpropyl group, or a t-butyl group;

a group derived from aromatic compound such as benzene, naphthalene, or anthracene; and the group derived from the atomatic compound and substituted with one or more linear or branched alkyl group such as a methyl group, an ethyl group, a n-propyl group, an i-propyl group, a n-butyl group, a 2-methylpropyl group, a 1-methylpropyl group, or a t-butyl group;

a group derived from heterocyclic compound such as pyrrolidine, piperidine, morpholine, tetrahydrofuran, tetrahydropyrane, indole, indoline, quinoline, perhydroquinoline, indazole, or benzimidazole; the group derived from heterocyclic compound and substituted with one or more linear or branched alkyl group or a group derived from the aromatic compound;

a group derived from linear or branched alkane and substituted with a group derived from aromatic compound such as a phenyl group, a naphthyl group, or an anthracenyl group;

a group derived from cycloalkane and substituted with a group derived from aromatic compound such as a phenyl group, a naphthyl group, or an anthracenyl group; or

each of these groups substituted with a functional group such as a hydroroxyl group, a cyano group, an amino group, a pyrrolidino group, a piperidino group, a morpholino group, or an oxo group.

Rb represents prelerably a linear or branched alkyl group, a cycloalkyl group or aryl group, more preferably a linear or branched alkyl group or a cycloalkyl group.

As the ring formed by connecting two of Rb's each other, an alicyclic hydrocarbon group, an aromatic hydrocarbon group, a heterocyclic hydrocarbon group, or their derivatives are exemplified.

Concrete structures of groups represented by the general formula (d-1) will be shown below.

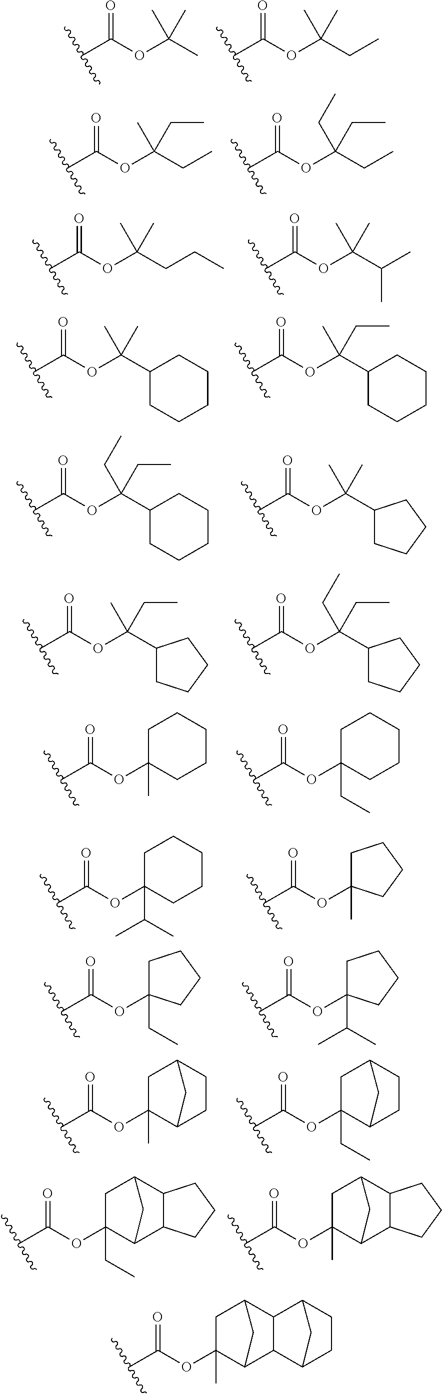

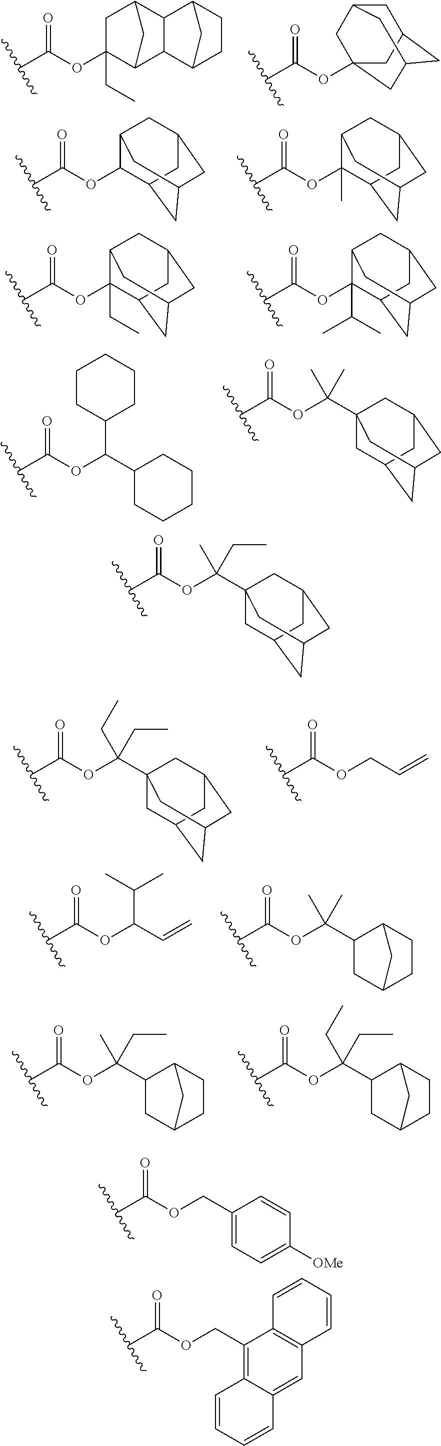

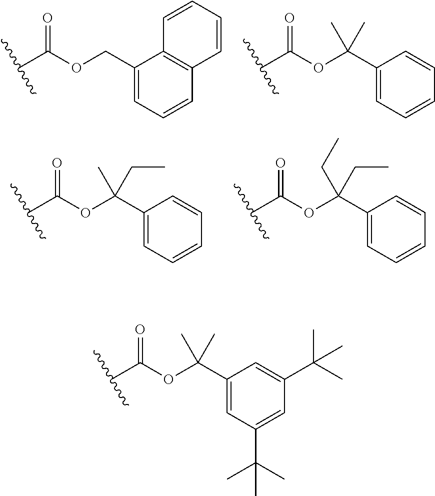

The compound (D) may have a structure in which any of the above-mentioned basic compounds are combined with the structure represented by general formula (d-1).

The compound (D) is especially preferred to be the one represented by general formula (A) below. Note that, the compound (D) may be any of the basic compounds described above as long as it is a low-molecular compound containing a group that is eliminated by the action of an acid.

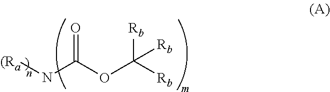

In the general formula (A), Ra represents a hydrogen atom, an alkyl group, a cycloalkyl group, an aryl group, or an aralkyl group. When n=2, two Ra's may be the same or different from each other, and may be connected to each other to form a bivalent heterocyclic hydrocarbon group (preferably having 20 or less carbon atoms) or its derivatives.

Rb has the same definition as Rb in the general formula (d-1) above, and ditto for preferable examples. When at least one of Rb's are hydrogen atoms in —C(Rb)(Rb)(Rb), at least one of the remainder represents a cyclopropyl group, 1-alkoxyalkyl group, or an aryl group.

n represents an integer of 0 to 2, m represents an integer of 1 to 3, and n+m=3.

In the formula (A), the alkyl group, the cycloalkyl group, the aryl group, and the aralkyl group represented by Ra may be substituted with a functional group same as the functional group above which substitutes the alkyl group, the cycloalkyl group, the aryl group, and the aralkyl group represented by Rb. As specific examples of the alkyl group, the cycloalkyl group, the aryl group, and the aralkyl group represented by Ra (the alkyl group, the cycloalkyl group, the aryl group, and the aralkyl group may be substituted with the functional group above), the same group as the specific examples of Rb are exemplified.

Further, as the bivalent heterocyclic hydrocarbon group (preferably having 1 to 20 carbon atoms) or its derivative, formed by mutual binding of Ra's, for example, the followings can be exemplified:

a group derived from heterocyclic compound such as pyrrolidine, piperidine, morpholine, 1,4,5,6-tetrahydropyrimidine, 1,2,3,4-tetrahydroquinoline, 1,2,3,6-tetrahydroquinoline, homopiperadine, 4-azabenzimidazole, benztriazole, 5-azabenztriazole, 1H-1,2,3-triazole, 1,4,7-triazacyclononane, tetrazole, 7-azaindole, indazole, benzimidazole, imidazo[1,2-a]pyridine, (1S,4S)-(+)2,5-azabicyclo[2.2.1]heptane, 1,5,7-triazabicyclo[4.4.0]dec-5-en, indole, indoline, 1,2,3,4-tetrahydroquinoxaline, perhydroquinoline, or 1,5,9-triazacyclododecane; or

the group derived from heterocyclic compound and substituted with at least one of a group derived from linear or branched alkane, a group derived from cycloalkane, a group derived from aromatic compound, a group derived from heterocyclic compound, or a functional group such as a hydroxyl group, a cyano group, an amino group, a pyrrolidino group, a piperidino group, a morpholino group, or an oxo group.

Particularly preferred examples of the compound (D) will be shown below, which however in no way limit the scope of the present invention.

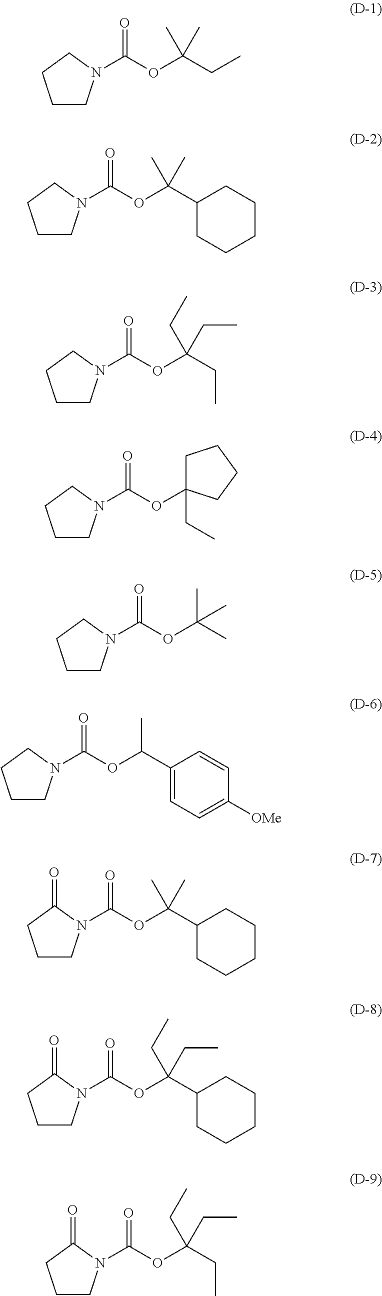

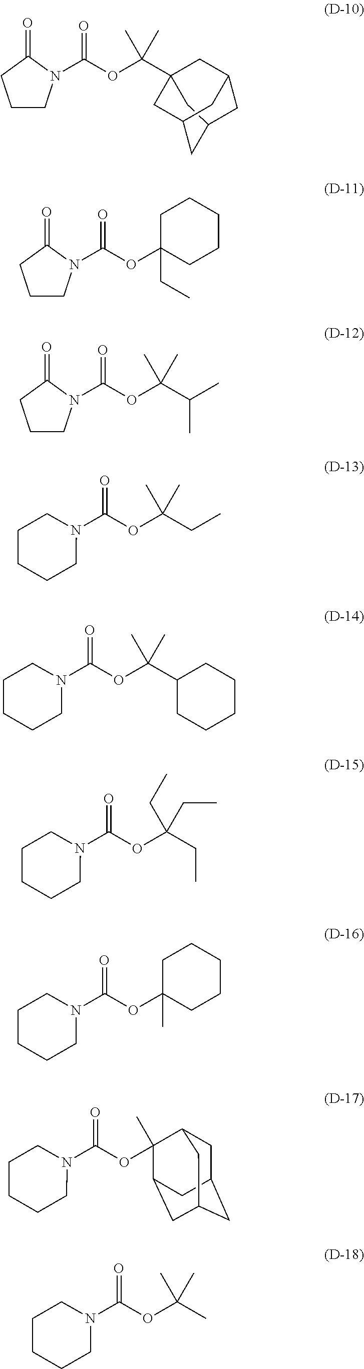

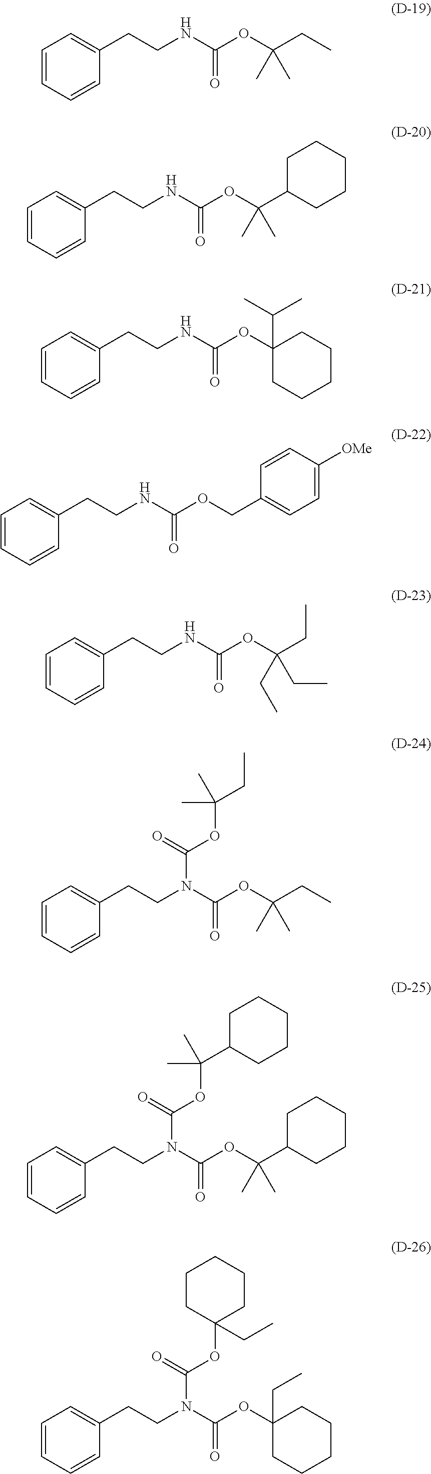

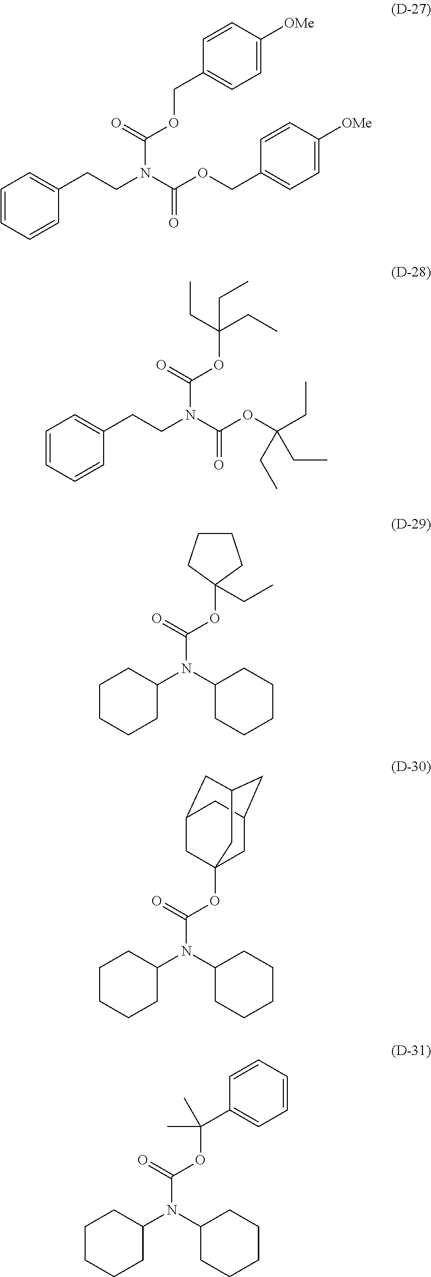

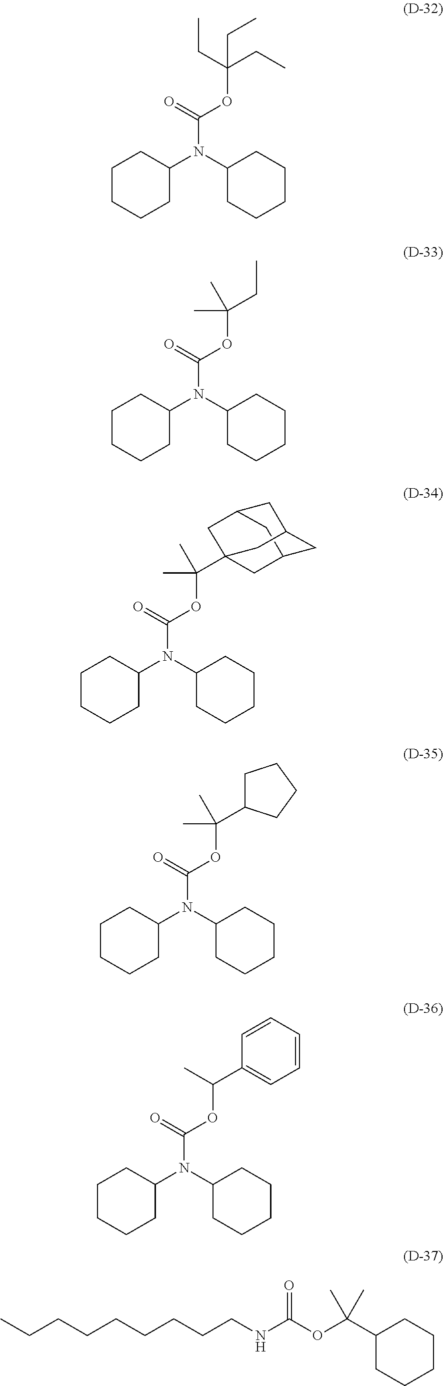

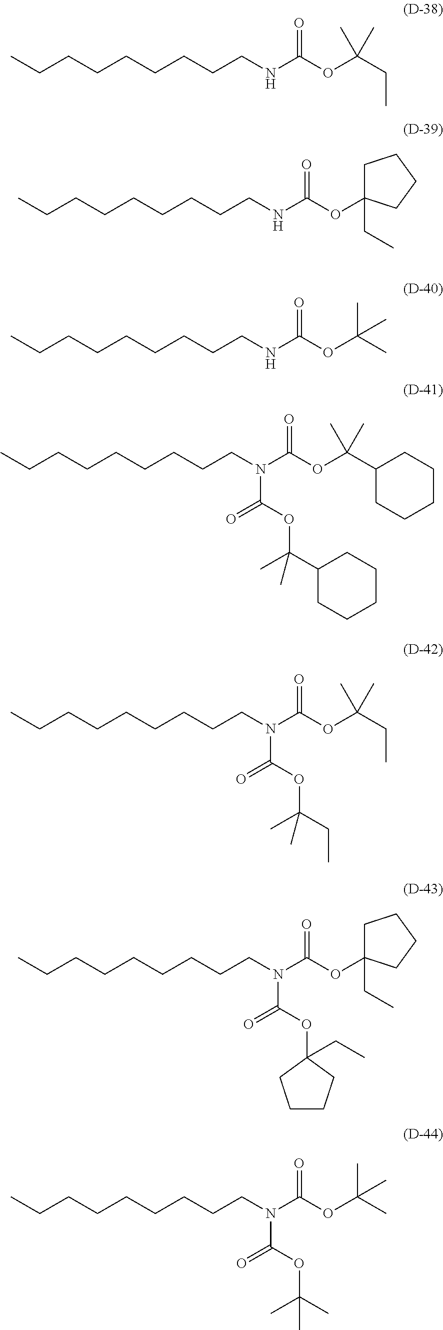

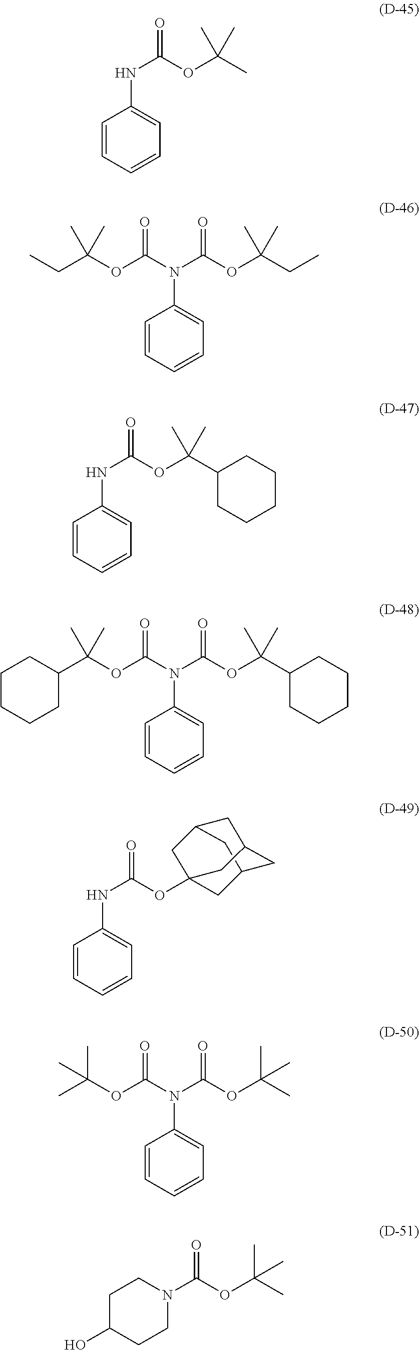

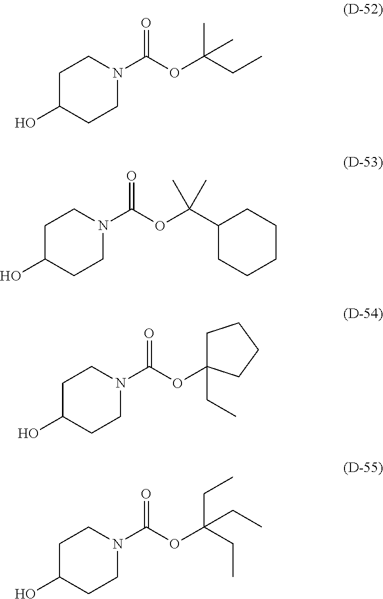 [SMILES: CCC(C)(C)OC(=O)N1CCC(O)CC1 ; CC(C)(OC(=O)N1CCC(O)CC1)C1CCCCC1 ; CCC1(OC(=O)N2CCC(O)CC2)CCCC1 ; CCC(CC)(CC)OC(=O)N1CCC(O)CC1]

The compounds of general formula (A) can be synthesized based on JP-A-2007-298569, JP-A-2009-199021 and the like.

In the present invention, each of the low-molecular compounds (D) containing a nitrogen atom and a group that is eliminated by the action of an acid may be used alone, or two or more thereof may be used in a mixture.

The actinic-ray- or radiation-sensitive resin composition according to the present invention may or may not contain the low-molecular compounds (D) having a nitrogen atom and a group that is eliminated by the action of an acid. When the actinic-ray- or radiation-sensitive resin composition according to the present invention contains the low-molecular compounds (D) having a nitrogen atom and a group that is eliminated by the action of an acid, the content of the compound (D), based on the total solids of the actinic-ray- or radiation-sensitive resin composition, is generally in the range of 0.001 to 20 mass %, preferably 0.001 to 10 mass % and more preferably 0.01 to 5 mass %.

With respect to the ratio between acid generator and compound (D) used in the composition, it is preferable that the molar ratio of acid generator/[compound (D)+above-mentioned basic compound] be in the range of 2.5 to 300. Namely, the molar ratio is preferred to be 2.5 or higher from the viewpoint of sensitivity and resolution, and the molar ratio is preferred to be 300 or below from the viewpoint of inhibiting the lowering of resolution by thickening of resist pattern over time from exposure to baking treatment. The molar ratio of acid generator/[compound (D)+above-mentioned basic compound] is more preferably in the range of 5.0 to 200, further more preferably 7.0 to 150.

[6] Basic Compound and Ammonium Salt Compound (E) that when Exposed to Actinic Rays or Radiation, Exhibit Lowered Basicity

It is preferable for the actinic-ray- or radiation-sensitive resin composition of the present invention to contain a basic compound or ammonium salt compound (hereinafter also referred to as “compound (E)”) that when exposed to actinic rays or radiation, exhibits a lowered basicity.

It is preferable for the compound (E) to be a compound (E-1) containing a basic functional group or ammonium group and a group that when exposed to actinic rays or radiation, generates an acid functional group. Namely, it is preferable for the compound (E) to be a basic compound containing a basic functional group and a group that when exposed to actinic rays or radiation, generates an acid functional group, or an ammonium salt compound containing an ammonium group and a group that when exposed to actinic rays or radiation, generates an acid functional group.

As the compounds each exhibiting a lowered basicity, generated by the decomposition of compound (E) or compound (E-1) upon exposure to actinic rays or radiation, there can be mentioned the compounds of general formulae (PA-I), (PA-II) and (PA-III) below. The compounds of general formulae (PA-II) and (PA-III) are especially preferable from the viewpoint of the higher-order simultaneous attainment of excellent effects concerning LWR, local pattern dimension uniformity and DOF.

First, the compounds of general formula (PA-I) will be described.

Q-A₁-(X)n-B—R (PA-I)

In general formula (PA-I),

A₁ represents a single bond or a bivalent connecting group.

Q represents —SO₃H or —CO₂H. Q corresponds to the acid functional group generated upon exposure to actinic rays or radiation.

X represents —SO₂— or —CO—, and

n is 0 or 1.

B represents a single bond, an oxygen atom or —N(Rx)-.

Rx represents a hydrogen atom or a monovalent organic group.

R represents a monovalent organic group containing a basic functional group, or a monovalent organic group containing an ammonium group.

Now, the compounds of general formula (PA-II) will be described.

Q₁-X₁—NH—X₂-Q₂ (PA-II)

In general formula (PA-II),

each of Q₁ and Q₂ independently represents a monovalent organic group, provided that either Q₁ or Q₂ contains a basic functional group. Q₁ and Q₂ may be bonded to each other, thereby forming a ring, the formed ring containing a basic functional group.

Each of X₁ and X₂ independently represents —CO— or —SO₂—.

In the formula, —NH— corresponds to the acid functional group generated upon exposure to actinic rays or radiation.

Below, the compounds of general formula (PA-III) will be described.

Q₁-X₁—NH—X₂-A₂-(X₃)ₘ—B-Q3 (PA-III)

In general formula (PA-III),

each of Q₁ and Q₃ independently represents a monovalent organic group, provided that either Q₁ or Q₃ contains a basic functional group. Q₁ and Q₃ may be bonded to each other, thereby forming a ring, the formed ring containing a basic functional group.

Each of X₁, X₂ and X₃ independently represents —CO— or —SO₂—.

A₂ represents a bivalent connecting group.

B represents a single bond, an oxygen atom or —N(Qx)-.

Qx represents a hydrogen atom or a monovalent organic group.

When B is —N(Qx)-, Q₃ and Qx may be bonded to each other, thereby forming a ring, and

m is 0 or 1.

In the formula, —NH— corresponds to the acid functional group generated upon exposure to actinic rays or radiation.

Particular examples of the compounds (E) that generate the compounds of general formula (PA-I) upon exposure to actinic rays or radiation are shown below, which in no way limit the scope of the present invention.

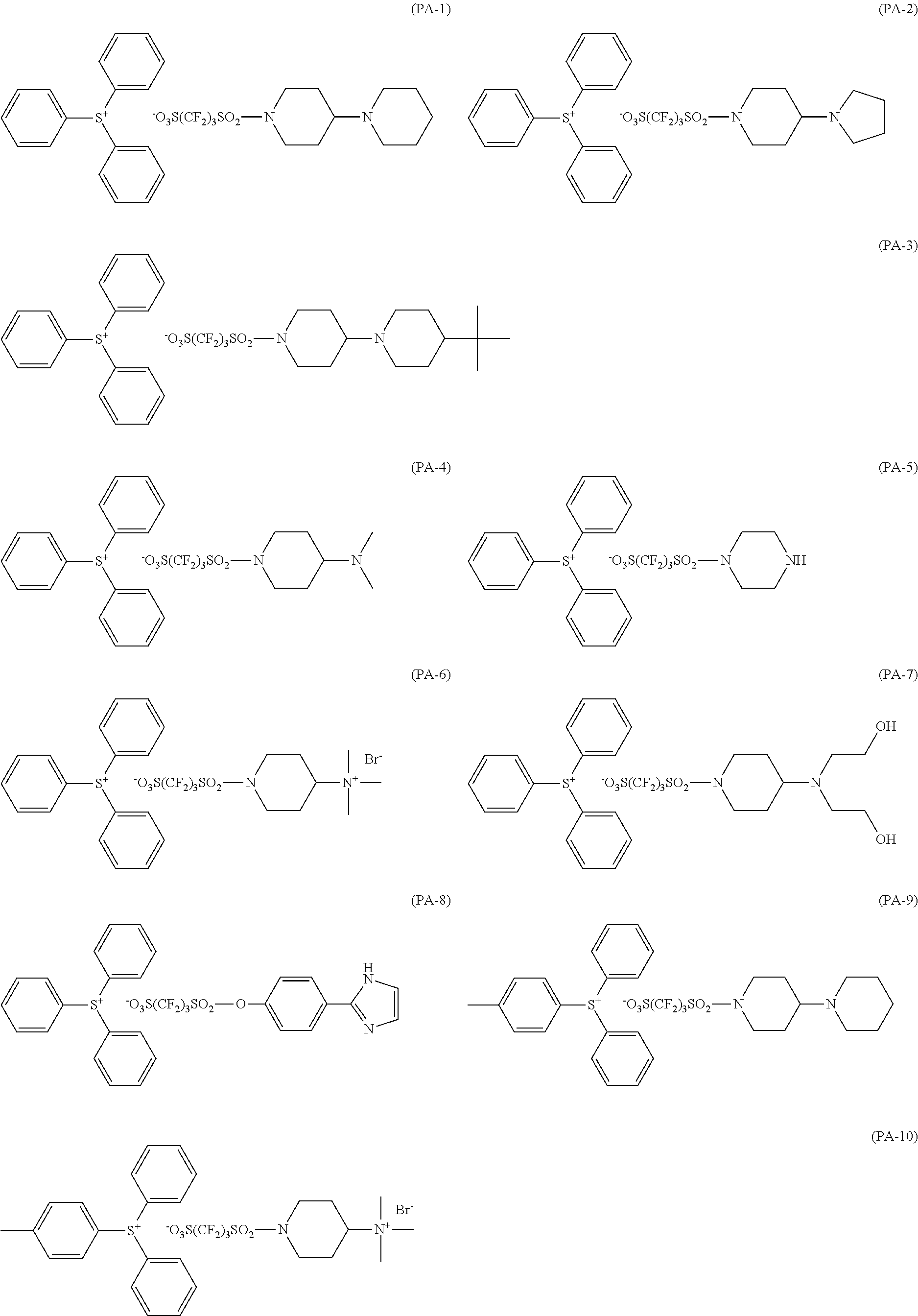

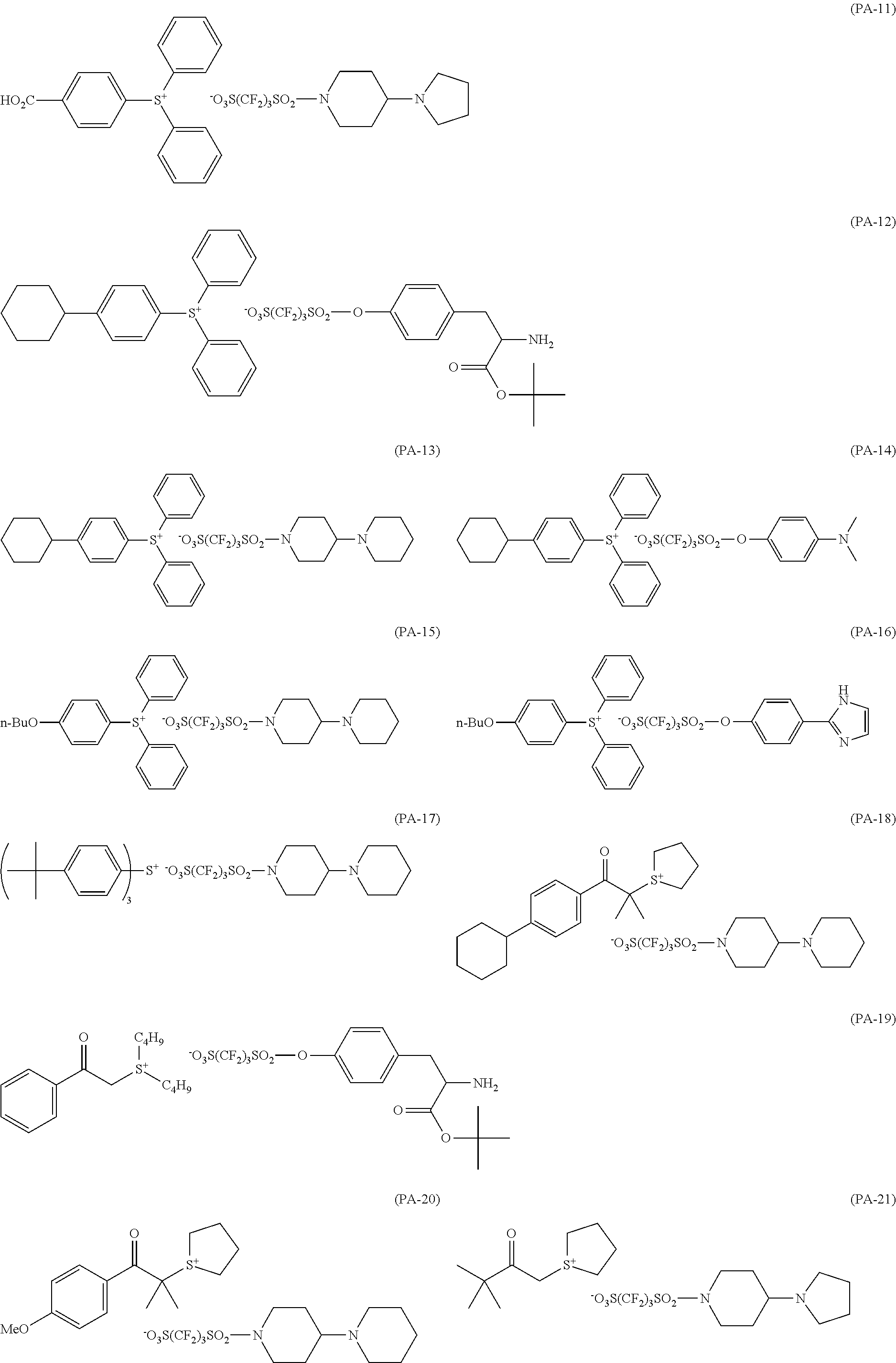

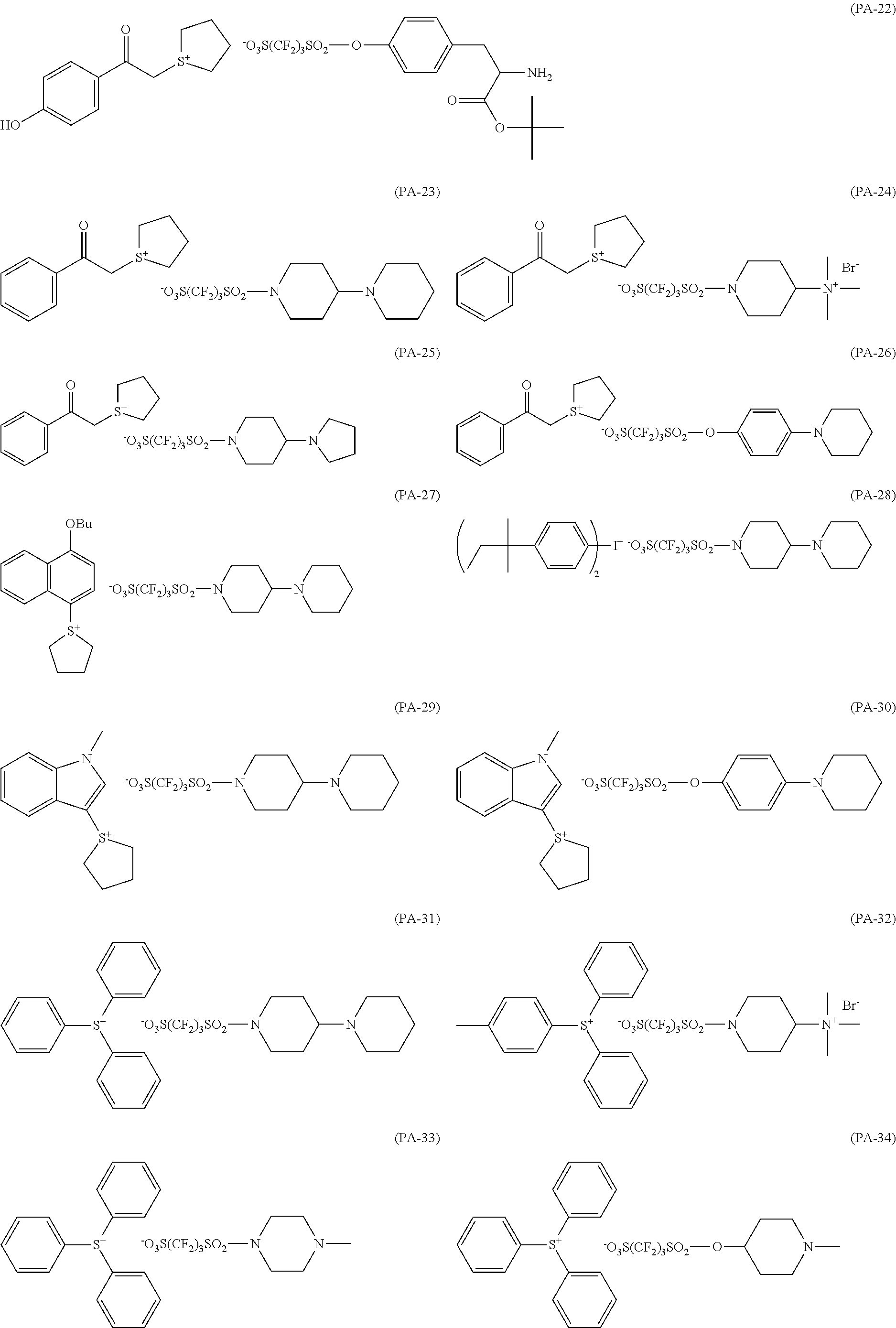

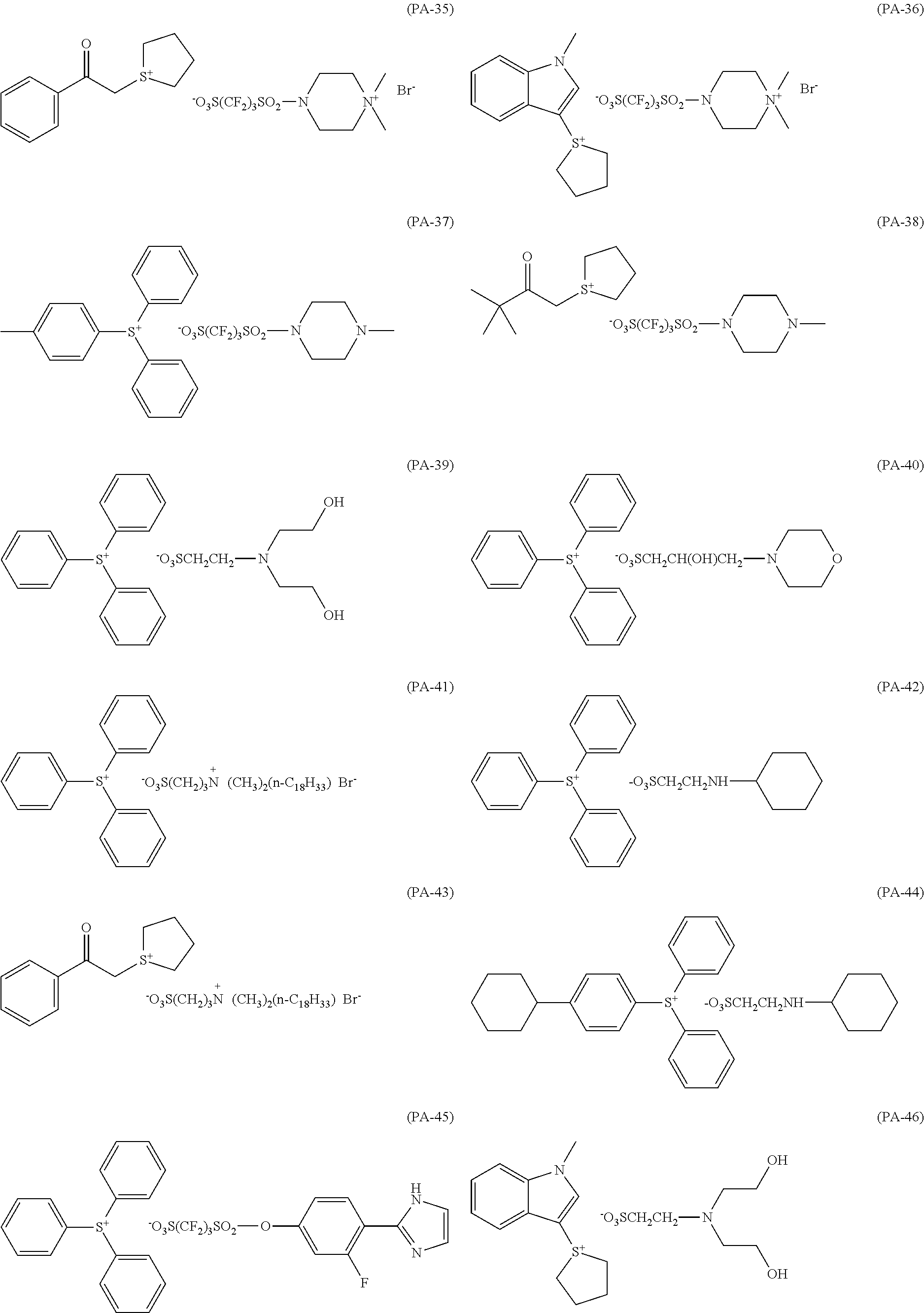

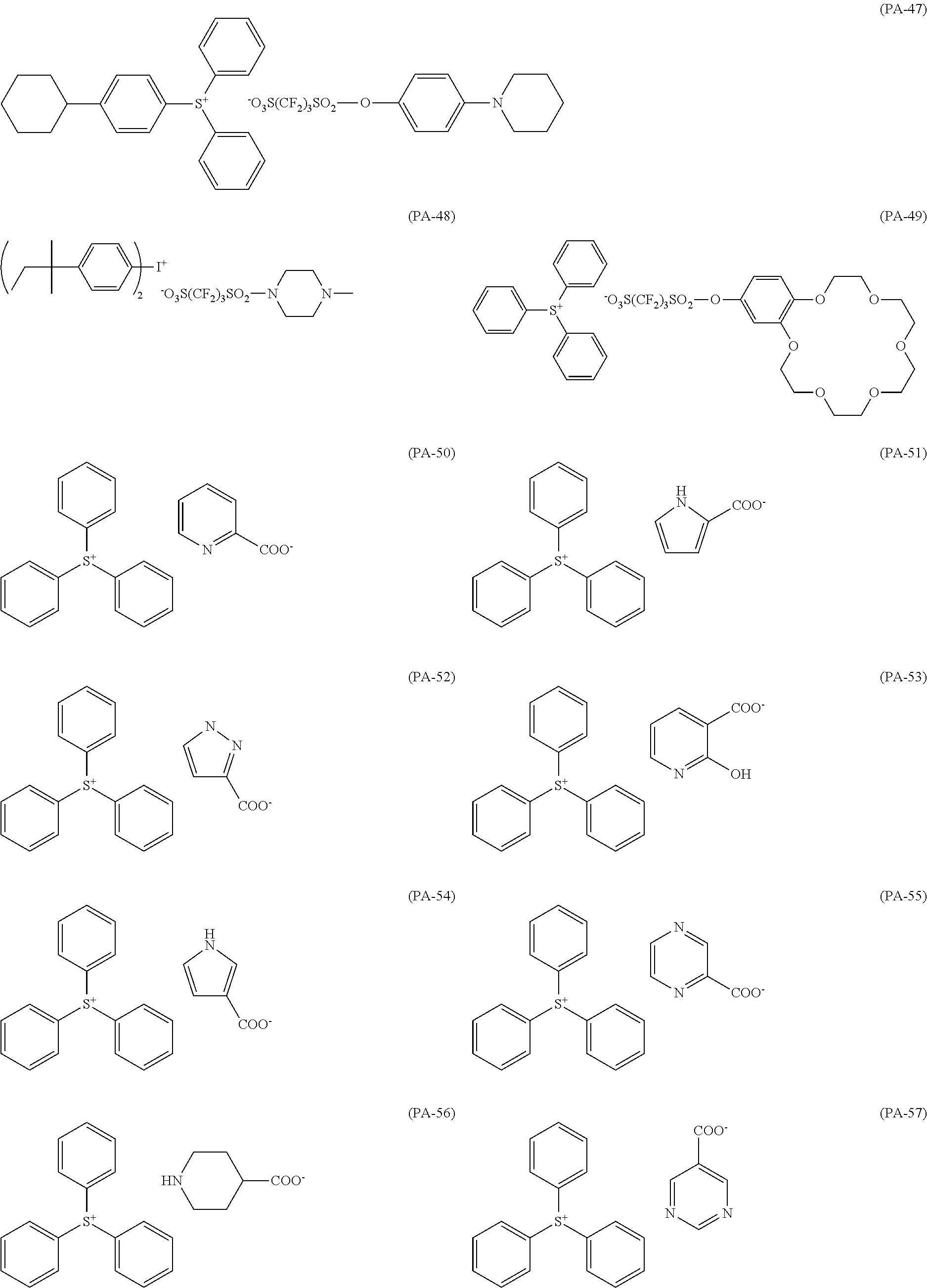

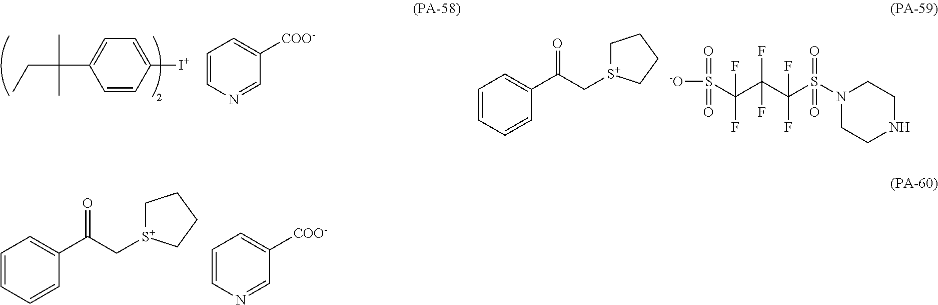

These compounds can be easily synthesized from the compounds of general formula (PA-I), or a lithium, sodium or potassium salt thereof, and a hydroxide, bromide or chloride of iodonium or sulfonium, etc. by the salt exchange method described in Jpn. PCT National Publication No. H11-501909 and JP-A-2003-246786. Also, the synthesis can be performed in accordance with the method described in JP-A-H7-333851.

Particular examples of the compounds (E) that generate the compounds of general formulae (PA-II) and (PA-III) upon exposure to actinic rays or radiation are shown below, which in no way limit the scope of the present invention.

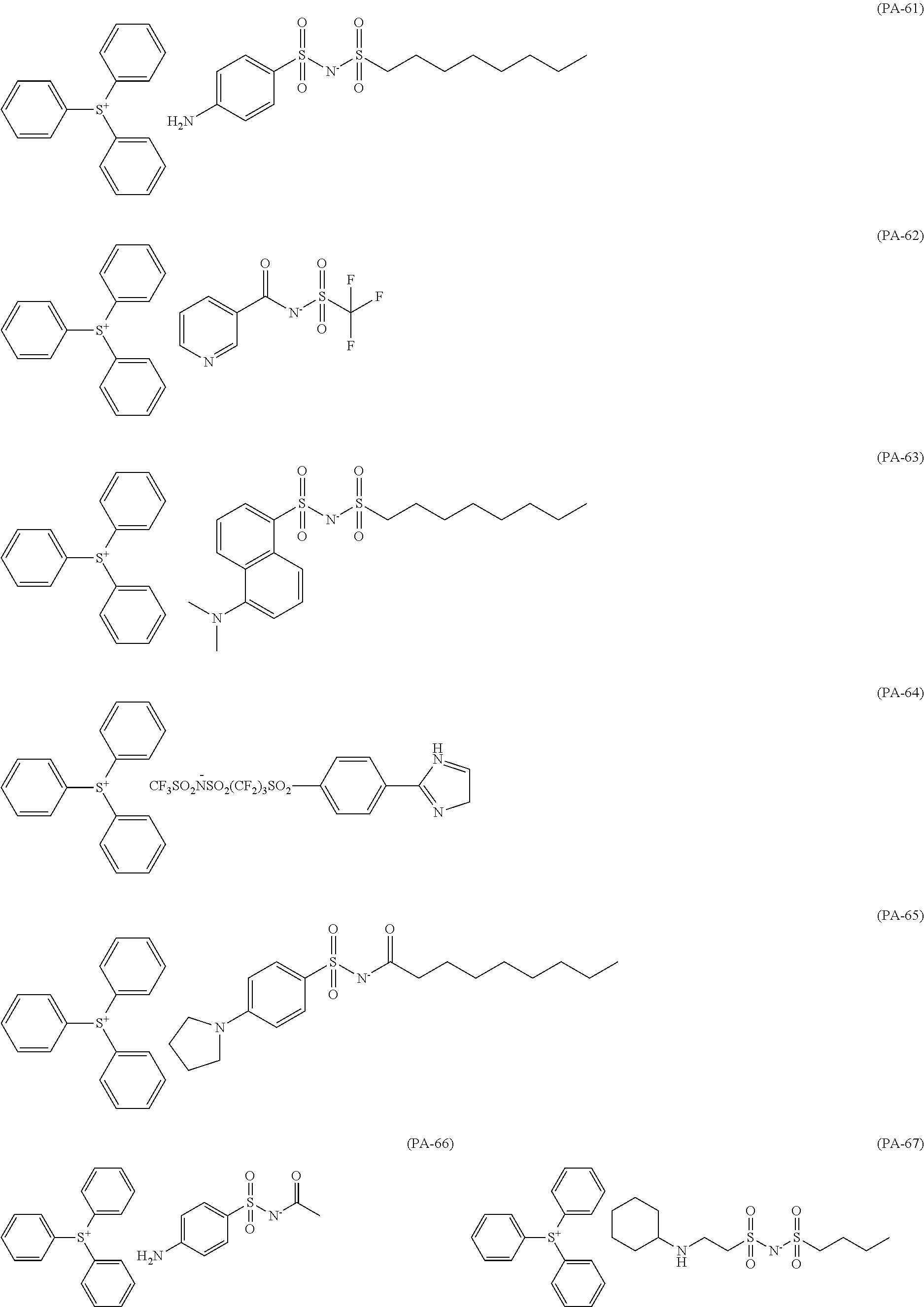

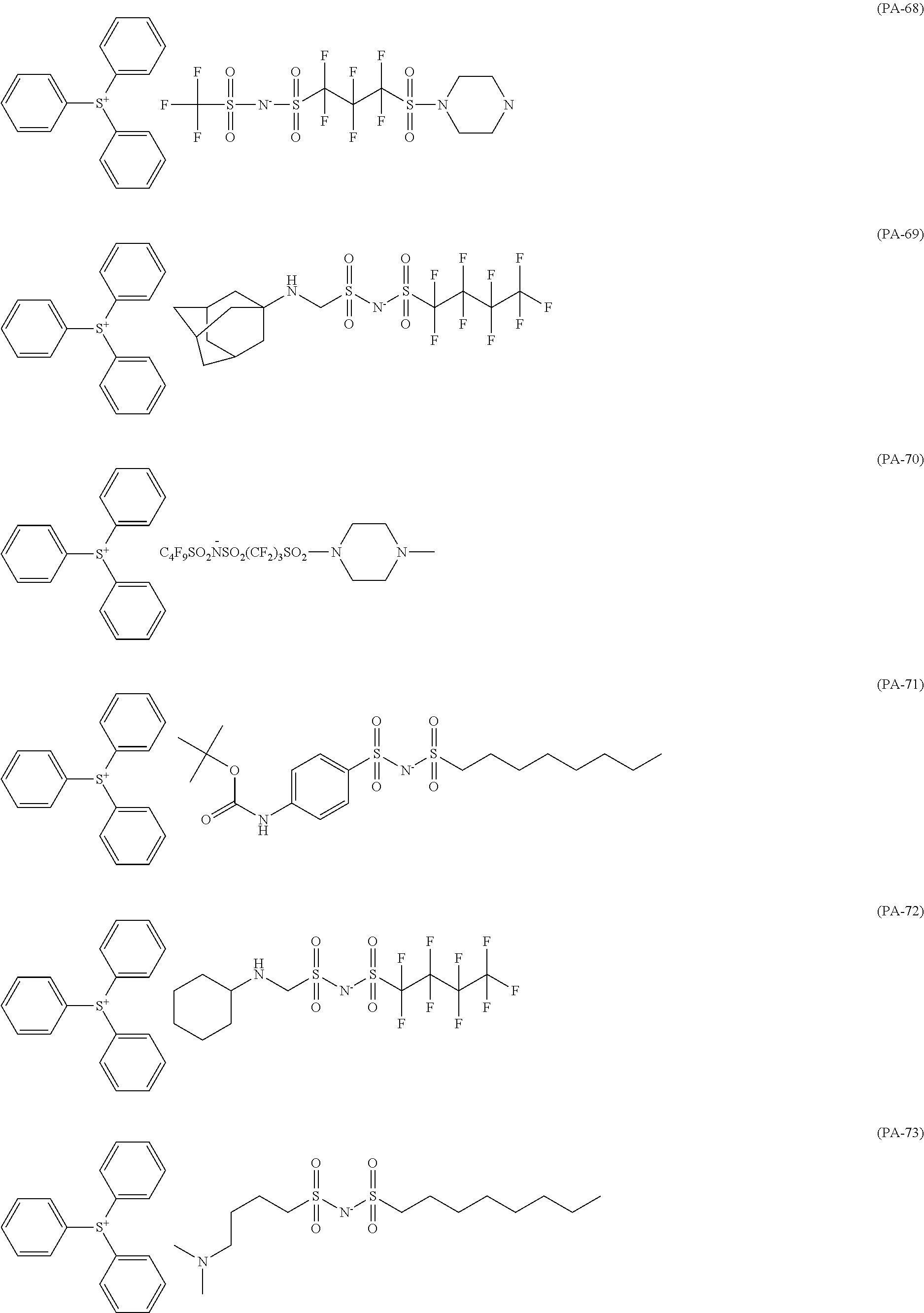

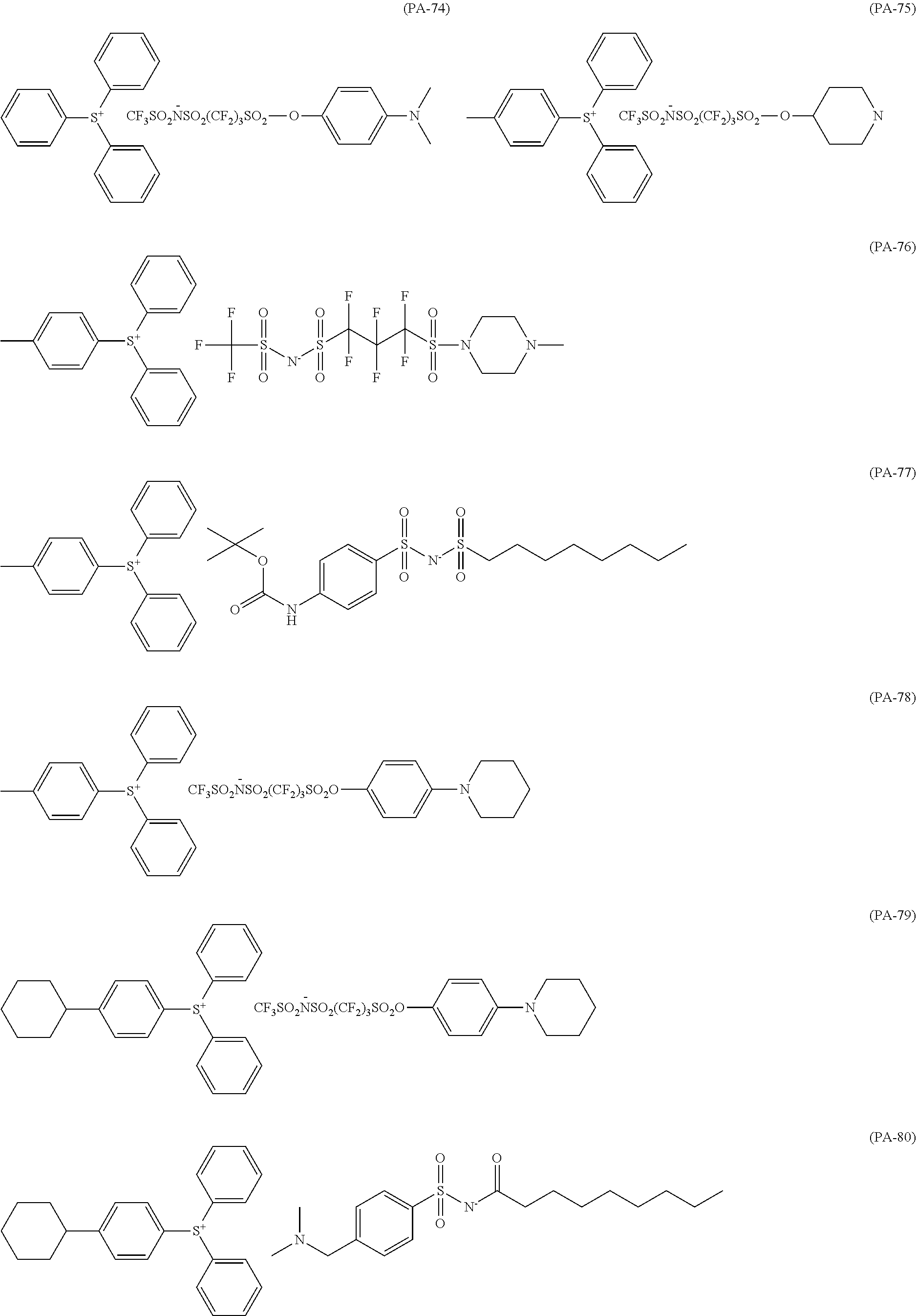

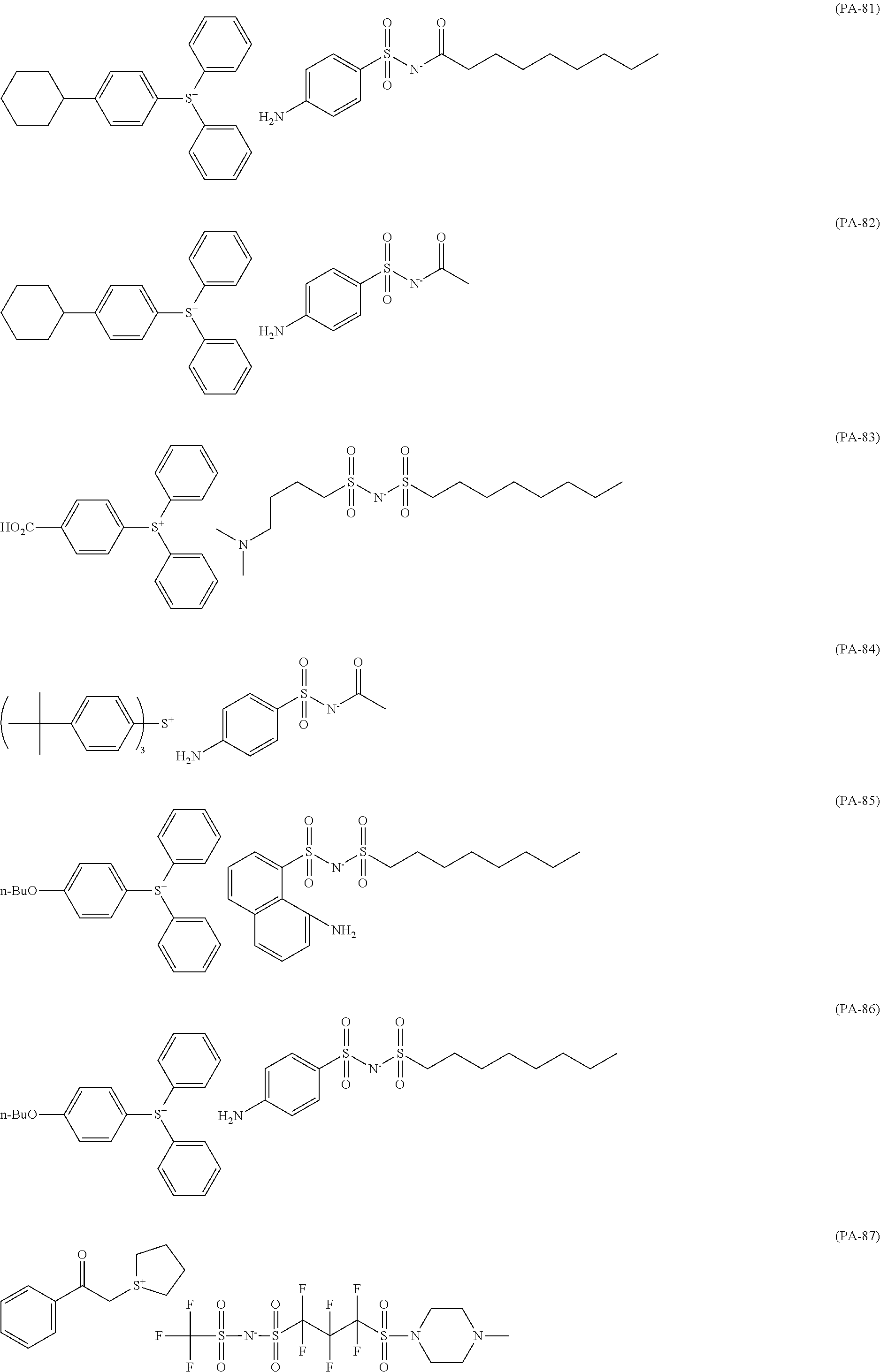

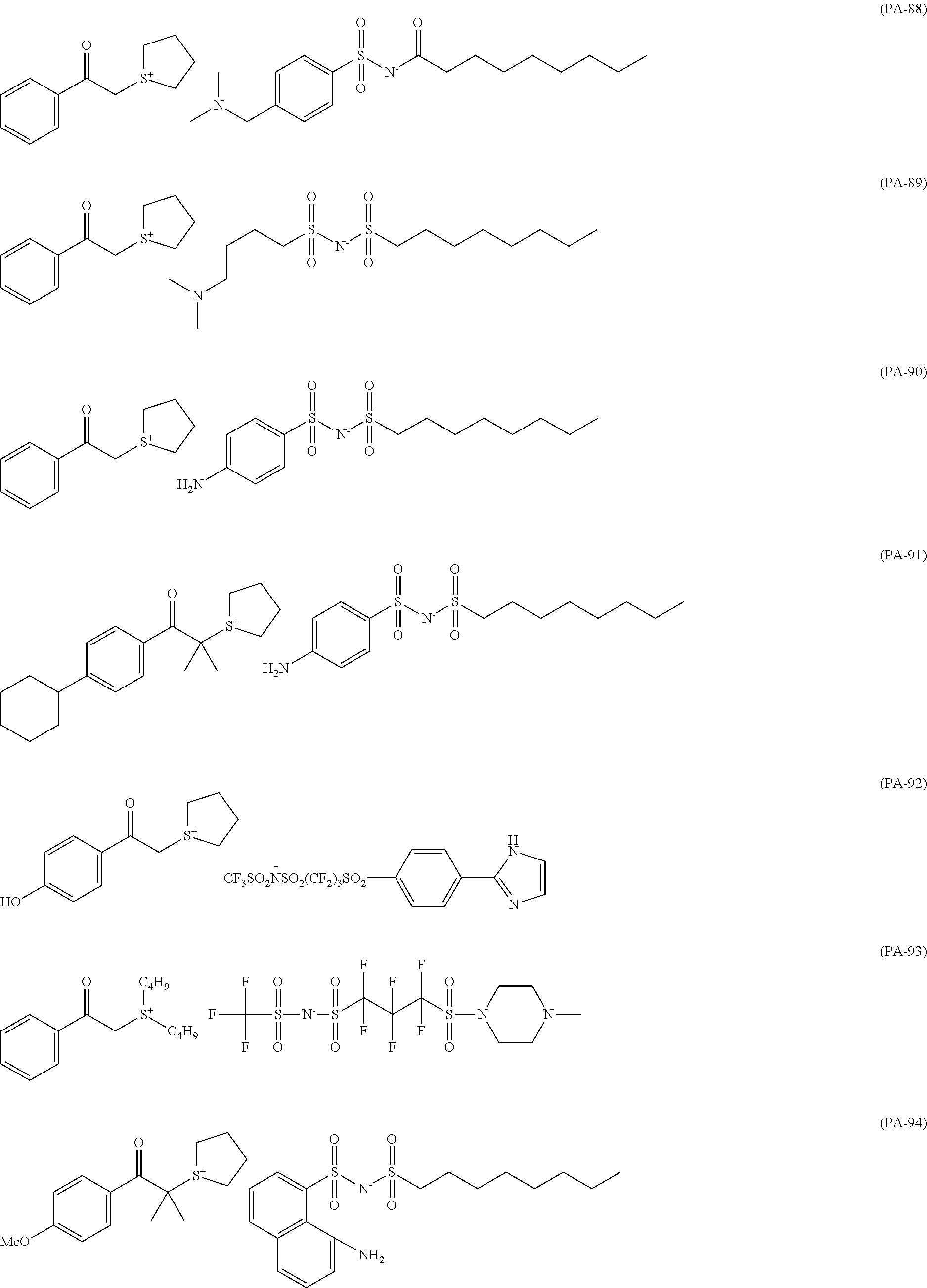

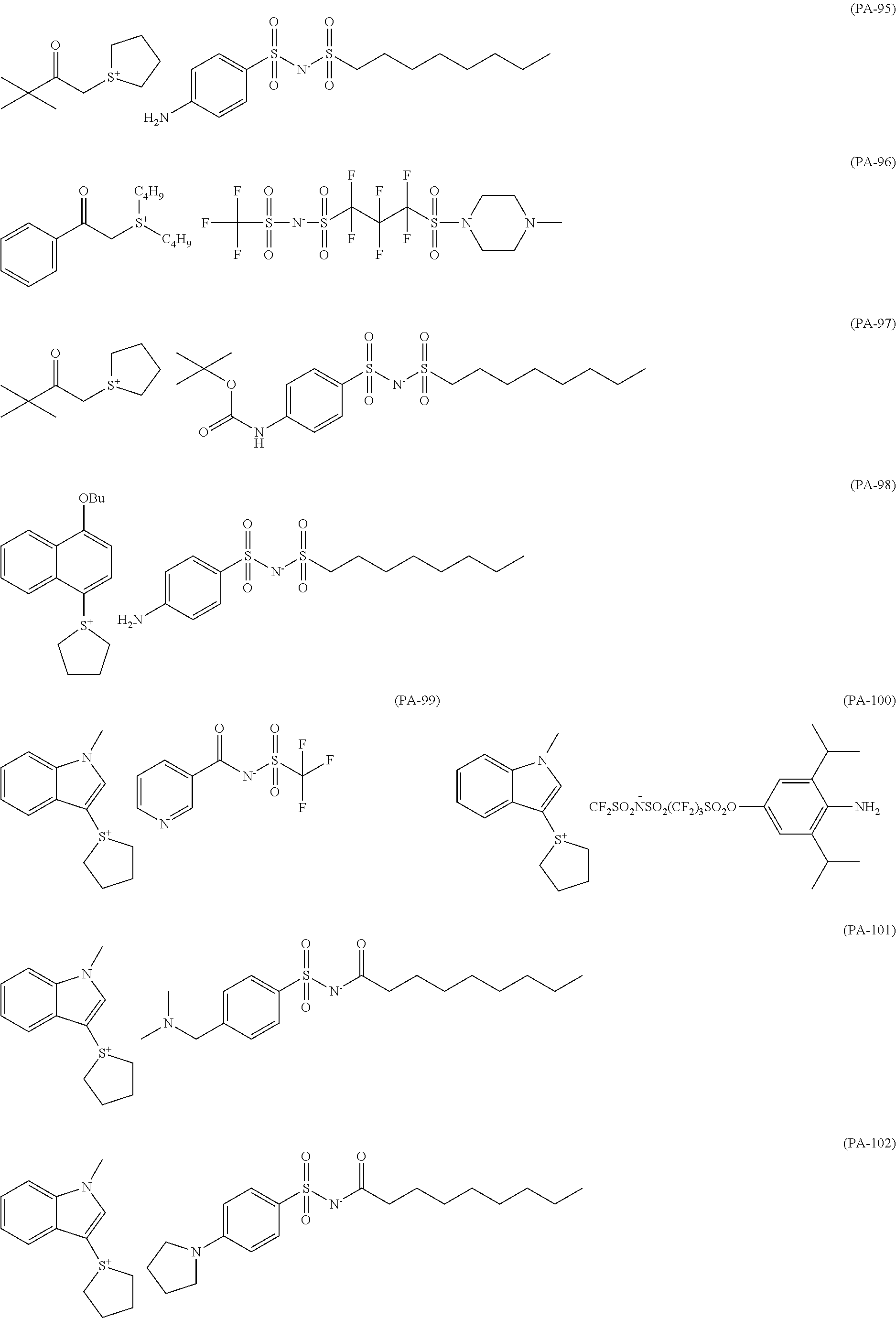

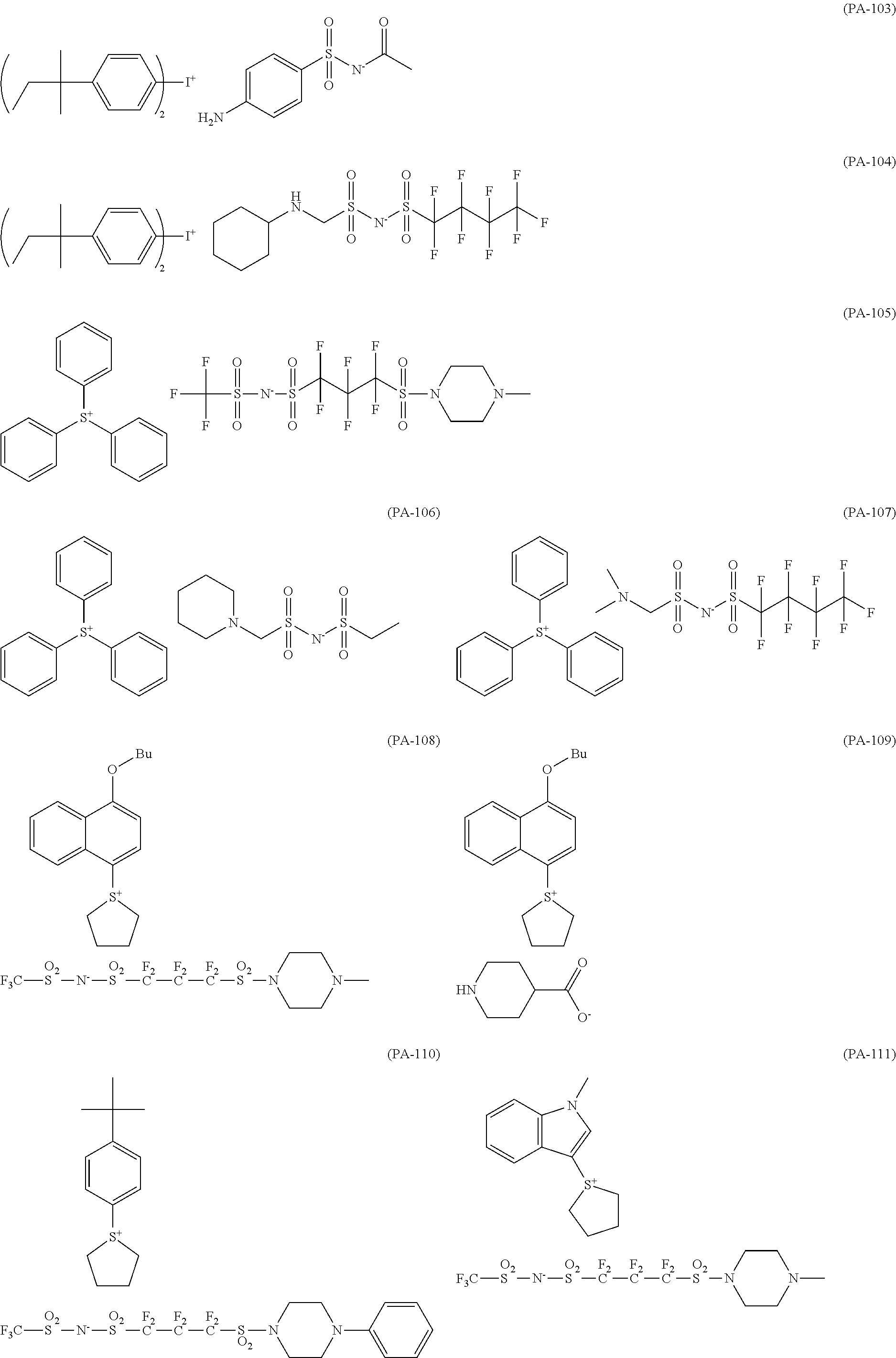

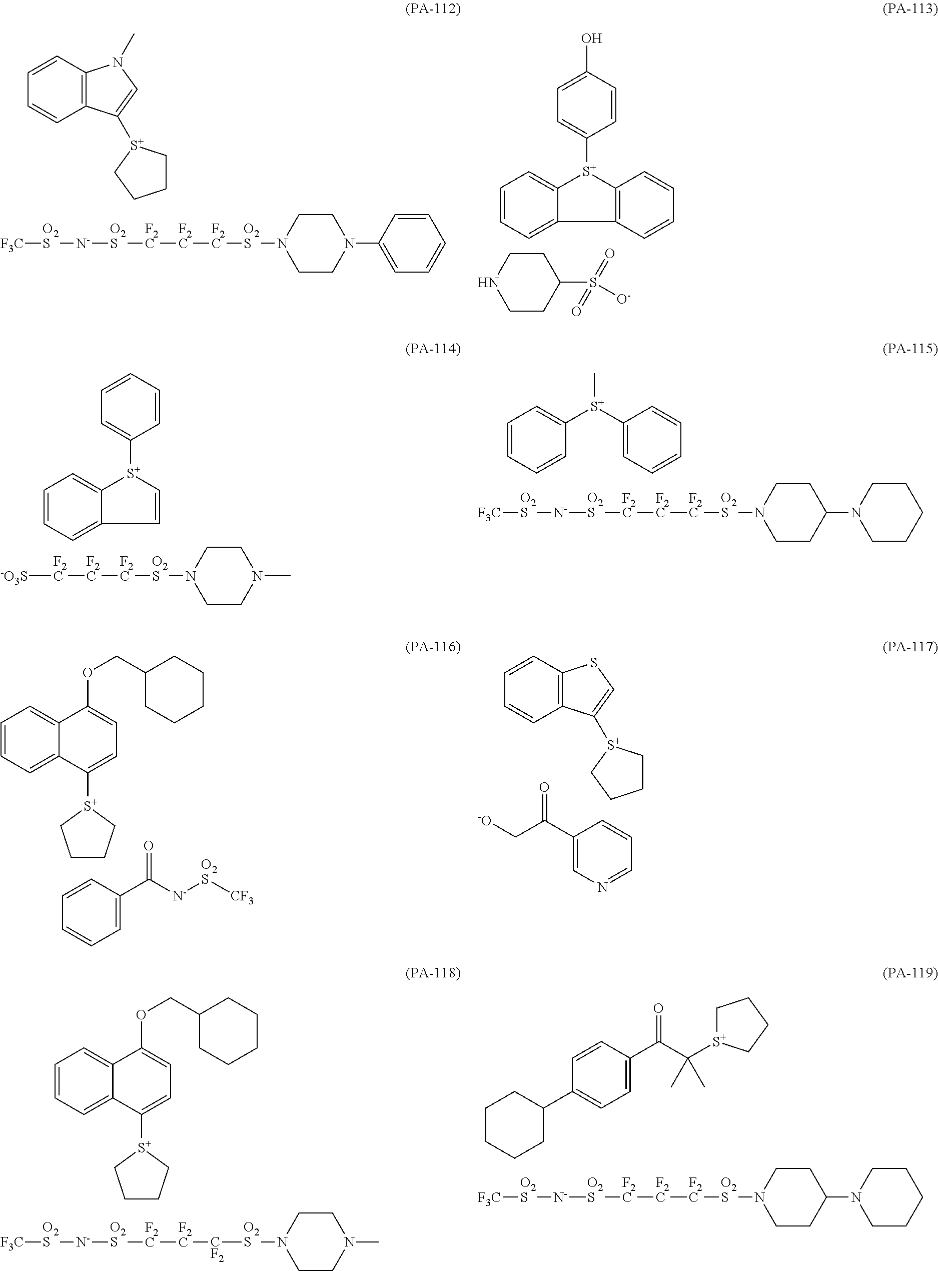

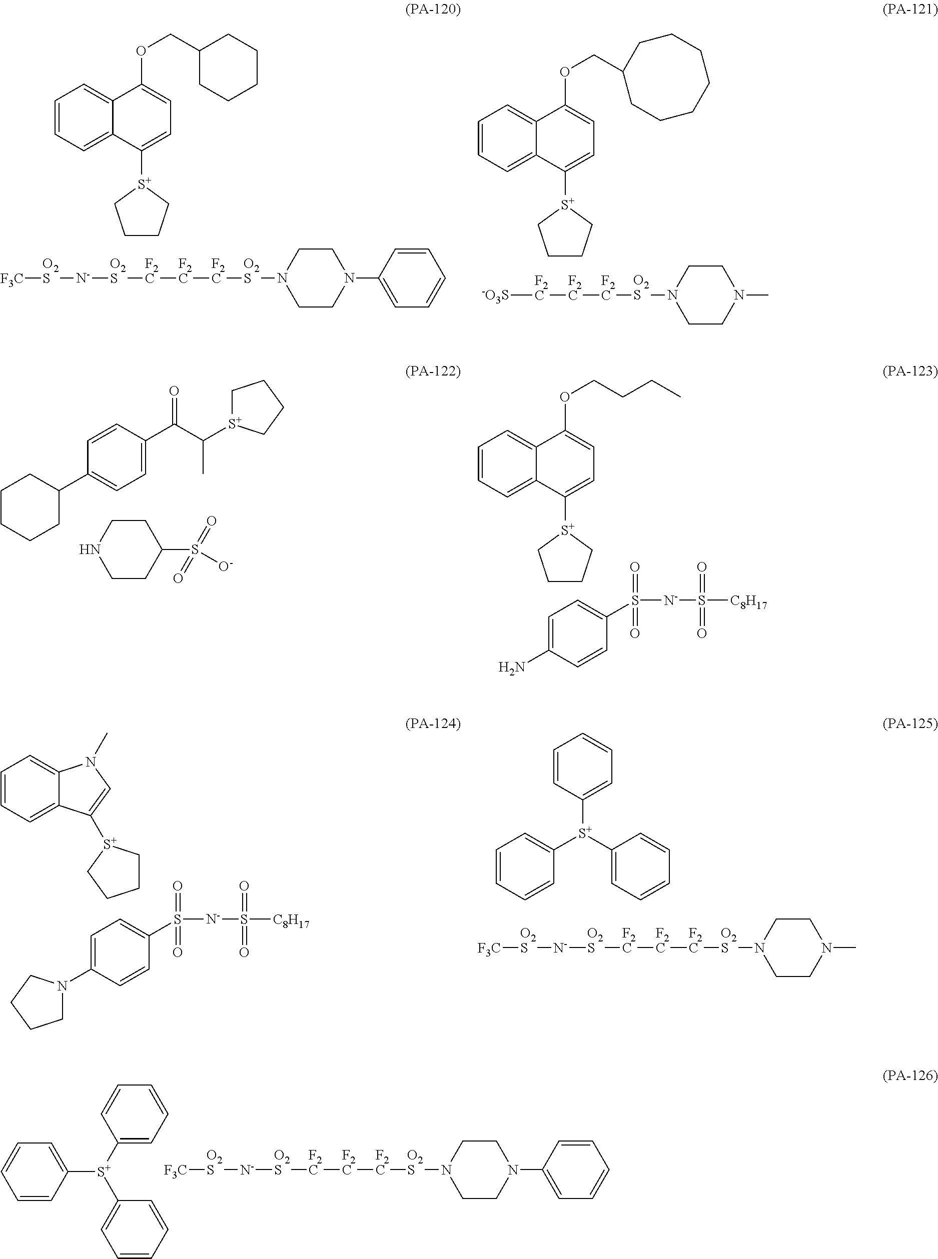

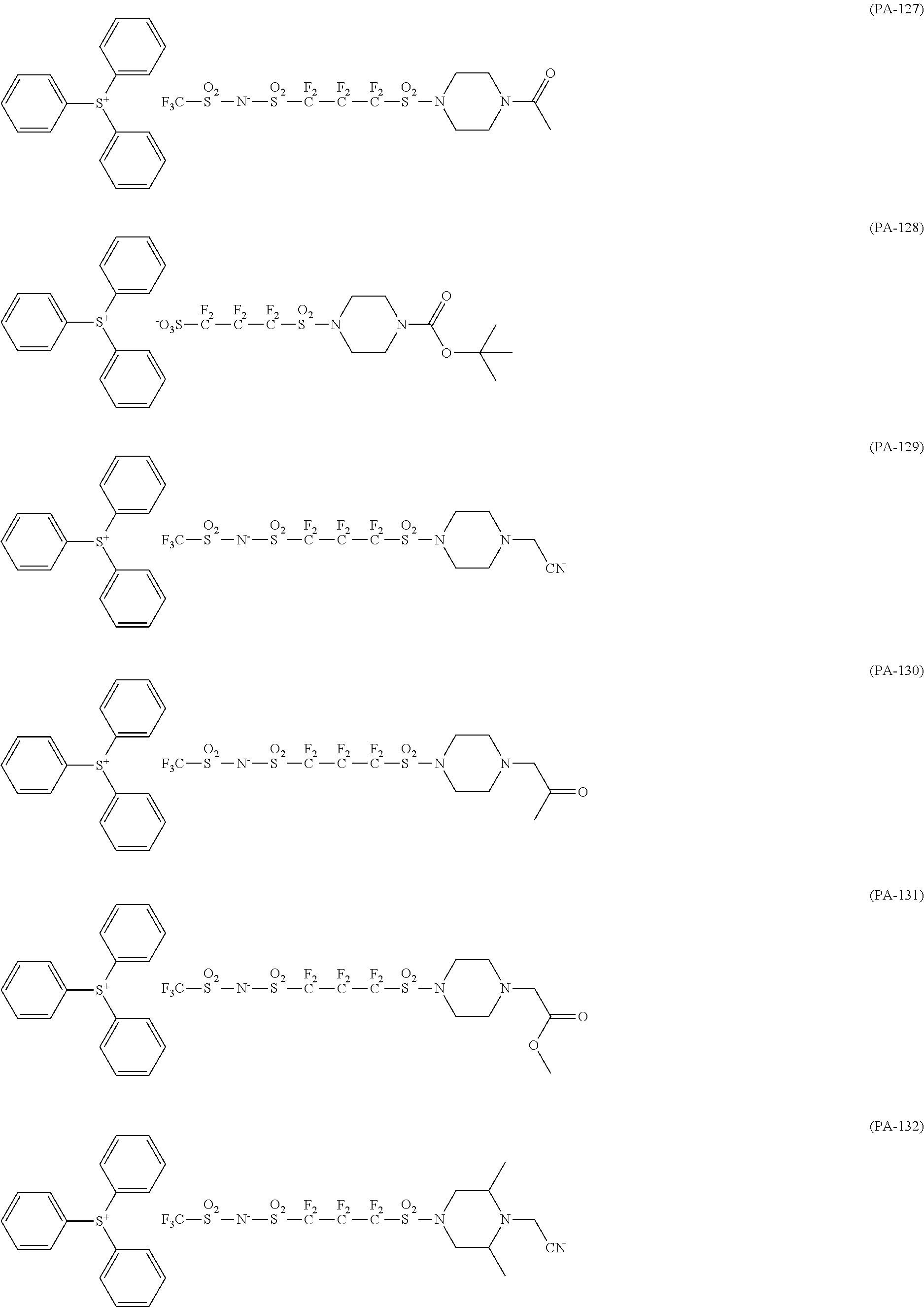

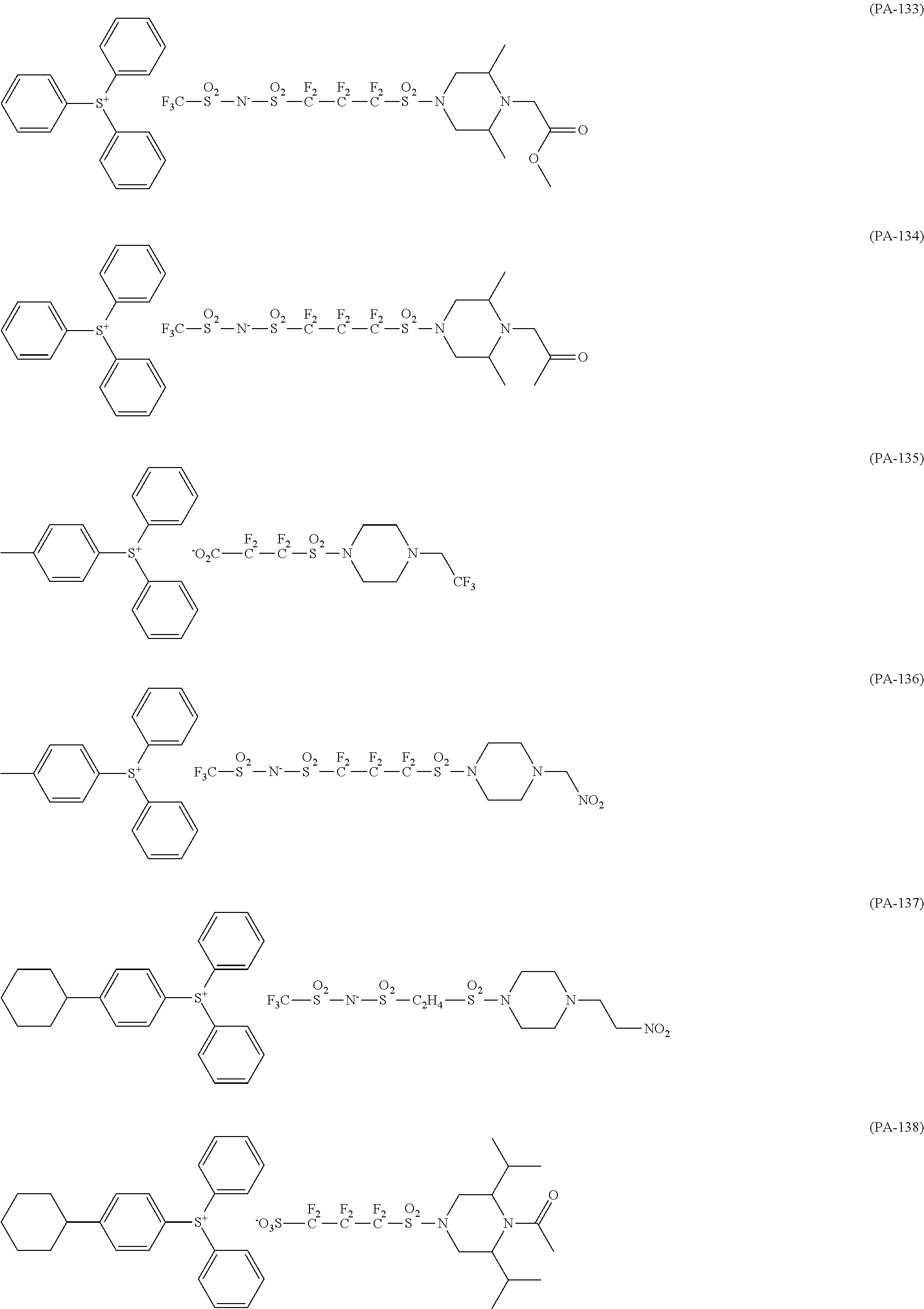

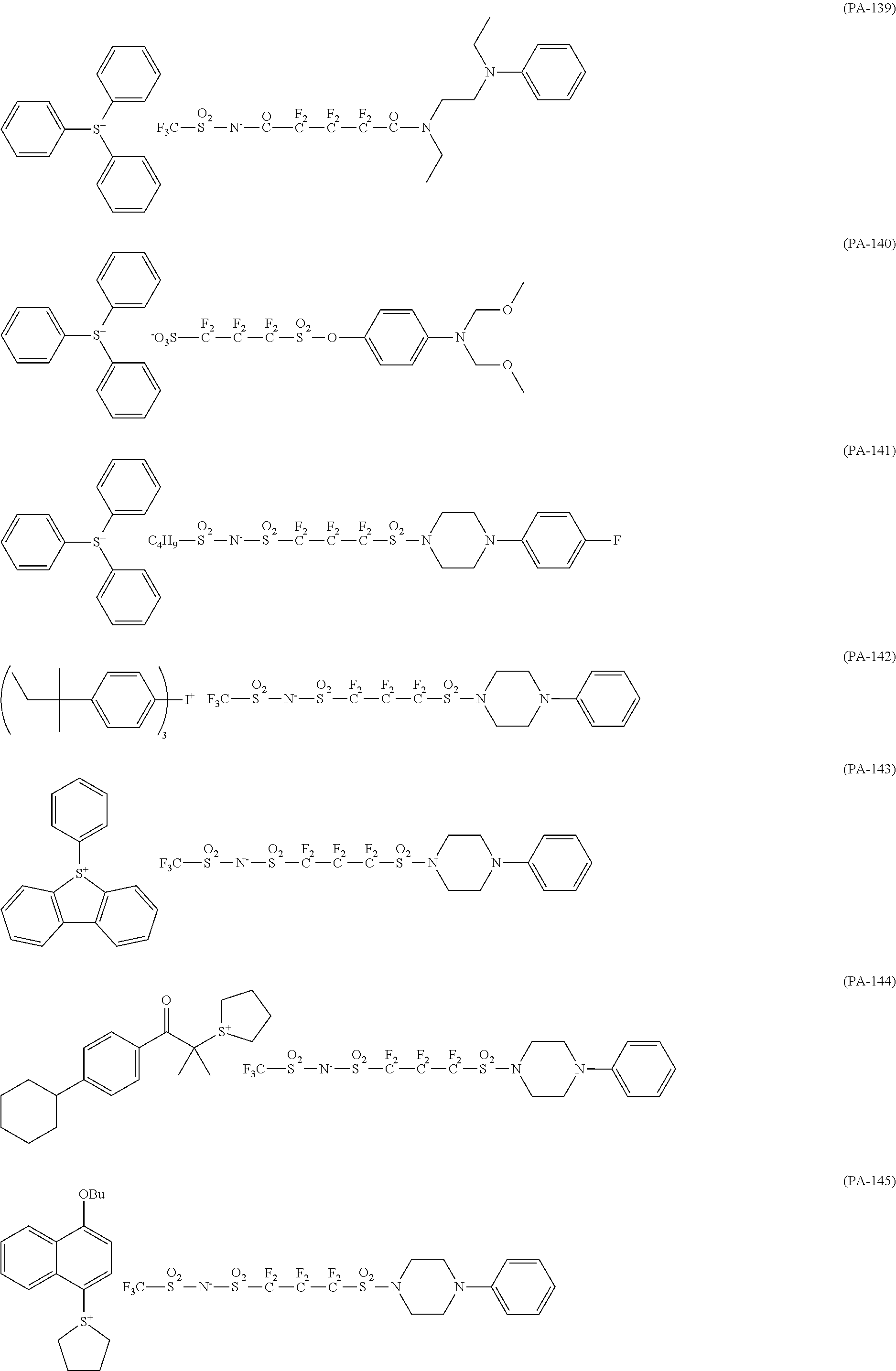

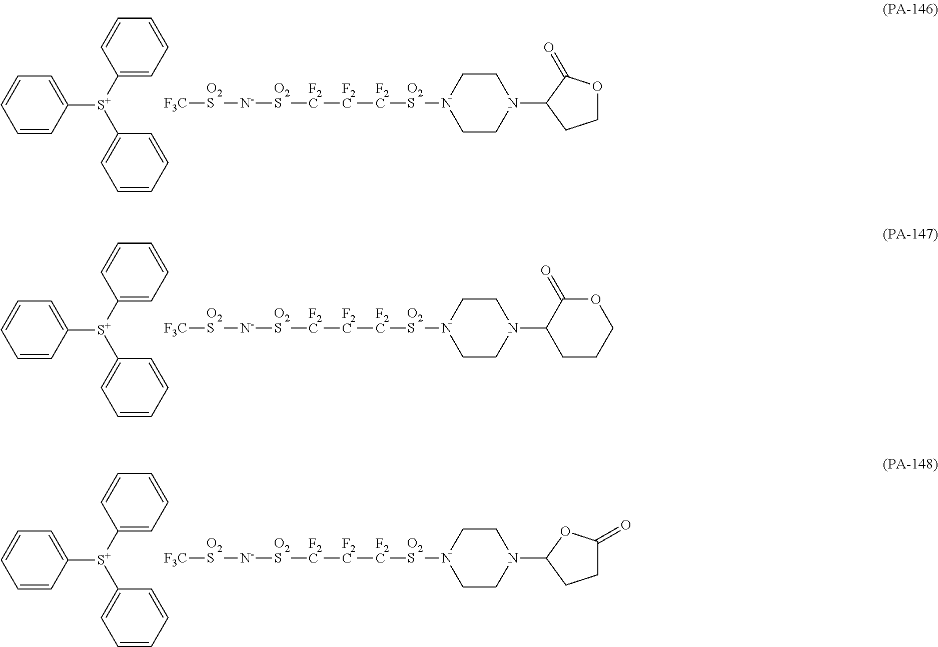

These compounds can be easily synthesized by using a common sulfonic-esterification reaction or sulfonamidation reaction. For example, these compounds can be synthesized by a method in which one sulfonyl halide moiety of a bissulfonyl halide compound is caused to selectively react with, for example, an amine or alcohol containing the partial structure of general formula (PA-II) or (PA-III), thereby forming a sulfonamido bond or a sulfonic ester bond, and thereafter the other sulfonyl halide moiety is hydrolyzed, or alternatively by a method in which the ring of a cyclic sulfonic anhydride is opened by an amine or alcohol containing the partial structure of general formula (PA-II). The above amine and alcohol each containing the partial structure of general formula (PA-II) or (PA-III) can be synthesized by causing an amine and an alcohol to react, in basic condition, with an anhydride, such as (R′O₂C)₂O or (R′SO₂)₂O, or an acid chloride compound, such as R′O₂CCl or R′SO₂Cl (in the formulae, R′ is a methyl group, an n-octyl group, a trifluoromethyl group or the like).

In particular, the synthesis of the compounds (E) can be performed in accordance with, for example, the synthetic examples described in JP-A 2006-330098 and JP-A 2011-100105.

The molecular weight of the compounds (E) is preferably in the range of 500 to 1000.

It is optional for the actinic-ray- or radiation-sensitive resin composition of the present invention to contain the compound (E). When the compound (E) is contained, the content thereof based on the solids of the actinic-ray- or radiation-sensitive resin composition is preferably in the range of 0.1 to 20 mass %, more preferably 0.1 to 10 mass %.

[7] Surfactant

The composition according to the present invention may further contain one or more surfactants. When the composition contains surfactants, it is especially preferred to use a fluorinated and/or siliconized surfactant as the surfactant.

As such surfactants, for example, Megafac F176 and (produced by Dainippon Ink & Chemicals, Inc.); PF656 and PF6320 (produced by OMNOVA); Troy Sol S-366 (produced by Troy Chemical Co., Ltd.); Florad FC 430 (produced by Sumitomo 3M Ltd.); and polysiloxane polymer KP-341 (produced by Shin-Etsu Chemical Co., Ltd.) can be exemplified.

Further, use may be made of surfactants other than the fluorinated and/or siliconized surfactants. More specifically, for example, a polyoxyethylenealkylether and a polyoxyethylenealkylarylether can be exemplified.

Further, other known surfactants can also be used. As employable surfactants, those described in section [0273] et seq. of US Patent Application Publication No. 2008/0248425 can be exemplified.

These surfactants may be used either individually or in combination.

It is optional for the actinic-ray- or radiation-sensitive resin composition of the present invention to contain the surfactant. When the composition according to the present invention contains the surfactant, the total amount thereof used based on the total solids of the composition (all amount except for solvents) is preferably in the range of 0 to 2 mass %, more preferably 0.0001 to 2 mass %, and especially preferably 0.0005 to 1 mass %.

On the other hand, it is preferable to control the amount of surfactant added at 10 ppm or less, or nil. If so, the uneven distribution of the hydrophobic resin in the surface portion is promoted, so that the surface of the resist film can be rendered highly hydrophobic, thereby enhancing the water tracking property in the stage of liquid-immersion exposure.

[8] Solvent

A solvent which can be used for preparing the actinic-ray- or radiation-sensitive resin composition of the present invention is not particularly limited as long as each component in the composition can be dissolved. For example, use can be made of an alkylene glycol monoalkyl ether carboxylate (propylene glycol monomethyl ether acetate or the like), an alkylene glycol monoalkyl ether (propylene glycol monomethyl ether or the like), an alkyl lactate (ethyl lactate, methyl lactate or the like), a cyclolactone (γ-butyrolactone or the like, preferably having 4 to 10 carbon atoms), a chain or cyclic ketone (2-heptanone, cyclohexanone or the like, preferably having 4 to 10 carbon atoms), an alkylene carbonate (ethylene carbonate, propylene carbonate or the like), an alkyl carboxylate (preferably an alkyl acetate such as butyl acetate), an alkyl alkoxycarboxylate (ethyl ethoxypropionate or the like) or the like.

As other useful solvents, there can be mentioned, for example, those described in section [0244] et seq. of US 2008/0248425 A1 and the like.

Among the above solvents, an alkylene glycol monoalkyl ether carboxylate and an alkylene glycol monoalkyl ether are preferred.

Any of these solvents may be used alone, and also two or more of these solvents may be used in combination. When two or more of these solvents are mixed together, it is preferred to mix a hydroxylated solvent with a non-hydroxylated solvent. The mass ratio of hydroxylated solvent to non-hydroxylated solvent is in the range of 1/99 to 99/1, preferably 10/90 to 90/10 and more preferably 20/80 to 60/40. The hydroxylated solvent is preferably an alkylene glycol monoalkyl ether. The non-hydroxylated solvent is preferably an alkylene glycol monoalkyl ether carboxylate.

[9] Other Component

The composition of the present invention can be appropriately loaded with, in addition to the above components, an onium salt of carboxylic acid, any of the dissolution inhibiting compounds of 3000 or less molecular weight described in, for example, Proceeding of SPIE, 2724,355 (1996), an acid-increasing agent, a dye, a plasticizer, a photosensitizer, a light absorber, etc.

[Method of Forming Pattern]

The method of forming a pattern according to the present invention comprises the operations of exposing a resist film to light and developing the exposed film.

The resist film is one formed from the above actinic-ray- or radiation-sensitive resin composition of the present invention. In particular, the resist film is preferably formed on a substrate. In the patterning method of the present invention, the operation of forming a film of the resist composition on a substrate, the operation of exposing the film to light and the operation of developing the exposed film can be carried out by generally known methods.

From the viewpoint of enhancement of resolving power, it is preferred that the actinic-ray- or radiation-sensitive resin composition of the present invention be used with a coating thickness of 30 to 250 nm. More preferably, it is used with a coating thickness of 30 to 200 nm. This coating thickness can be attained by setting the solid content of the actinic-ray- or radiation-sensitive resin composition within an appropriate range so as to cause the composition to have an appropriate viscosity, thereby improving the applicability and film forming property.

The total solid content of the actinic-ray- or radiation-sensitive resin composition according to the present invention is generally in the range of 1 to 10 mass %, preferably 1 to 8.0 mass % and still preferably 1.0 to 6.0 mass %.

In the use of the actinic-ray- or radiation-sensitive resin composition of the present invention, the above-described components are dissolved in a solvent, filtered and applied to a support. The filter medium is preferably one made of a polytetrafluoroethylene, polyethylene or nylon having a pore size of 0.1 μm or less, more preferably 0.05 μm or less and further more preferably 0.03 μm or less. In the filtration, two or more types of filters may be connected in series or parallel. Moreover, the composition may be filtered two or more times. Further, the composition may be deaerated prior to and/or after the filtration.

The composition of the present invention can be applied to a substrate, such as one for use in the production of integrated circuit elements (e.g., silicon/silicon dioxide coating), by appropriate application means, such as a spinner. Thereafter, the applied composition is dried, thereby forming a photosensitive resist film.

This resist film is exposed through a given mask to actinic rays or radiation, preferably baked (heated), developed and rinsed. Thus, a favorable pattern can be obtained. When the film is irradiated with electron beams, lithography through no mask (direct lithography) is generally carried out.

The method preferably comprises a prebake (PB) operation performed after the film formation but before the exposure operation. The method also preferably comprises a post-exposure bake (PEB) operation performed after the exposure operation but before the development operation.

In both the PB operation and the PEB operation, the baking is preferably performed at 70 to 140° C. and more preferably 80 to 135° C.

The baking time is preferably in the range of 30 to 300 seconds, more preferably 30 to 180 seconds, and further more preferably 30 to 90 seconds.

The baking can be carried out by means provided in common exposure/development equipment. The baking may also be carried out with the use of a hot plate or the like.

The baking accelerates the reaction in exposed areas, thereby enhancing the sensitivity and pattern profile.

The actinic rays or radiation is not particularly limited, and, for example, a KrF excimer laser (248 nm), an ArF excimer laser (193 nm), EUV light (13 nm), electron beams and the like are used. An ArF excimer laser, EUV light and electron beams are preferred.

Generally, a quaternary ammonium salt, typically tetramethylammonium hydroxide (TMAH), is used in the alkali developer employed in the development step. The alkali developer is not limited to this, and use can be made of an aqueous solution of an alkali selected from among an inorganic alkali, a primary to tertiary amine, an alcoholamine, a cycloamine and the like. Further, appropriate amounts of an alcohol and a surfactant may be added to the alkali developer.

The alkali concentration of the alkali developer is generally in the range of 0.1 to 20 mass %.

The pH value of the alkali developer is generally in the range of 10.0 to 15.0.

Pure water is preferably used as a rinse liquid, and before the use, an appropriate amount of surfactant can be added thereto.

Prior to the formation of the photosensitive resist film, the substrate may be coated with an antireflection film.

As the antireflection film, use can be made of not only an inorganic film of titanium, titanium dioxide, titanium nitride, chromium oxide, carbon, amorphous silicon or the like but also an organic film composed of a light absorber and a polymer material. Also, as the organic antireflection film, use can be made of any of commercially available organic antireflection films, such as the DUV30 Series and DUV40 Series produced by Brewer Science Inc., and the AR-2, AR-3 and AR-5 produced by Shipley Co., Ltd.

Exposure to a resist film including the actinic-ray- or radiation-sensitive resin composition of the present invention may be carried out after filling the interstice between the film and a lens with a liquid (immersion medium) of refractive index higher than that of air at the time of exposure to actinic rays or radiation. That is, liquid immersion exposure may also be carried out. The resolution can be enhanced by the exposure through the immersion medium. Any liquid can be used as long as the liquid has refractive index higher than that of air. Especially, pure water is preferable.

The liquid for liquid immersion for use in the liquid immersion exposure will now be described.

The liquid for liquid immersion preferably consists of a liquid being transparent in exposure wavelength whose temperature coefficient of refractive index is as low as possible so as to ensure minimization of any strain of optical image projected on the resist film. Especially in the use of an ArF excimer laser (wavelength: 193 nm) as an exposure light source, however, it is more preferred to use water from not only the above viewpoints but also the viewpoints of easy procurement and easy handling.

Further, from the viewpoint of refractive index increase, use can be made of a medium of 1.5 or higher refractive index. Such a medium may be an aqueous solution or an organic solvent.

In the use of water as a liquid for liquid immersion, a slight proportion of additive (liquid) that would not dissolve the resist film on a wafer and would be negligible with respect to its influence on an optical coat for an under surface of lens element may be added in order to not only decrease the surface tension of water but also increase a surface activating power. The additive is preferably an aliphatic alcohol with a refractive index approximately equal to that of water, for example, methyl alcohol, ethyl alcohol, isopropyl alcohol or the like. The addition of an alcohol with a refractive index approximately equal to that of water is advantageous in that even when the alcohol component is evaporated from water to thereby cause a change of content concentration, the change of refractive index of the whole liquid can be minimized. On the other hand, when a substance being opaque in 193 nm rays or an impurity whose refractive index is greatly different from that of water is mixed in, the mixing would invite a strain of optical image projected on the resist film. Accordingly, it is preferred to use distilled water as the liquid immersion water. Furthermore, use may be made of pure water having been filtered through an ion exchange filter or the like.

Desirably, the electrical resistance of the water is 18.3 MQcm or higher, and the TOC (organic matter concentration) thereof is 20 ppb or below. Prior deaeration of the water is desired. Raising the refractive index of the liquid for liquid immersion would enable an enhancement of lithography performance. From this viewpoint, an additive suitable for refractive index increase may be added to the water, or heavy water (D₂O) may be used in place of water.

As mentioned hereinbefore, when the film comprised of the composition of the present invention is exposed through a liquid immersion medium to light, a hydrophobic resin (HR) can further be added to the composition according to necessity.

For the prevention of direct contact of a film with a liquid for liquid immersion, a film that is highly insoluble in the liquid for liquid immersion (hereinafter also referred to as a “top coat”) may be provided between the film produced from the composition of the present invention and the liquid for liquid immersion. The functions to be fulfilled by the top coat are applicability to an upper layer portion of the resist, transparency in radiation of especially 193 nm and being highly insoluble in the liquid for liquid immersion. Preferably, the top coat does not mix with the resist and is uniformly applicable to an upper layer of the resist.

From the viewpoint of 193 nm transparency, the top coat preferably consists of a polymer not abundantly containing an aromatic moiety. As such, there can be mentioned, for example, a hydrocarbon polymer, an acrylic ester polymer, polymethacrylic acid, polyacrylic acid, polyvinyl ether, a siliconized polymer, a fluoropolymer or the like. The aforementioned hydrophobic resins (HR) also find appropriate application in the top coat. From the viewpoint of contamination of an optical lens by leaching of impurities from the top coat into the liquid for liquid immersion, it is preferred to reduce the amount of residual monomer components of the polymer contained in the top coat.

At the detachment of the top coat, use may be made of a developer, or a separate peeling agent may be used. The peeling agent preferably consists of a solvent having a lower permeation into the film. Detachability by an alkali developer is preferred from the viewpoint of simultaneous attainment of the detachment step with the development processing step for the film. The top coat is preferred to be acidic from the viewpoint of detachment with the use of an alkali developer. However, from the viewpoint of non-intermixability with the film, the top coat may be neutral or alkaline.

The less the difference in refractive index between the top coat and the liquid for liquid immersion, the higher the resolving power. In an ArF excimer laser (wavelength: 193 nm), when water is used as the liquid for liquid immersion, the top coat for ArF liquid immersion exposure preferably has a refractive index close to that of the liquid for liquid immersion. From the viewpoint of approximation of the refractive index to that of the liquid for liquid immersion, it is preferred for the top coat to contain a fluorine atom. From the viewpoint of transparency and refractive index, it is preferred to reduce the thickness of the film.

Preferably, the top coat does not mix with the film and also does not mix with the liquid for liquid immersion. From this viewpoint, when the liquid for liquid immersion is water, it is preferred for the solvent used in the top coat to be highly insoluble in the solvent used in the positive resist composition and be a non-water-soluble medium. When the liquid for liquid immersion is an organic solvent, the top coat may be soluble or insoluble in water.

Furthermore, the present invention relates to a process for manufacturing an electronic device in which the above-described patterning method of the present invention is included, and relates to an electronic device manufactured by the process. The electronic device of the present invention can be appropriately mounted in electrical and electronic equipments (household electronic appliance, OA/media-related equipment, optical apparatus, telecommunication equipment and the like).

### Examples

The present invention will be described in greater detail below with reference to the following Examples, which however in no way limit the scope of the present invention.

(Acid-Decomposable Resin)

The following resins (P-1) to (P-11) and (PA-1) to (PA-4) were synthesized in the manner described below.

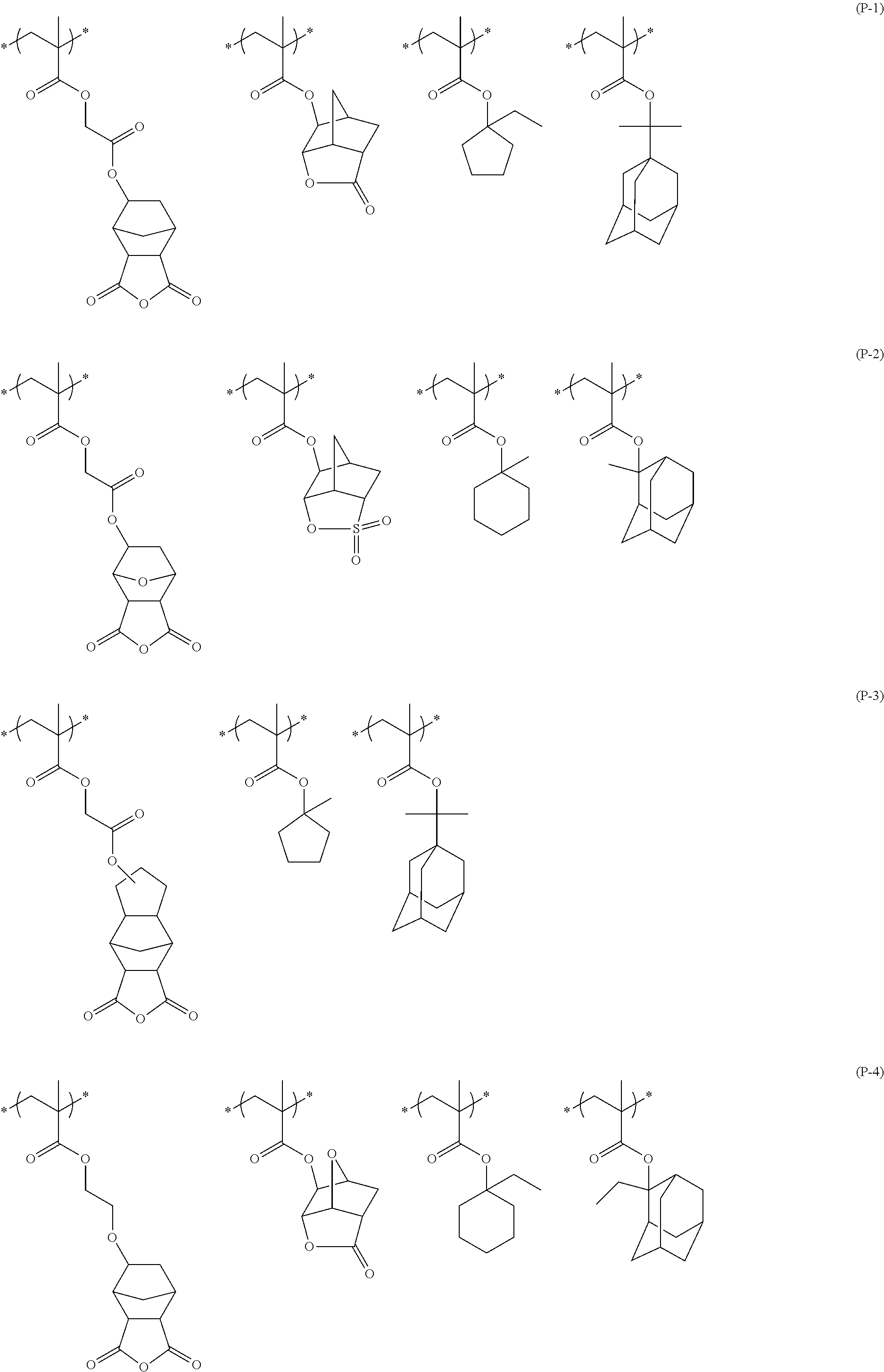

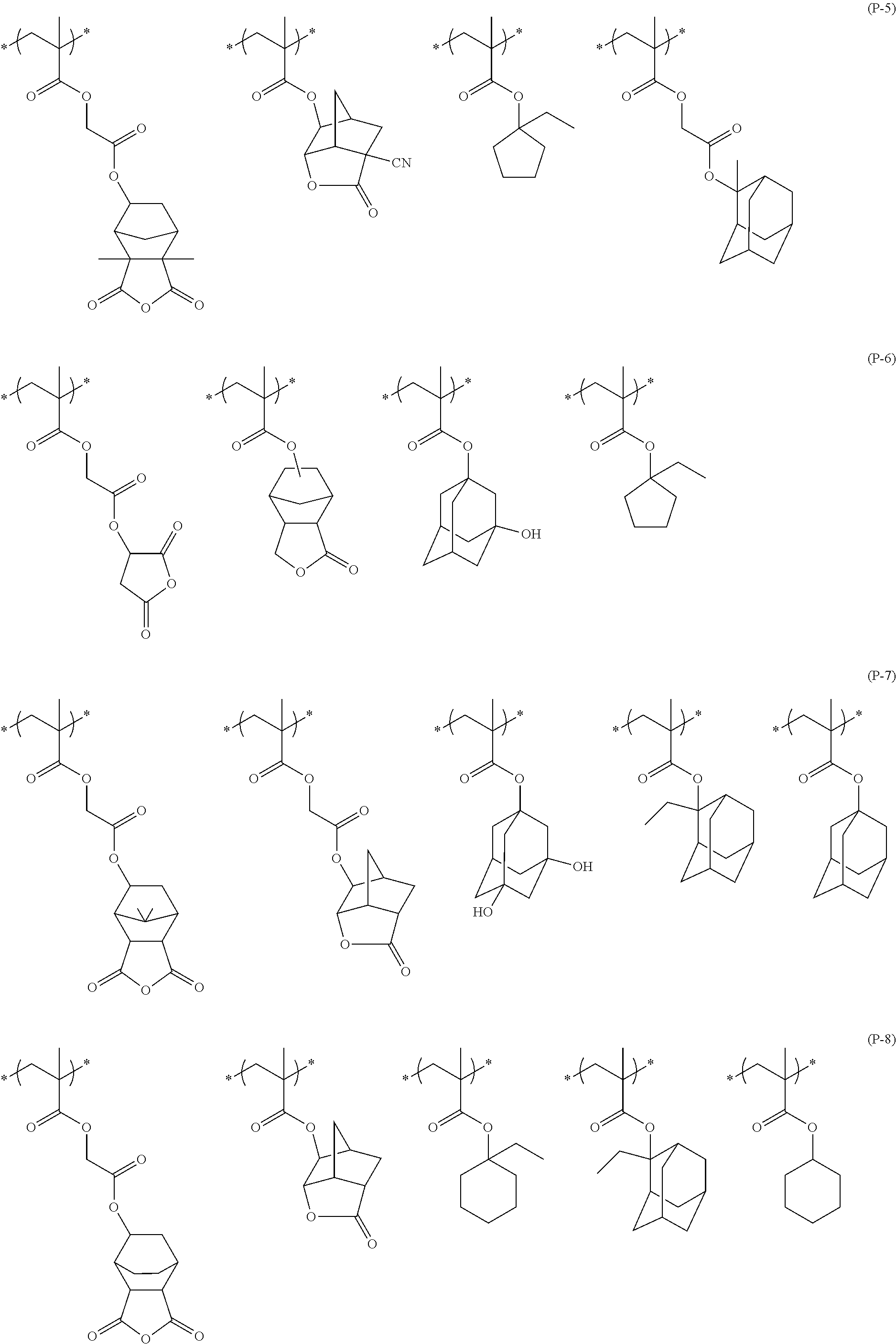

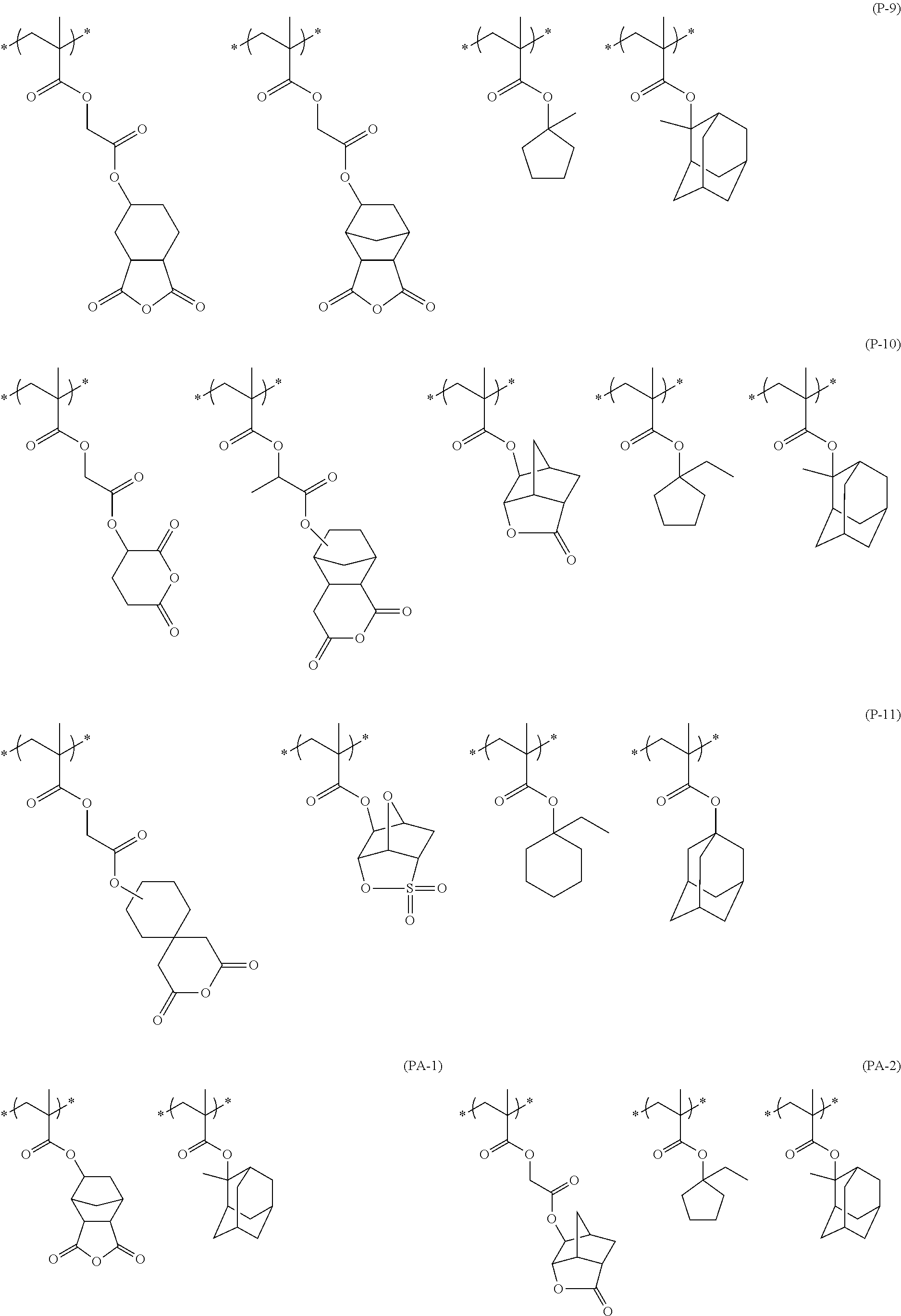

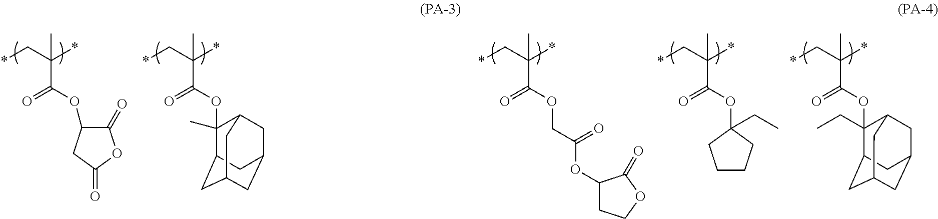

With respect to each of the resins (P-1) to (P-11) and (PA-1) to (PA-4), the weight average molecular weight (Mw), polydispersity index (Mw/Mn) and individual repeating unit ratios (component ratios, molar ratios) are summarized in Table 2 below. The positional relationship of numerics indicating component ratios of Table 2 corresponds to that of the individual repeating units of each resin shown in the above structural formulae.

TABLE 2

| | Component ratio | | | | | | |
|---|---|---|---|---|---|---|---|
| Resin | (molar ratio) | | | | | Mw | Mw/Mn |
| P-1 | 20 | 30 | 30 | 20 | | 8400 | 1.57 |
| P-2 | 30 | 10 | 40 | 20 | | 7500 | 1.54 |
| P-3 | 50 | 25 | 25 | | | 9200 | 1.55 |
| P-4 | 20 | 25 | 35 | 20 | | 11200 | 1.68 |
| P-5 | 15 | 35 | 40 | 10 | | 6200 | 1.51 |
| P-6 | 10 | 40 | 10 | 40 | | 13000 | 1.71 |
| P-7 | 25 | 20 | 5 | 40 | 10 | 8100 | 1.59 |
| P-8 | 35 | 10 | 20 | 25 | 10 | 7300 | 1.55 |
| P-9 | 25 | 25 | 30 | 20 | | 12100 | 1.69 |
| P-10 | 20 | 20 | 10 | 20 | 30 | 8900 | 1.51 |
| P-11 | 20 | 20 | 40 | 10 | 10 | 7200 | 1.68 |
| PA-1 | 50 | 50 | | | | 8800 | 1.55 |
| PA-2 | 50 | 25 | 25 | | | 7800 | 1.52 |
| PA-3 | 50 | 50 | | | | 8000 | 1.53 |
| PA-4 | 50 | 20 | 30 | | | 9300 | 1.61 |

[Synthetic Example for Acid-Decomposable Resin]

In a nitrogen gas stream, 4.2 g of cyclohexanone was placed in a three-necked flask, and heated at 85° C. Thus, solvent 1 was obtained. Separately, the following monomer-1 (1.85 g), monomer-2 (2.00 g), monomer-3 (1.64 g) and monomer-4 (1.57 g) were dissolved in cyclohexanone (17.0 g), thereby obtaining a monomer solution. Further, a polymerization initiator V601 (produced by Wako Pure Chemical Industries, Ltd.) was added to the solution in an amount of 6.5 mol % based on the total amount of monomers and dissolved therein. The thus obtained solution was dropped into the solvent 1 over a period of six hours. After the completion of the dropping, reaction was continued at 85° C. for two hours. The reaction liquid was allowed to cool, and dropped into a mixed solvent comprised of 173 g of heptane and 74 g of ethyl acetate. The thus precipitated powder was collected by filtration and dried. Thus, 5.0 g of resin (P-1) was obtained. With respect to the thus obtained resin (P-1), the weight average molecular weight was 8400, the polydispersity index (Mw/Mn) 1.57 and the component ratios determined by ¹³C-NMR 20/30/30/20.

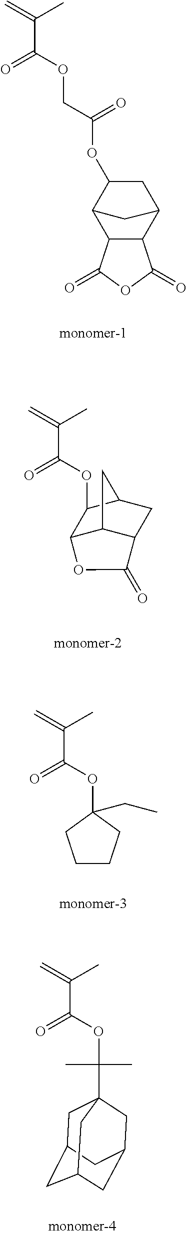 [SMILES: C=C(C)C(=O)OCC(=O)OC1CC2CC1C1C(=O)OC(=O)C21 ; C=C(C)C(=O)OC1C2CC3C(=O)OC1C3C2 ; C=C(C)C(=O)OC1(CC)CCCC1 ; C=C(C)C(=O)OC(C)(C)C12CC3CC(CC(C3)C1)C2]

The resins (P-2) to (P-11) and (PA-1) to (PA-4) were synthesized in the same manner as described above for the resin (P-1). The weight average molecular weight, polydispersity index (Mw/Mn) and component ratio of each of these resins were as indicated in Table 2 above.

[Synthetic Example for Monomer-1]

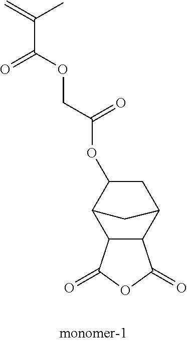 [SMILES: C=C(C)C(=O)OCC(=O)OC1CC2CC1C1C(=O)OC(=O)C21]

First, 5-norbornene-2,3-dicarboxylic anhydride (65.66 g, 0.4 mol) and chloroacetic acid (75.60 g, 0.8 mol) were placed in a three-necked flask, and melted by heating at 80° C., thereby obtaining a homogeneous solution. Then, trifluorosulfonic acid (3.5 ml, 40 mmol) was dropped into the solution, and agitated at 100° C. for three hours. After the completion of the reaction, the reaction solution was cooled to 50° C., and 500 ml of toluene was added, thereby cooling the solution to 25° C. This solution was added to a solution comprised of 40 g of sodium hydrogen carbonate, 320 ml of distilled water and 160 ml of saturated saline while stirring, and a liquid separation purification was carried out. Thereafter, the obtained organic phase was washed with 480 ml of saturated saline, and the solvent was distilled off in vacuum. Thus, 80 g of an oily compound was obtained.

The obtained oil was placed in a three-necked flask, and 550 ml of dimethylacetamide was added thereto. Further, methacrylic acid (34.61 g, 0.402 mol), sodium hydrogen carbonate (33.77 g, 0.402 mol) and potassium iodide (12.82 g, 0.077 mol) were added and agitated at 60° C. for four hours. Subsequently, 1.5 L of toluene was added, thereby cooling the mixture to 25° C. Thereafter, 1N hydrochloric acid was added to the mixture until the pH value became 3, and a liquid separating operation was carried out. The thus obtained organic phase was washed with an aqueous solution of sodium hydrogen carbonate and saturated saline, and the solvent was distilled off in vacuum. Thus, 50 g of an oily compound was obtained.

The obtained oil was subjected to column purification (hexane/ethyl acetate: 2/1), and the purified oil was crystallized from ethyl acetate/heptane. Thus, 26.4 g of monomer-1 was obtained (white crystal).

¹H-NMR (400 MHz in (CD₃)₂CO): δ (ppm)=1.17-2.31 (m, 7H), 2.70-3.44 (m, 4H), 4.58-5.18 (m, 3H), 6.22 (s, 1H), 7.27 (s, 1H).

(Acid Generator)

An appropriate one was selected from among the above-mentioned acid generators z1 to z110 and used as the acid generator.

(Hydrophobic Resin)

An appropriate one was selected from among the above-mentioned hydrophobic resins (B-1) to (B-55) and used as the hydrophobic resin.

(Basic Compound)

DIA: 2,6-diisopropylaniline,

TMEA: tris(methoxyethoxyethyl)amine,

PEA: N-phenyldiethanolamine,

TOA: trioctylamine,

PBI: 2-phenylbenzimidazole, and

DHA: N,N-dihexylaniline.

(Low-Molecular Compound (D))

The above-mentioned low-molecular compound (D-52) or (D-13) was selected and used.

(Surfactant)

W-1: Megafac F176 (produced by Dainippon Ink & Chemicals, Inc., fluorinated),

W-2: Megafac R08 (produced by Dainippon Ink & Chemicals, Inc., fluorinated and siliconized),

W-3: Troy Sol S-366 (produced by Troy Chemical Co., Ltd., fluorinated),

W-4: PF656 (produced by Omnova Solutions, Inc., fluorinated), and

W-5: PF6320 (produced by Omnova Solutions, Inc., fluorinated).

(Solvent)

S1-1: propylene glycol monomethyl ether acetate (PGMEA, 1-methoxy-2-acetoxypropane),

S1-2: cyclohexanone,

S2-1: propylene glycol monomethyl ether (PGME, 1-methoxy-2-propanol),

S2-2: propylene carbonate, and

S2-3: γ-butyrolactone.

[Exposure Condition: ArF Liquid-Immersion Exposure]

<Preparation of Actinic-Ray- or Radiation-Sensitive Resin Composition>

As listed in Table 3 below, individual components were dissolved in solvents, thereby obtaining solutions each of 4 mass % solid content. The solutions were each passed through a polyethylene filter of 0.1-μm pore size, thereby obtaining actinic-ray- or radiation-sensitive resin compositions (positive photosensitive resin compositions). The thus obtained positive photosensitive resin compositions were evaluated by the following methods, and the evaluation results are given in Table 3.

<Image Performance Test>

An ARC29SR organic antireflection film (produced by Nissan Chemical Industries, Ltd.) was applied to a silicon wafer (12-inch caliber) and baked at 205° C. for 60 seconds, thereby forming a 98-nm-thick antireflection film. Each of the prepared positive photosensitive resin compositions was applied thereto and baked at 120° C. for 60 seconds, thereby forming a 100-nm-thick photosensitive film (resist film). The resultant wafer was exposed through a 6% halftone mask of 1:1 line and space pattern of 75-nm line width to light by means of an ArF excimer laser liquid-immersion scanner (manufactured by ASML, XT1700i, NA 1.20, C-Quad, outer sigma 0.981, inner sigma 0.895, XY deflection). Ultrapure water was used as the immersion liquid. Thereafter, the exposed wafer was baked at 120° C. for 60 seconds, developed with an aqueous solution of tetramethylammonium hydroxide (2.38 mass %) for 30 seconds, rinsed with pure water and spin dried, thereby obtaining a resist pattern.

<Pattern Collapse>

The optimum exposure amount was defined as the exposure amount that reproduced a line-and-space (1:1) mask pattern of 45-nm line width, and the pattern collapse was defined as the line width (nm) allowing pattern resolution without any pattern collapse upon decreasing of the line width of a line pattern formed with an exposure amount increased from the optimum exposure amount. The smaller the value thereof, the finer the pattern resolved without any collapse, that is, the more effective the suppression of pattern collapse.

<Line Edge Roughness (LER)>

In the measurement of line edge roughness (nm), a line-and-space (1/1) pattern of 45-nm line width was observed by means of a critical dimension scanning electron microscope (SEM). In a 5-μm edge region along the longitudinal direction of the line pattern, the distances of actual edges from a reference line on which edges were to be present were measured on 50 points by means of a critical dimension SEM (model S-9380 manufactured by Hitachi, Ltd.). The standard deviation of measurements was determined, and 3σ was computed therefrom. The smaller the value thereof, the more favorable the performance exhibited.

<Storage Stability>

The line widths from the resists aged at 5, 25, 40 and 60° C. for 30 days were compared with that from the resist (reference resist) aged at 0° C. for 30 days, and the storage stability was evaluated by any line width differences therebetween. In particular, first, with respect to the resist aged at 0° C. for 30 days, the exposure amount (E₁) that reproduced a mask pattern of 45-nm line width (line/space:1/1) was determined. Subsequently, E₁ exposure was performed on each of four types of resist films aged at raised temperatures for 30 days. The line widths of thus obtained patterns were measured by means of a scanning electron microscope (model S-9380 manufactured by Hitachi, Ltd.), and pattern line width variations from the line width (45 nm) obtained from the reference resist were calculated. On the basis of thus obtained 4-point data, plotting was performed on a semilogarithmic graph wherein the X-axis indicated the reciprocal of aging temperature (absolute temperature) while the Y-axis indicated the line width variation per year (namely, 12 times the line width variation determined at aging for 30 days), and a collinear approximation was applied. On the thus obtained line, the Y-coordinate value corresponding to the aging temperature 25° C. was read. This value was denoted as the line width variation upon undisturbed storage at 25° C. for a year. The evaluation marks A, B and C were given when the line width variation upon one-year aging was 1 nm or less, in the range of 1 to 2 nm, and greater than 2 nm, respectively.

TABLE 3

| | | | | Basic com- | | | | | |
|---|---|---|---|---|---|---|---|---|---|
| | | Hydro- | Acid | pound/Low- | | Organic | Pattern | | |
| | Resin | phobic | gener- | molecurar | Sur- | solvent | col- | | Strage |
| Exam- | (A) | resin | ator | compound | factant | (mass | lapse | LER | sta- |
| ple | (2g) | (B)(mg) | (mg) | (D)(mg) | (mg) | ratio) | (nm) | (nm) | bility |
| 1 | P-1 | B-2 | z71 | TMEA | W-4 | S1-1/S2-1 | 36 | 5.9 | A |
| | | (40) | (600) | (10) | (2) | (8/2) | | | |
| 2 | P-2 | B-3 | z45 | D-52 | W-1 | S1-1/S2-1 | 35 | 6.1 | A |
| | | (40) | (500) | (6) | (3) | (6/4) | | | |
| 3 | P-3 | B-14 | z39 | TOA | W-4 | S1-1/S1-2 | 32 | 5.9 | A |
| | | (70) | (800) | (6) | (2) | (9/1) | | | |
| 4 | P-4 | B-21 | z71 | DIA | — | S1-1/S2-3 | 36 | 6.0 | A |
| | | (80) | (500) | (10) | | (9/1) | | | |
| 5 | P-5 | B-32 | z45 | PEA | W-2 | S1-1/S2-2 | 35 | 6.1 | A |
| | | (60) | (700) | (5) | (2) | (9/1) | | | |
| 6 | P-6 | B-39 | z81 | DHA | W-4 | S1-2/S2-1 | 36 | 6.0 | B |
| | | (40) | (500) | (14) | (2) | (6/4) | | | |
| 7 | P-7 | B-39 | z111 | D-13 | W-3 | S1-2/S1-3/ | 35 | 6.1 | A |
| | | (40) | (500) | (6) | (2) | S2-3 (8/1/1) | | | |
| 8 | P-8 | B-39 | z112 | DIA | W-4 | S1-1 | 34 | 5.8 | A |
| | | (40) | (500) | (10) | (2) | | | | |
| 9 | P-9 | B-42 | z29/z39 | PBI | W-5 | S1-1 | 33 | 5.8 | A |
| | | (50) | (400/200) | (8) | (1.5) | | | | |
| 10 | P-10 | B-50 | z71 | DIA | W-1/W-3 | S1-2/S2-3 | 33 | 6.0 | B |
| | | (80) | (600) | (7) | (1/1) | (9/1) | | | |
| 11 | P-11 | B-55 | z45 | TMEA | W-3 | S1-1/S2-1 | 32 | 6.1 | A |
| | | (30) | (600) | (12) | (2) | (8/2) | | | |
| 12 | P-1/P-3 | B-21 | z45 | DHA | W-2 | S1-1/S2-1 | 33 | 5.9 | A |
| | (1 g/1 g) | (30) | (600) | (10) | (3) | (8/2) | | | |
| 13 | P-1 | B-1/B-3 | z45 | DIA | W-5 | S1-1/S2-1 | 35 | 6.0 | A |
| | | (40/5) | (600) | (5) | (2) | (8/2) | | | |
| Com- | | Hydro- | Acid | | | Organic | Pattern | | |
| parative | Resin | phobic | gener- | Basic | Sur- | solvent | col- | | Strage |
| Exam- | (A) | resin | ator | compound | factant | (mass | lapse | LER | sta- |
| ple | (2g) | (B)(mg) | (mg) | (mg) | (mg) | ratio) | (nm) | (nm) | bility |
| 1 | PA-1 | B-2 | z45 | TMEA | W-4 | S1-1 | 40 | 6.5 | A |
| | | (40) | (500) | (8) | (2) | | | | |
| 2 | PA-2 | B-3 | z45 | TMEA | W-1 | S1-1/S2-1 | 44 | 6.9 | A |
| | | (40) | (500) | (8) | (2) | (8/2) | | | |
| 3 | PA-3 | B-3 | z45 | TMEA | W-1 | S1-1/S2-1 | 41 | 6.6 | B |
| | | (40) | (500) | (8) | (2) | (8/2) | | | |
| 4 | PA-4 | B-3 | z45 | TMEA | W-1 | S1-1/S2-1 | 42 | 6.8 | A |
| | | (40) | (500) | (8) | (2) | (8/2) | | | |

It is apparent from Table 3 above that the compositions used in the Examples exhibited favorable results in the pattern collapse and LER. It is also apparent that the storage stability is higher when the cyclic acid anhydride structure has a multicyclic structure than when the cyclic acid anhydride structure has a monocyclic structure (P-6, P-10).

What is claimed is:

1. An actinic ray- or radiation-sensitive resin composition comprising:
(A) a resin containing a repeating unit represented by general formula (1) below and a repeating unit that is decomposed by an action of an acid to generate an alkali-soluble group, and
(B) a compound that generates the acid when exposed to actinic rays or radiation, 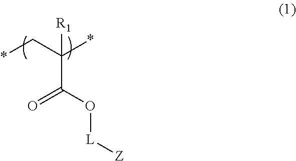
where
L represents a bivalent connecting group,
R₁ represents a hydrogen atom or an alkyl group, and
Z represents a cyclic acid anhydride structure.

2. The actinic ray- or radiation-sensitive resin composition according to claim 1, wherein L in the general formula (1) contains at least one oxygen atom.

3. The actinic ray- or radiation-sensitive resin composition according to claim 1, wherein Z in the general formula (1) contains a polycyclic structure.

4. The actinic ray- or radiation-sensitive resin composition according to claim 3, wherein Z in the general formula (1) is represented by general formula (2) below, 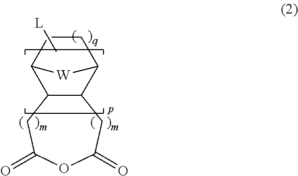
where
L is L of general formula (1) above,
W is absent or represents a methylene group, an ethylene group, an oxygen atom or a sulfur atom,
p represents an integer of 1 or greater,
q represents an integer of 0 to 2, and
each m independently represents an integer of 0 to 2.

5. The actinic ray- or radiation-sensitive resin composition according to claim 4, wherein Z in the general formula (1) is represented by general formula (3) below, 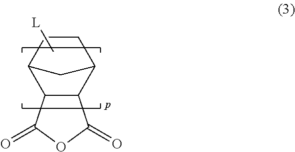
where
L is L of general formula (1) above, and
p is 1 or 2.

6. The actinic ray- or radiation-sensitive resin composition according to claim 1, wherein the resin (A) contains the repeating unit represented by the general formula (1) in an amount of 5 to 50 mol % and the repeating unit that is decomposed by an action of an acid to generate an alkali-soluble group in an amount of 30 to 70 mol %.

7. An actinic ray- or radiation-sensitive film comprising the actinic ray- or radiation-sensitive resin composition according to claim 1.

8. A method of forming a pattern, comprising:
forming an actinic ray- or radiation-sensitive film containing the actinic ray- or radiation-sensitive resin composition according to claim 1,
exposing the film to the actinic rays or radiation, and
developing the exposed film.

9. A process for manufacturing an electronic device comprising the method according to claim 8.

10. An electronic device manufactured by the process according to claim 9.

11. A compound represented by general formula (4) below, 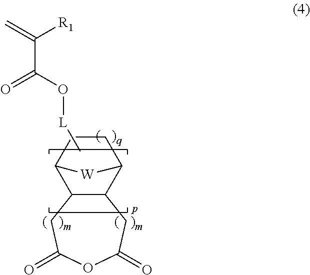
where
L represents a bivalent connecting group,
R₁ represents a hydrogen atom or an alkyl group,
W is absent or represents a methylene group, an ethylene group, an oxygen atom or a sulfur atom,
p represents an integer of 1 or greater,
q represents an integer of 0 to 2, and
each m independently represents an integer of 0 to 2.
